(19) United States
(12) Patent Application Publication
(10) Pub. No.: US 2026/0007073 A1
(43) Pub. Date: Jan. 1, 2026

(54) LIGHT-EMITTING ELEMENT, FUSED POLYCYCLIC COMPOUND FOR THE SAME, AND ELECTRONIC APPARATUS INCLUDING THE SAME

(71) Applicant: Samsung Display Co., Ltd., Yongin-si (KR)

(72) Inventors: MinJae SUNG, Yongin-si (KR); SUN YOUNG PAK, Yongin-si (KR); HYUN SHIN, Yongin-si (KR); Chihyun RYOO, Yongin-si (KR); Giwoong HAN, Yongin-si (KR); Seonhyoung HUR, Yongin-si (KR)

(73) Assignee: Samsung Display Co., Ltd., Yongin-si (KR)

(21) Appl. No.: 19/172,826

(22) Filed: Apr. 8, 2025

(30) Foreign Application Priority Data
Jun. 27, 2024 (KR) 10-2024-0084585

(51) Int. Cl. H10K 85/60; C07F 5/02; C09K 11/02; C09K 11/06; H10K 50/11; H10K 59/38; H10K 85/30; H10K 85/40; H10K 101/00

(52) U.S. Cl. CPC H10K 85/658; C07F 5/027; C09K 11/02; C09K 11/06; H10K 85/346; H10K 85/40; H10K 85/654; H10K 85/657; H10K 85/6572; C09K 2211/1007; C09K 2211/1018; H10K 50/11; H10K 59/38; H10K 2101/90

(57) ABSTRACT

Embodiments provide a fused polycyclic compound, a light-emitting element that includes the fused polycyclic compound, and an electronic apparatus that includes the light-emitting element. The light-emitting element includes a first electrode, a second electrode disposed on the first electrode, and an emission layer disposed between the first electrode and the second electrode, wherein the emission layer includes the fused polycyclic compound. The fused polycyclic compound is represented by Formula 1, which is explained in the specification:

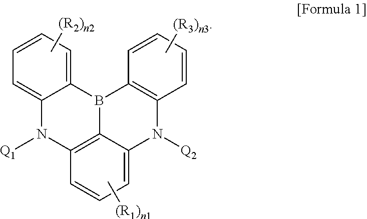

### CROSS-REFERENCE TO RELATED APPLICATION(S)

This application claims priority to and benefits of Korean Patent Application No. 10-2024-0084585 under 35 U.S.C. § 119, filed on Jun. 27, 2024, in the Korean Intellectual Property Office, the entire contents of which are incorporated herein by reference.

### BACKGROUND

### 1. Technical Field

The disclosure relates to a light-emitting element, a fused polycyclic compound for the light-emitting element, and an electronic apparatus including the light-emitting element.

### 2. Description of the Related Art

An electronic apparatus may include a display device that displays an image. Ongoing development continues for an organic electroluminescence display device as an image display device. In contrast to liquid display devices, organic electroluminescence display device are so-called self-emissive display devices in which holes and electrons respectively injected from a first electrode and a second electrode recombine in an emission layer, so that in the emission layer, an emission material, which contains an organic compound, emits light to achieve display.

In the application of an organic electroluminescence element to a display device, there is a persistent demand for improvements in low-driving voltage, high luminous efficiency, and long lifespan. Thus, continuous development is required for materials for an organic electroluminescence element that are capable of stably achieving such characteristics.

In order to implement an organic electroluminescence element having high efficiency, technologies pertaining to phosphorescent emission, which utilizes triplet state energy, or pertaining to fluorescent emission, which uses triplet-triplet annihilation (TTA) in which a singlet exciton is generated by the collision of triplet excitons, are under development. Research and development are presently directed to materials for thermally activated delayed fluorescence (TADF) that utilize delayed fluorescence phenomena.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light-emitting element having improved luminous efficiency and element lifespan.

The disclosure also provides a fused polycyclic compound capable of improving luminous efficiency and element lifespan of a light-emitting element.

The disclosure also provides an electronic apparatus including a light-emitting element having improved luminous efficiency and lifespan, thereby having excellent display quality.

According to an embodiment a light-emitting element may include a first electrode, a second electrode disposed on the first electrode, and at least one functional layer disposed between the first electrode and the second electrode, wherein the at least one functional layer includes a first compound represented by Formula 1:

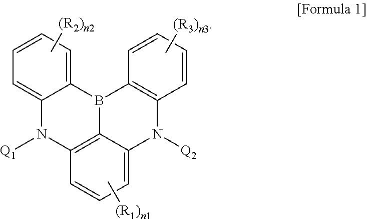

In Formula 1, R₁ to R₃ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring; n1 may be an integer from 0 to 3; n2 and n3 may each independently be an integer from 0 to 4; and Q₁ and Q₂ may each independently be a group represented by Formula 2 or Formula 3:

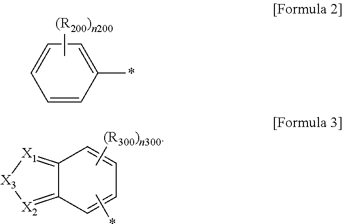

In Formula 2 and Formula 3, R₂₀₀ and R₃₀₀ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring; n200 may be an integer from 1 to 5; n300 may be an integer from 0 to 3; X₁ and X₂ may each independently be N or P; and X₃ may be O or S. In Formula 1, if Q₁ and Q₂ are each a group represented by Formula 2, among Q₁ and Q₂, at least one of R₂₀₀ may each independently be a group represented by Formula 3; in Formula 2, —* represents a bond to Formula 1; and in Formula 3, —* represents a bond to Formula 1 or Formula 2.

In an embodiment, a group represented by Formula 2 may be a group represented by Formula 2-a:

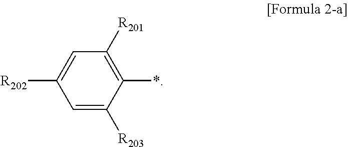

In Formula 2-a, R₂₀₁ to R₂₀₃ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring, and —* represents a bond to Formula 1.

In an embodiment, in Formula 2-a, R₂₀₂ may be a substituted or unsubstituted t-butyl group or a substituted or unsubstituted phenyl group.

In an embodiment, a group represented by Formula 2 may be a group represented by Formula 2-b:

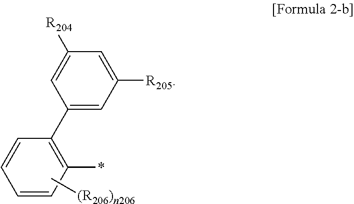

In Formula 2-b, R₂₀₄ and R₂₀₅ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons; R₂₀₆ may be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring; n206 may be an integer from 0 to 4; and —* represents a bond to Formula 1.

In an embodiment, a group represented by Formula 2 may be a group represented by Formula 2-c1, Formula 2-c2, Formula 2-d1, or Formula 2-d2:

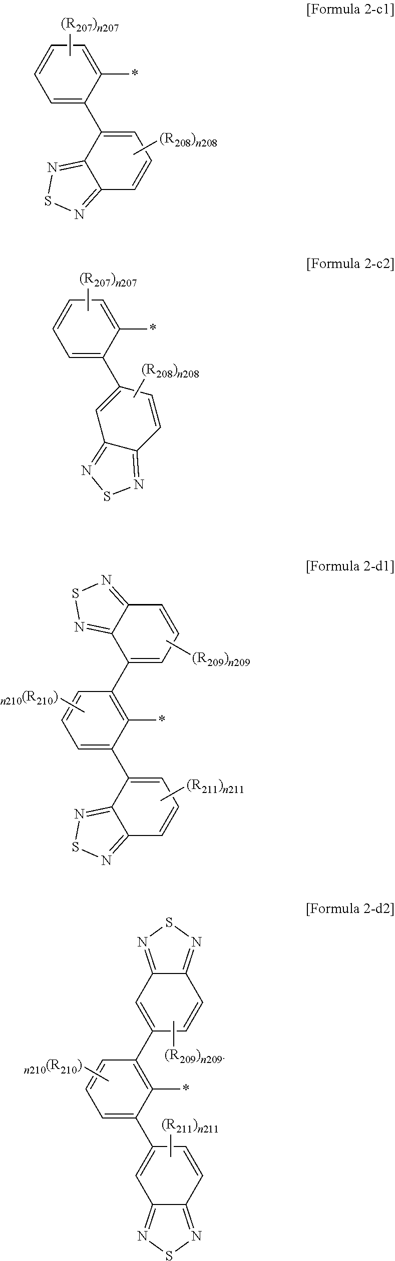

In Formula 2-cl, Formula 2-c2, Formula 2-d1, and Formula 2-d2, R₂₀₇ to R₂₁₁ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring; n207 may be an integer from 0 to 4; n208 to n211 may each independently be an integer from 0 to 3; and —* represents a bond to Formula 1.

In an embodiment, a group represented by Formula 2 may be a group represented by Formula 2-e:

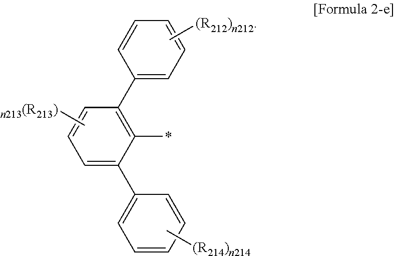

In Formula 2-e, R₂₁₂ to R₂₁₄ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring; n212 and n214 may each independently be an integer from 0 to 5; n213 may be an integer from 0 to 3; and —* represents a bond to Formula 1.

In an embodiment, a group represented by Formula 2 may be a group represented by Formula 2-f:

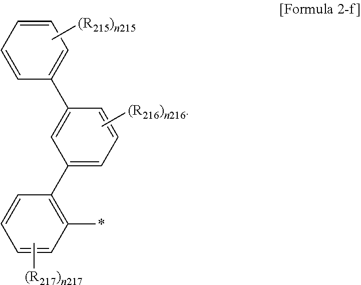

In Formula 2-f, R₂₁₅ to R₂₁₇ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring; n215 may be an integer from 0 to 5; n216 and n217 may each independently be an integer from 0 to 4; and —* represents a bond to Formula 1.

In an embodiment, a group represented by Formula 2 may be a group represented by Formula 2-g1 or Formula 2-g2:

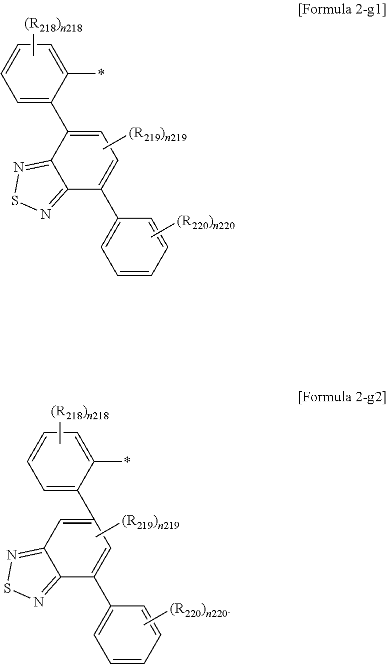

In Formula 2-gi and Formula 2-g2, R₂₁₈ to R₂₂₀ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring; n218 may be an integer from 0 to 4; n219 may be an integer from 0 to 2; n220 may be an integer from 0 to 5; and —* represents a bond to Formula 1.

In an embodiment, in Formula 3, X₁ and X₂ may each be N, and X₃ may be S.

In an embodiment, a group represented by Formula 3 may be a group represented by Formula 3-a or Formula 3-b:

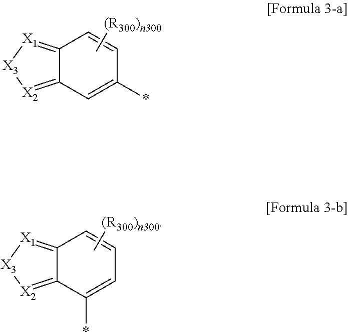

In Formula 3-a and Formula 3-b, X₁ to X₃, R₃₀₀, and n300 are the same as defined in Formula 3; and —* represents a bond to Formula 1 or Formula 2.

In an embodiment, a group represented by Formula 3 may be a group represented by Formula 3-c:

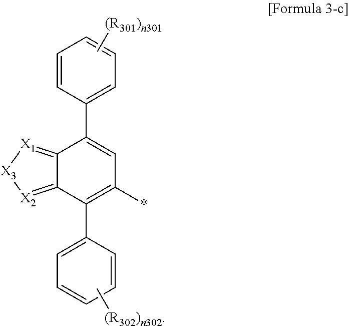

In Formula 3-c, R₃₀₁ and R₃₀₂ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring; n301 and n302 may each independently be an integer from 0 to 5; X₁ to X₃ are the same as defined in Formula 3; and —* represents a bond to Formula 1 or Formula 2.

In an embodiment, the first compound represented by Formula 1 may be represented by Formula 4:

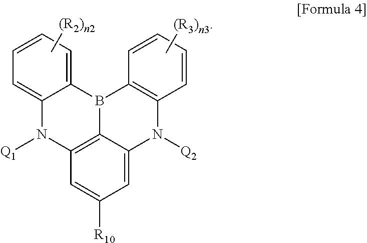

In Formula 4, R₁₀ may be a substituted or unsubstituted alkyl group having 1 to 60 carbons or a substituted or unsubstituted aryl group having 6 to 60 ring-forming carbons; and R₂, R₃, Q₁, Q₂, n2, and n3 are the same as defined in Formula 1.

In an embodiment, in Formula 1, R₁ may be a substituted or unsubstituted t-butyl group or a substituted or unsubstituted phenyl group.

In an embodiment, the first compound represented by Formula 1 may be represented by one of Formula 5-1 to Formula 5-3:

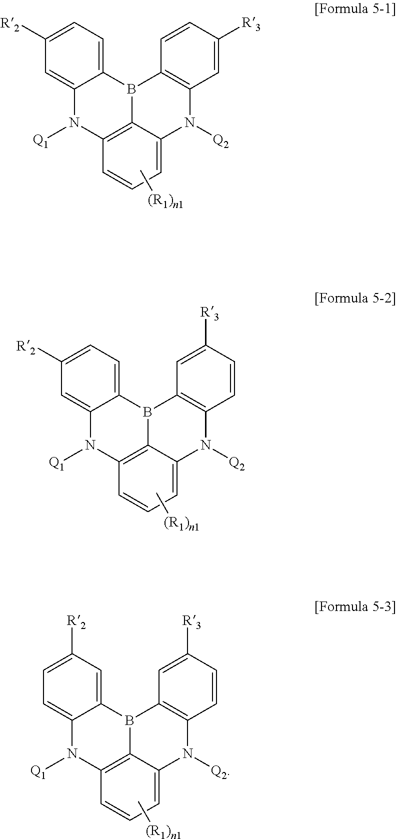

In Formula 5-1 to Formula 5-3, R′₂ and R′₃ may each independently be a substituted or unsubstituted aryl group having 6 to 60 ring-forming carbons, or a substituted or unsubstituted heteroaryl group having 2 to 60 ring-forming carbons; and R₁, Q₁, Q₂, and n1 are the same as defined in Formula 1.

In an embodiment, in Formula 1, R₂ and R₃, may each independently be a hydrogen atom, a substituted or unsubstituted phenyl group, or a substituted or unsubstituted carbazole group.

In an embodiment, the at least one functional layer may include an emission layer; and the emission layer may include the first compound, and at least one of a second compound represented by Formula HT-1, a third compound represented by Formula ET-1, and a fourth compound represented by Formula D-1.

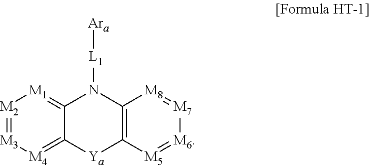

In Formula HT-1, M₁ to M₈ may each independently be N or C(R₅₁); L₁ may be a direct linkage, a substituted or unsubstituted arylene group having 6 to 30 ring-forming carbons, or a substituted or unsubstituted heteroarylene group having 2 to 30 ring-forming carbons; Yₐ may be a direct linkage, C(R₅₂)(R₅₃), or Si(R₅₄)(R₅₅); Arₐ may be a substituted or unsubstituted aryl group having 6 to 30 ring-forming carbons or a substituted or unsubstituted heteroaryl group having 2 to 30 ring-forming carbons; and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, or bonded to an adjacent group to form a ring.

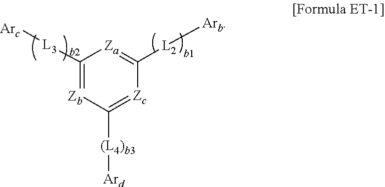

In Formula ET-1, at least one of Zₐ to Zₑ may be N; the remainder of Zₐ to Zₑ may each independently be C(R₅₆); R₅₆ may be a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons; b1 to b3 may each independently be an integer from 0 to 10; Ar_{b} to Ar_{d} may each independently be a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons; and L₂ to L₄ may each independently be a direct linkage, a substituted or unsubstituted arylene group having 6 to 30 ring-forming carbons, or a substituted or unsubstituted heteroarylene group having 2 to 30 ring-forming carbons.

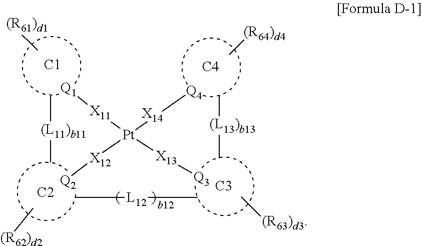

In Formula D-1, Q₁ to Q₄ may each independently be C or N; C1 to C4 may each independently be a substituted or unsubstituted hydrocarbon ring having 5 to 30 ring-forming carbons or a substituted or unsubstituted heterocycle having 2 to 30 ring-forming carbons; X₁₁ to X₁₄ may each independently be a direct linkage or *—O—*; L₁₁ to L₁₃ may each independently be a direct linkage, *—O—*, *—S—*,

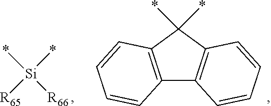

a substituted or unsubstituted alkylene group having 1 to 20 carbons, a substituted or unsubstituted arylene group having 6 to 30 ring-forming carbons, or a substituted heteroarylene group having 2 to 30 ring-forming carbons; b11 to b13 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a s unsubstituted or unsubstituted alkynyl group having 2 to 20 carbons, a substituted or unsubstituted aryl group having 6 to 60 ring-forming carbons, or a substituted or unsubstituted heretoaryl group having 2 to 60 ring-forming carbons; and d1 to d4 may each independently be an integer from 0 to 4.

According to an embodiment, an electronic apparatus may include a circuit layer disposed on a base layer, and a display element layer disposed on the circuit layer and including the light-emitting element, wherein the light-emitting element may include a first electrode, a second electrode disposed on the first electrode, and an emission layer disposed between the first electrode and the second electrode, and the emission layer includes a first compound represented by Formula 1, which is explained herein.

In an embodiment, the electronic apparatus may further include an optical control layer disposed on a display element layer and including a quantum dot, wherein the light-emitting element may emit a first color light, and the optical control layer may include a first optical control part that includes a first quantum dot that converts the first color light to a second color light in a longer wavelength region than the first color light, a second optical control part that includes a second quantum dot that converts the first color light to a third color light in a longer wavelength region than the first color light and the second color light, and a third optical control part that transmits the first color light.

In an embodiment, the electronic apparatus may further include a color filter layer disposed on the optical control layer, wherein the color filter layer may include a first filter that transmits the second color light, a second filter that transmits the third color light, and a third filter that transmits the first color light.

According to an embodiment, a fused polycyclic compound may be represented by Formula 1, which is explained herein.

In an embodiment, a group represented by Formula 2 may be a group represented by Formula 2-a, which is explained herein.

In an embodiment, a group represented by Formula 2 may be a group represented by Formula 2-c1, Formula 2-c2, Formula 2-d1, or Formula 2-d2, which are explained herein.

In an embodiment, the fused polycyclic compound represented by Formula 1 may be selected from Compound Group 1, which is explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment, illustrating a section taken along virtual line I-I′ in FIG. 1;

FIG. 3 to FIG. 6 are each a schematic cross-sectional of a light-emitting element according to an embodiment;

FIG. 7 and FIG. 8 are each a schematic cross-sectional view of a display device according to an embodiment;

FIG. 9 is a schematic cross-sectional view of a display device according to an embodiment;

FIG. 10 is a schematic cross-sectional view of a display device according to an embodiment;

FIG. 11 is a schematic diagram of an interior of a vehicle in which a display device according to an embodiment is disposed;

FIG. 12 is a schematic perspective view of an electronic apparatus according to an embodiment;

FIG. 13 is an exploded schematic perspective view of an electronic apparatus according to an embodiment;

FIG. 14 is a block diagram of an electronic apparatus according to an embodiment;

FIG. 15 is a schematic diagram of electronic apparatuses according to embodiments; and

FIG. 16 is a schematic diagram of electronic apparatuses according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC.

When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, ±10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may refer to a group that is bonded to an adjacent group to form a substituted or unsubstituted hydrocarbon ring or a substituted or unsubstituted heterocycle. A hydrocarbon ring may be aliphatic or aromatic. A heterocycle may be aliphatic or aromatic. A hydrocarbon ring and a heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbons in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbons in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 50, 6 to 40, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

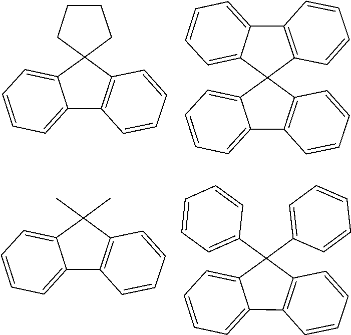

In the specification, a heterocyclic group may be any functional group or substituent derived from a ring that includes at least one of B, O, N, P, S, Si, and Se as a heteroatom. A heterocyclic group may be aliphatic heterocyclic group or aromatic. An aromatic heterocyclic group may be a heteroaryl group. An aliphatic heterocycle and an aromatic heterocycle may each independently be monocyclic or polycyclic.

If a heterocyclic group contains two or more heteroatoms, the two or more heteroatoms may be the same as or different from each other. The number of ring-forming carbon atoms in a heterocyclic group may be 2 to 60, 2 to 50, 2 to 40, 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in an acyl group (or carbonyl group) is not particularly limited, and may be 1 to 40, 1 to 30, 1 to 20, or 1 to 10. Examples of an acyl group may include an acetyl group, an ethylcarbonyl group, an isopropylcarbonyl group, a naphthylenecarbonyl group, a cyclopentylcarbonyl group, a cyclohexylcarbonyl group, a phenylcarbonyl group, etc., but embodiments are not limited thereto. For example, an acyl group

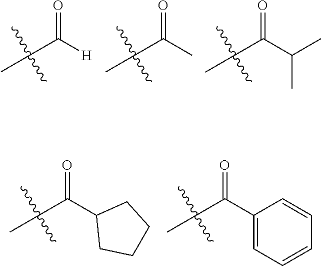

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or to an aryl group as defined above. An oxy group may be an alkoxy group or an aryl oxy group.

An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or to an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group.

Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

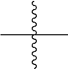

and —* each represent a bond to a neighboring atom in a corresponding formula or moiety.

Hereinafter, embodiments will be described with reference to the accompanying drawings.

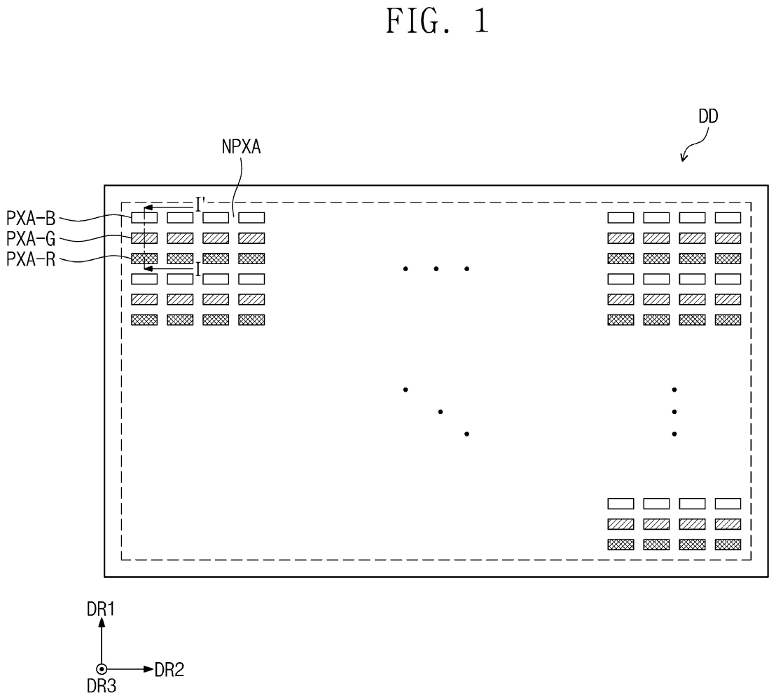

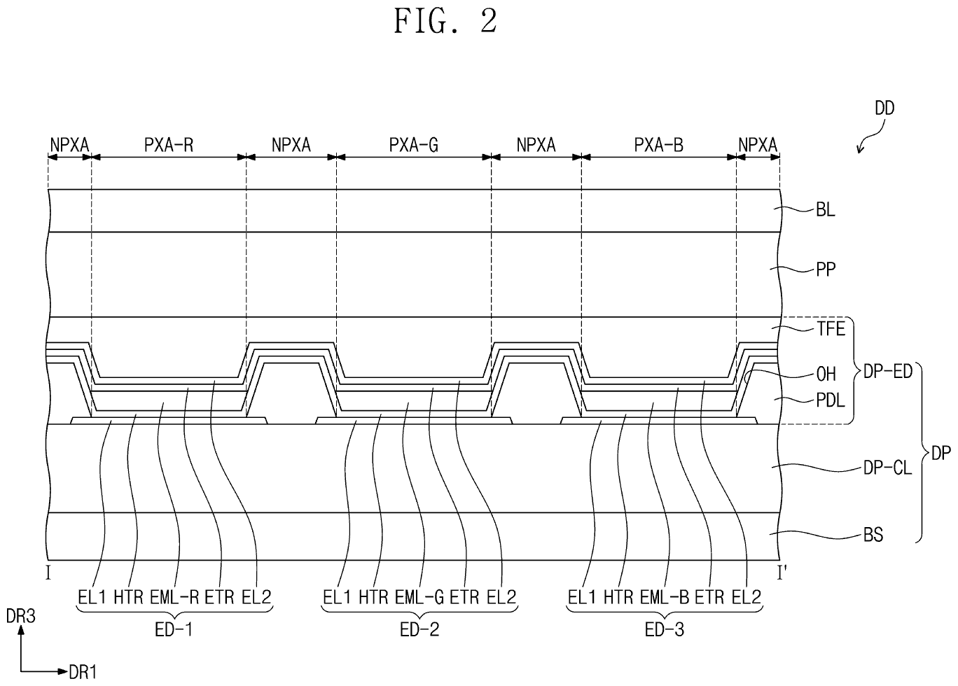

FIG. 1 is a schematic plan view of a display device DD according to an embodiment. FIG. 2 is a schematic cross-sectional view of the display device DD according to an embodiment. FIG. 2 is a schematic cross-sectional view of a portion taken along virtual line I-I′ in FIG. 1.

Hereinafter, components included in the display device DD according to an embodiment will be described with reference to FIGS. 1 and 2.

The display device DD may include a display panel DP and an optical layer PP disposed on the display panel DP. The display panel DP includes light-emitting elements ED-1, ED-2, and ED-3. The display device DD may include multiples of each of the light-emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer.

The filling layer (not shown) may include at least one of an acrylic-based resin, a silicone-based resin, and an epoxy-based resin.

The display panel DP may include a base layer BS, a circuit layer DP-CL provided on the base layer BS, and the display element layer DP-ED. The display element layer DP-ED may include a pixel defining film PDL, light-emitting elements ED-1, ED-2, and ED-3 disposed between portions of the pixel defining film PDL, and an encapsulation layer TFE disposed on the light-emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light-emitting elements ED-1, ED-2, and ED-3 of the display element layer DP-ED.

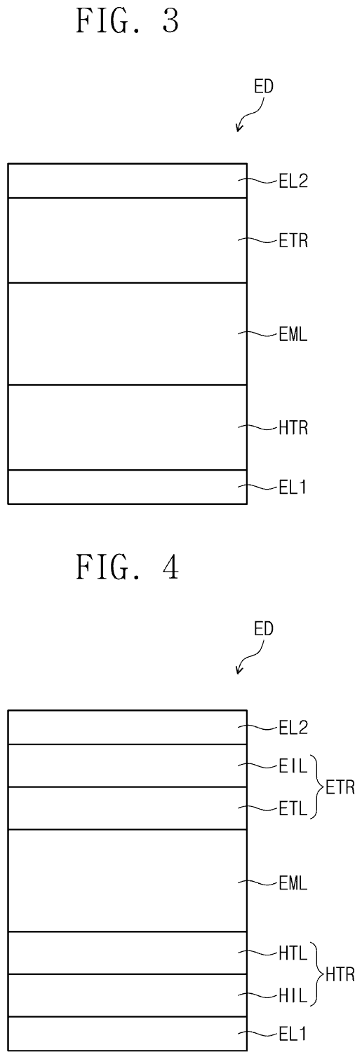

The light-emitting elements ED-1, ED-2, and ED-3 may each have a structure of a light-emitting element ED of an embodiment according to any of FIGS. 3 to 6, which will be described later. The light-emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light-emitting elements ED-1, ED-2, and ED-3 are disposed in openings OH defined in the pixel defining film PDL, and the hole transport region HTR, the electron transport region ETR, and the second electrode EL2 are each provided as a common layer for the light-emitting elements ED-1, ED-2, and ED-3. However, embodiments are not limited thereto. Although not shown in FIG. 2, in an embodiment, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of light-emitting elements ED-1, ED-2, and ED-3 may be provided by being patterned through an inkjet printing method.

The encapsulation layer TFE may cover the light-emitting elements ED-1, ED-2, and ED-3. The encapsulation layer TFE may seal the display element layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display element layer DP-ED from moisture and/or oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light emitting devices ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be areas between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light-emitting elements ED-1, ED-2, and ED-3. The emission layers EML-R, EML-G, and EML-B of the light-emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light-emitting elements ED-1, ED-2, and ED-3.

In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light-emitting elements ED-1, ED-2, and ED-3 may emit light having wavelengths that are different from each other. For example, in an embodiment, the display device DD may include a first light-emitting element ED-1 that emits red light, a second light-emitting element ED-2 that emits green light, and a third light-emitting element ED-3 that emits blue light. For example, the red light emitting region PXA-R, the green light emitting region PXA-G, and the blue light emitting region PXA-B of the display device DD may respectively correspond to the first light-emitting element ED-1, the second light-emitting element ED-2, and the third light-emitting element ED-3.

However, embodiments are not limited thereto, and the first to third light light-emitting elements ED-1, ED-2, and ED-3 may emit light in a same wavelength range, or at least one light emitting device may emit light in a wavelength range that is different from the remainder. For example, the first to third light-emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel™)

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIGS. 3 to 6 are each a schematic cross-sectional view of a light-emitting element ED according to embodiments. The light-emitting elements ED according to embodiments may each include a first electrode EL1, a second electrode EL2 facing the first electrode EL1, and at least one functional layer disposed between the first electrode EL1 and the second electrode EL2. The light-emitting element ED according to an embodiment may include a fused polycyclic compound according to an embodiment, which will be described below, in the at least one functional layer.

The light-emitting element ED may include, as at least one functional layer, a hole transport region HTR, an emission layer EML, and an electron transport region ETR, which are stacked. Referring to FIG. 3, the light-emitting element ED according to an embodiment may include a first electrode EL1, a hole transport region HTR, an emission layer EML, an electron transport region ETR, and a second electrode EL2, which are stacked in that order.

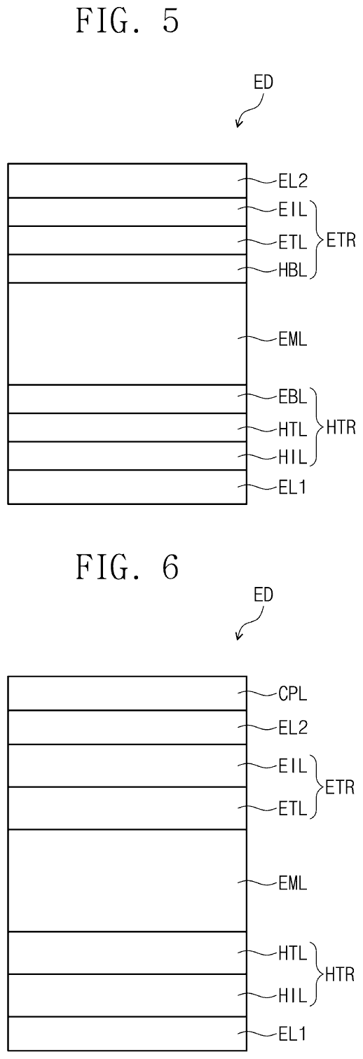

In comparison to FIG. 3, FIG. 4 is a schematic cross-sectional view of a light-emitting element ED, in which the hole transport region HTR includes a hole injection layer HIL and a hole transport layer HTL, and the electron transport region ETR includes an electron injection layer EIL and an electron transport layer ETL. In comparison to FIG. 3, FIG. 5 is a schematic cross-sectional view of a light-emitting element ED, in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. In comparison to FIG. 4, FIG. 6 is a schematic cross-sectional view of a light-emitting element ED that further includes a capping layer CPL disposed on the second electrode EL2.

The light-emitting element ED may include a fused polycyclic compound according to an embodiment, which will be described below, in the at least one functional layer included therein.

The light-emitting element ED may include the fused polycyclic compound according to an embodiment in at least one of the hole transport region HTR, the emission layer EML, and the electron transport region ETR. For example, the emission layer EML may include the fused polycyclic compound according to an embodiment.

The first electrode ELI has conductivity. The first electrode ELI may be formed of a metal material, a metal alloy, or a conductive compound. The first electrode EL1 may be an anode or a cathode. However, embodiments are not limited thereto. In an embodiment, the first electrode ELI may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode ELI may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayered structure including a reflective film or a transflective film formed of the above-described materials, and a transparent conductive film formed of ITO, IZO, ZnO, ITZO, etc. For example, the first electrode EL1 may have a three-layered structure of ITO/Ag/ITO, but embodiments are not limited thereto. In an embodiment, the first electrode EL1 may include the above-described metal materials, combinations of at least two of the above-described metal materials, oxides of the above-described metal materials, or the like.

A thickness of the first electrode ELI may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may have a structure consisting of a layer consisting of a single material, a structure consisting of a layer including different materials, or a structure including multiple layers including different materials.

For example, the hole transport region HTR may have a single-layered structure of a hole injection layer HIL or a hole transport layer HTL, or may have a single-layered structure formed of a hole injection material and a hole transport material. In embodiments, the hole transport region HTR may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respectively stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light-emitting element ED according to an embodiment, the hole transport region HTR may include a compound represented by Formula H-1:

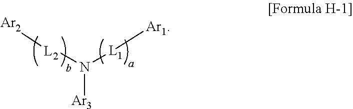

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ or multiple L₂ may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and a compound represented by Formula H-1 is not limited to Compound Group H:

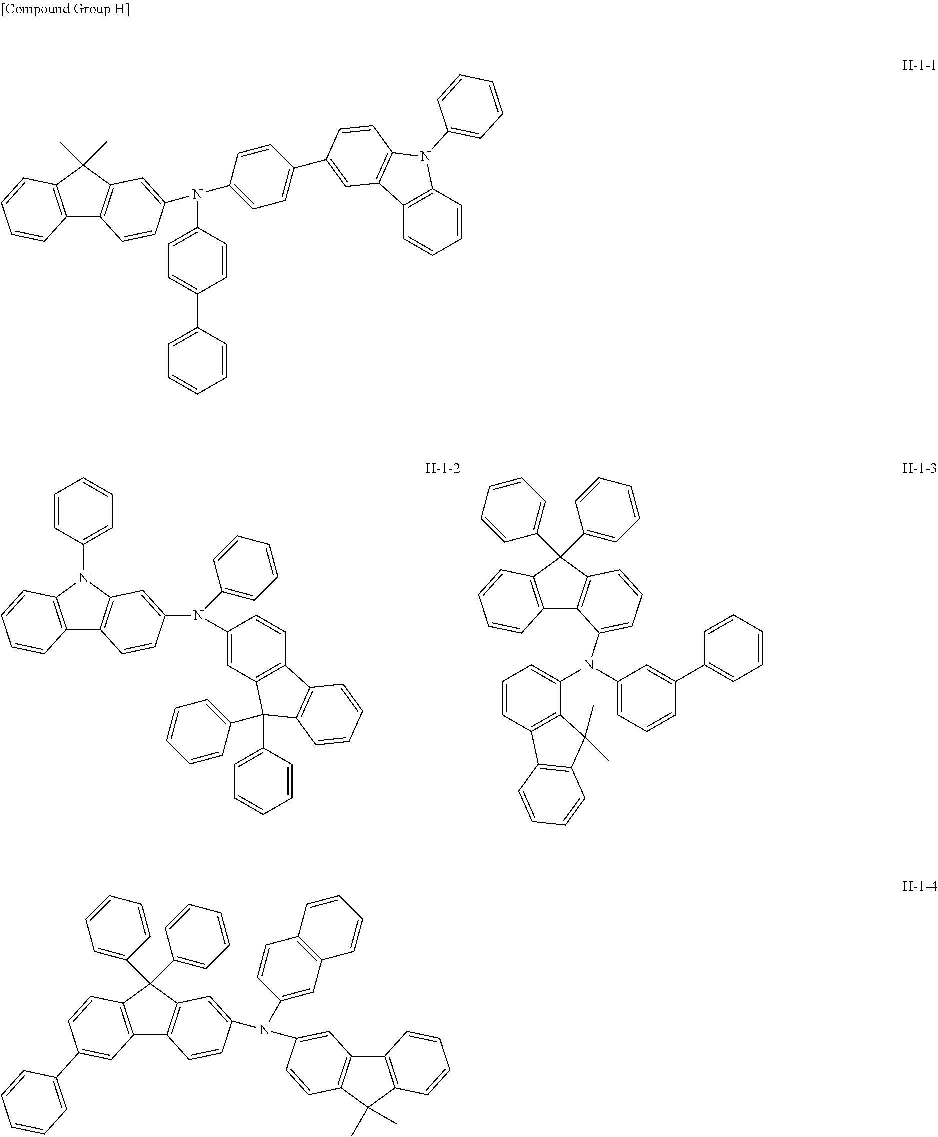 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

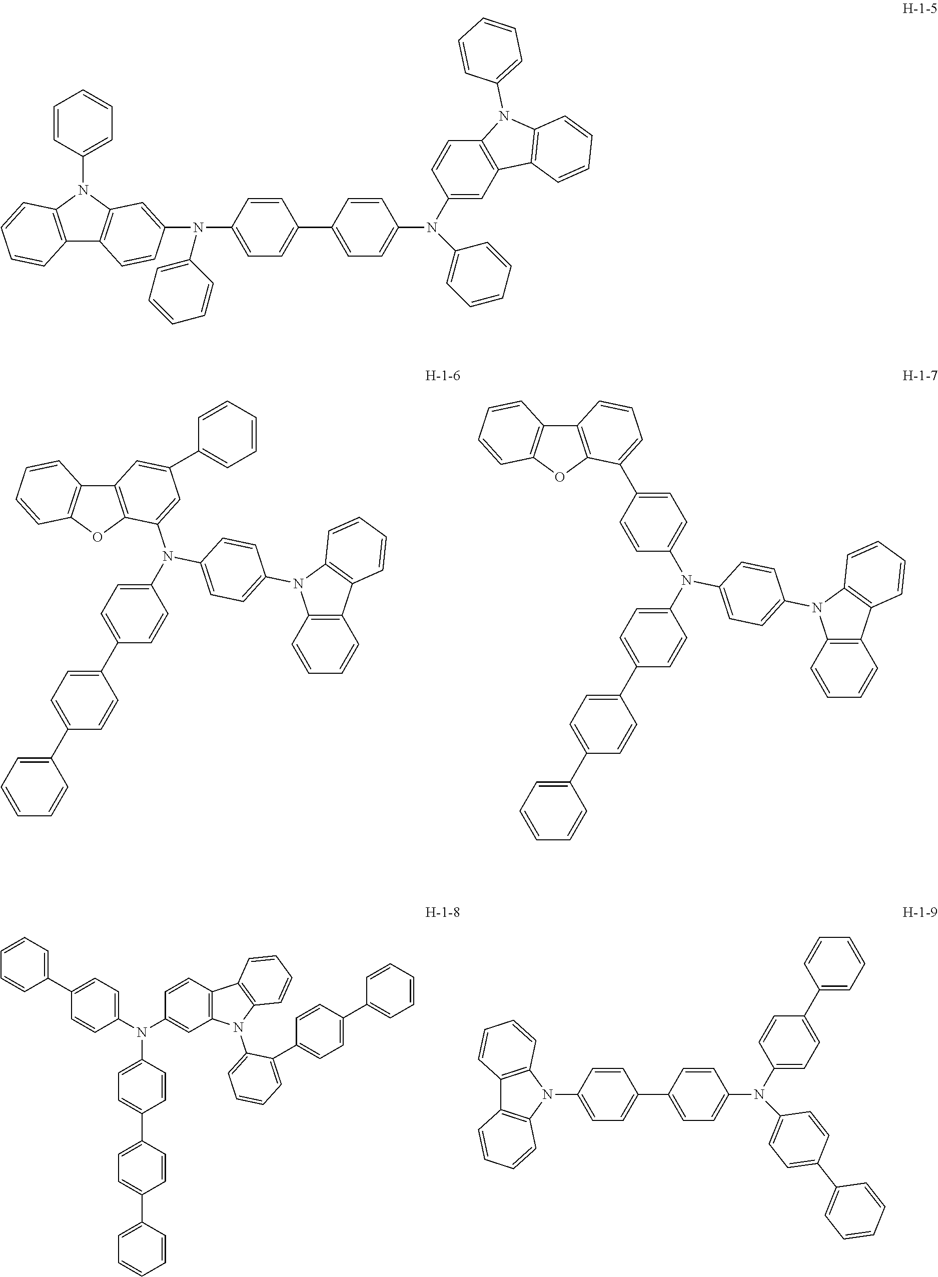 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

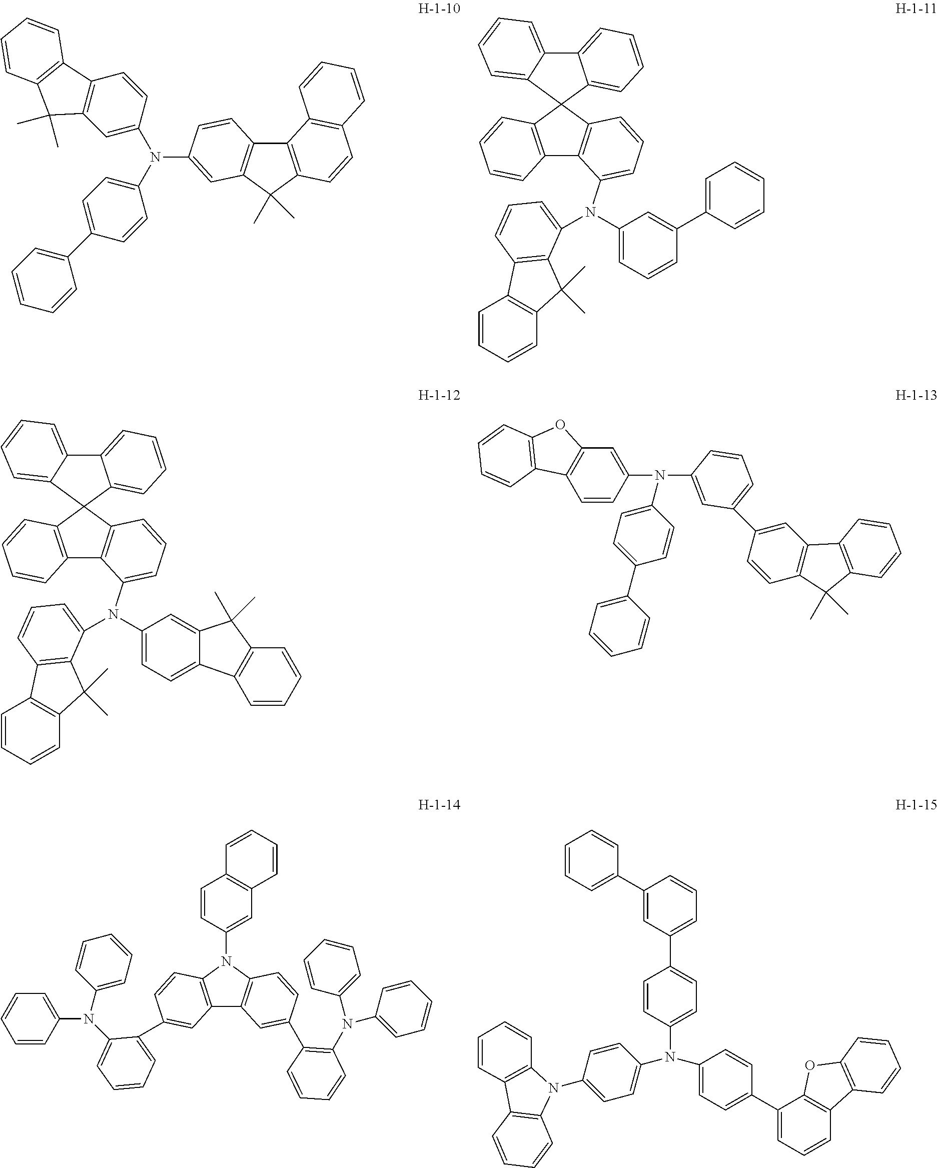

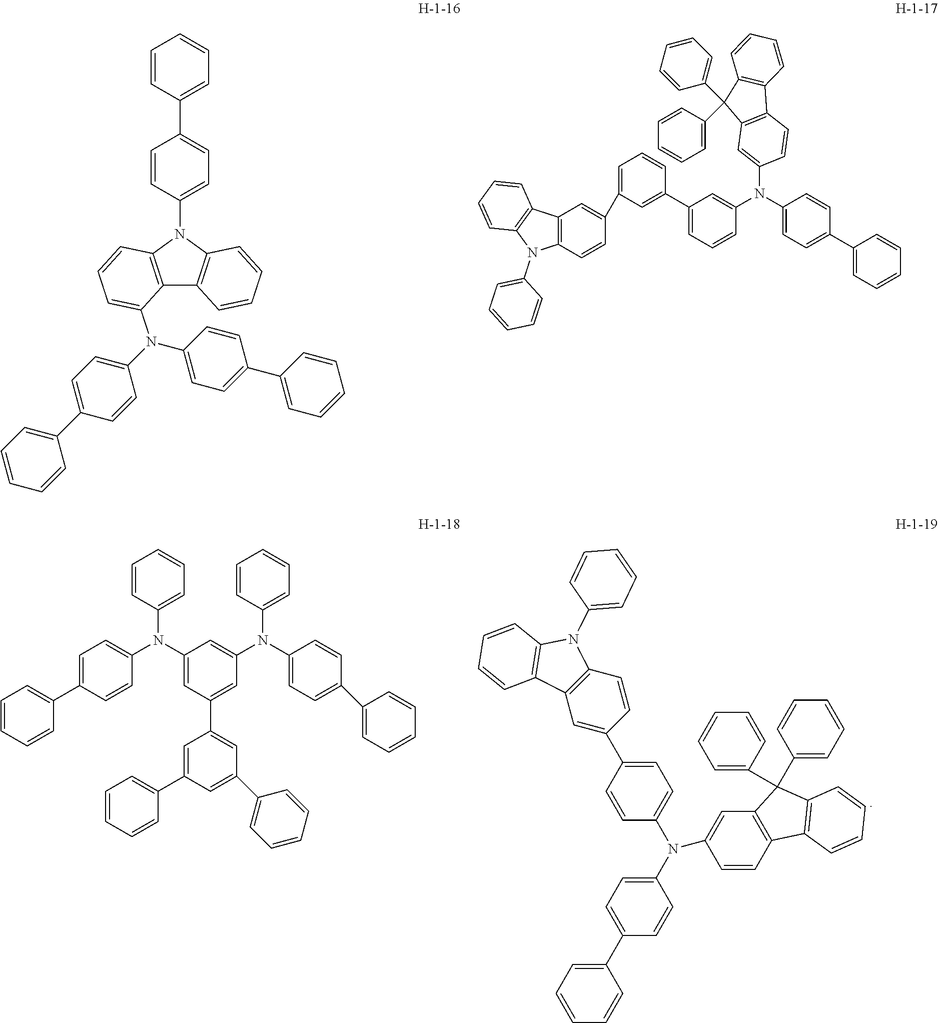 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[11,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7 ′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material in the buffer layer (not shown). The electron blocking layer EBL may prevent the injection of electrons from an electron transport region ETR to the hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may have a structure consisting of a layer consisting of a single material, a structure consisting of a layer including different materials, or a structure including multiple layers including different materials.

A light-emitting element ED according to an embodiment may include a fused polycyclic compound represented by Formula 1 in at least one functional layer disposed between a first electrode EL1 and a second electrode EL2. In the light-emitting element ED, an emission layer EML may include a fused polycyclic compound according to an embodiment. In an embodiment, the emission layer EML may include the fused polycyclic compound as a dopant. The fused polycyclic compound according may be a dopant material of the emission layer EML. In the specification, the fused polycyclic compound according to an embodiment may be referred to as a first compound.

The fused polycyclic compound includes a core that includes a nitrogen atom. The core may be represented by Formula x. The core has a fused polycyclic structure that includes a boron atom, two nitrogen atoms, and three benzene rings. The core has a structure in which first to third aromatic rings are fused via a boron atom, a first nitrogen atom, and a second nitrogen atom. The first aromatic ring and the second aromatic ring are connected via the boron atom. The first aromatic ring and the third aromatic ring are connected via the boron atom and the first nitrogen atom. The second aromatic ring and the third aromatic ring are connected via the boron atom and the second nitrogen atom.

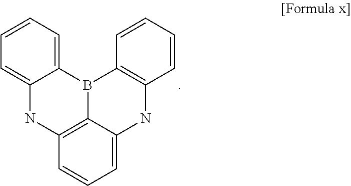 [SMILES: c1ccc2c(c1)Nc1cccc3c1B2c1ccccc1N3]

The fused polycyclic compound according to an embodiment may be represented by Formula 1:

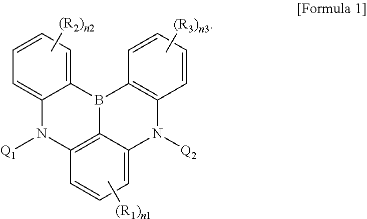

The fused polycyclic compound represented by Formula 1 includes a core represented by Formula x as described above. In Formula 1, an aromatic ring substituted with R₂ is the first aromatic ring, an aromatic ring substituted with R₃ is the second aromatic ring, an aromatic ring substituted with R₁ is the third aromatic ring, a nitrogen atom substituted with Q₁ is the first nitrogen atom, and a nitrogen atom substituted with Q₂ is the second nitrogen atom.

In Formula 1, R₁ to R₃ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring. As described above, a ring may be formed by bonding adjacent groups together by a chemical bond. For example, the substituents of two carbon atoms that are adjacent to each other in a benzene ring may be bonded to each other to form a thiadiazole group.

For example, R₁ may be a substituted or unsubstituted alkyl group having 1 to 60 carbons, or a substituted or unsubstituted aryl group having 6 to 60 ring-forming carbons. In an embodiment, in Formula 1, R₁ may be a substituted or unsubstituted t-butyl group or a substituted or unsubstituted phenyl group. For example, R₁ may be an unsubstituted t-butyl group or an unsubstituted phenyl group. For example, R₂ and R₃ may each independently be a hydrogen atom, a substituted or unsubstituted aryl group having 6 to 60 ring-forming carbons, or a substituted or unsubstituted heteroaryl group having 2 to 60 ring-forming carbons. In an embodiment, in Formula 1, R₂ and R₃ may each independently be a hydrogen atom, a substituted or unsubstituted phenyl group, or a substituted or unsubstituted carbazole group. For example, R₂ and R₃ may each independently be an unsubstituted phenyl group or an unsubstituted carbazole group.

In Formula 1, n1 may be an integer from 0 to 3. If n1 is 0, the fused polycyclic compound may not be substituted with R₁. A case where n1 is 3 and three R₁ groups are all hydrogen atoms may be the same as a case where n1 is 0. If n1 is 2 or more, multiple R₁ may all be the same, or at least one thereof may be different from the remainder.

In Formula 1, n2 and n3 may each independently be an integer from 0 to 4. If n2 is 0, the fused polycyclic compound may not be substituted with R₂. A case where n2 is 4 and four R₂ groups are all hydrogen atoms may be the same as a case where n2 is 0. If n2 is 2 or more, multiple R₂ may all be the same, or at least one thereof may be different from the remainder. If n3 is 0, the fused polycyclic compound may not be substituted with R₃. A case where n3 is 4 and four R₃ groups are all hydrogen atoms may be the same as a case where n3 is 0. If n3 is 2 or more, multiple R₃ may all be the same, or at least one thereof may be different from the remainder.

In Formula 1, Q₁ and Q₂ may each independently be a group represented by Formula 2 or Formula 3:

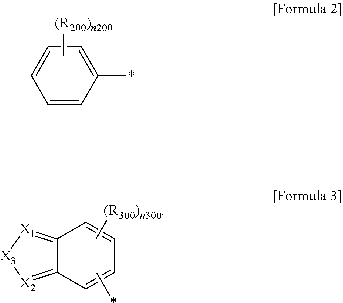

In Formula 2 and Formula 3, R₂₀₀ and R₃₀₀ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring.

In Formula 2, n200 may be an integer from 1 to 5. If n200 is 2 or more, multiple R₂₀₀ may all be the same, or at least one thereof may be different from the remainder. In Formula 3, n300 may be an integer from 0 to 3. If n300 is 0, the fused polycyclic compound may not be substituted with R₃₀₀. A case where n300 is 3 and three R₃₀₀ group are all hydrogen atoms may be the same as a case where n300 is 0. If n300 is 2 or more, multiple R₃₀₀ may all be the same, or at least one thereof may be different from the remainder.

In Formula 3, X₁ and X₂ may each independently be N or P; and X₃ may be O or S. In an embodiment, in Formula 3, X₁ and X₂ may each be N, and X₃ may be S.

In Formula 1, if Q₁ and Q₂ are each a group represented by Formula 2, among Q₁ and Q₂, at least one of R₂₀₀ may each independently be a group represented by Formula 3. In Formula 2, —* represents a bond to Formula 1. In Formula 3, —* represents a bond to Formula 1 or Formula 2.

Since the fused polycyclic compound according to embodiments includes at least one group represented by Formula 3, an electron cloud of the core represented by Formula x may be concentrated on a center of the core, and an energy bandgap may increase, and thus color purity may be improved and reverse intersystem crossing may readily occur due to high triplet energy. Therefore, the light-emitting element according to embodiments may have improved luminous efficiency and lifespan.

In an embodiment, a group represented by Formula 2 may be a group represented by Formula 2-a:

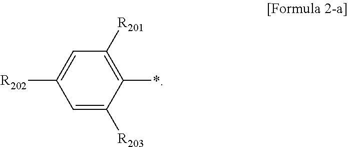

In Formula 2-a,

R₂₀₁ to R₂₀₃ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring. For example, R₂₀₁ to R₂₀₃ may each independently be a substituted or unsubstituted alkyl group having 1 to 60 carbons, a substituted or unsubstituted aryl group having 6 to 60 ring-forming carbons, or a substituted or unsubstituted heteroaryl group having 2 to 60 ring-forming carbons. For example, R₂₀₁ to R₂₀₃ may each independently be a substituted or unsubstituted t-butyl group, a substituted or unsubstituted phenyl group, or a substituted or unsubstituted benzothiadiazole group. For example, R₂₀₁ may be a substituted or unsubstituted phenyl group or a substituted or unsubstituted benzothiadiazole group. For example, R₂₀₂ may be an unsubstituted t-butyl group or an unsubstituted phenyl group. For example, R₂₀₃ may be a substituted or unsubstituted benzothiadiazole group. In an embodiment, in Formula 1, if Q₁ and Q₂ are each a group represented by Formula 2-a, at least one of R₂₀₁ and R₂₀₃ may each independently be a substituted or unsubstituted benzothiadiazole group.

In Formula 2-a, —* represents a bond to Formula 1.

In an embodiment, a group represented by Formula 2 may be a group represented by Formula 2-b:

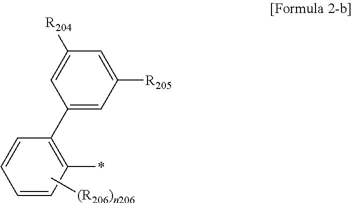

In Formula 2-b, R₂₀₄ and R₂₀₅ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons. For example, R₂₀₄ and R₂₀₅ may each independently be a substituted or unsubstituted alkyl group having 1 to 60 carbons, a substituted or unsubstituted aryl group having 6 to 60 ring-forming carbons, or a substituted or unsubstituted heteroaryl group having 2 to 60 ring-forming carbons. For example, R₂₀₄ may be an unsubstituted phenyl group. For example, R₂₀₅ may be an unsubstituted t-butyl group.

In Formula 2-b, R₂₀₆ may be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring. For example, R₂₀₆ may be a substituted or unsubstituted amine group. If multiple R₂₀₆ groups are present, two or more adjacent R₂₀₆ groups may be bonded to each other to form a thiadiazole group. In an embodiment, in Formula 1, if Q₁ and Q₂ are each a group represented by Formula 2-b, at least one of R₂₀₄ and R₂₀₅ may each independently be a substituted or unsubstituted benzothiadiazole group. In another embodiment, if multiple R₂₀₆ groups are present, two or more adjacent R₂₀₆ groups may be bonded to each other to form a thiadiazole group.

In Formula 2-b, n206 may be an integer from 0 to 4. If n206 is 0, the fused polycyclic compound may not be substituted with R₂₀₆. A case where n206 is 4 and four R₂₀₆ groups are all hydrogen atoms may be the same as a case where n206 is 0. If n206 is 2 or more, multiple R₂₀₆ may all be the same, or at least one thereof may be different from the remainder. When n206 is 2 or more, multiple adjacent R₂₀₆ groups may be bonded to each other to form a ring.

In Formula 2-b, —* represents a bond to Formula 1.

In an embodiment, a group represented by Formula 2 may be a group represented by Formula 2-cl, Formula 2-c2, Formula 2-d1, or Formula 2-d2:

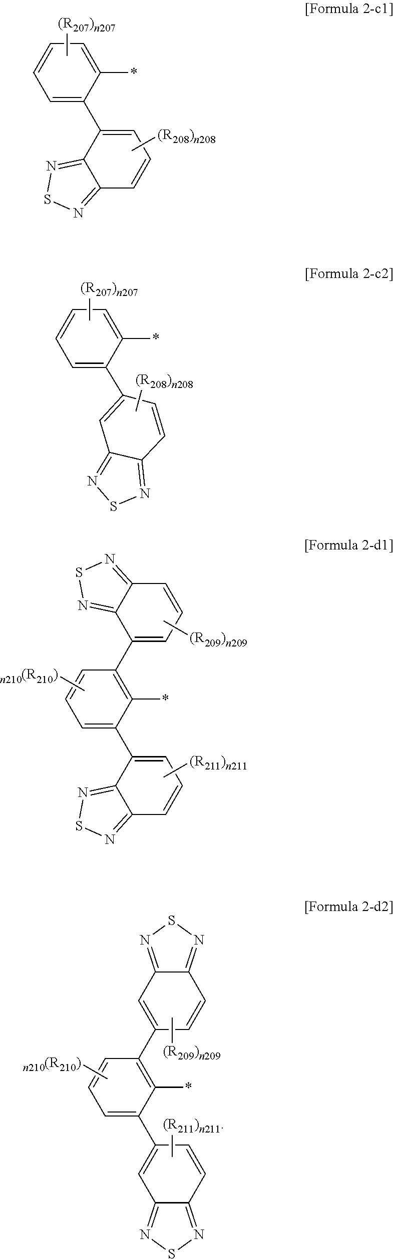

In Formula 2-c1, Formula 2-c2, Formula 2-d1, and Formula 2-d2, R₂₀₇ to R₂₁₁ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring. For example, R₂₀₇ to R₂₁₁ may each independently be a substituted or unsubstituted alkyl group having 1 to 60 carbons or a substituted or unsubstituted aryl group having 6 to 60 ring-forming carbons. For example, R₂₀₇ to R₂₁₁ may each independently be a hydrogen atom, a substituted or unsubstituted t-butyl group, or a substituted or unsubstituted phenyl group. For example, R₂₀₇ and R₂₀₈ may each be an unsubstituted phenyl group. For example, R₂₀₉ and R₂₁₁ may each be a hydrogen atom. For example, R₂₁₀ may be a hydrogen atom or a substituted or unsubstituted t-butyl group.

In Formula 2-c l and Formula 2-c2, n207 may be an integer from 0 to 4. If n207 is 0, the fused polycyclic compound may not be substituted with R₂₀₇. A case where n207 is 4 and four R₂₀₇ groups are all hydrogen atoms may be the same as a case where n207 is 0. If n207 is 2 or more, multiple R₂₀₇ may all be the same, or at least one thereof may be different from the remainder. If n207 is 2 or more, multiple adjacent R₂₀₇ groups may be bonded to each other to form a ring.

In Formula 2-cl, Formula 2-c2, Formula 2-d1, and Formula 2-d2, n208 to n211 may each independently be an integer from 0 to 3. If n208 is 0, the fused polycyclic compound may not be substituted with R₂₀₈. A case where n208 is 3 and three R₂₀₈ groups are all hydrogen atoms may be the same as a case where n208 is 0. If n208 is 2 or more, multiple R₂₀₈ may all be the same, or at least one thereof may be different from the remainder.

If n209 is 0, the fused polycyclic compound may not be substituted with R₂₀₉. A case where n209 is 3 and three R₂₀₉ groups are all hydrogen atoms may be the same as a case where n209 is 0. If n209 is 2 or more, multiple R₂₀₉ may all be the same, or at least one thereof may be different from the remainder.

If n210 is 0, the fused polycyclic compound may not be substituted with R₂₁₁. A case where n210 is 3 and three R₂₁₀ groups are all hydrogen atoms may be the same as a case where n210 is 0. If n210 is 2 or more, multiple R₂₁₀ may all be the same, or at least one thereof may be different from the remainder.

If n211 is 0, the fused polycyclic compound may not be substituted with R₂₁₁. A case where n211 is 3 and three R₂₁₁ groups are all hydrogen atoms may be the same as a case where n211 is 0. If n211 is 2 or more, multiple R₂₁₁ may all be the same, or at least one thereof may be different from the remainder.

In Formula 2-c1, Formula 2-c2, Formula 2-d1, and Formula 2-d2, —* represents a bond to Formula 1.

In an embodiment, a group represented by Formula 2 may be a group represented by Formula 2-e:

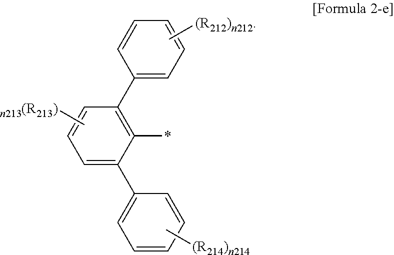

In Formula 2-e, R₂₁₂ to R₂₁₄ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring. For example, R₂₁₂ to R₂₁₄ may each independently be a hydrogen atom, a substituted or unsubstituted alkyl group having 1 to 60 carbons, or a substituted or unsubstituted aryl group having 6 to 60 ring-forming carbons. For example, R₂₁₂ may be a hydrogen atom, a substituted or unsubstituted t-butyl group, or a substituted or unsubstituted phenyl group. For example, R₂₁₃ may be a hydrogen atom, or a substituted or unsubstituted t-butyl group. For example, R₂₁₄ may be a hydrogen atom, a substituted or unsubstituted t-butyl group, or a substituted or unsubstituted phenyl group. If multiple R₂₁₂ groups are present, two or more adjacent R₂₁₂ groups may be bonded to each other to form a thiadiazole group. If multiple R₂₁₃ groups are present, two or more adjacent R₂₁₃ groups may be bonded to each other to form a thiadiazole group. If multiple R₂₁₄ groups are present, two or more adjacent R₂₁₄ groups may be bonded to each other to form a thiadiazole group. In an embodiment, in Formula 1, if Q₁ and Q₂ are each a group represented by Formula 2-e, multiple R₂₁₂ groups may be present and bonded to each other to form a thiadiazole group, and/or multiple R₂₁₄ groups may be present and bonded to each other to form a thiadiazole group.

In Formula 2-e, n212 and n214 may each independently be an integer from 0 to 5. If n212 is 0, the fused polycyclic compound may not be substituted with R₂₁₂. A case where n212 is 5 and five R₂₁₂ groups are all hydrogen atoms may be the same as a case where n212 is 0. If n212 is 2 or more, multiple R₂₁₂ may all be the same, or at least one thereof may be different from the remainder.

If n212 is 2 or more, multiple adjacent R₂₁₂ groups may be bonded to each other to form a ring. If n214 is 0, the fused polycyclic compound may not be substituted with R₂₁₄. A case where n214 is 5 and five R₂₁₄ groups are all hydrogen atoms may be the same as a case where n214 is 0. If n214 is 2 or more, multiple R₂₁₄ may all be the same, or at least one thereof may be different from the remainder. If n214 is 2 or more, multiple adjacent R₂₁₄ groups may be bonded to each other to form a ring.

In Formula 2-e, n213 may be an integer from 0 to 3. If n213 is 0, the fused polycyclic compound may not be substituted with R₂₁₃. A case where n213 is 3 and three R₂₁₃ groups are all hydrogen atoms may be the same as a case where n213 is 0. If n213 is 2 or more, multiple R₂₁₃ may all be the same, or at least one thereof may be different from the remainder. If n213 is 2 or more, multiple adjacent R₂₁₃ groups may be bonded to each other to form a ring.

In Formula 2-e, —* represents a bond to Formula 1.

In an embodiment, a group substituent represented by Formula 2 may be a group represented by Formula 2-f:

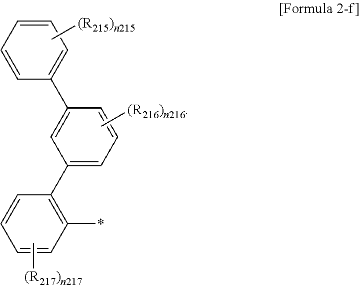

In Formula 2-f, R₂₁₅ to R₂₁₇ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring. For example, R₂₁₅ may be a hydrogen atom or a substituted or unsubstituted phenyl group. For example, R₂₁₅ and R₂₁₆ may each be a hydrogen atom. For example, R₂₁₇ may be a substituted or unsubstituted heteroaryl group having 2 to 60 ring-forming carbons. For example, R₂₁₇ may be a substituted or unsubstituted benzothiadiazole group. In an embodiment, in Formula 1, if Q₁ and Q₂ are each a group represented by Formula 2-f, multiple R₂₁₅ may be present and bonded to each other to form a thiadiazole group, and/or multiple R₂₁₇ may be present and bonded to each other to form a thiadiazole group.

In Formula 2-f, n215 may be an integer from 0 to 5. If n215 is 0, the fused polycyclic compound may not be substituted with R₂₁₅. A case where n215 is 5 and five R₂₁₅ groups are all hydrogen atoms may be the same as case where n215 is 0. If n215 is 2 or more, multiple R₂₁₅ may all be the same, or at least one thereof may be different from the remainder.

In Formula 2-f, n216 and n217 may each independently be an integer from 0 to 4. If n216 is 0, the fused polycyclic compound may not be substituted with R₂₁₆. A case where n216 is 4 and four R₂₁₆ groups are all hydrogen atoms may be the same as a case where n216 is 0. If n216 is 2 or more, multiple R₂₁₆ may all be the same, or at least one thereof may be different from the remainder. If n217 is 0, the fused polycyclic compound may not be substituted with R₂₁₇. A case where n217 is 4 and four R₂₁₇ groups are all hydrogen atoms may be the same as a case where n217 is 0. If n217 is 2 or more, multiple R₂₁₇ may all be the same, or at least one thereof may be different from the remainder.

In Formula 2-f, —* represents a bond to Formula 1.

In an embodiment, a group represented by Formula 2 may be a group represented by Formula 2-g1 or Formula 2-g2:

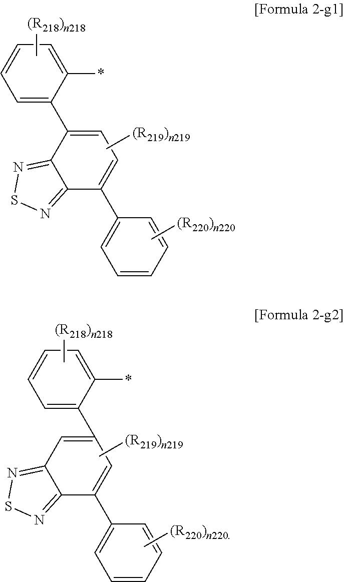

In Formula 2-g1 and Formula 2-g2, R₂₁₈ to R₂₂₀ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring. For example, R₂₁₈ to R₂₂₀ may each be a hydrogen atom.

In Formula 2-g1 and Formula 2-g2, n218 may be an integer from 0 to 4. If n218 is 0, the fused polycyclic compound may not be substituted with R₂₁₈. A case where n218 is 4 and four R₂₁₈ groups are all hydrogen atoms may be the same as a case where n218 is 0. If n218 is 2 or more, multiple R₂₁₈ may all be the same, or at least one thereof may be different from the remainder.

In Formula 2-g1 and Formula 2-g2, n219 may be an integer from 0 to 2. If n219 is 0, the fused polycyclic compound may not be substituted with R₂₁₉. A case where n219 is 2 and two R₂₁₉ groups are both hydrogen atoms may be the same as a case where n219 is 0. If n219 is 2, two R₂₁₉ groups may be the same as or different from each other.

In Formula 2-g1 and Formula 2-g2, n220 may be an integer from 0 to 5. If n220 is 0, the fused polycyclic compound may not be substituted with R₂₂₀. A case where n220 is 5 and five R₂₂₀ groups are all hydrogen atoms may be the same as a case where n220 is 0. If n220 is 2 or more, multiple R₂₂₀ may all be the same, or at least one thereof may be different from the remainder.

In Formula 2-g1 and Formula 2-g2, —* represents a bond to Formula 1.

In an embodiment, a group represented by Formula 3 may be a group represented by Formula 3-a or Formula 3-b:

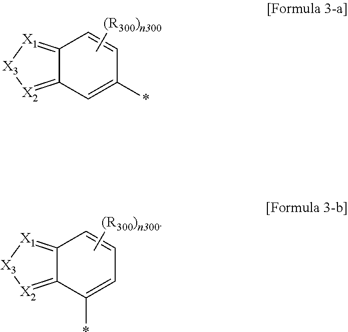

In Formula 3-a and Formula 3-b, X₁ to X₃, R₃₀₀, and n300 are the same as defined in Formula 3.

In Formula 3-a and Formula 3-b, —* represents a bond to Formula 1 or Formula 2.

In an embodiment, a group represented by Formula 3 may be a group represented by Formula 3-c:

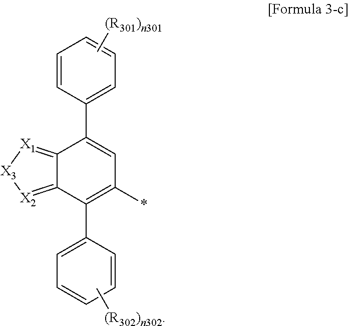

In Formula 3-c, R₃₀₁ and R₃₀₂ may each independently be a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring. For example, R₃₀₁ and R₃₀₂ may each be a hydrogen atom.

In Formula 3-c, n301 and n302 may each independently be an integer from 0 to 5.

If n301 is 0, the fused polycyclic compound may not be substituted with R₃₀₁. A case where n301 is 5 and five R₃₀₁ groups are all hydrogen atoms may be the same as a case where n301 is 0. If n301 is 2 or more, multiple R₃₀₁ may all be the same, or at least one thereof may be different from the remainder.

If n302 is 0, the fused polycyclic compound may not be substituted with R₃₀₂. A case where n302 is 5 and five R₃₀₂ groups are all hydrogen atoms may be the same as a case where n302 is 0. If n302 is 2 or more, multiple R₃₀₂ may all be the same, or at least one thereof may be different from the remainder.

In Formula 3-c, X₁ to X₃ are the same as defined in Formula 3.

In Formula 3-c, —* represents a bond to Formula 1 or Formula 2.

In an embodiment, the fused polycyclic compound represented by Formula 1 may be represented by Formula 4:

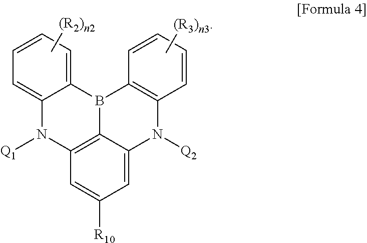

In Formula 4, R₁₀ may be a substituted or unsubstituted alkyl group having 1 to 60 carbons or a substituted or unsubstituted aryl group having 6 to 60 ring-forming carbons. For example, R₁₀ may be a substituted or unsubstituted t-butyl group or a substituted or unsubstituted phenyl group. For example, R₁₀ may be an unsubstituted t-butyl group or an unsubstituted phenyl group.

In Formula 4, R₂, R₃, Q₁, Q₂, n2, and n3 are the same as defined in Formula 1.

In an embodiment, the fused polycyclic compound represented by Formula 1 may be represented by one of Formula 5-1 to Formula 5-3:

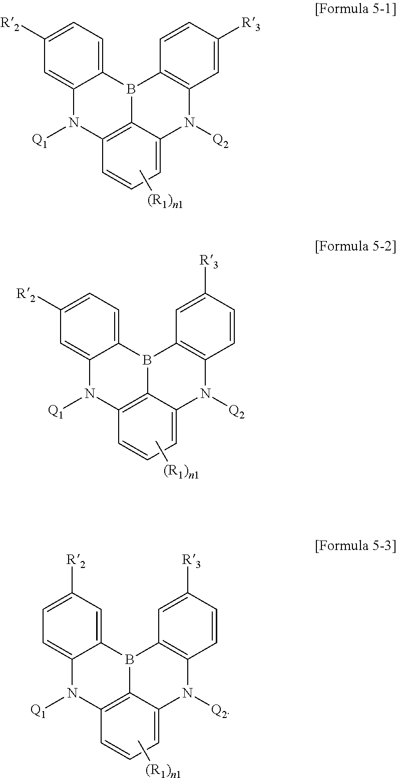

In Formula 5-1 to Formula 5-3, R′₂ and R′₃ may each independently be a substituted or unsubstituted aryl group having 6 to 60 ring-forming carbons or a substituted or unsubstituted heteroaryl group having 2 to 60 ring-forming carbons. For example, R′₂ and R′₃ may each independently be a substituted or unsubstituted phenyl group or a substituted or unsubstituted carbazole group. For example, R′₂ and R′₃ may each independently be an unsubstituted phenyl group, an unsubstituted carbazole group, or a carbazole group substituted with an unsubstituted phenyl group.

In Formula 5-1 to Formula 5-3, R₁, Q₁, Q₂, and n1 are the same as defined in Formula 1.

In an embodiment, at least one hydrogen atom in the fused polycyclic compound may be substituted with a deuterium atom.

In an embodiment, the fused polycyclic compound represented by Formula 1 may be any compound selected from Compound Group 1. In an embodiment, in the light-emitting element ED, at least one functional layer may include at least one compound selected from Compound Group 1. In an embodiment, in the light-emitting element ED, the first compound may include at least one compound selected from Compound Group 1:

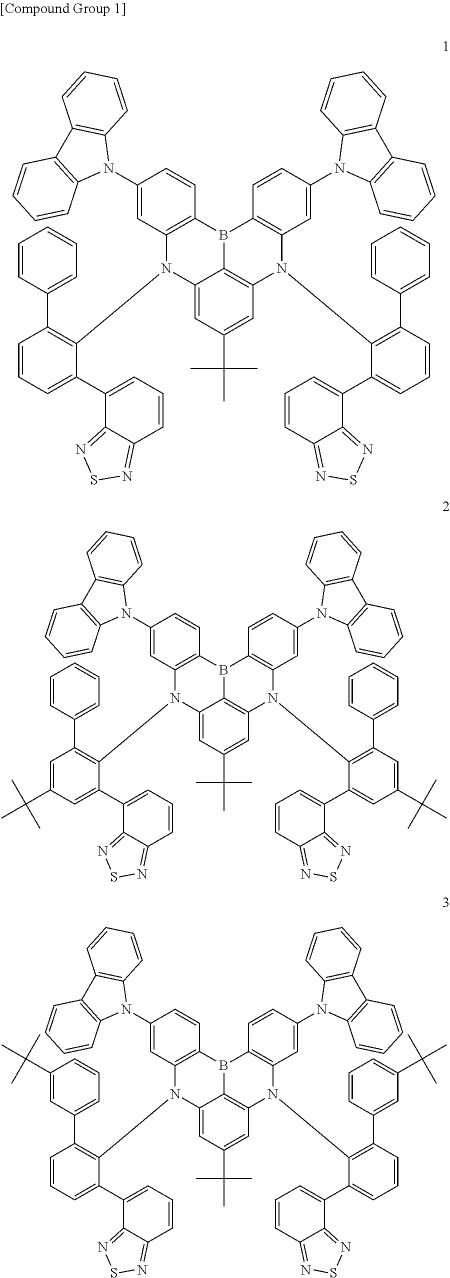

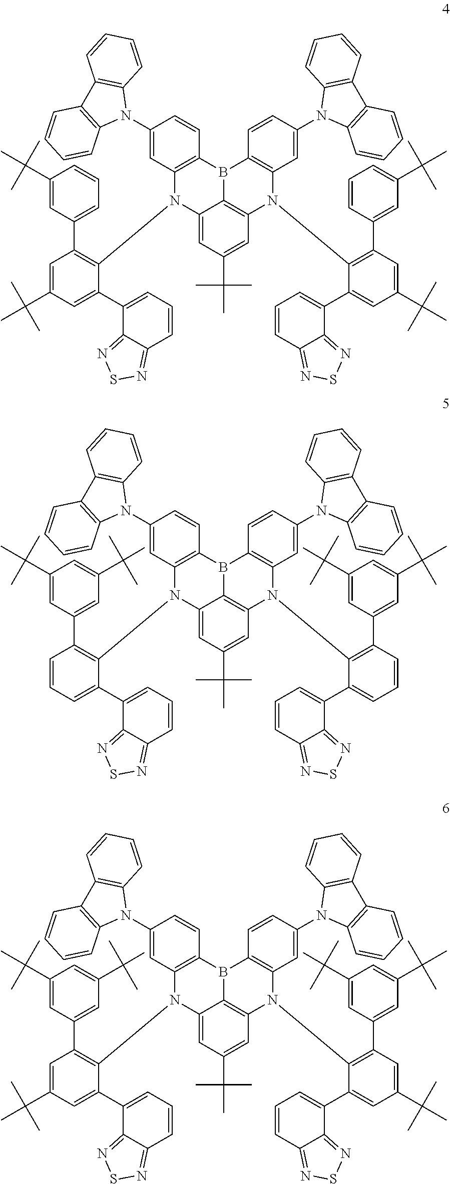

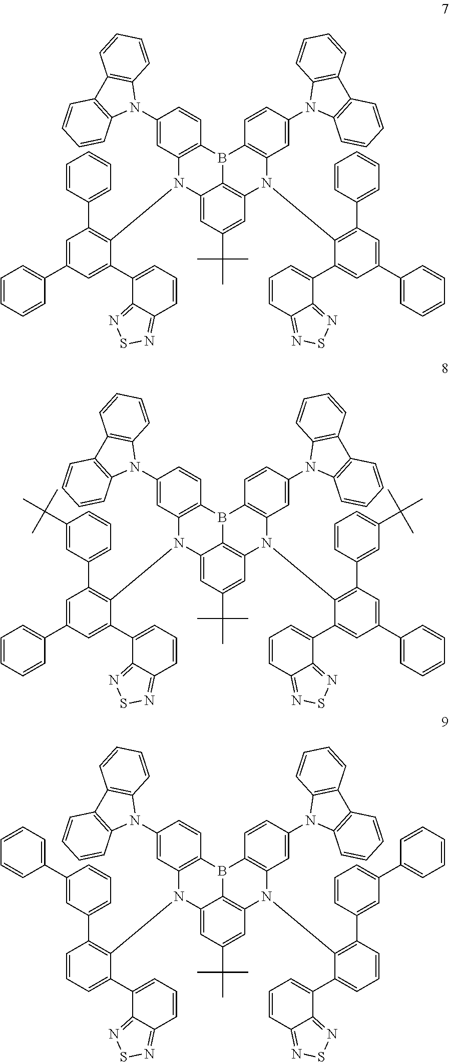

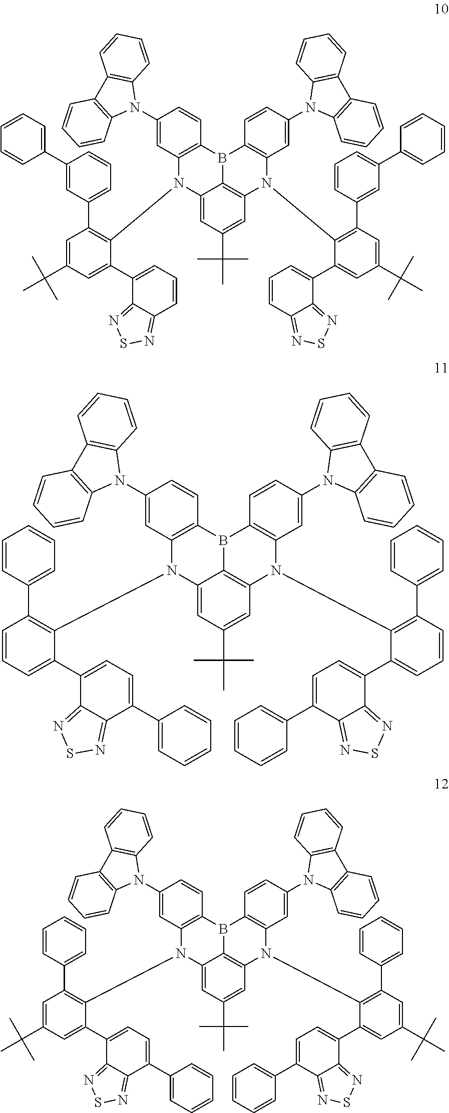

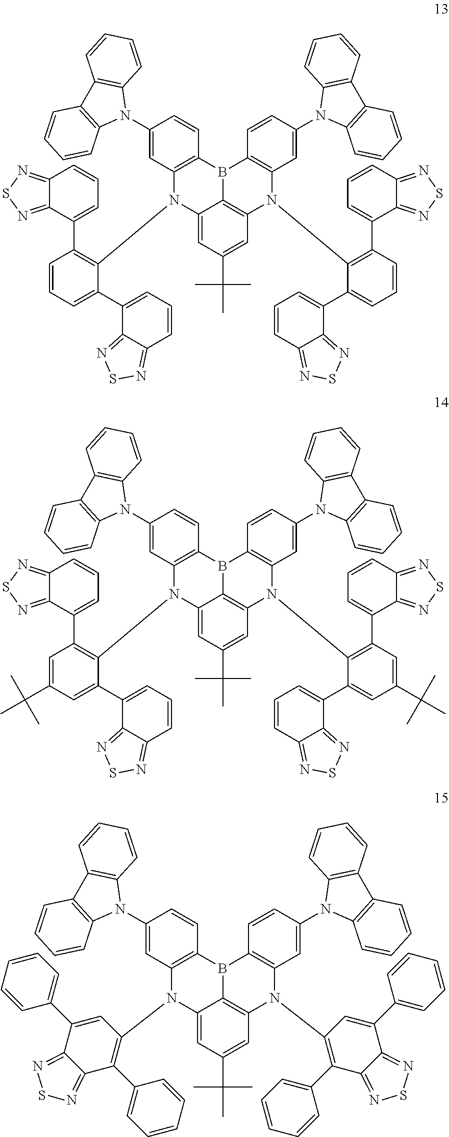

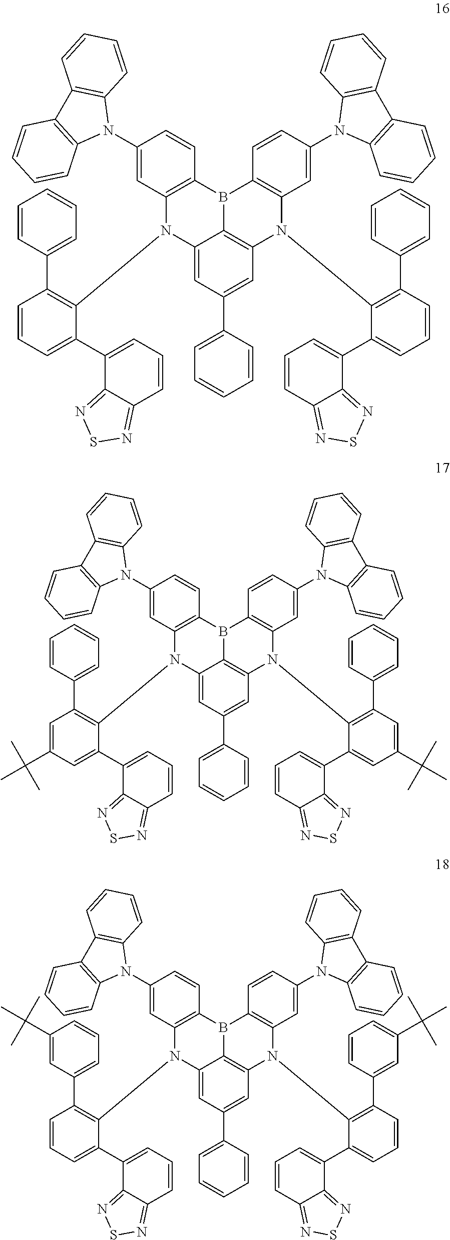

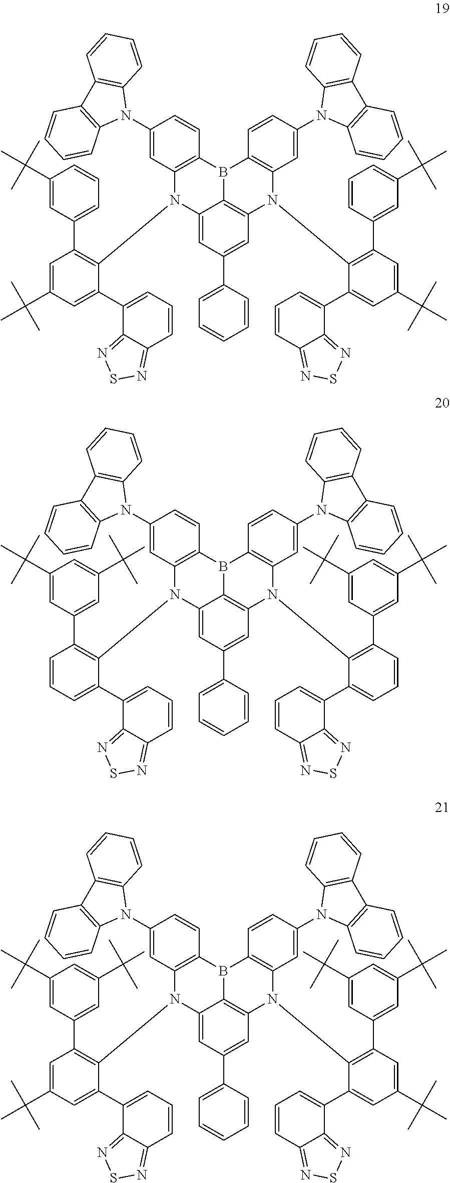

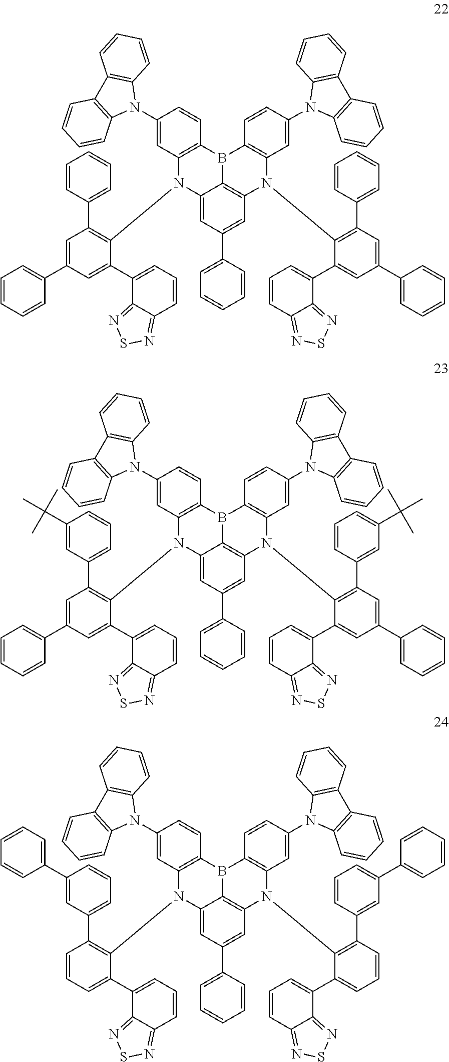

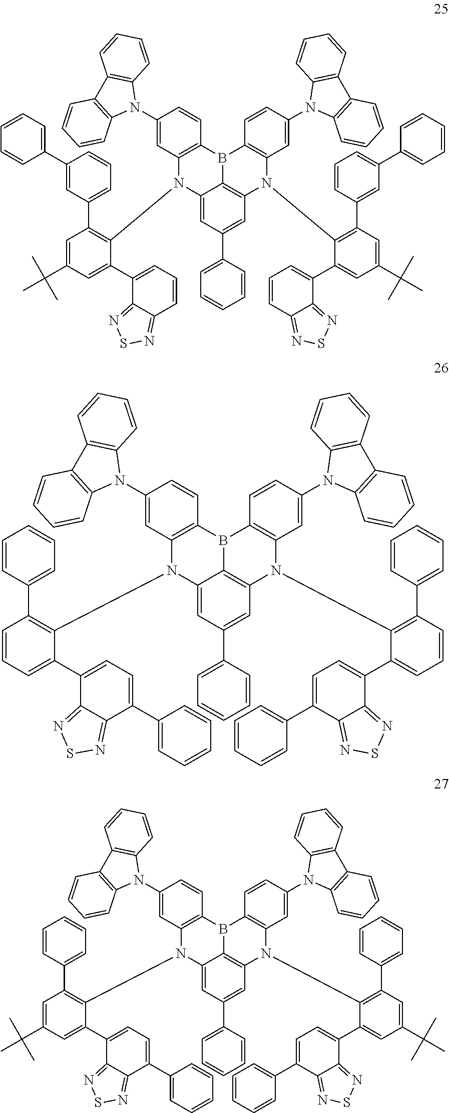

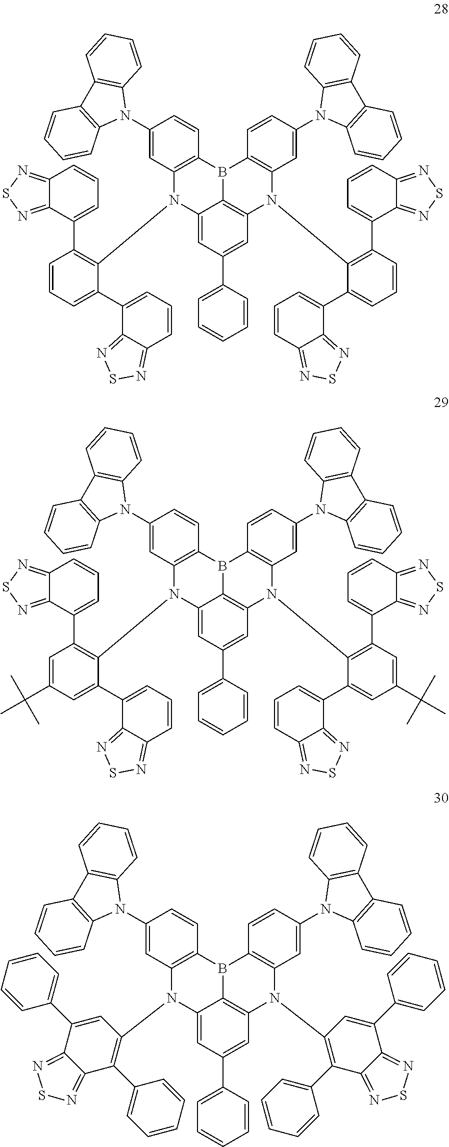

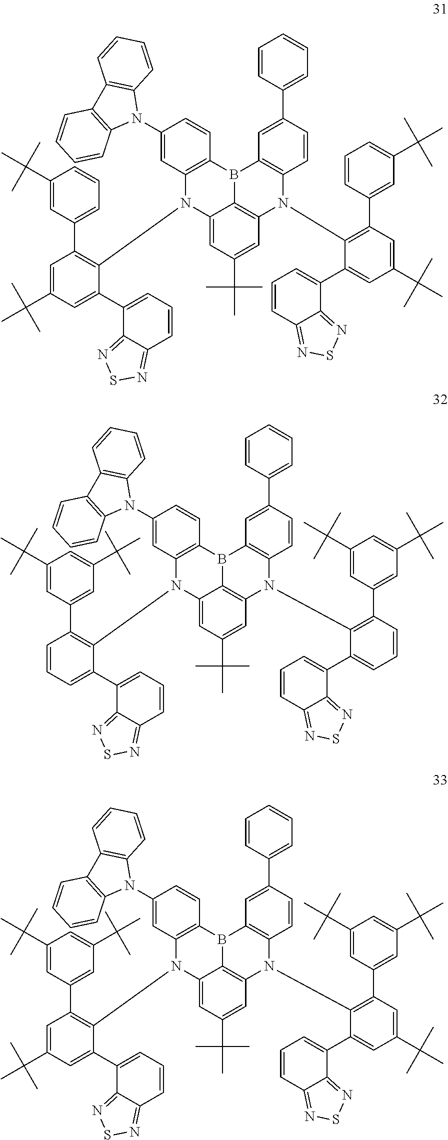

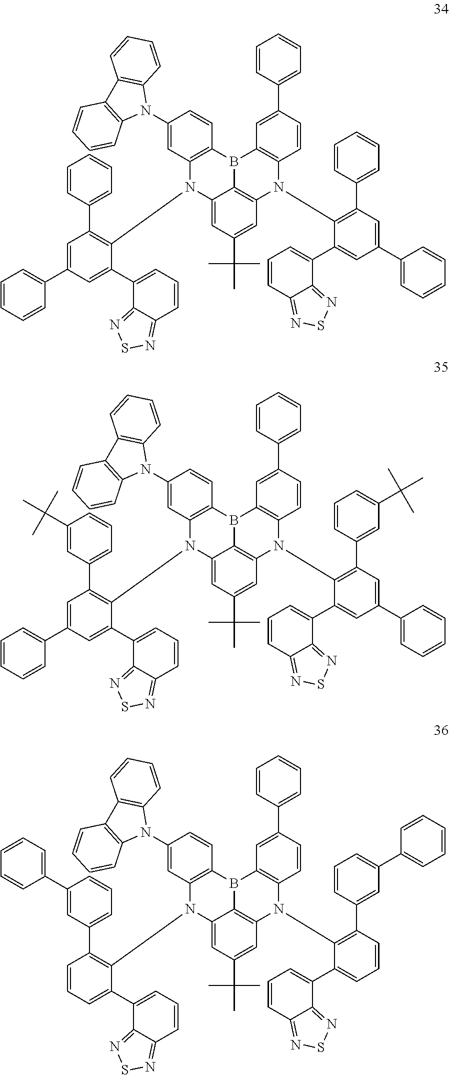

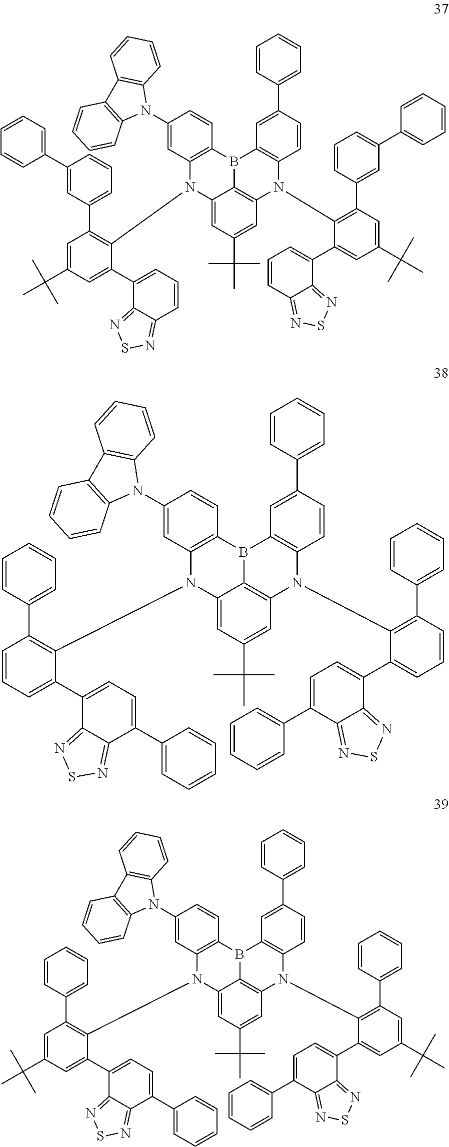

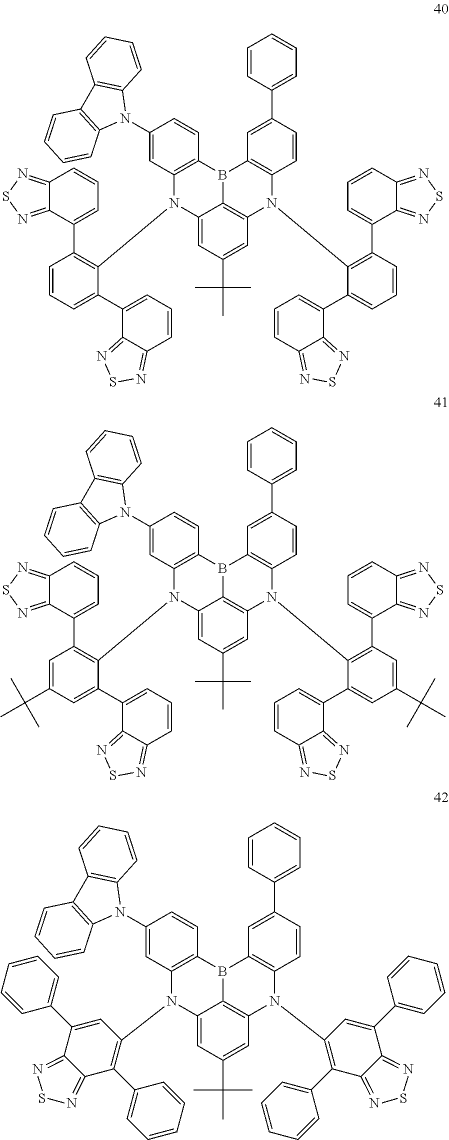 [SMILES: CC(C)(C)c1cc2c3c(c1)N(c1c(-c4cccc5nsnc45)cccc1-c1cccc4nsnc14)c1cc(-n4c5ccccc5c5ccccc54)ccc1B3c1cc(-c3ccccc3)ccc1N2c1c(-c2cccc3nsnc23)cccc1-c1cccc2nsnc12 ; CC(C)(C)c1cc(-c2cccc3nsnc23)c(N2c3ccc(-c4ccccc4)cc3B3c4ccc(-n5c6ccccc6c6ccccc65)cc4N(c4c(-c5cccc6nsnc56)cc(C(C)(C)C)cc4-c4cccc5nsnc45)c4cc(C(C)(C)C)cc2c43)c(-c2cccc3nsnc23)c1 ; CC(C)(C)c1cc2c3c(c1)N(c1cc(-c4ccccc4)c4nsnc4c1-c1ccccc1)c1cc(-n4c5ccccc5c5ccccc54)ccc1B3c1cc(-c3ccccc3)ccc1N2c1cc(-c2ccccc2)c2nsnc2c1-c1ccccc1]

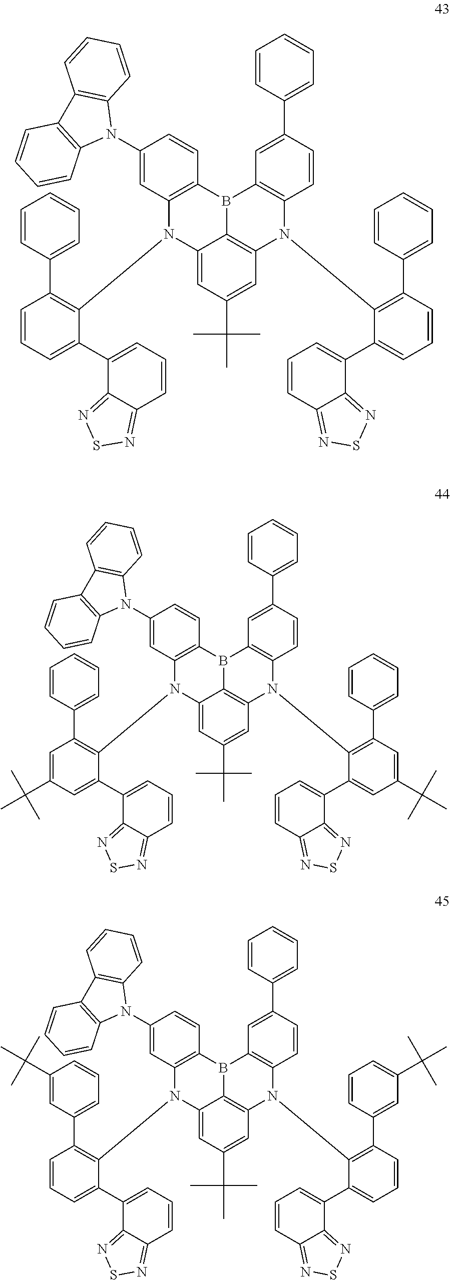

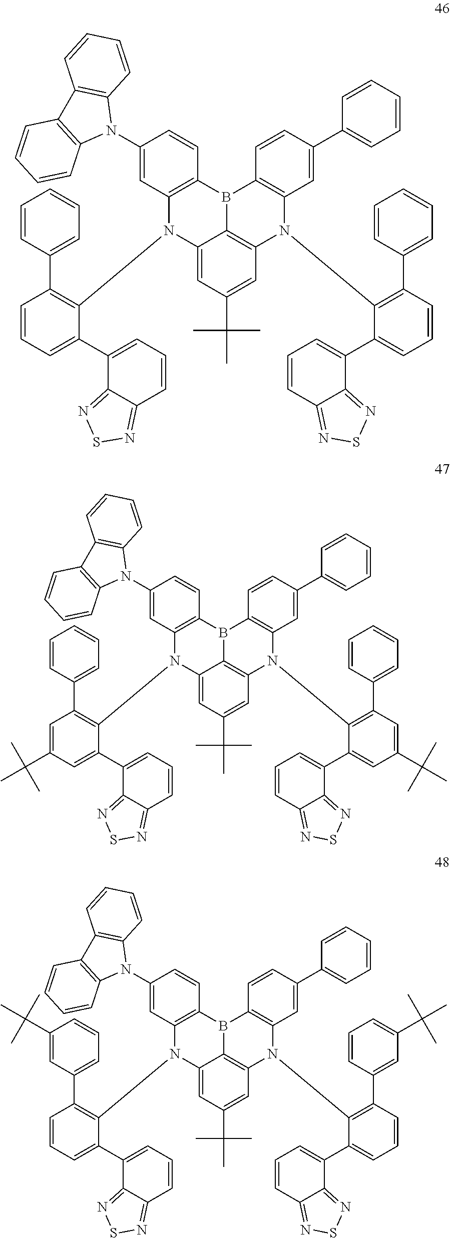

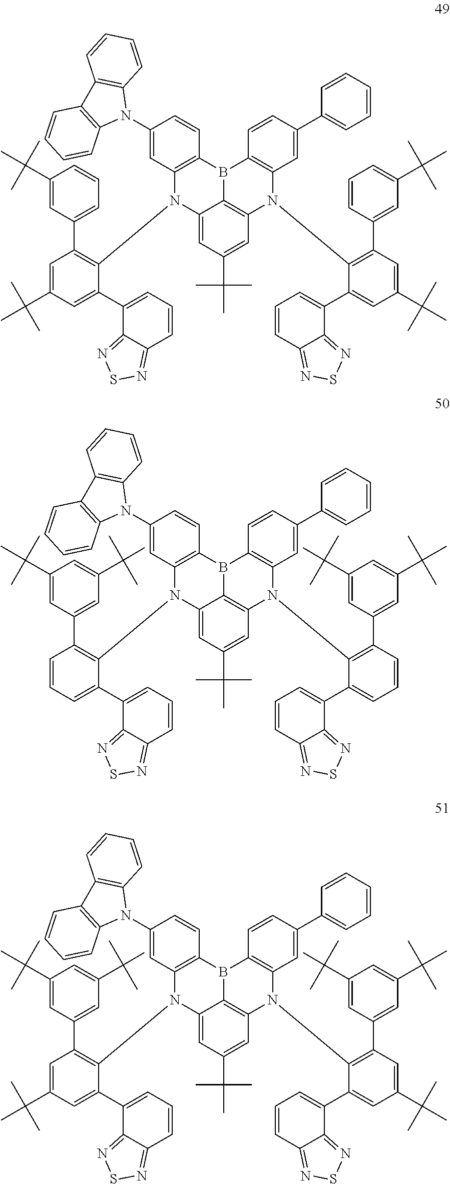

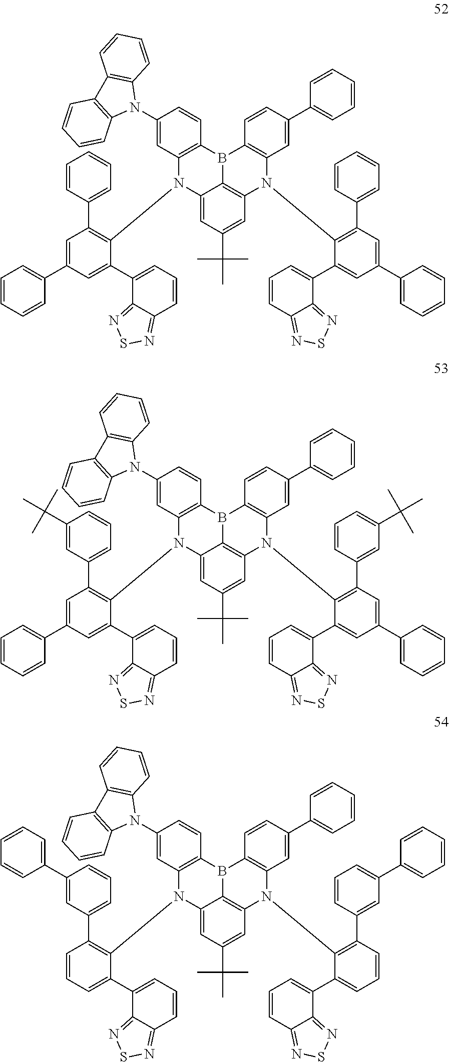

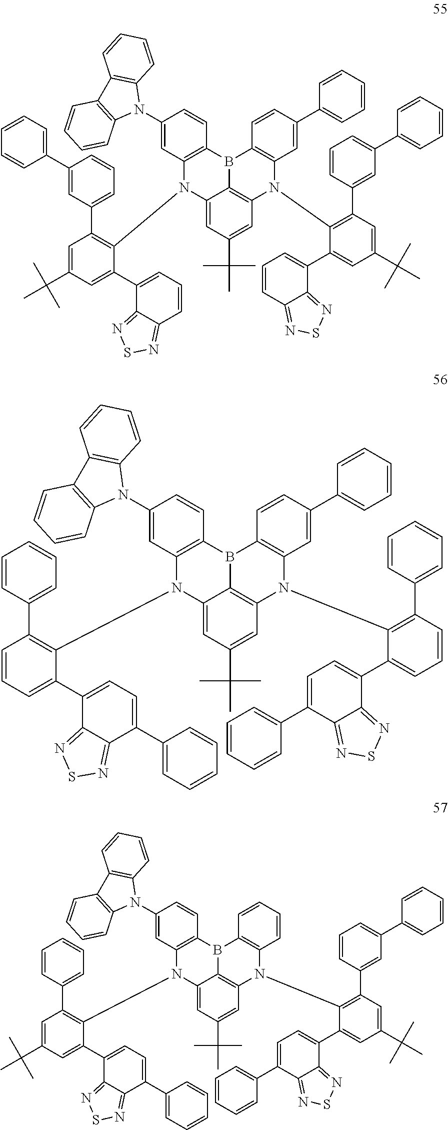

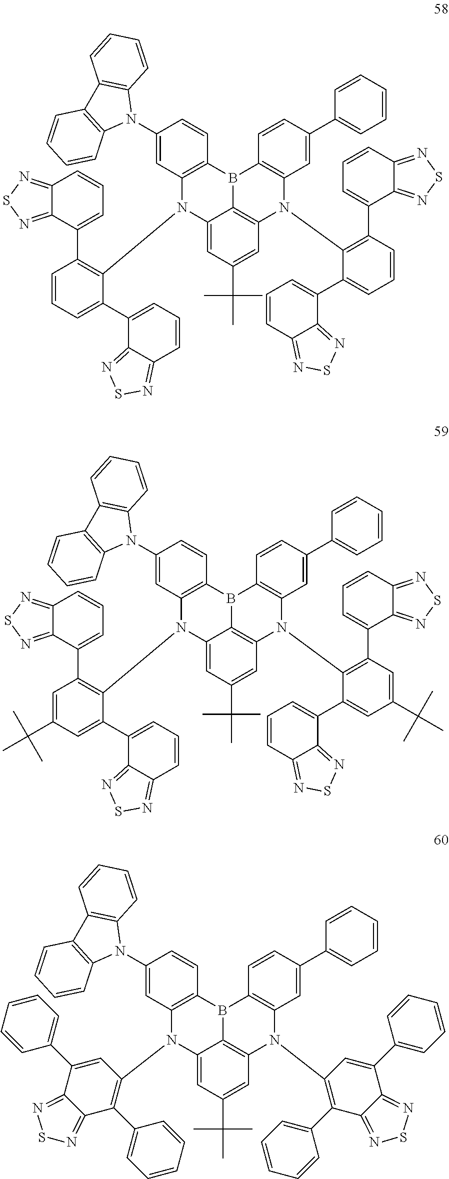 [SMILES: CC(C)(C)c1cc2c3c(c1)N(c1c(-c4cccc5nsnc45)cccc1-c1cccc4nsnc14)c1cc(-n4c5ccccc5c5ccccc54)ccc1B3c1ccc(-c3ccccc3)cc1N2c1c(-c2cccc3nsnc23)cccc1-c1cccc2nsnc12 ; CC(C)(C)c1cc(-c2cccc3nsnc23)c(N2c3cc(-c4ccccc4)ccc3B3c4ccc(-n5c6ccccc6c6ccccc65)cc4N(c4c(-c5cccc6nsnc56)cc(C(C)(C)C)cc4-c4cccc5nsnc45)c4cc(C(C)(C)C)cc2c43)c(-c2cccc3nsnc23)c1 ; CC(C)(C)c1cc2c3c(c1)N(c1cc(-c4ccccc4)c4nsnc4c1-c1ccccc1)c1cc(-n4c5ccccc5c5ccccc54)ccc1B3c1ccc(-c3ccccc3)cc1N2c1cc(-c2ccccc2)c2nsnc2c1-c1ccccc1]

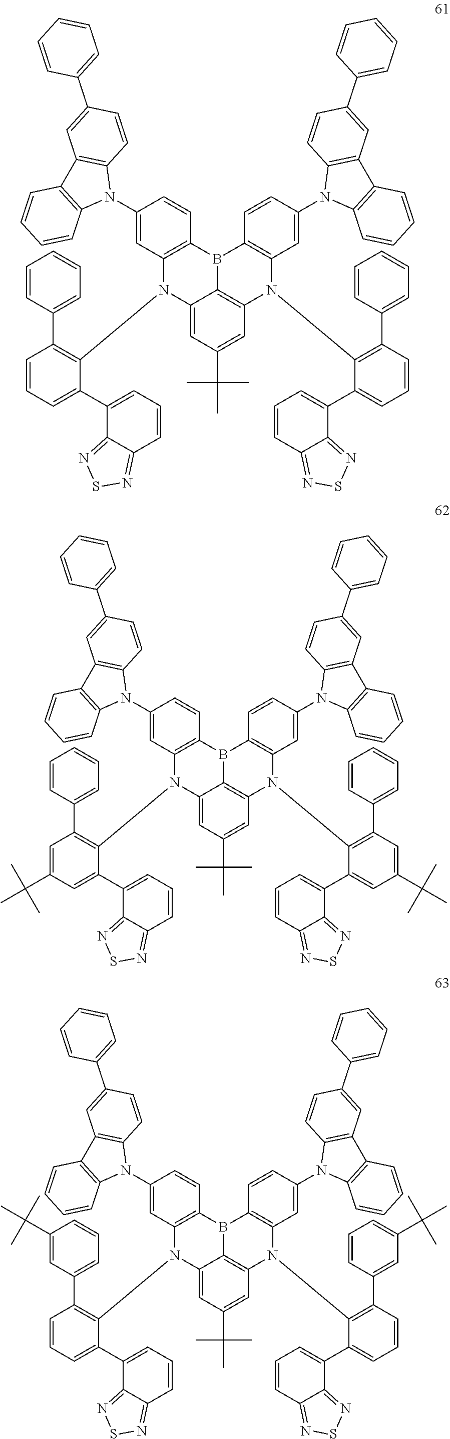

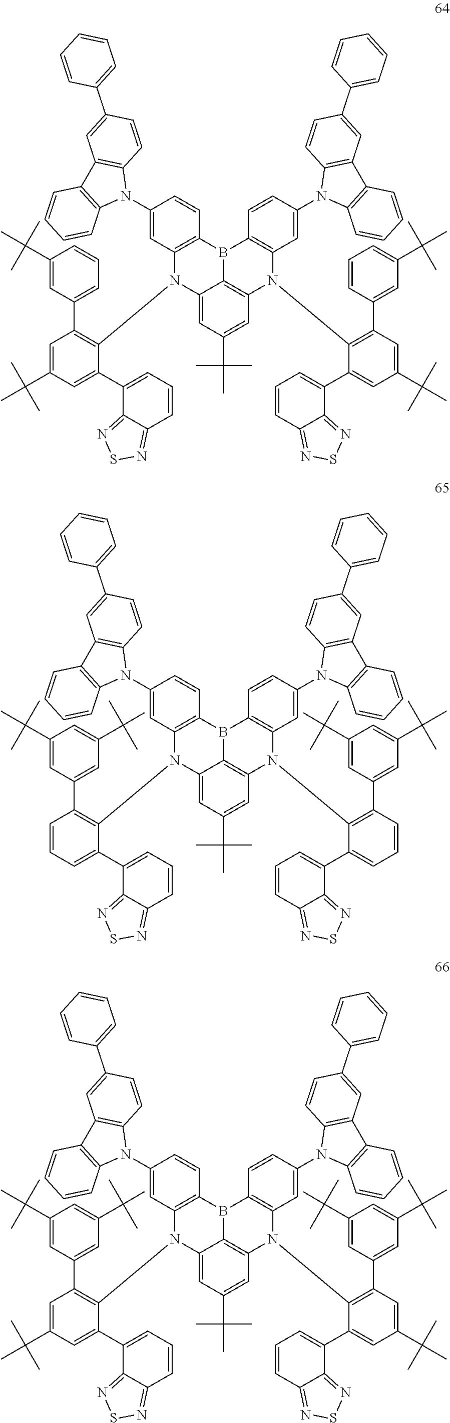

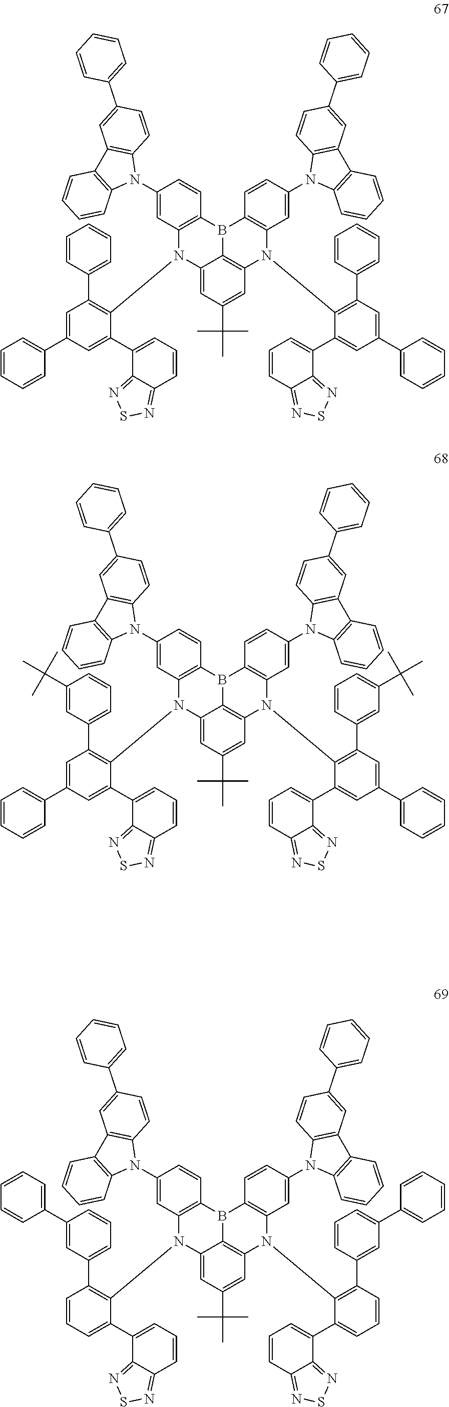

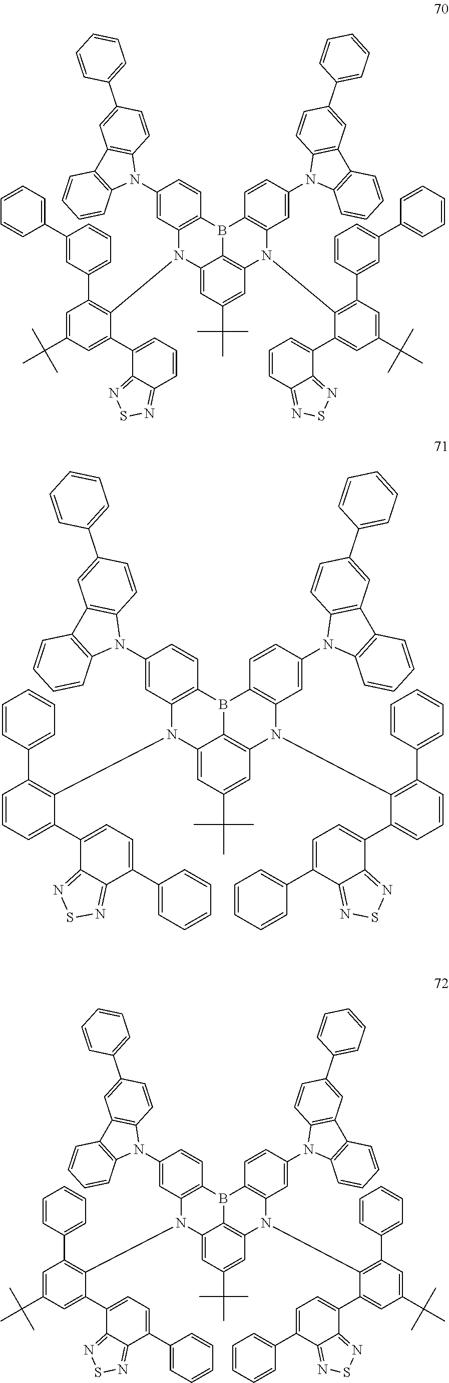

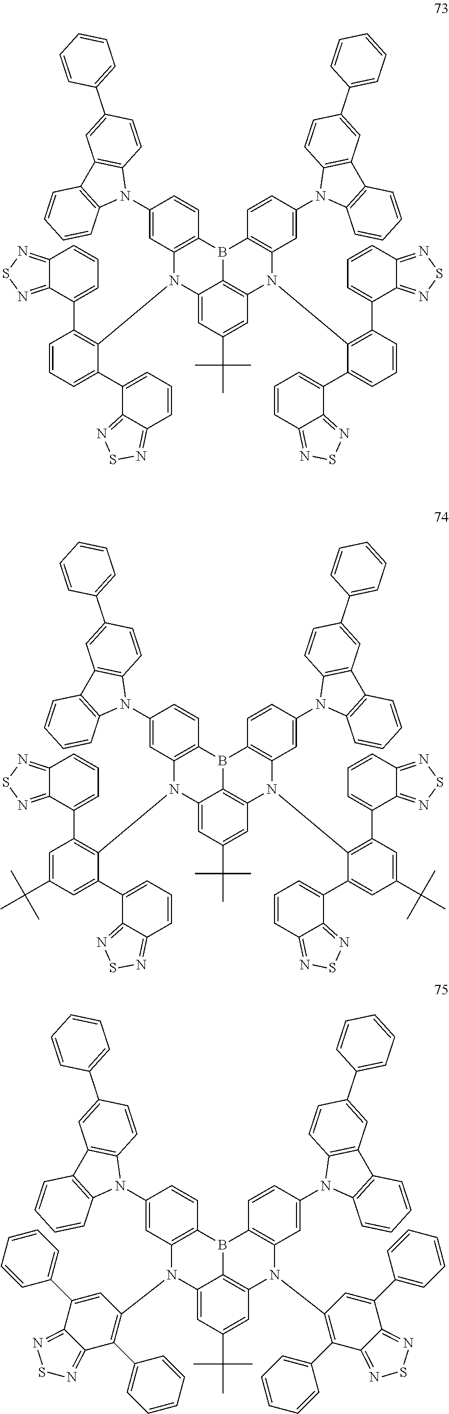

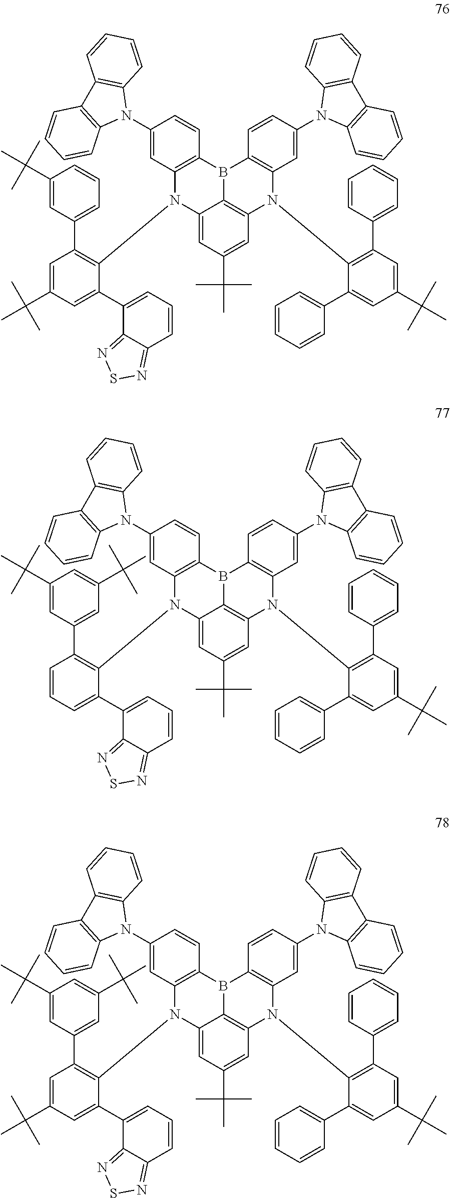

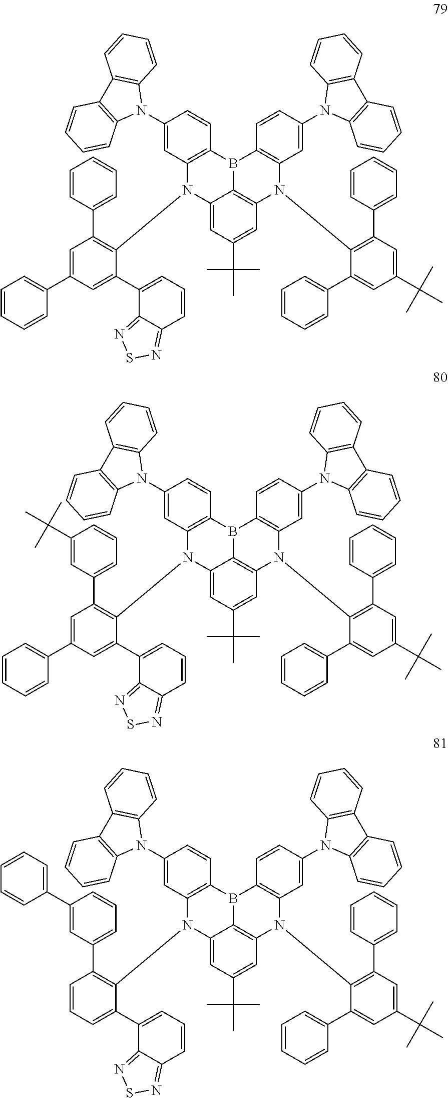

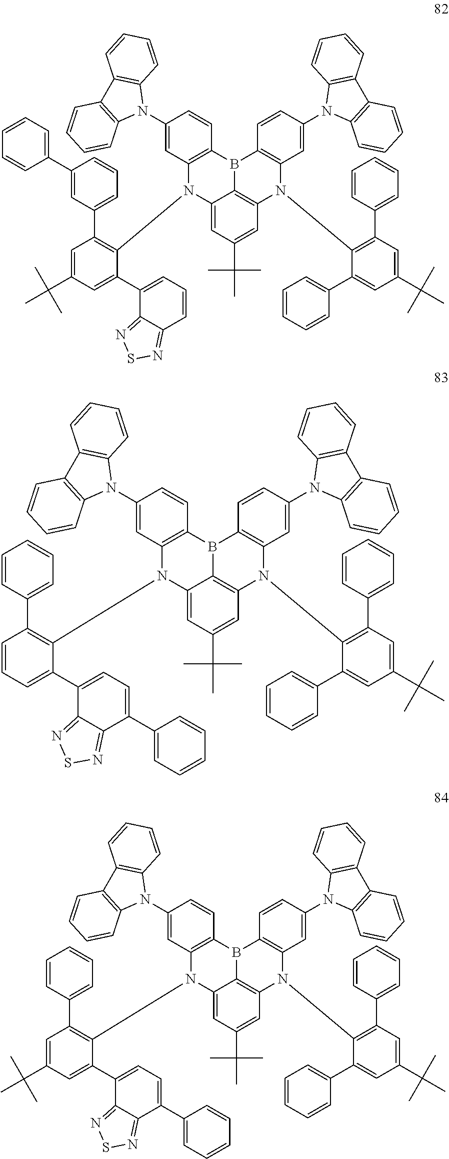

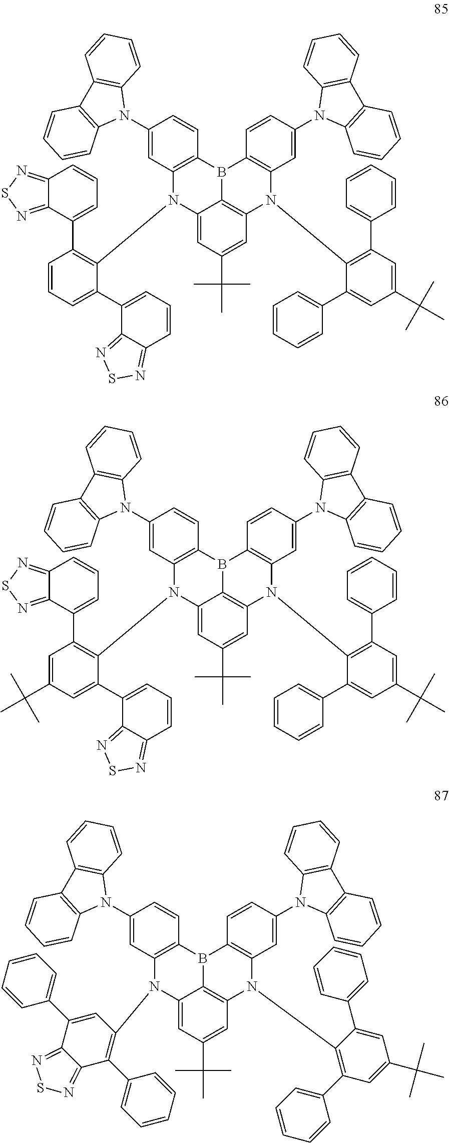

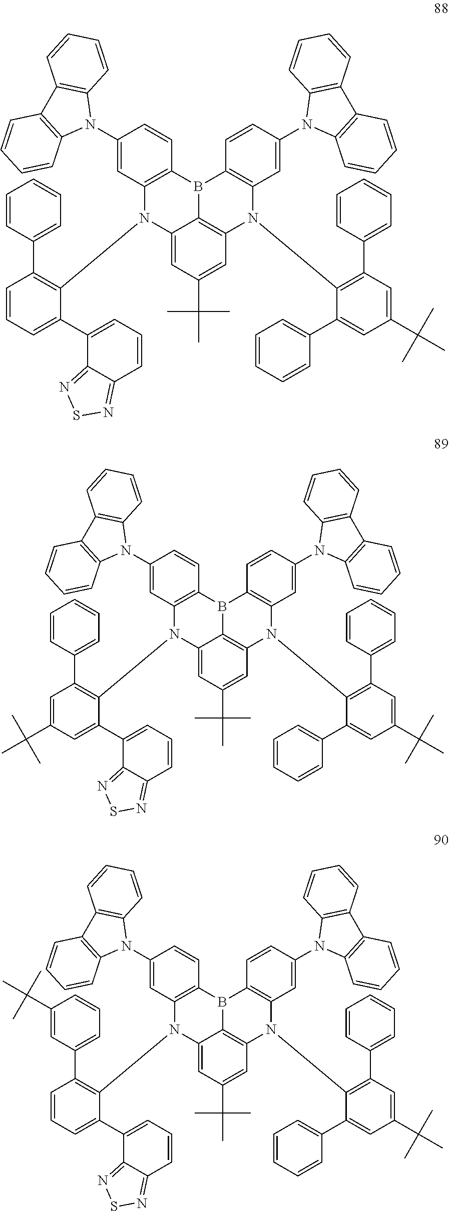

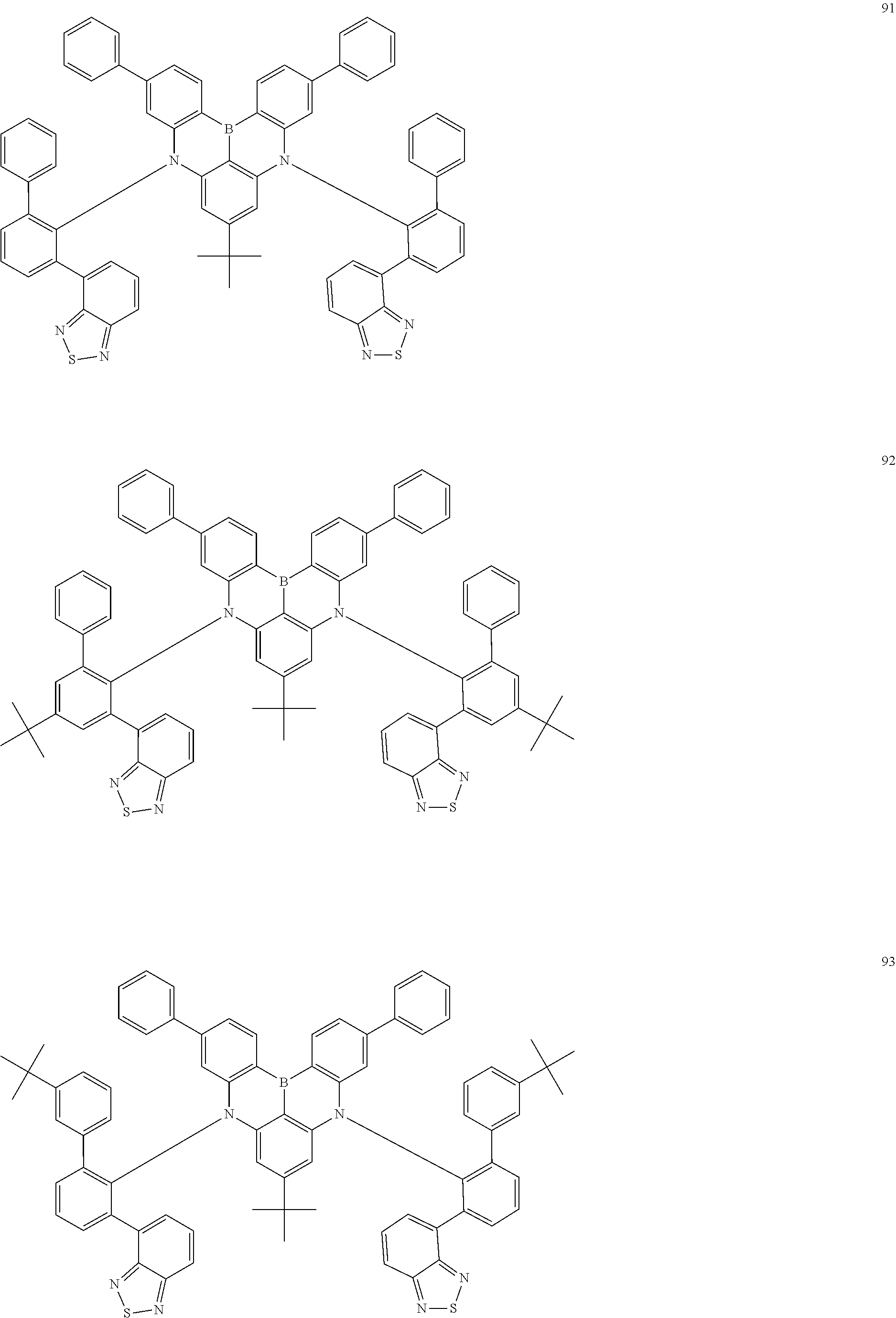

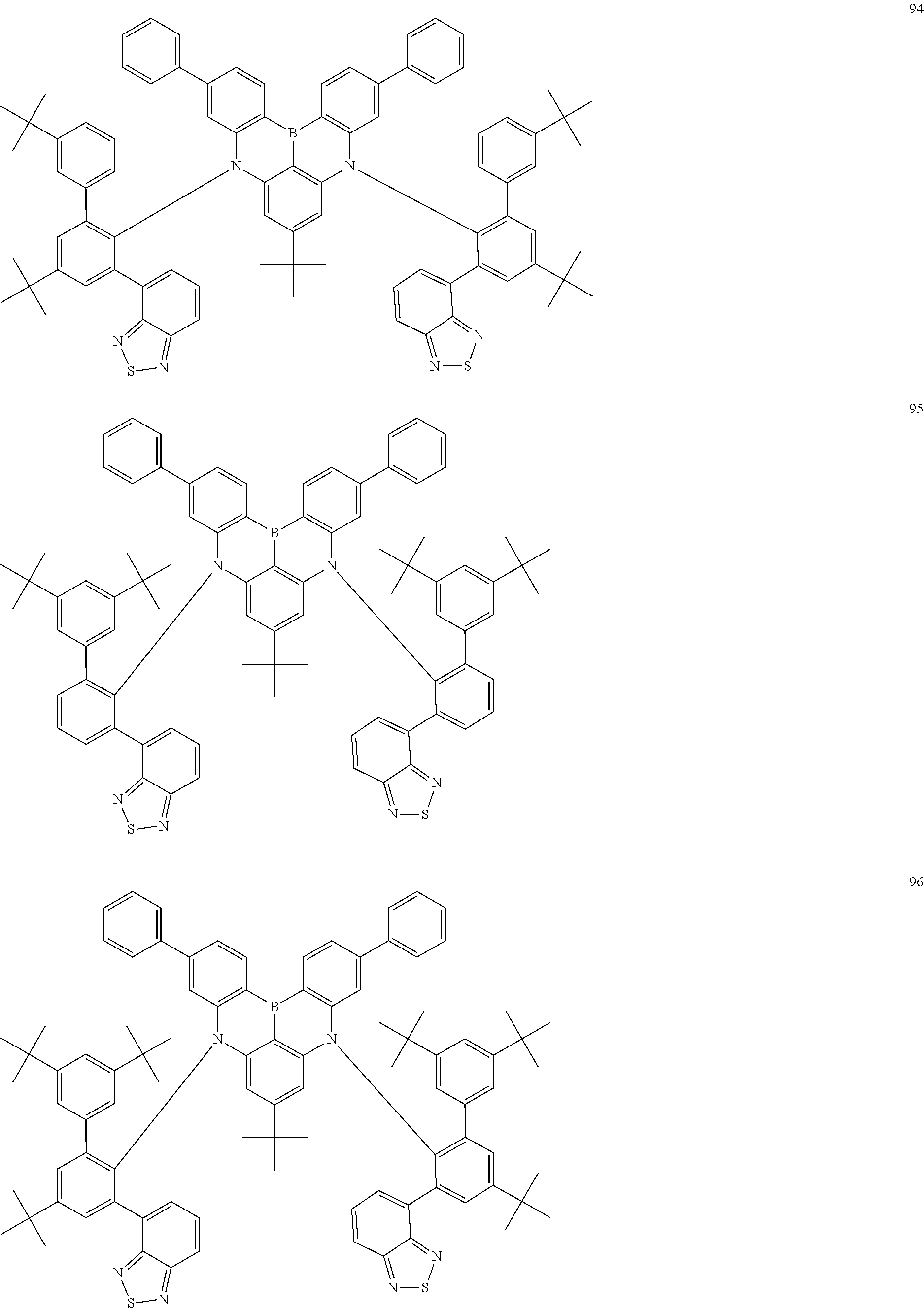

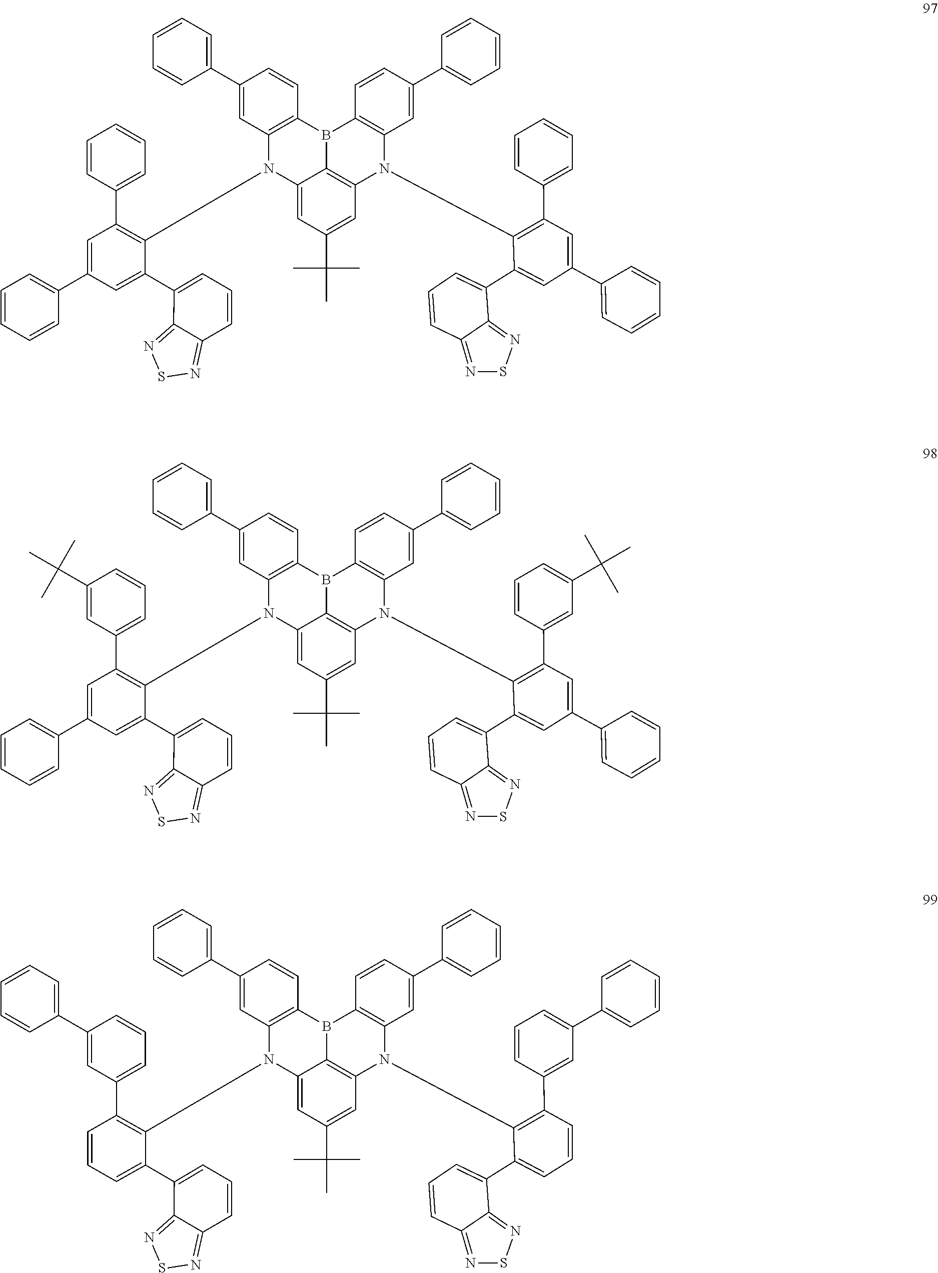 [SMILES: CC(C)(C)c1cc2c3c(c1)N(c1c(-c4ccccc4)cc(-c4ccccc4)cc1-c1cccc4nsnc14)c1cc(-c4ccccc4)ccc1B3c1ccc(-c3ccccc3)cc1N2c1c(-c2ccccc2)cc(-c2ccccc2)cc1-c1cccc2nsnc12 ; CC(C)(C)c1cccc(-c2cc(-c3ccccc3)cc(-c3cccc4nsnc34)c2N2c3cc(-c4ccccc4)ccc3B3c4ccc(-c5ccccc5)cc4N(c4c(-c5cccc(C(C)(C)C)c5)cc(-c5ccccc5)cc4-c4cccc5nsnc45)c4cc(C(C)(C)C)cc2c43)c1 ; CC(C)(C)c1cc2c3c(c1)N(c1c(-c4cccc(-c5ccccc5)c4)cccc1-c1cccc4nsnc14)c1cc(-c4ccccc4)ccc1B3c1ccc(-c3ccccc3)cc1N2c1c(-c2cccc(-c3ccccc3)c2)cccc1-c1cccc2nsnc12]

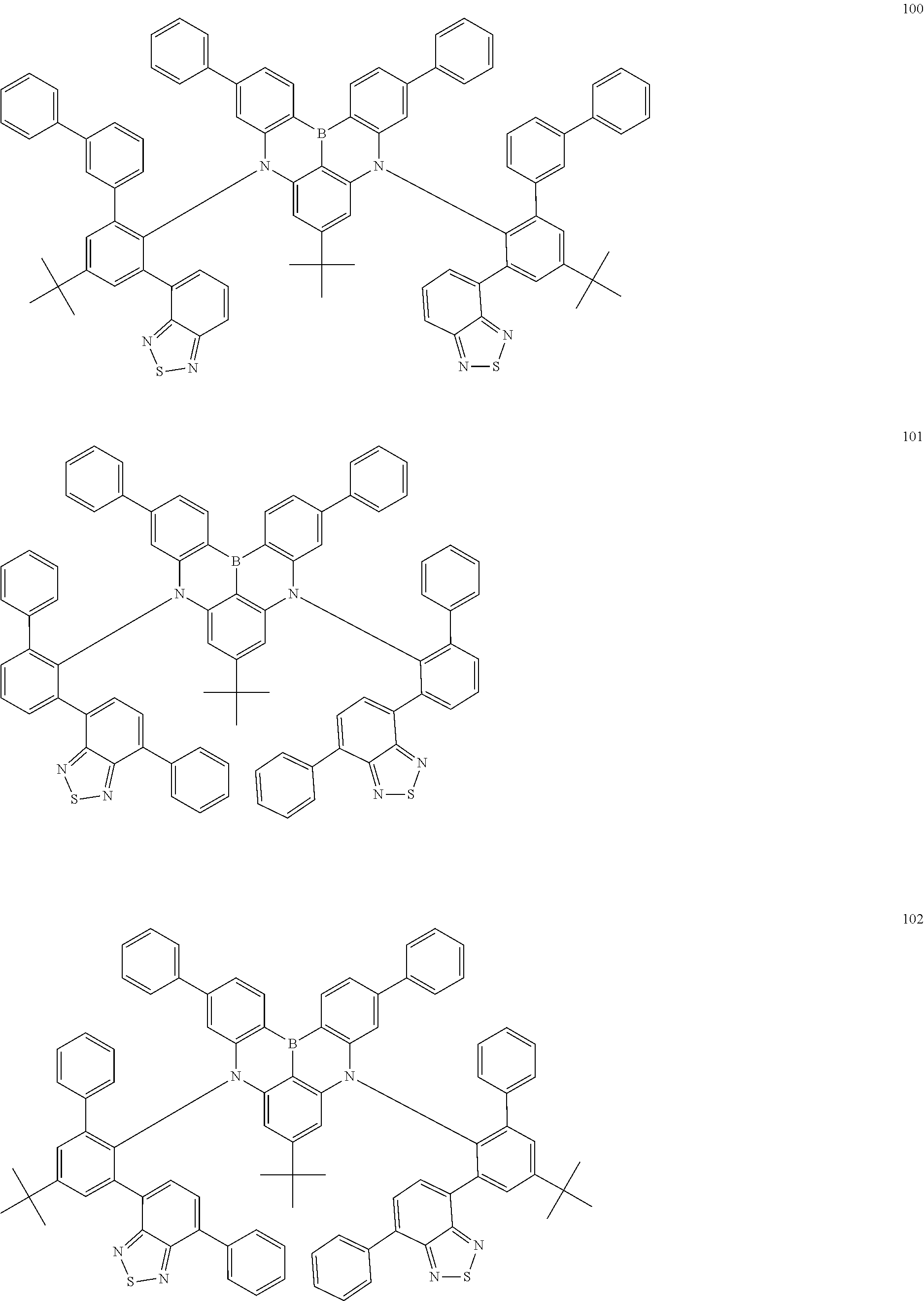

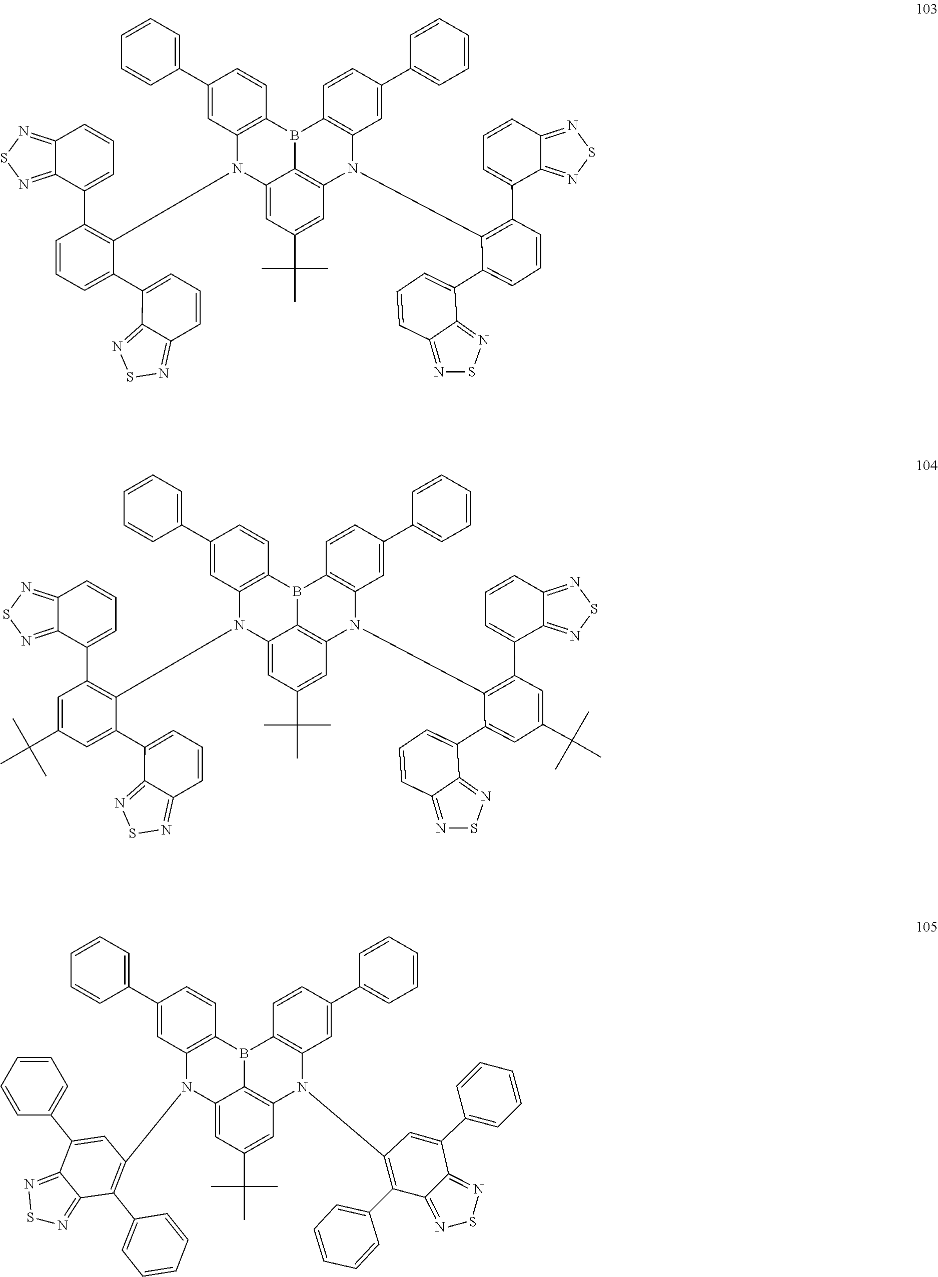 [SMILES: CC(C)(C)c1cc2c3c(c1)N(c1c(-c4cccc5nsnc45)cccc1-c1cccc4nsnc14)c1cc(-c4ccccc4)ccc1B3c1ccc(-c3ccccc3)cc1N2c1c(-c2cccc3nsnc23)cccc1-c1cccc2nsnc12 ; CC(C)(C)c1cc(-c2cccc3nsnc23)c(N2c3cc(-c4ccccc4)ccc3B3c4ccc(-c5ccccc5)cc4N(c4c(-c5cccc6nsnc56)cc(C(C)(C)C)cc4-c4cccc5nsnc45)c4cc(C(C)(C)C)cc2c43)c(-c2cccc3nsnc23)c1 ; CC(C)(C)c1cc2c3c(c1)N(c1cc(-c4ccccc4)c4nsnc4c1-c1ccccc1)c1cc(-c4ccccc4)ccc1B3c1ccc(-c3ccccc3)cc1N2c1cc(-c2ccccc2)c2nsnc2c1-c1ccccc1]

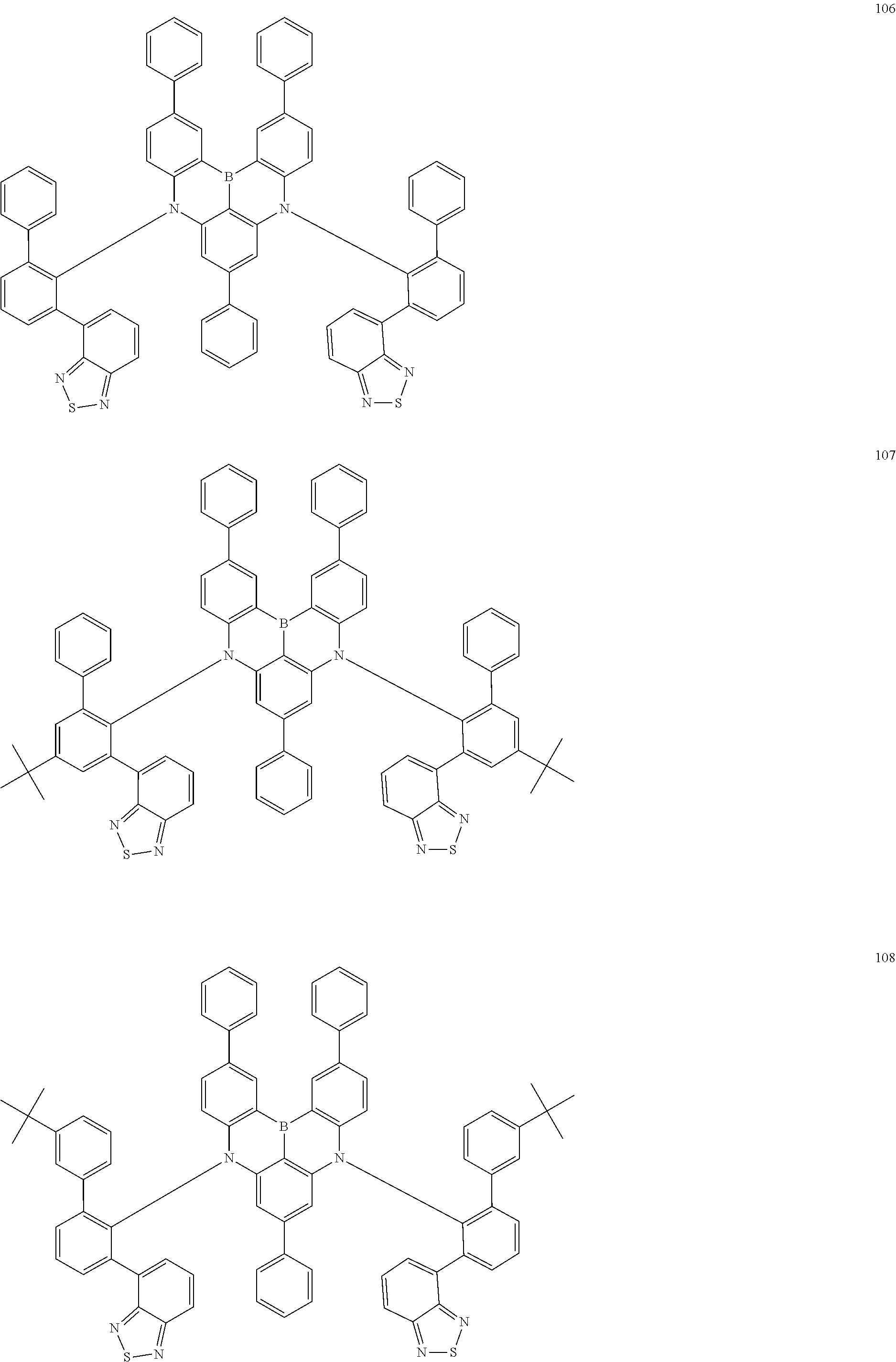

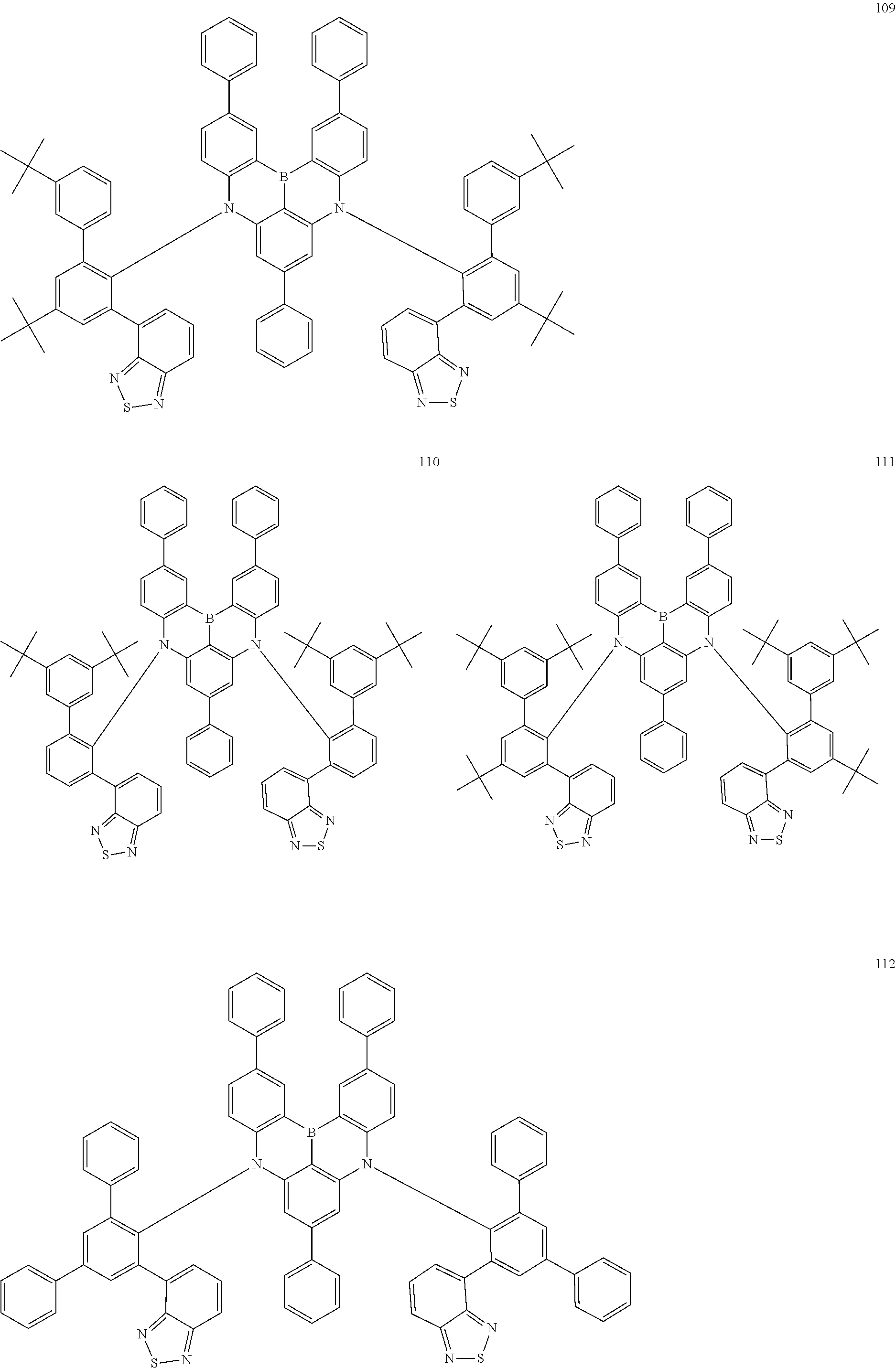

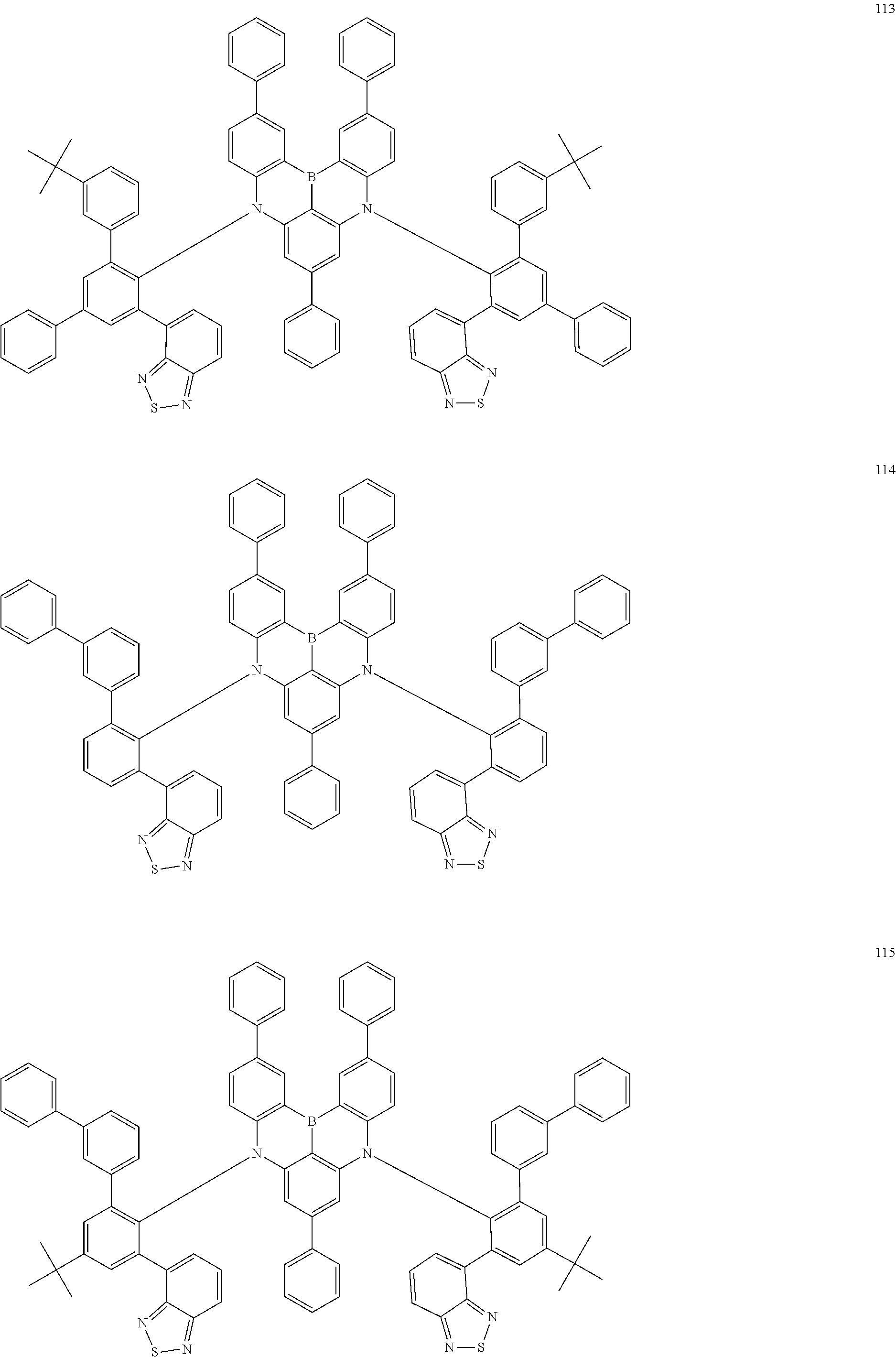

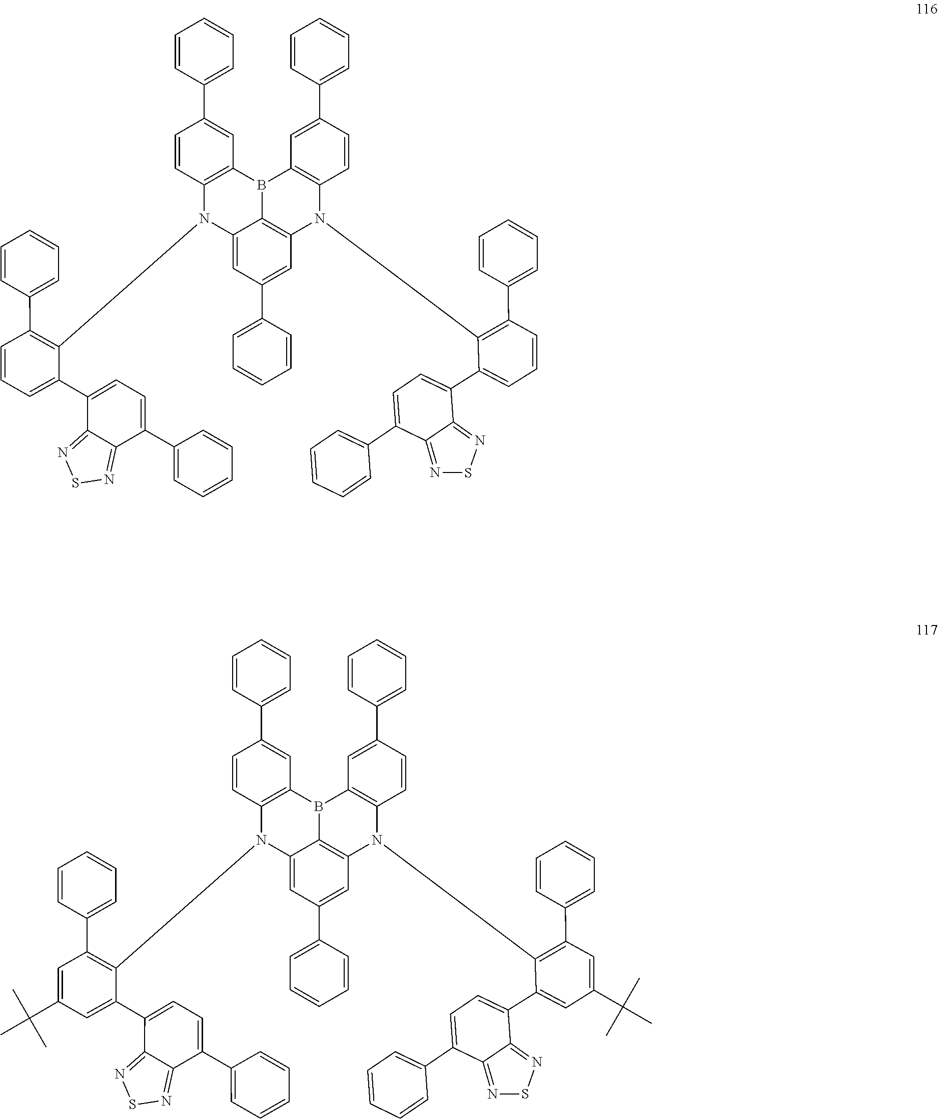 [SMILES: c1ccc(-c2ccc3c(c2)B2c4cc(-c5ccccc5)ccc4N(c4c(-c5ccccc5)cccc4-c4ccc(-c5ccccc5)c5nsnc45)c4cc(-c5ccccc5)cc(c42)N3c2c(-c3ccccc3)cccc2-c2ccc(-c3ccccc3)c3nsnc23)cc1 ; CC(C)(C)c1cc(-c2ccccc2)c(N2c3ccc(-c4ccccc4)cc3B3c4cc(-c5ccccc5)ccc4N(c4c(-c5ccccc5)cc(C(C)(C)C)cc4-c4ccc(-c5ccccc5)c5nsnc45)c4cc(-c5ccccc5)cc2c43)c(-c2ccc(-c3ccccc3)c3nsnc23)c1]

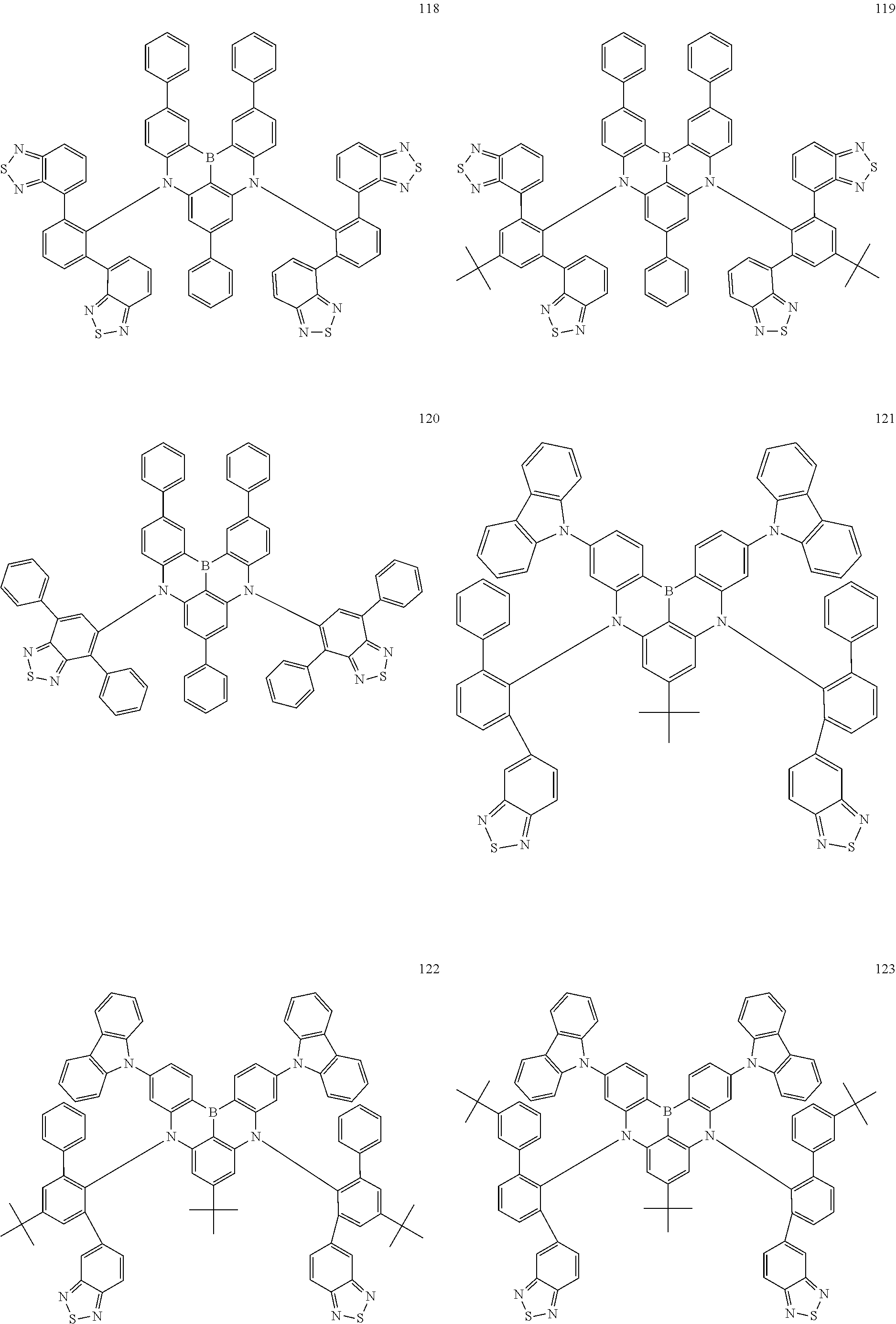

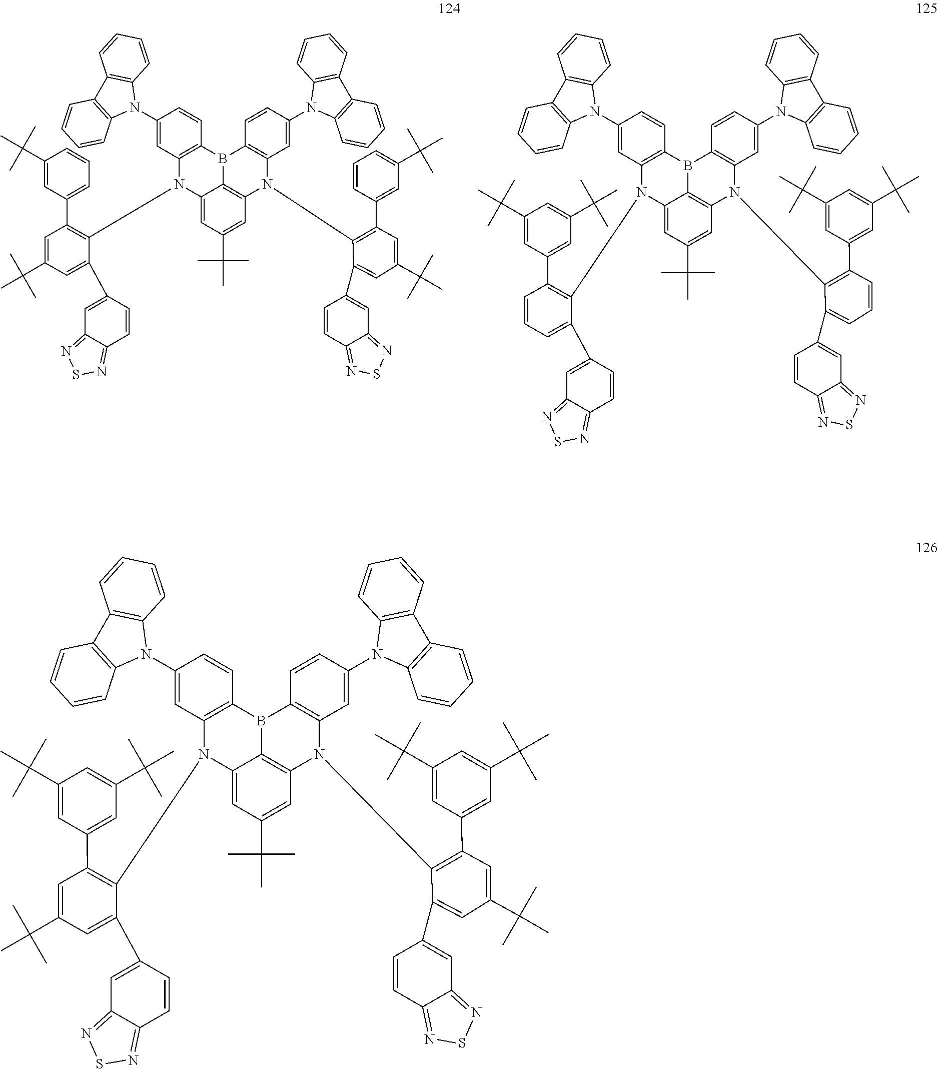

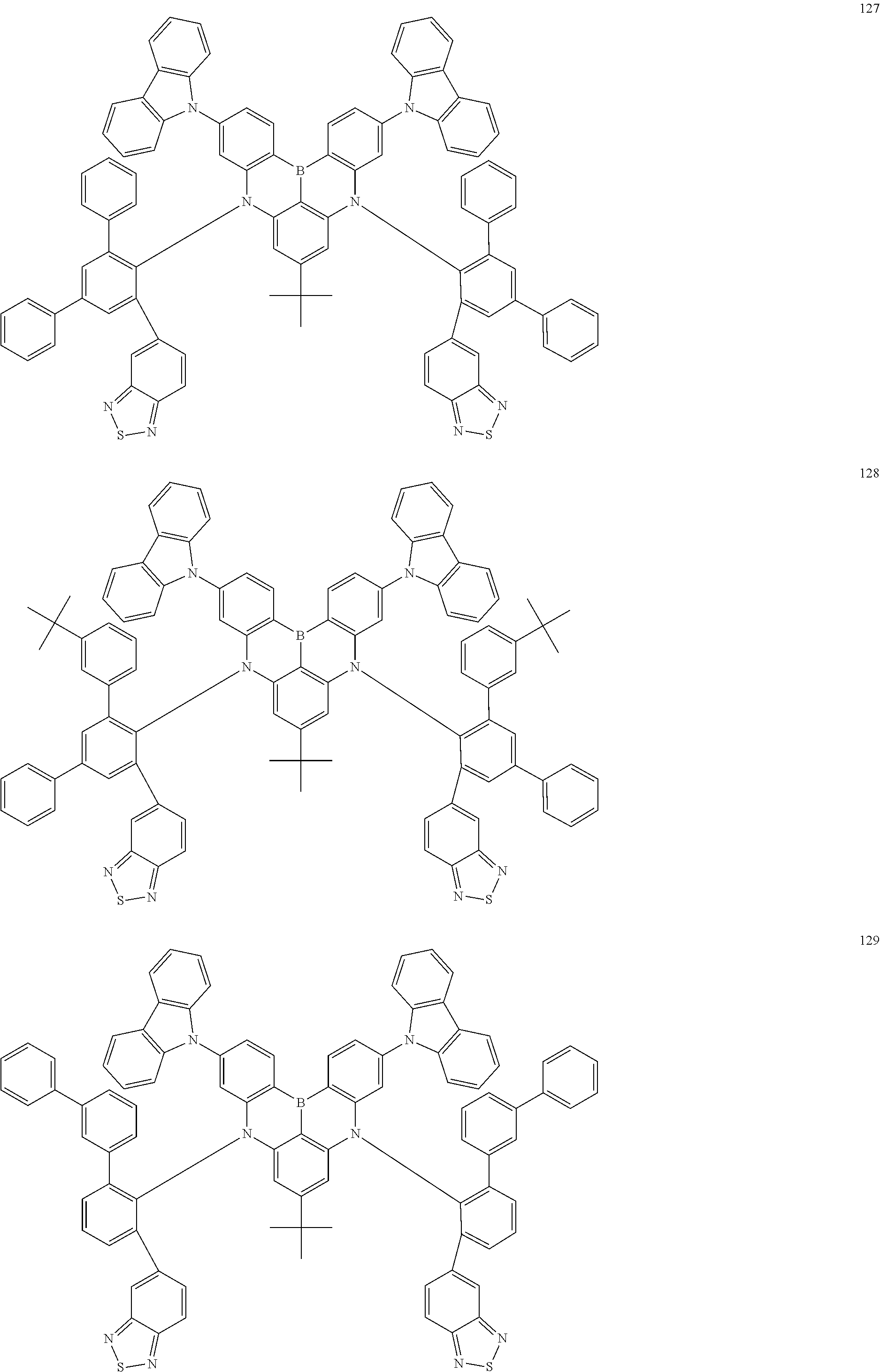

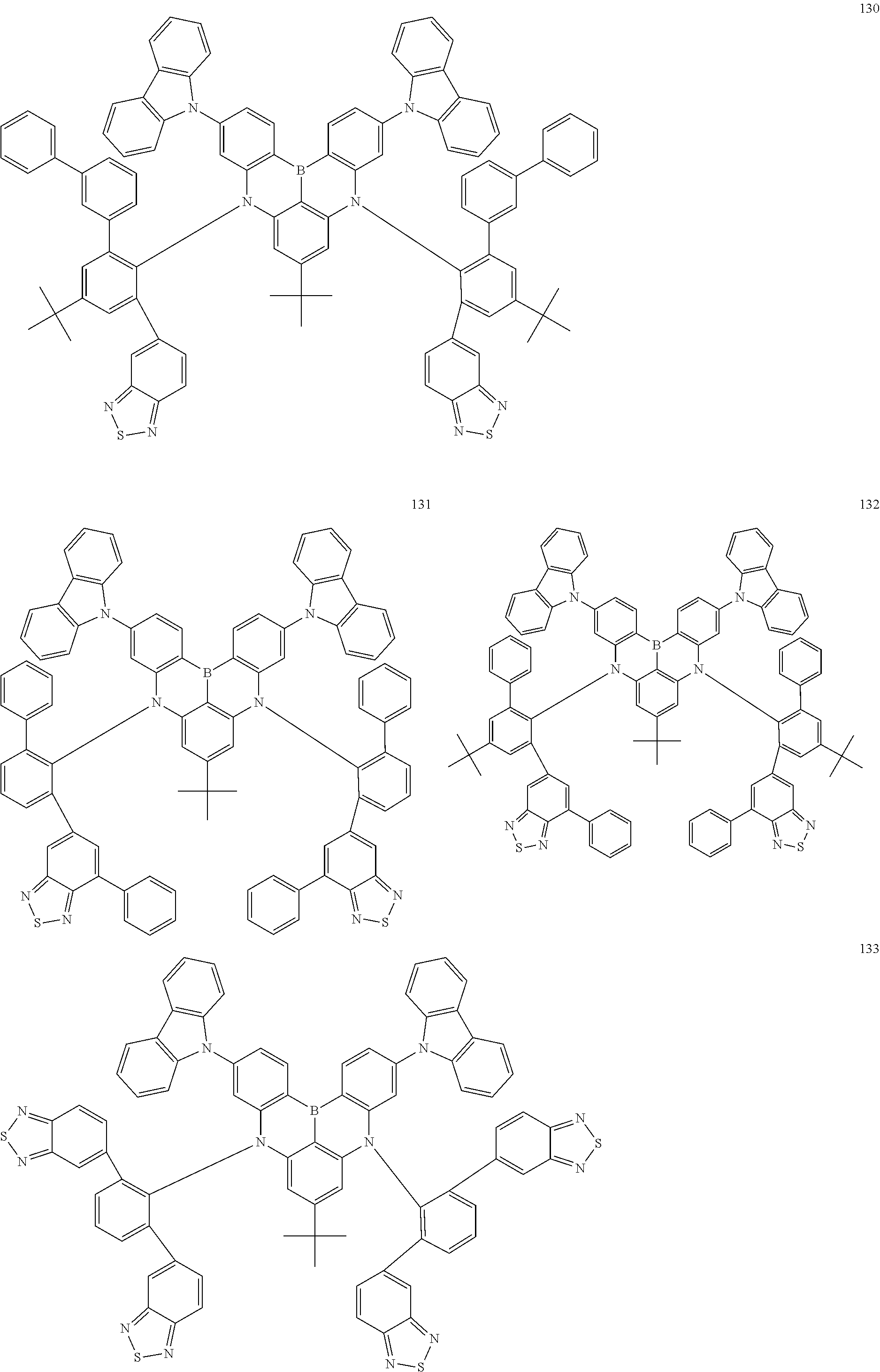

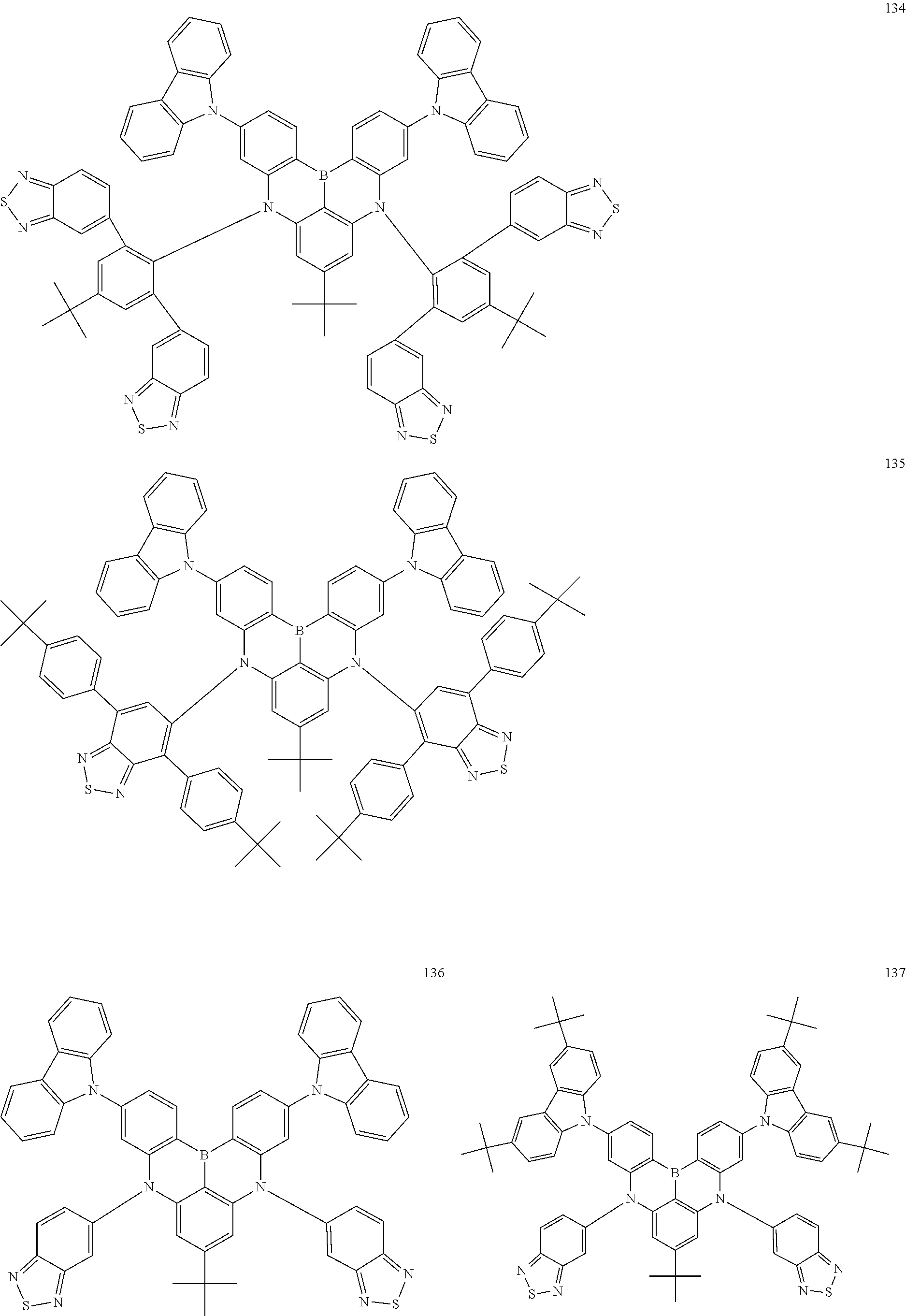

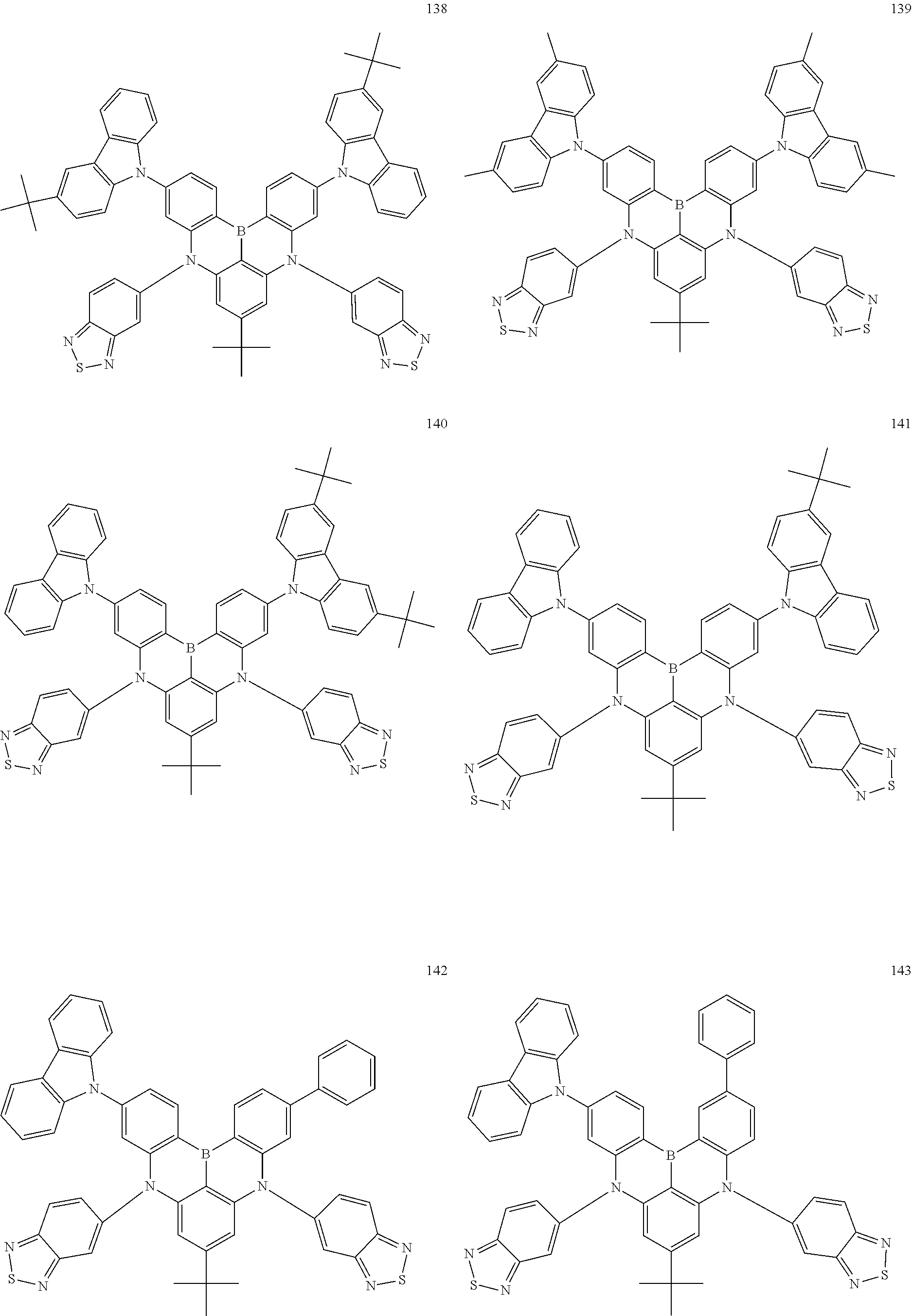

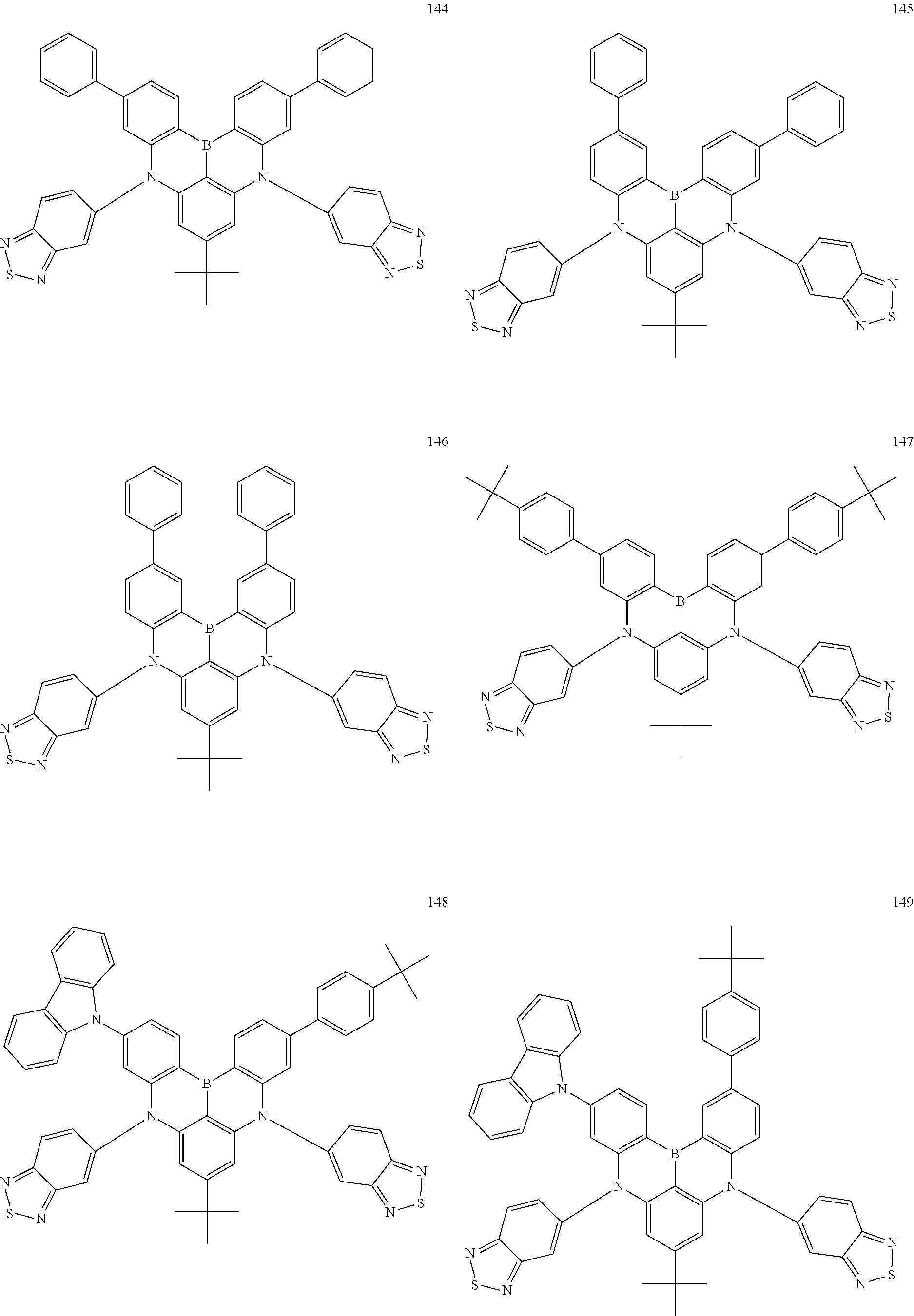

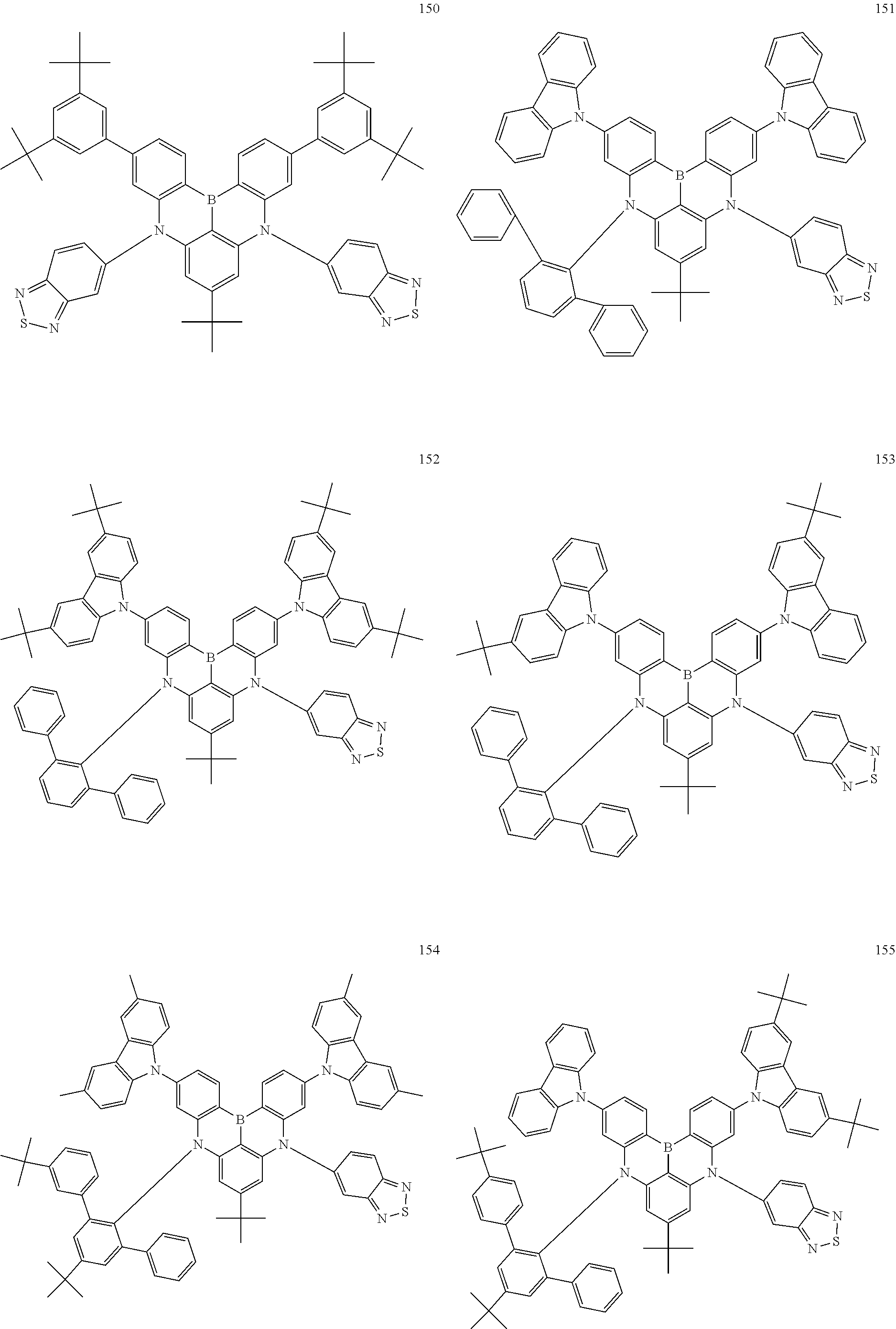

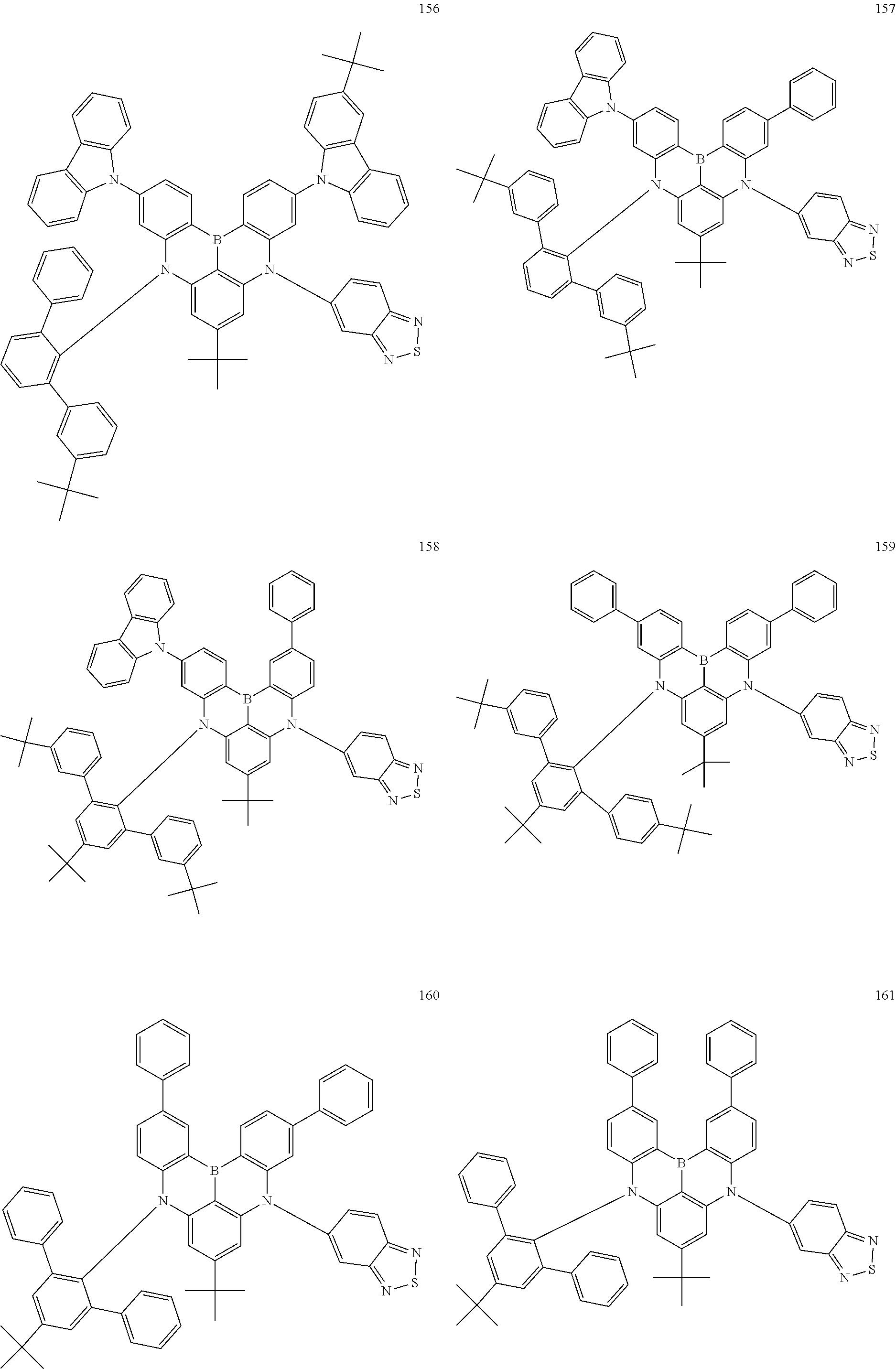

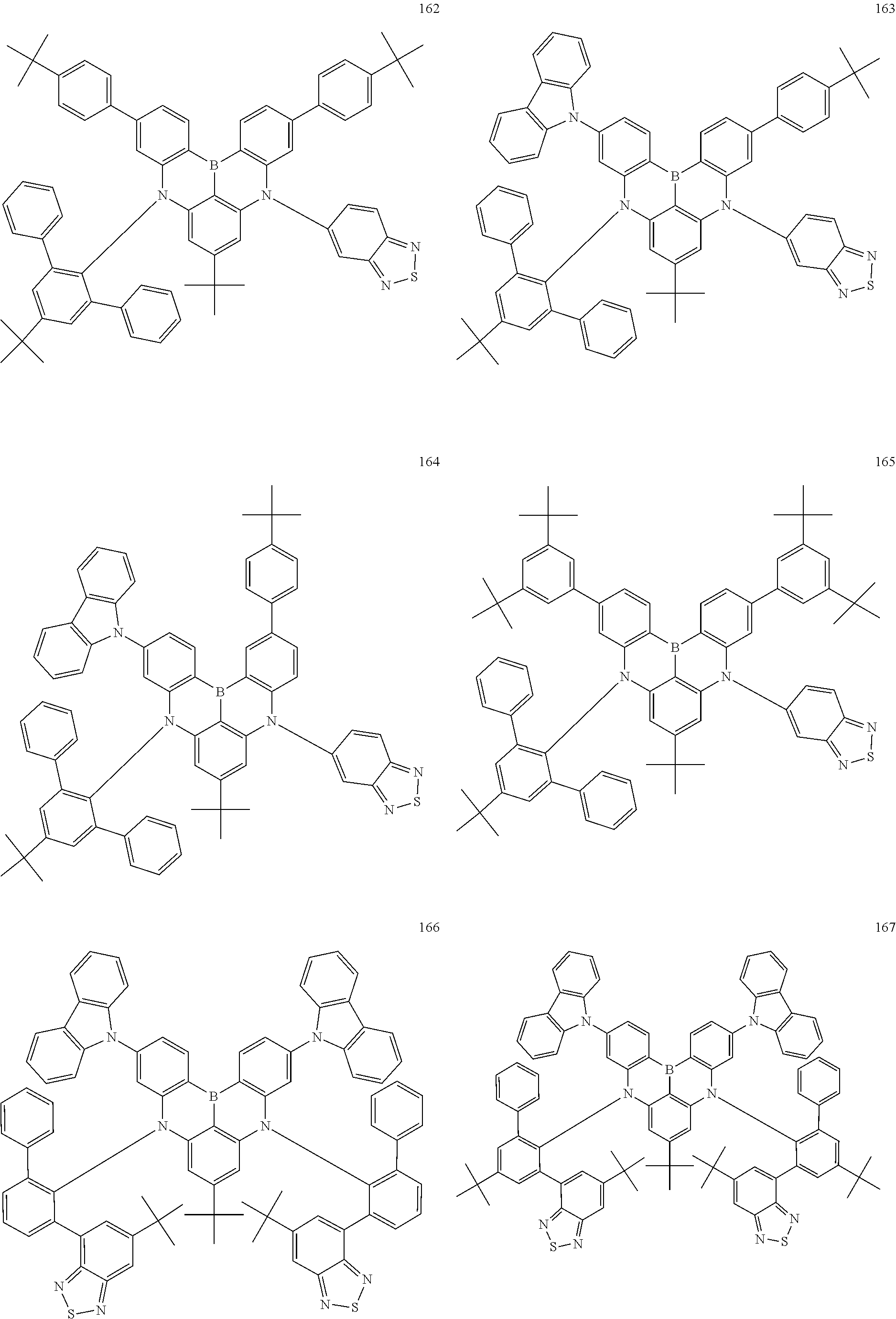

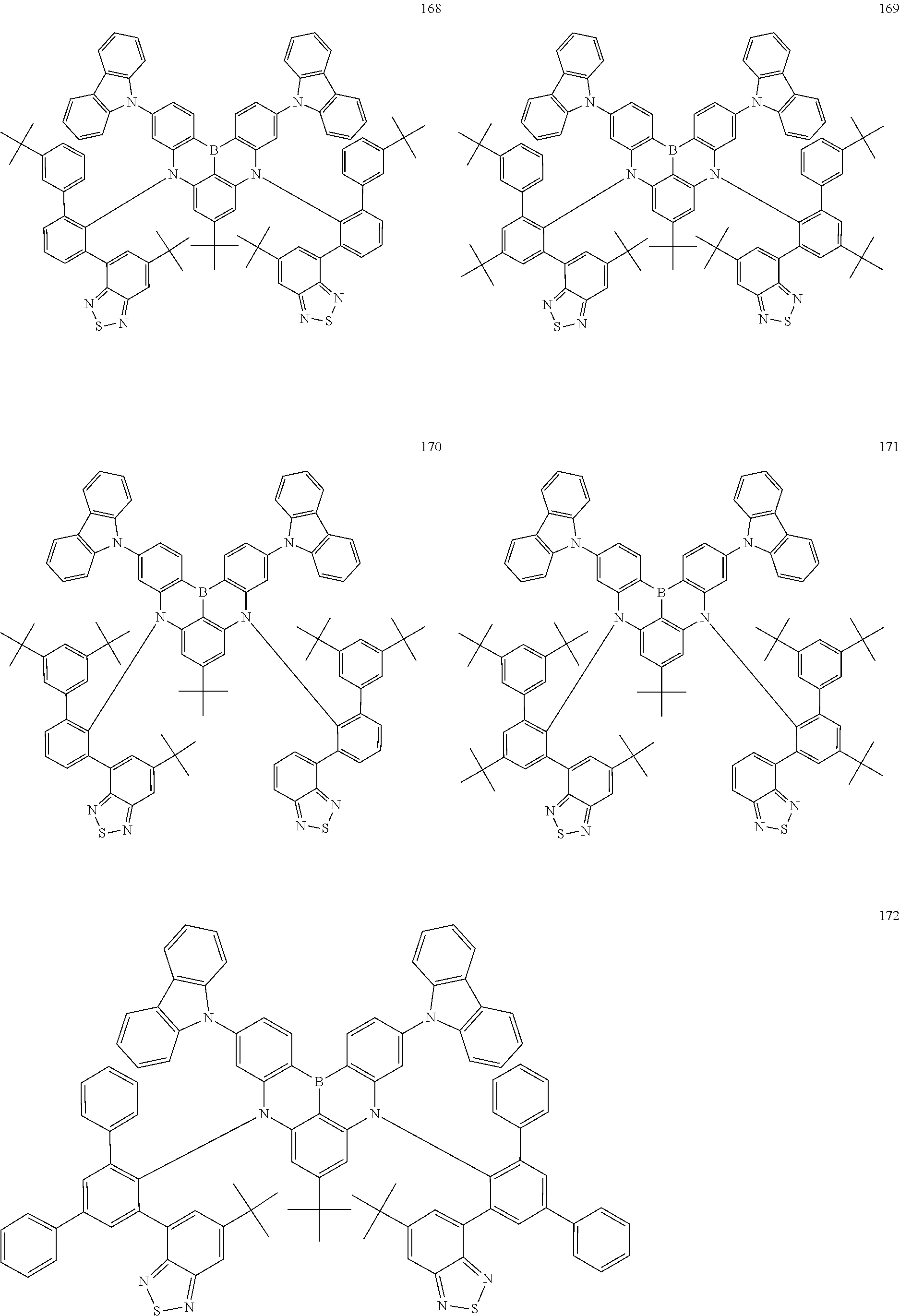

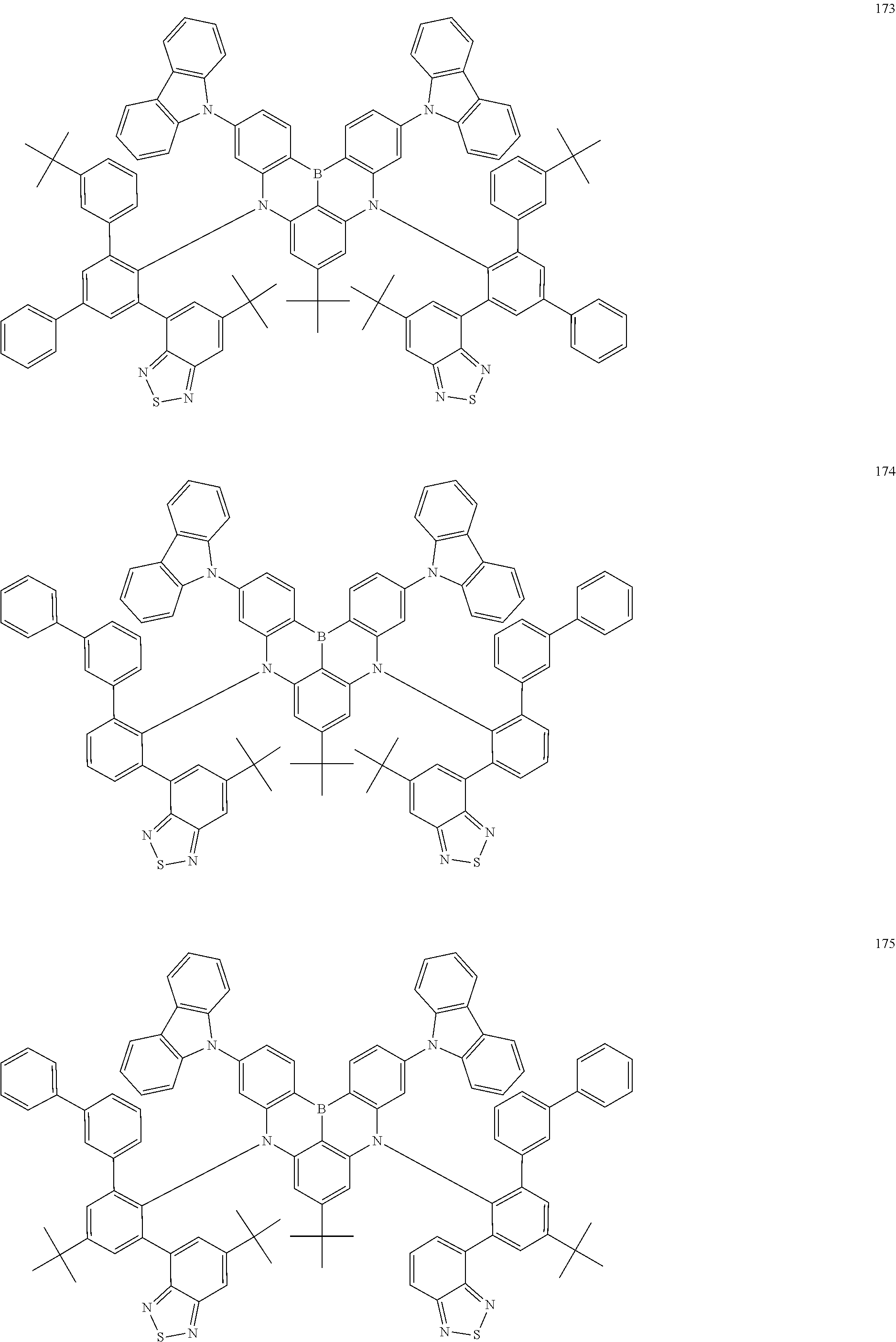

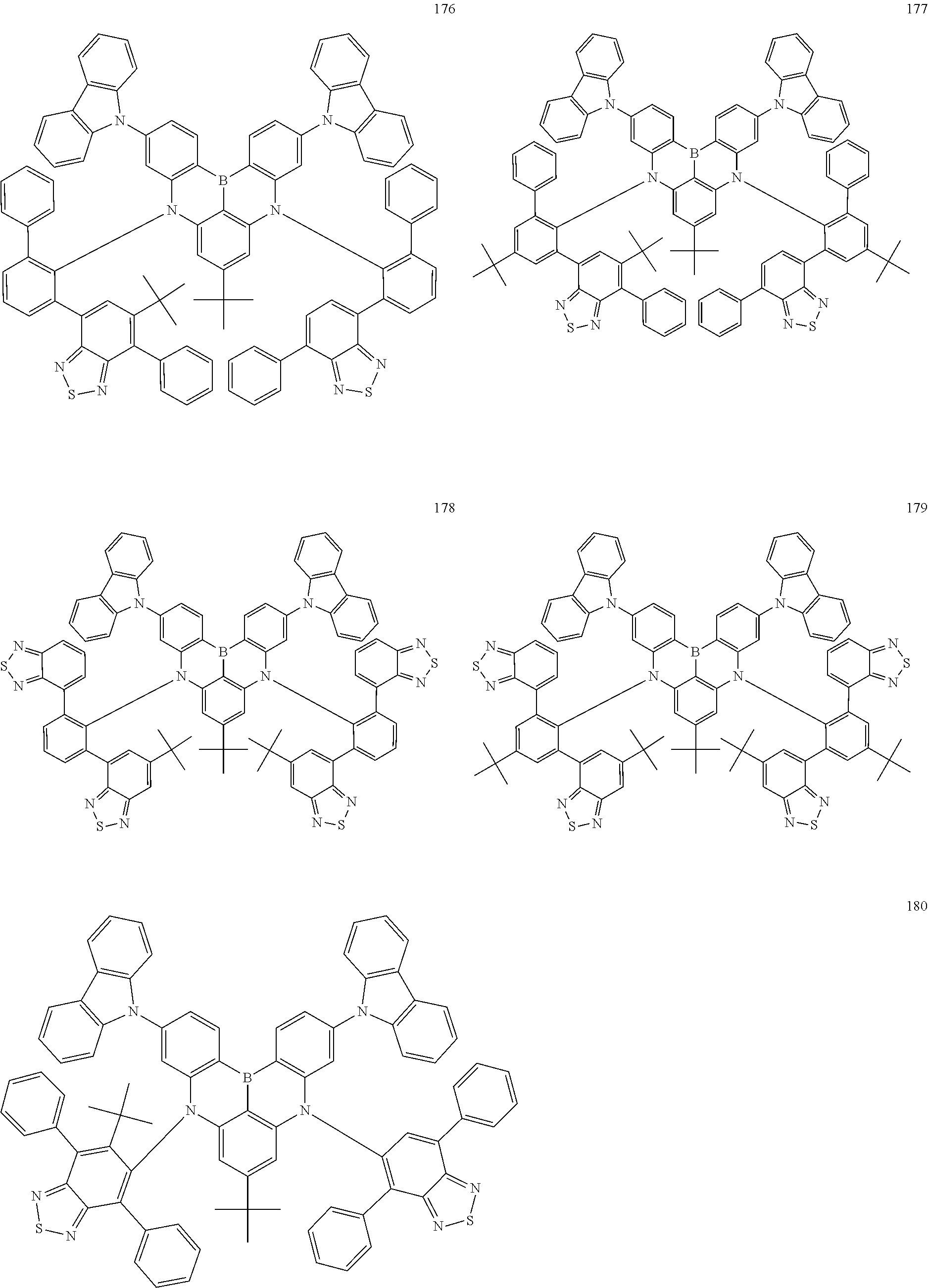

In a conventional organic light-emitting element of the related art, in the emission layer when a fused polycyclic compound includes a boron atom, the compound tends bond with a nucleophile, since electron density is low due to an unoccupied p-orbital of the boron atom. If the electrons of the nucleophile occupy the unoccupied p-orbital of the boron atom, the stereochemical structure of the fused polycyclic compound including the boron atom may become deformed, which may lead to a decrease in lifespan of the light-emitting element. The fused polycyclic compound according to an embodiment includes at least one substituent represented by Formula 3, and is thus capable of effectively protecting the unoccupied p-orbital of the boron atom from the electrons of a nucleophile, thereby improving the lifespan of the light-emitting element. Since the substituent represented by Formula 3 included in the fused polycyclic compound according to an embodiment has a relatively large volume, intermolecular distance increases. Therefore, stability of the light-emitting element may be improved, and thus luminous efficiency may increase.

In the fused polycyclic compound according to an embodiment, since a substituent that is directly bonded to the nitrogen atom of the core includes at least one benzothiadiazole group, a bandgap of the fused polycyclic compound increases, and thus color purity may be improved. The fused polycyclic compound according to an embodiment has high triplet energy, and thus is suitable for reverse intersystem crossing, which may improve the efficiency and lifespan of the light-emitting element.

The fused polycyclic compound represented by Formula 1 may be a light-emitting material having a maximum emission wavelength in a range of about 430 nm to about 490 nm.

For example, the fused polycyclic compound represented by Formula 1 may be a thermally activated delayed fluorescence (TADF) dopant that emits blue light. However, embodiments are not limited thereto, and when the fused polycyclic compound according to an embodiment is used as a light-emitting material, the fused polycyclic compound may be used as a light-emitting material that emits light in various wavelength regions, such as a red emission dopant or a green emission dopant.

In the light-emitting element ED according to an embodiment, the emission layer EML may emit delayed fluorescence. For example, the emission layer EML may emit thermally activated delayed fluorescence (TADF).

The emission layer EML of the light-emitting element ED may emit blue light. For example, the emission layer EML of the light-emitting element ED may emit blue light in a wavelength range equal to or less than about 490 nm. However, embodiments are not limited thereto, and the emission layer EML may emit green light or red light.

The fused polycyclic compound according to an embodiment may be included in the emission layer EML. The fused polycyclic compound according to an embodiment may be included in the emission layer EML as a dopant material. The fused polycyclic compound according to an embodiment may be a thermally activated delayed fluorescent light emitting material. The fused polycyclic compound according to an embodiment may be used as a thermally activated delayed fluorescent dopant. For example, in the light-emitting element ED, the emission layer EML may include at least one compound selected from Compound Group 1 as a thermally activated delayed fluorescence dopant. However, a use of the fused polycyclic compound according to an embodiment is not limited thereto.

In an embodiment, the emission layer EML may include multiple compounds. In an embodiment, the emission layer EML may include the fused polycyclic compound represented by Formula 1 as a first compound, and may further include at least one of a second compound represented by Formula HT-1, a third compound represented by Formula ET-1, and a fourth compound represented by Formula D-1.

In an embodiment, the emission layer EML may include the first compound represented by Formula 1, and may further include at least one of a second compound represented by Formula HT-1 and a third compound represented by Formula ET-1.

In an embodiment, the emission layer EML may further include a second compound represented by Formula HT-1. In an embodiment, the second compound may be used as a hole transport host material in an emission layer EML:

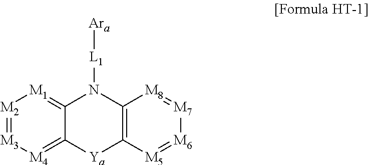

In Formula HT-1, M₁ to M₈ may each independently be N or C(R₅₁). For example, M₁ to M₈ may each independently be C(R₅₁). As another example, one of M₁ to M₈ may be N, and the remainder of M₁ to M₈ may each independently be C(R₅₁).

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT-1, Yₐ may be a direct linkage, C(R₅₂)(R₅₃), or Si(R₅₄)(R₅₅). For example, the two benzene rings that are connected to the nitrogen atom of Formula HT-1 may be connected to each other via a direct linkage,

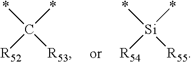

In Formula HT-1, if Yₐ is a direct linkage, the second compound represented by Formula HT-1 may include a carbazole moiety.

In Formula HT-1, Arₐ may be a substituted or unsubstituted aryl group of 6 to 30 ring-forming carbon atoms or a substituted or unsubstituted heteroaryl group of 2 to 30 ring-forming carbon atoms. For example, Arₐ may be a substituted or unsubstituted carbazole group, a substituted or unsubstituted dibenzofuran group, a substituted or unsubstituted dibenzothiophene group, a substituted or unsubstituted biphenyl group, or the like, but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or bonded to an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in light-emitting element ED, the second compound may include at least one compound selected from Compound Group 2:

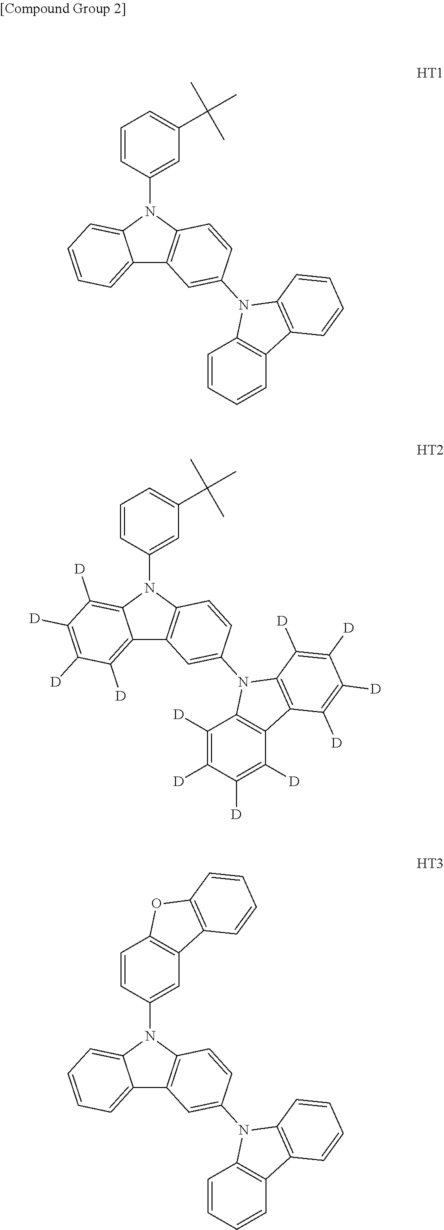 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

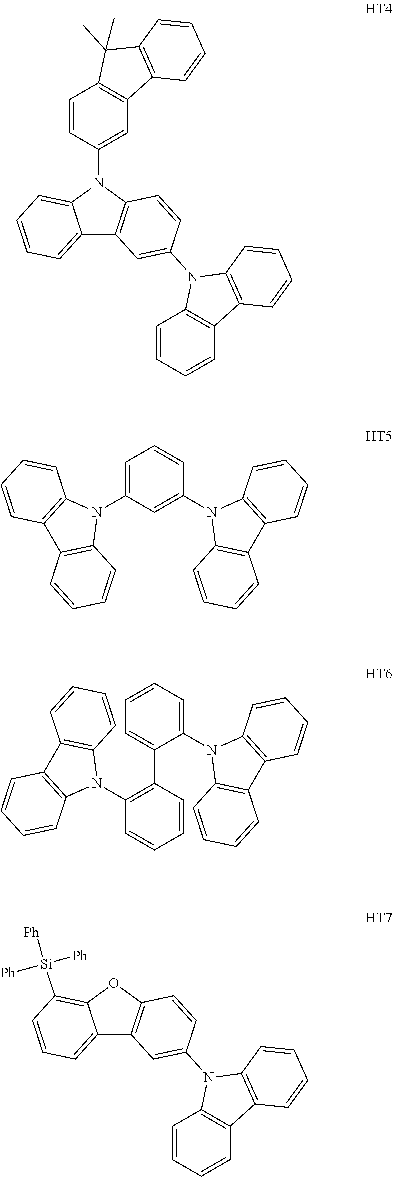 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

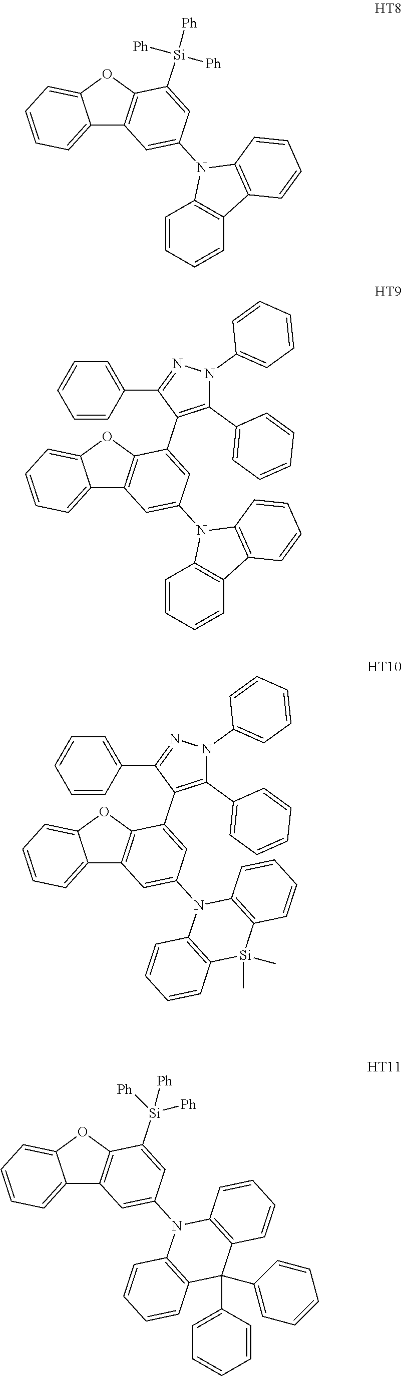 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; C[Si]1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

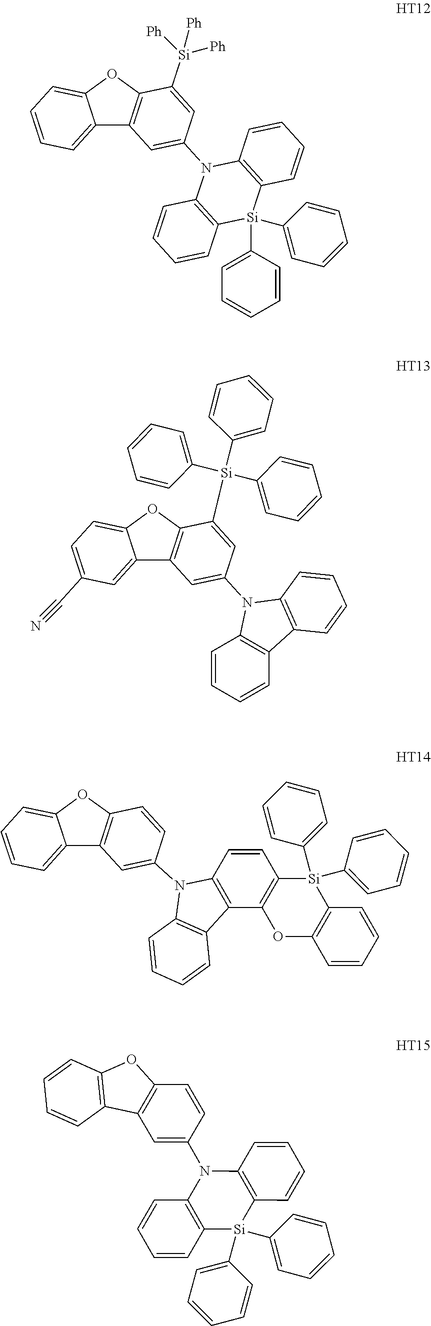 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1]

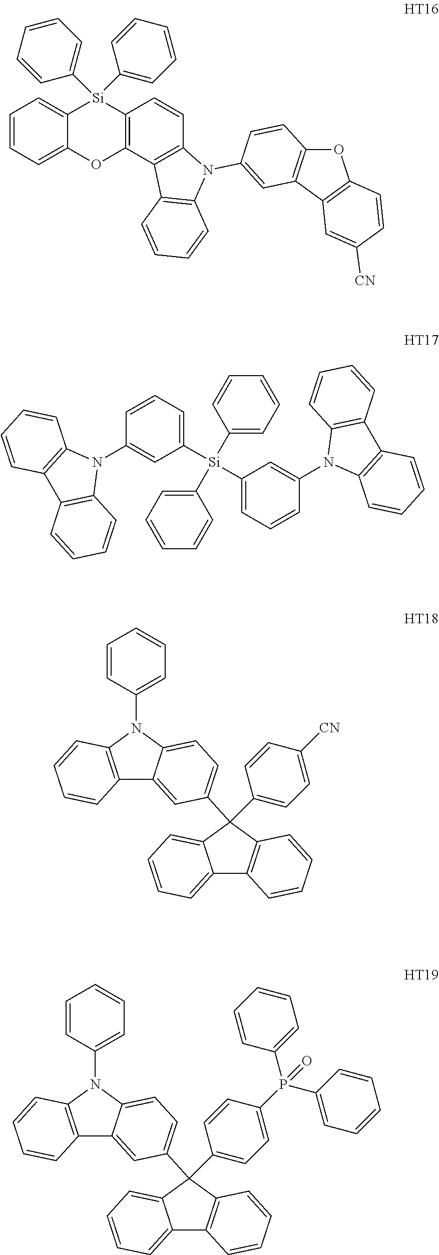 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

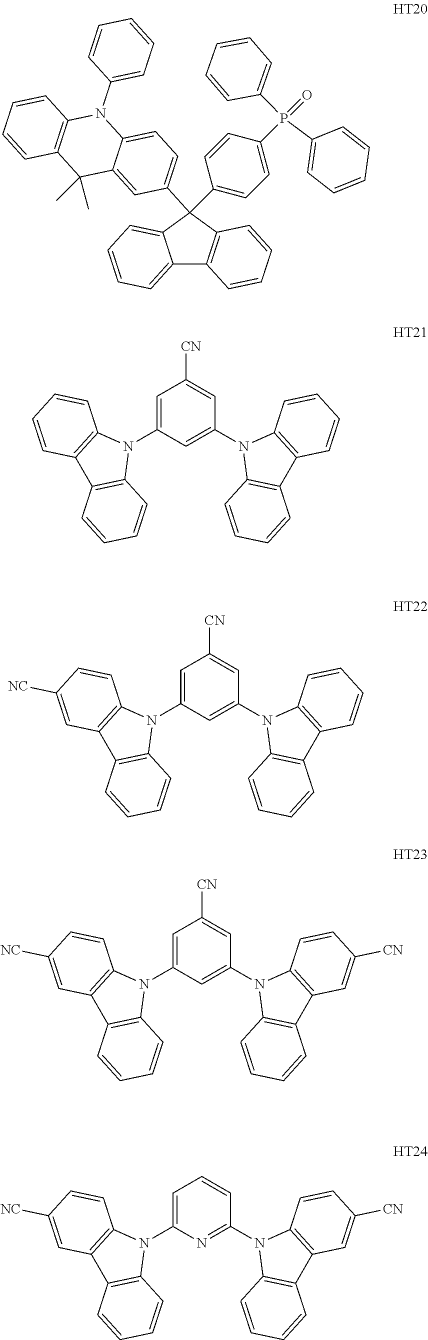 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

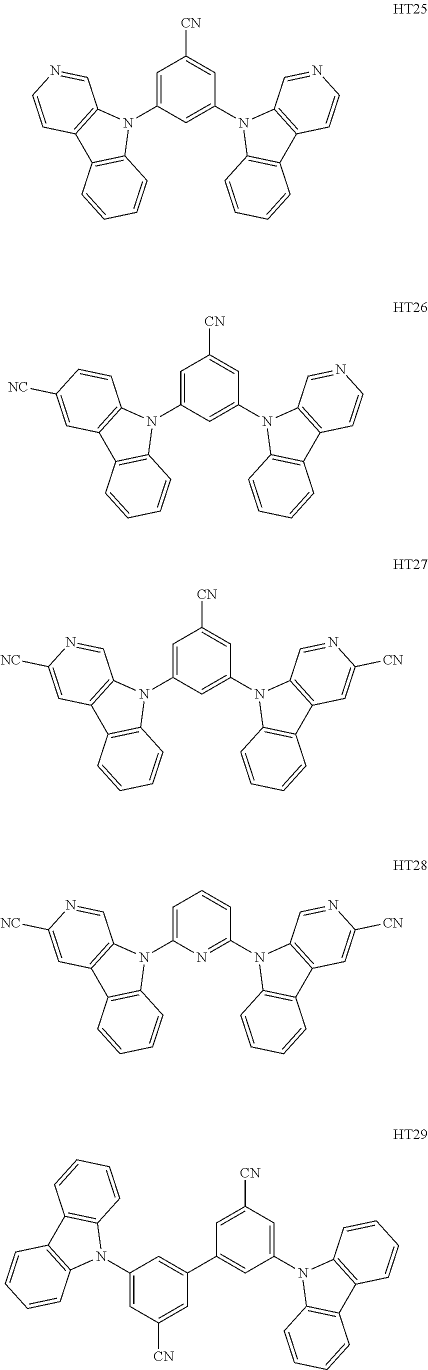 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

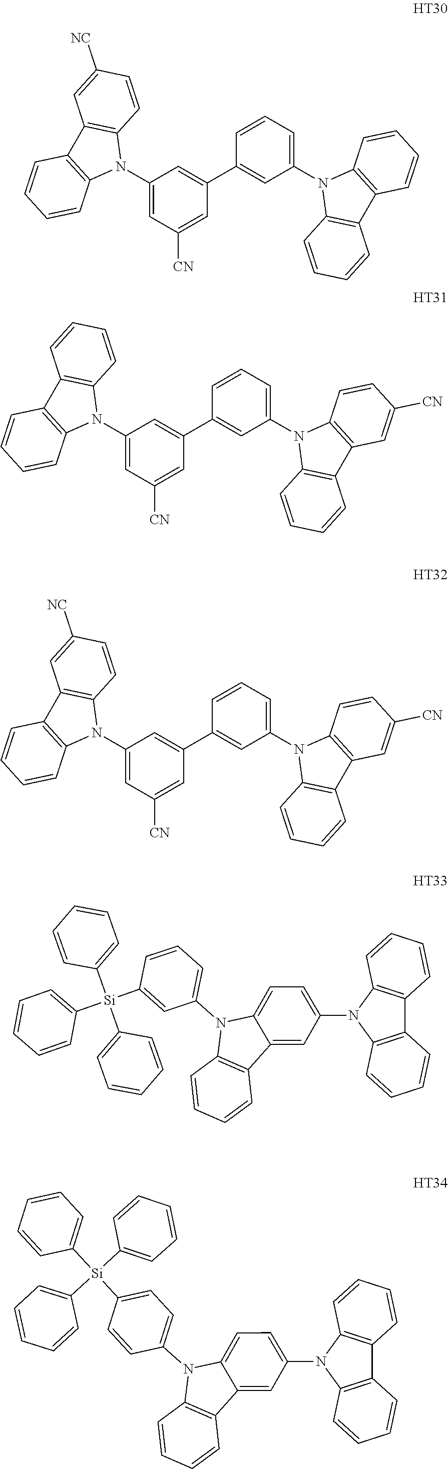 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

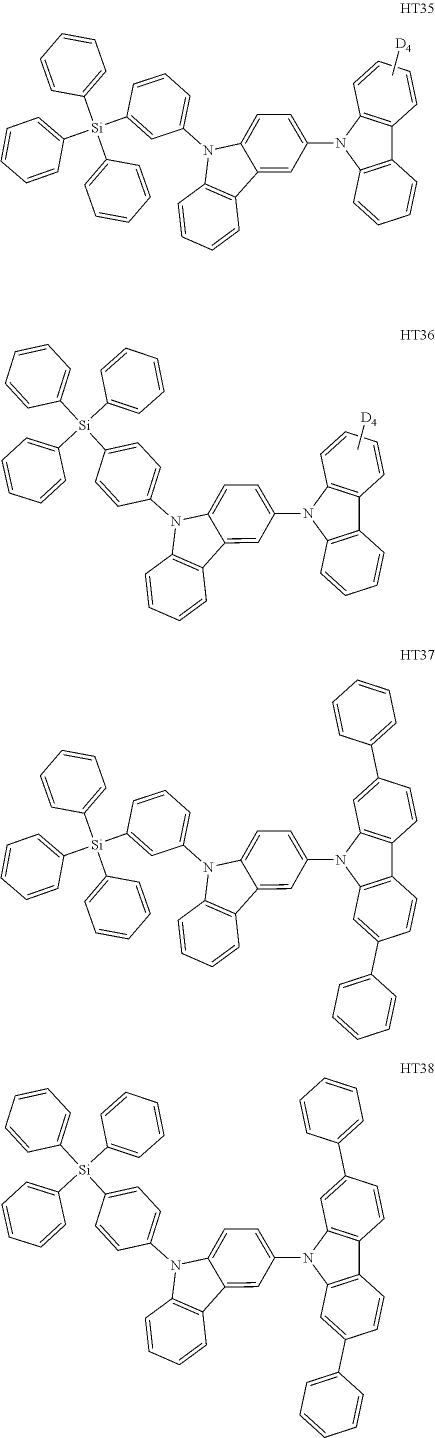

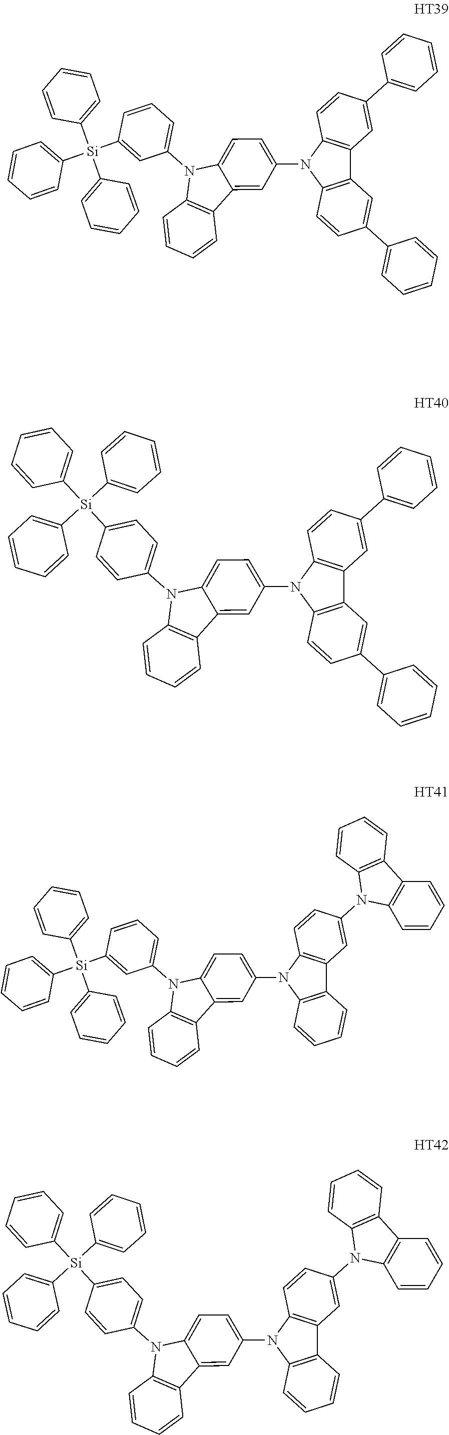 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

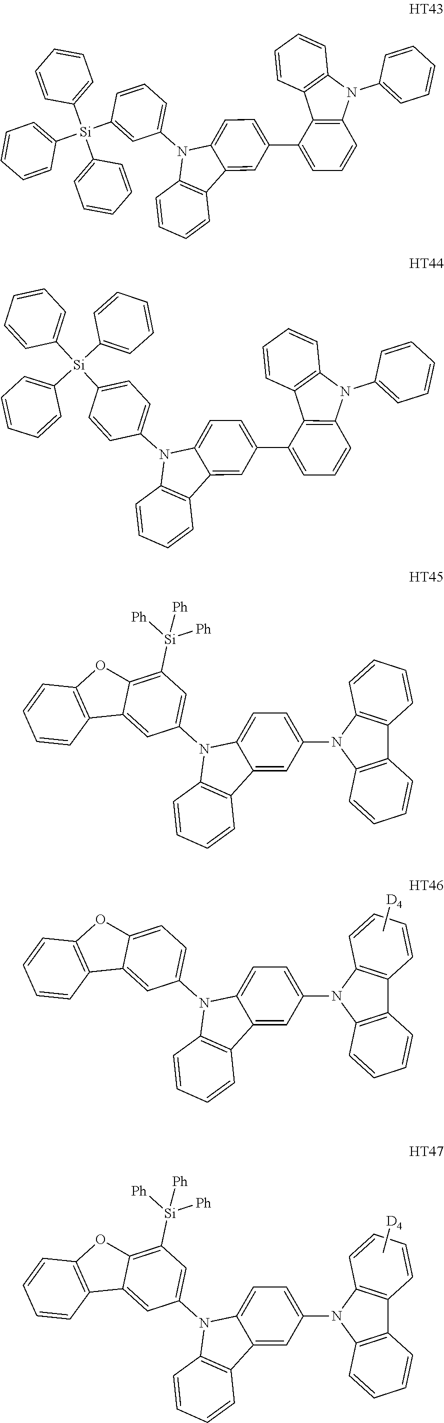

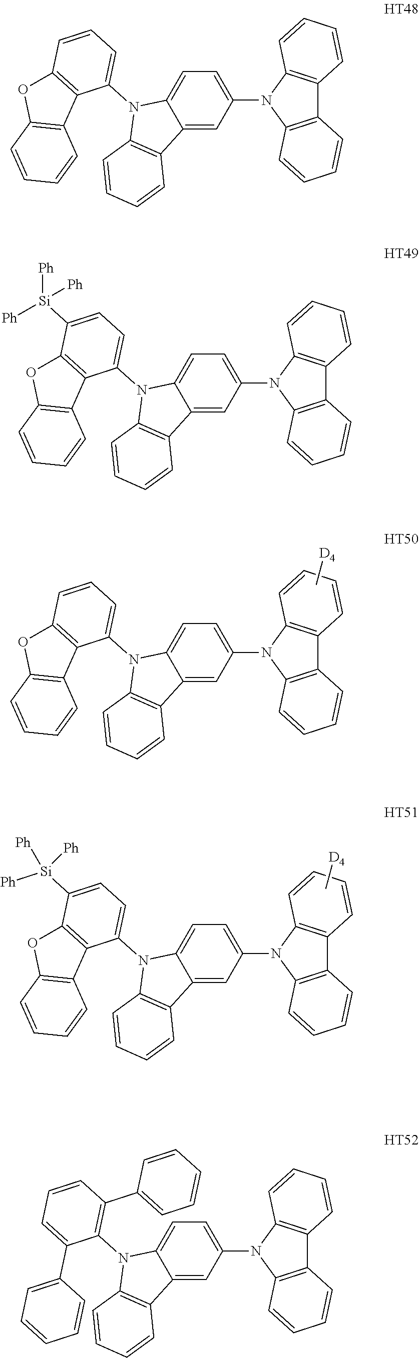

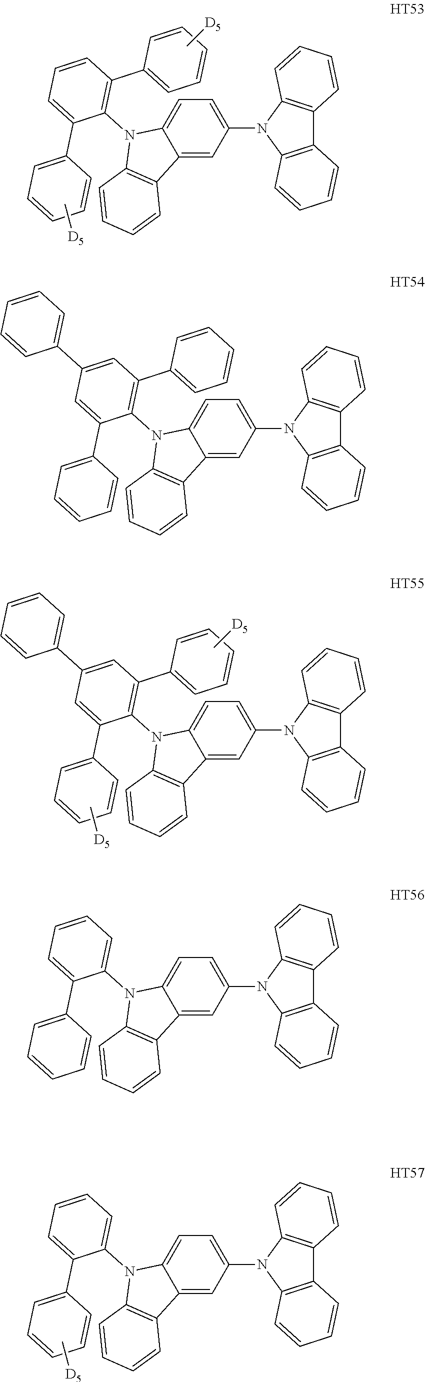

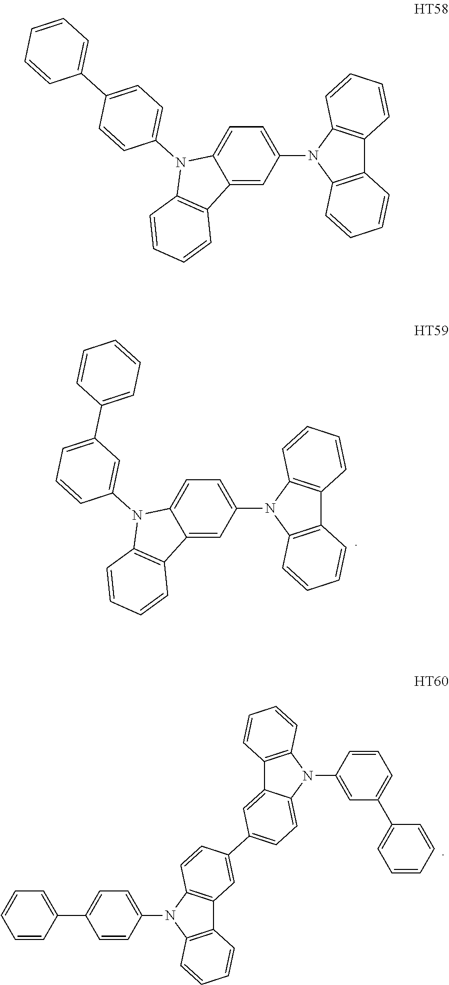 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

In Compound Group 2, D represents a deuterium atom, and Ph represents an unsubstituted phenyl group.

In an embodiment, the emission layer EML may further include a third compound represented by Formula ET-1. In an embodiment, the third compound may be used as an electron transport host material in the emission layer EML:

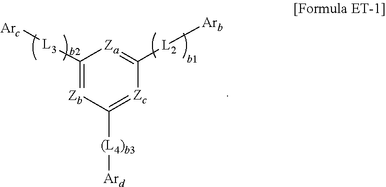

In Formula ET-1, at least one of Zₐ to Zₑ may each be N, and the remainder of Zₐ to Z_{c} may each independently be C(R₅₆). For example, one of Zₐ to Zₑ may be N, and the remainder of Zₐ to Zₑ may each independently be C(R₅₆). Thus, the third compound represented by Formula ET-1 may include a pyridine moiety. As another example, two of Zₐ to Zₑ may each be N, and the remainder of Zₐ to Zₑ may be C(R₅₆). Thus, the third compound represented by Formula ET-1 may include a pyrimidine moiety. As yet another example, Zₐ to Zₑ may each be N. Thus, the third compound represented by Formula ET-1 may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer from 0 to 10.

In Formula ET-1, Ar_{b} to Ar_{d} may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar_{b} to Ar_{d} may each independently be a substituted or unsubstituted phenyl group or a substituted or unsubstituted carbazole group.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. If b1 to b3 are each 2 or more, multiple groups of each of L₂ to L₄ may each independently be a substituted or unsubstituted arylene group of 6 to 30 ring-forming carbon atoms or a substituted or unsubstituted heteroarylene group of 2 to 30 ring-forming carbon atoms.

In an embodiment, the third compound represented by Formula ET-1 may be any compound selected from Compound Group 3. In an embodiment, in the light-emitting element ED, the third compound may include at least one compound selected from Compound Group 3:

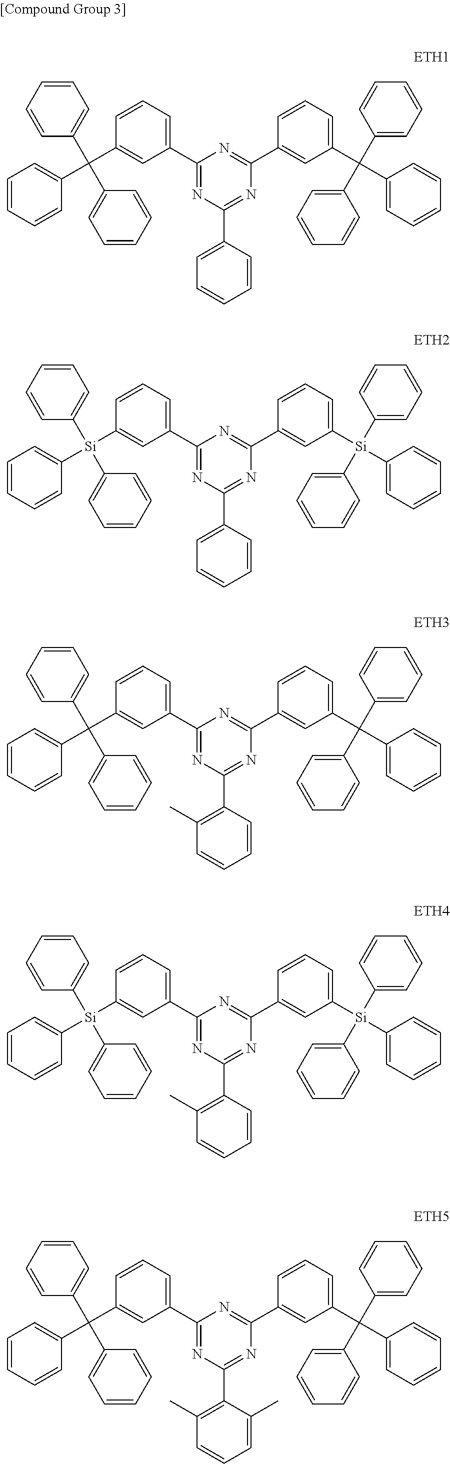

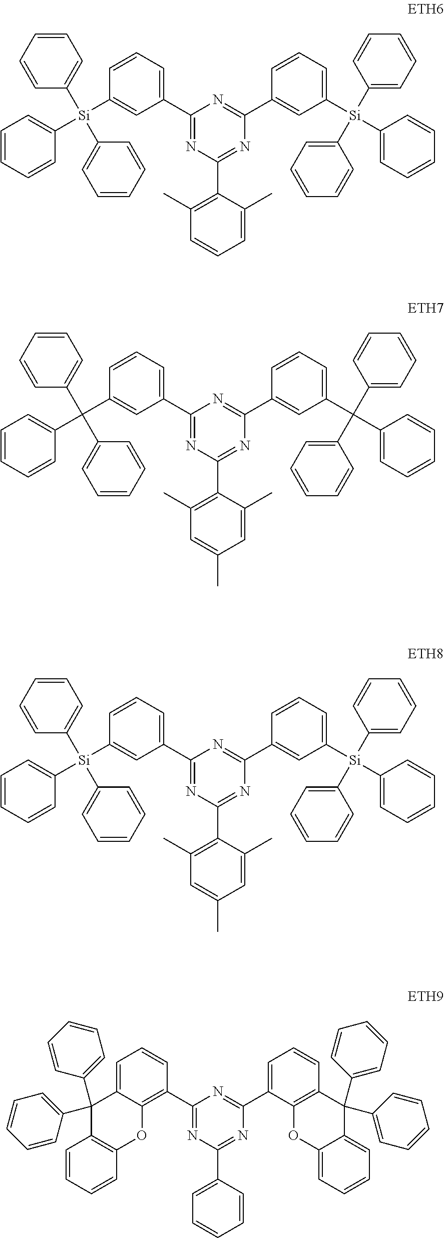 [SMILES: Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1]

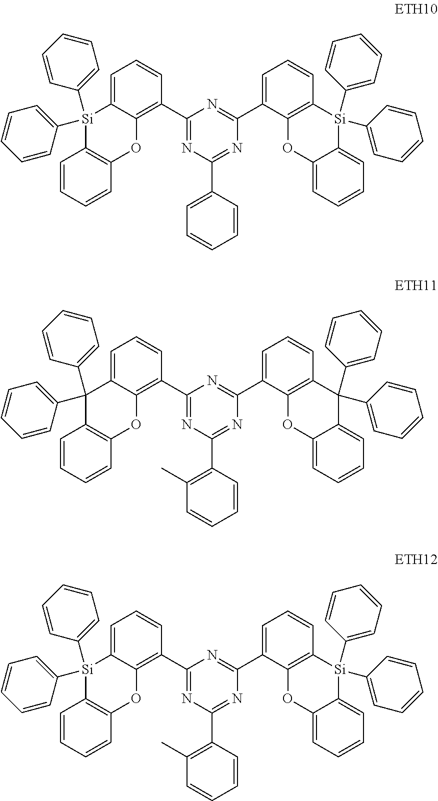 [SMILES: c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

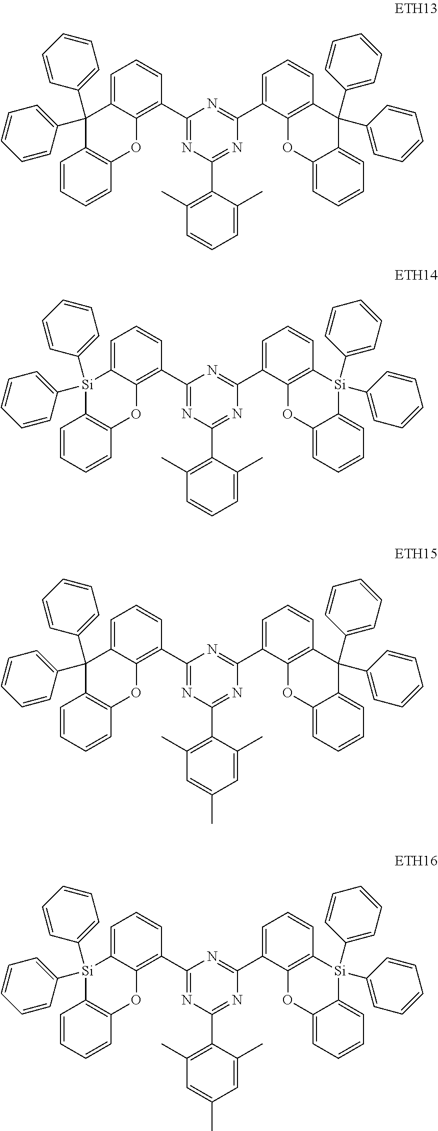 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

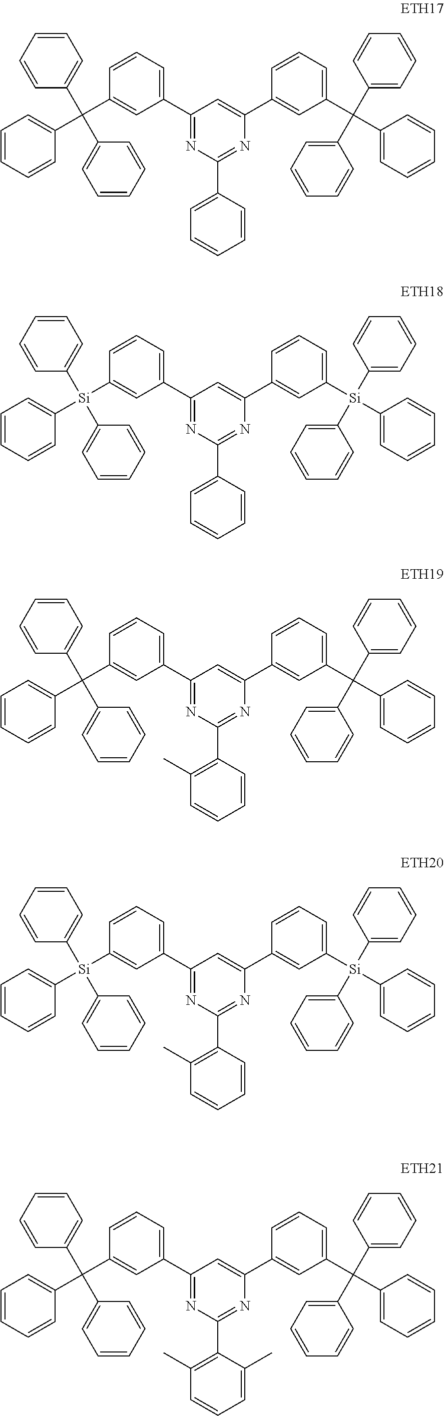

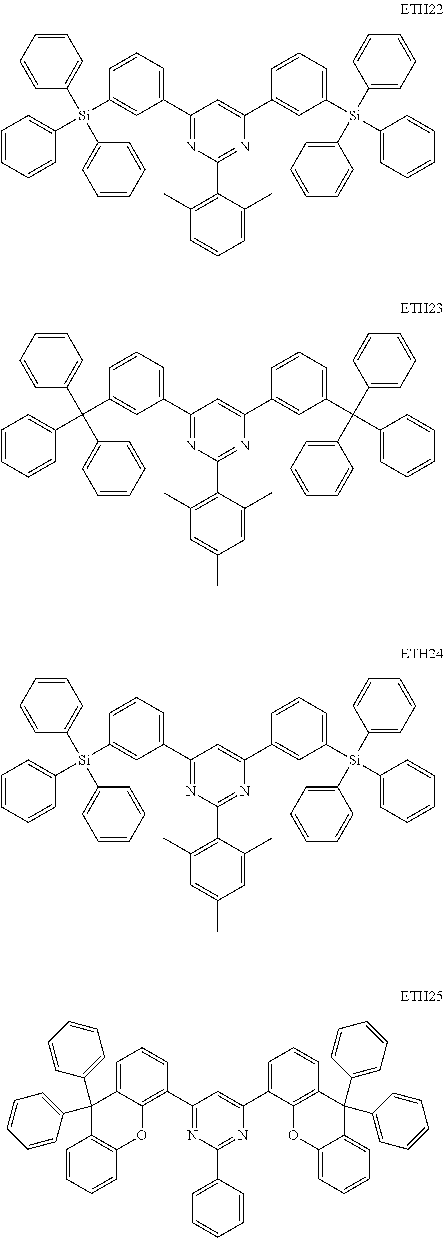 [SMILES: Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1]

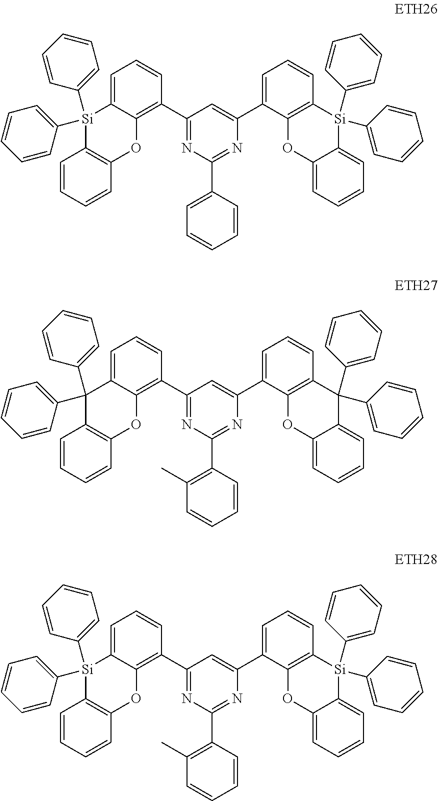 [SMILES: c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

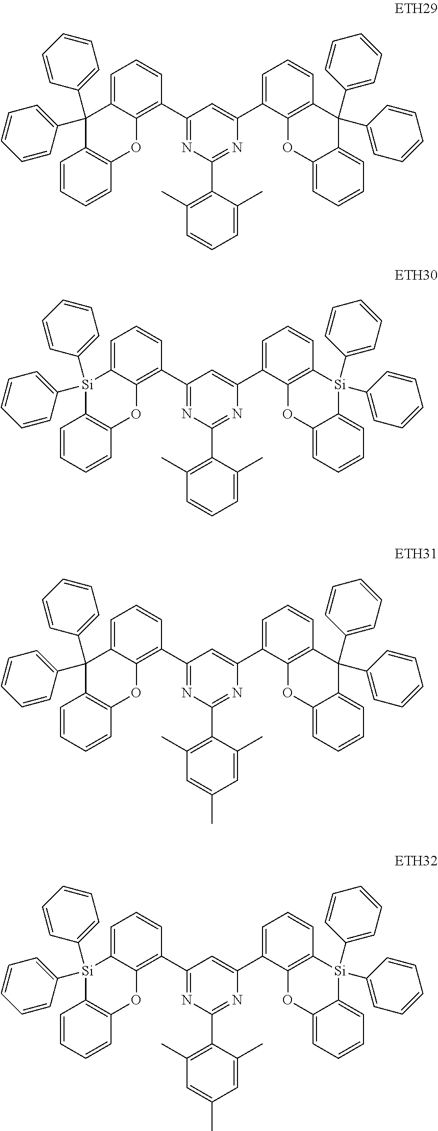 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

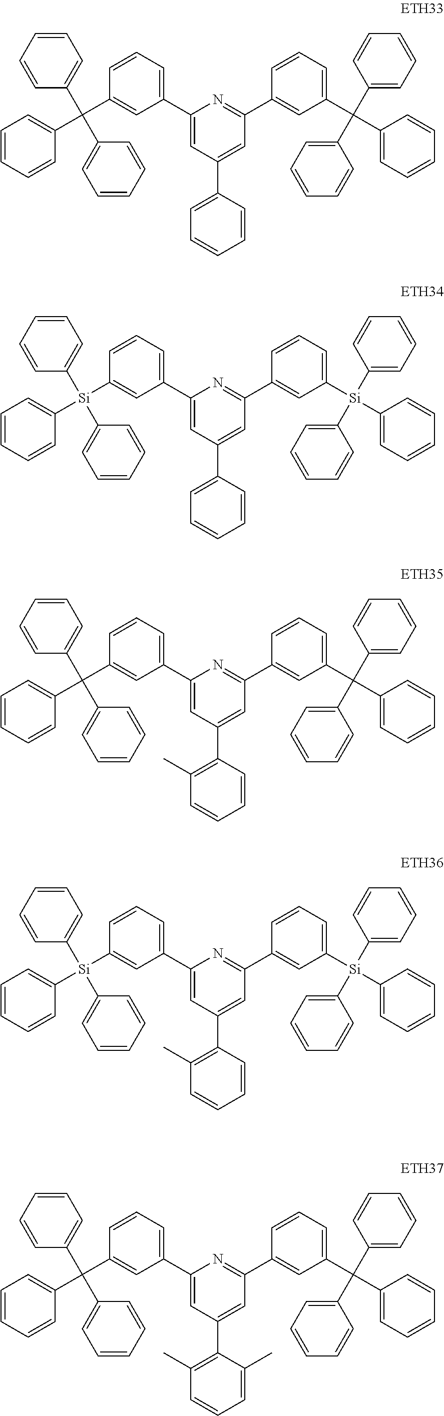

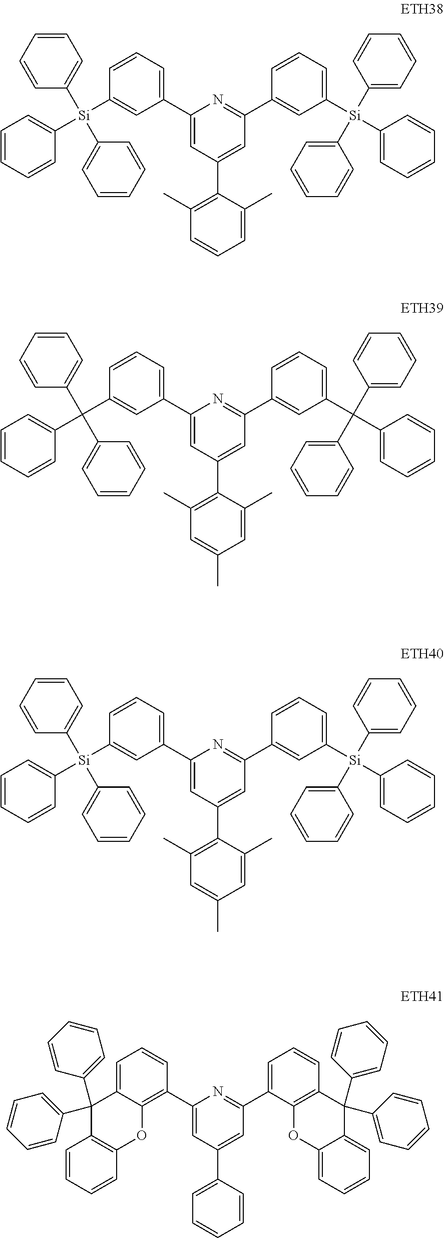 [SMILES: Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1 ; c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1]

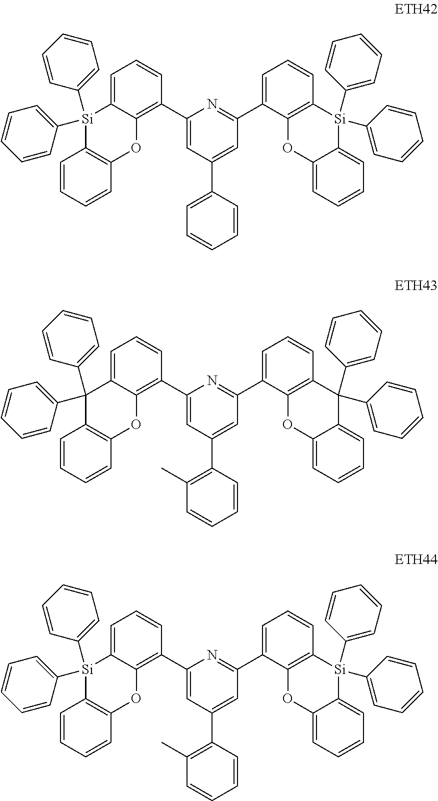 [SMILES: c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

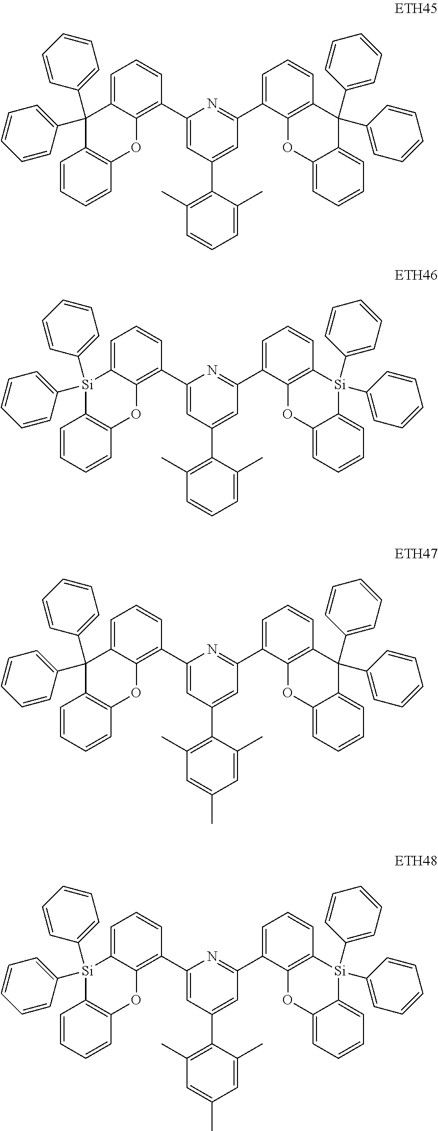 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

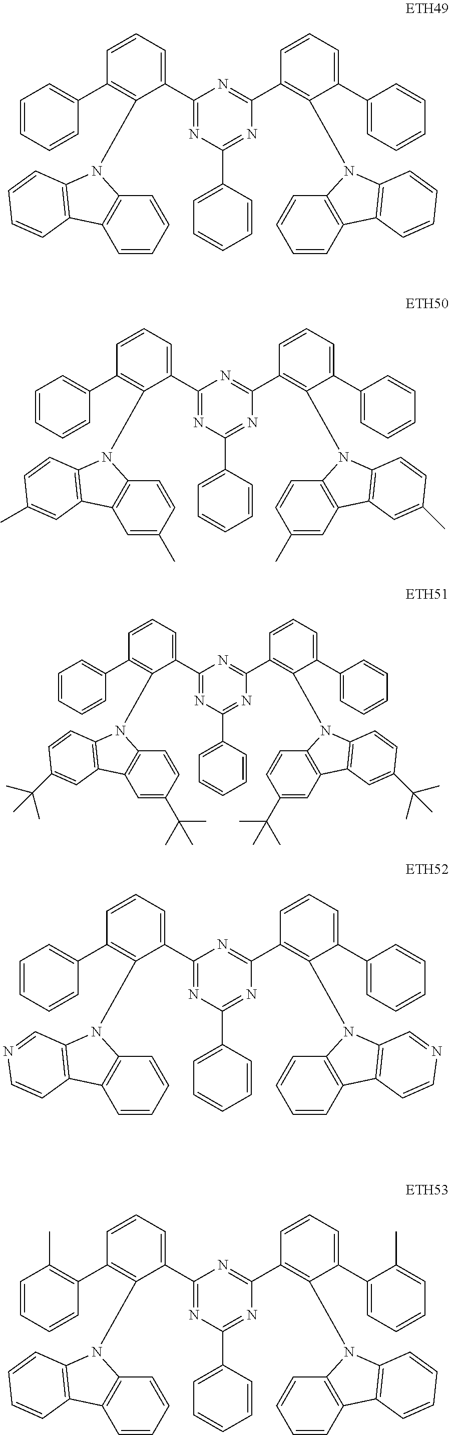

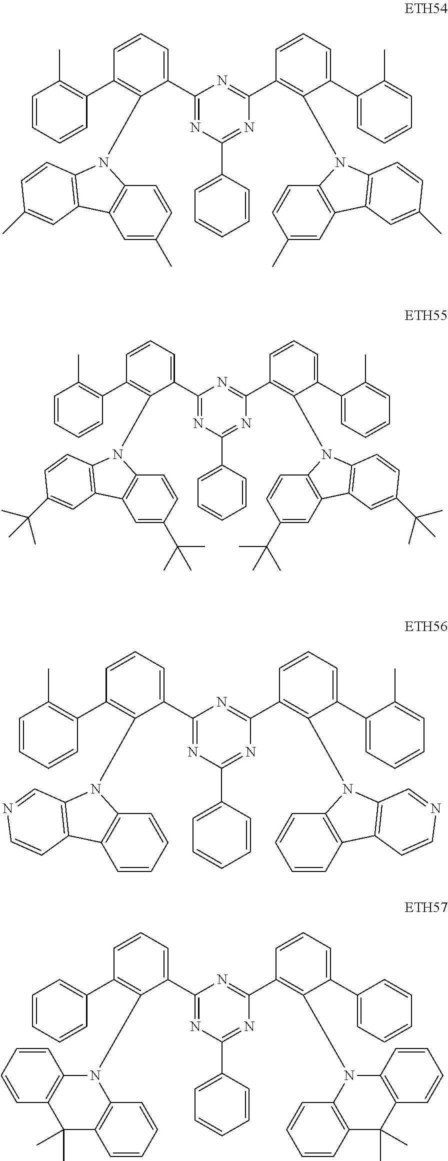

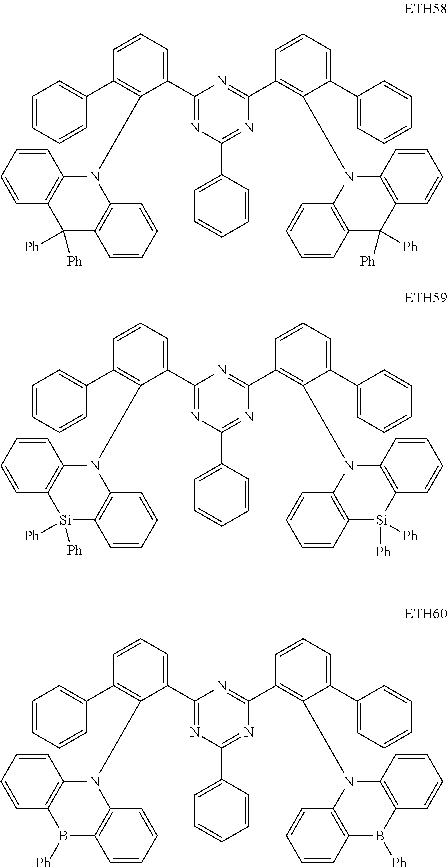 [SMILES: c1ccc(-c2nc(-c3cccc(-c4ccccc4)c3N3c4ccccc4C(c4ccccc4)(c4ccccc4)c4ccccc43)nc(-c3cccc(-c4ccccc4)c3N3c4ccccc4C(c4ccccc4)(c4ccccc4)c4ccccc43)n2)cc1 ; c1ccc(-c2nc(-c3cccc(-c4ccccc4)c3N3c4ccccc4[Si](c4ccccc4)(c4ccccc4)c4ccccc43)nc(-c3cccc(-c4ccccc4)c3N3c4ccccc4[Si](c4ccccc4)(c4ccccc4)c4ccccc43)n2)cc1 ; c1ccc(B2c3ccccc3N(c3c(-c4ccccc4)cccc3-c3nc(-c4ccccc4)nc(-c4cccc(-c5ccccc5)c4N4c5ccccc5B(c5ccccc5)c5ccccc54)n3)c3ccccc32)cc1]

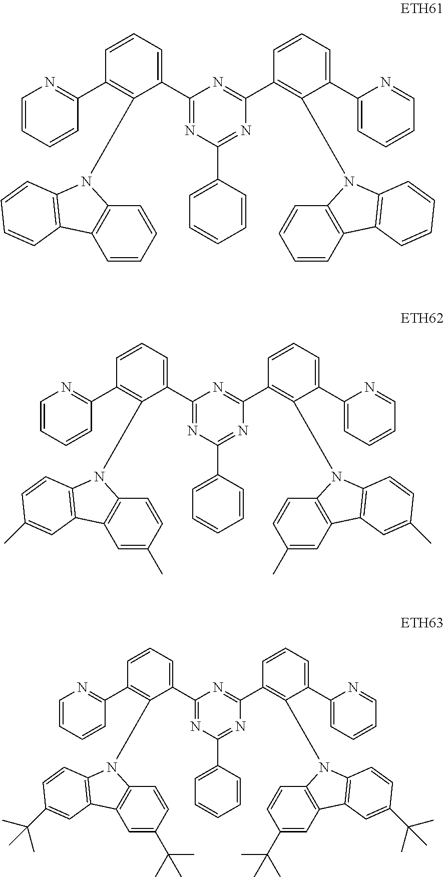

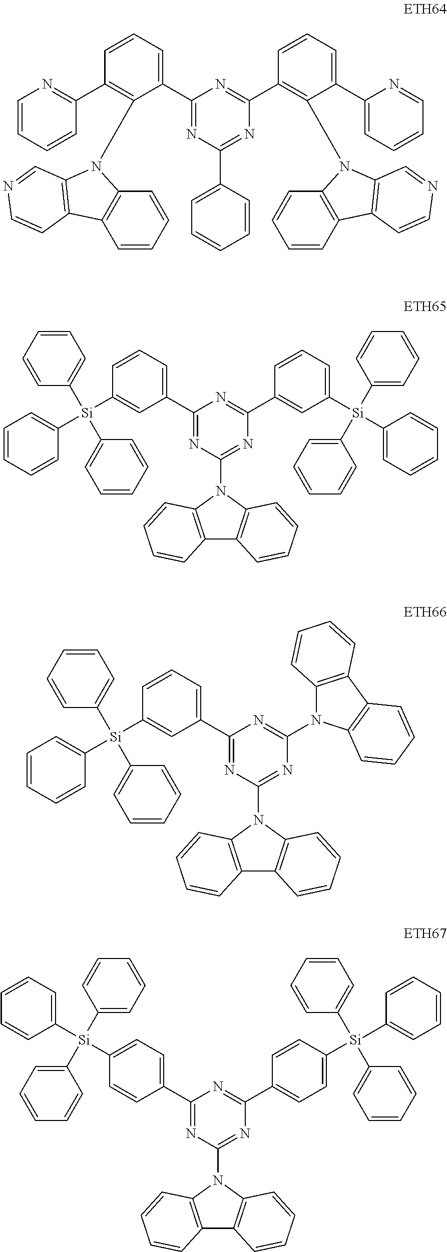 [SMILES: c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1]

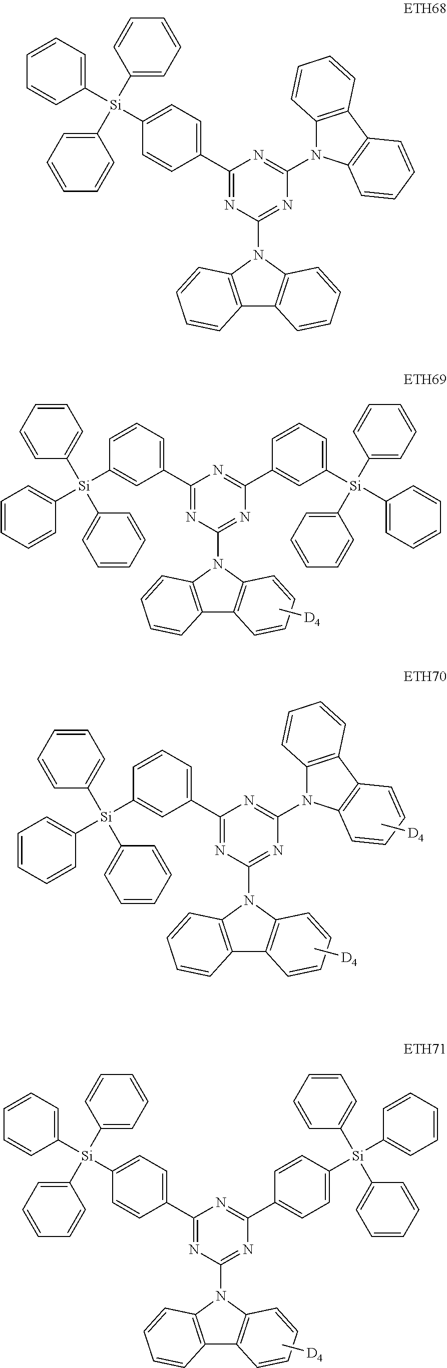

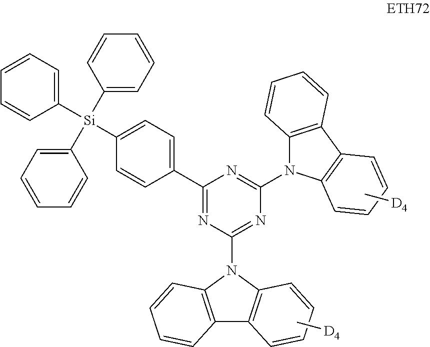

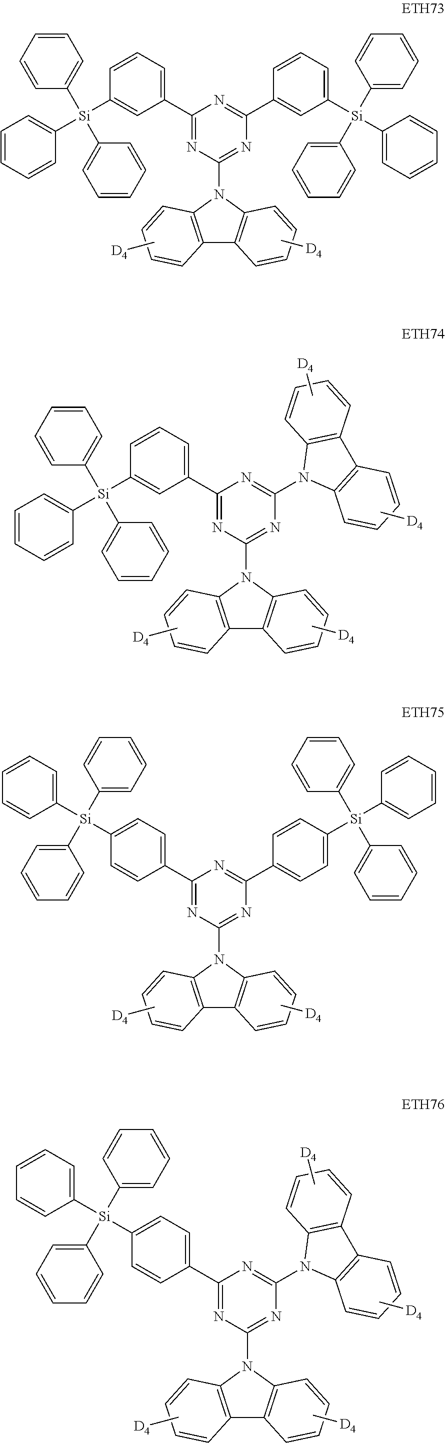

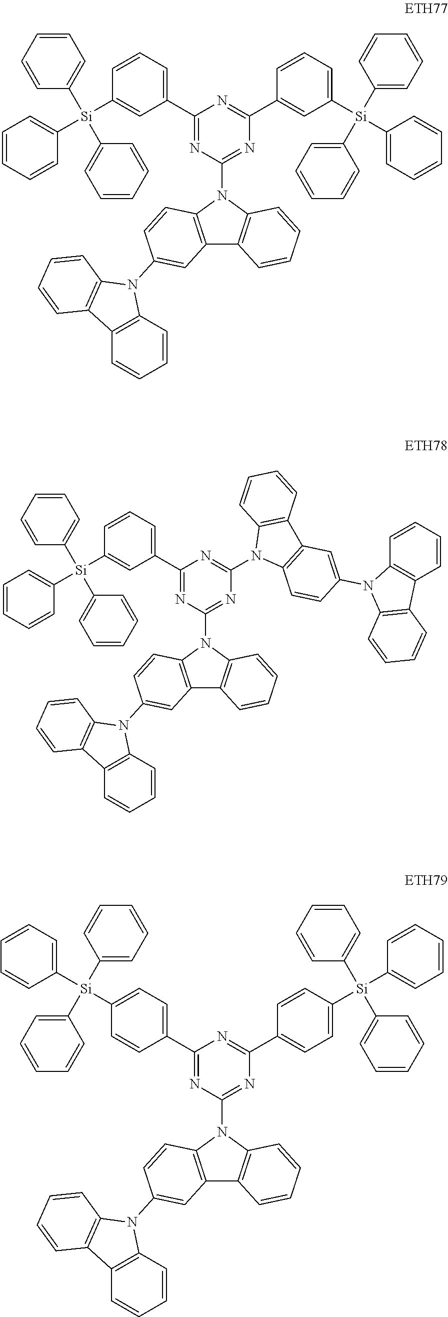 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

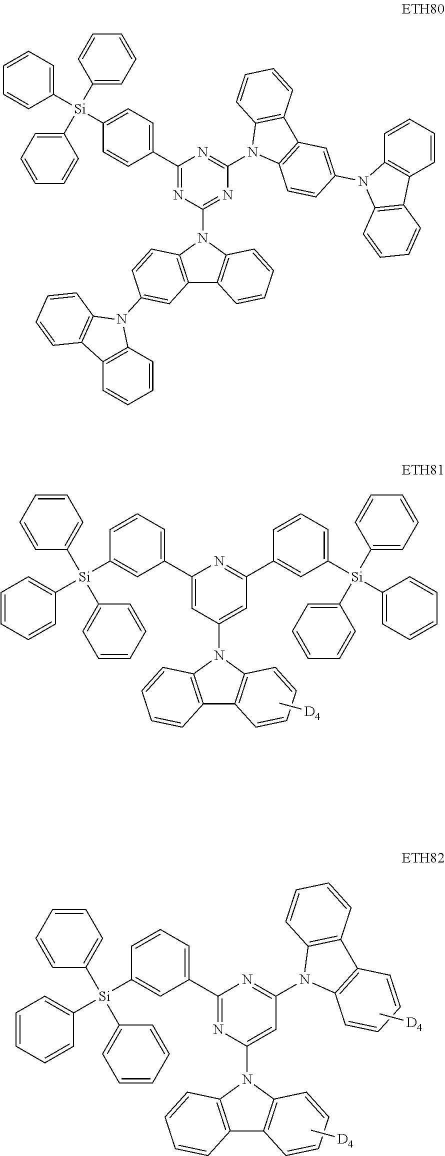

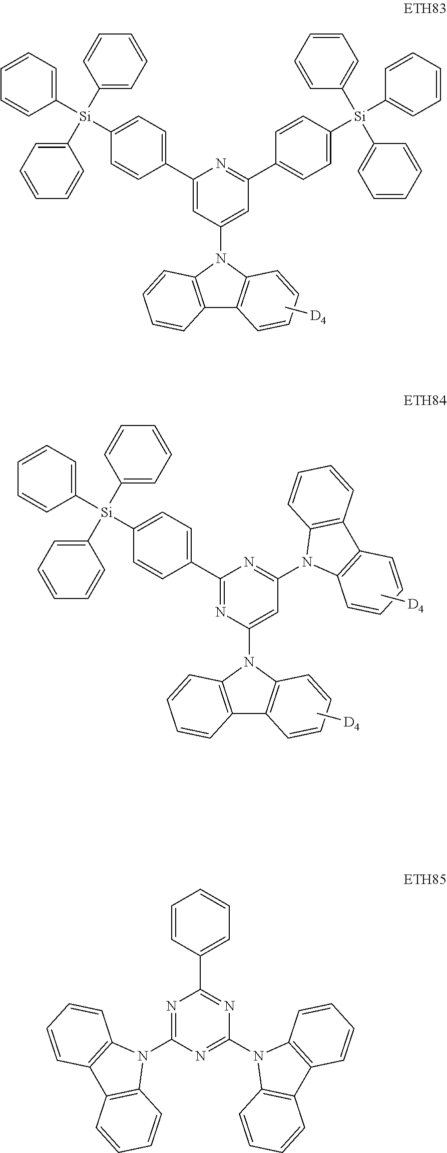

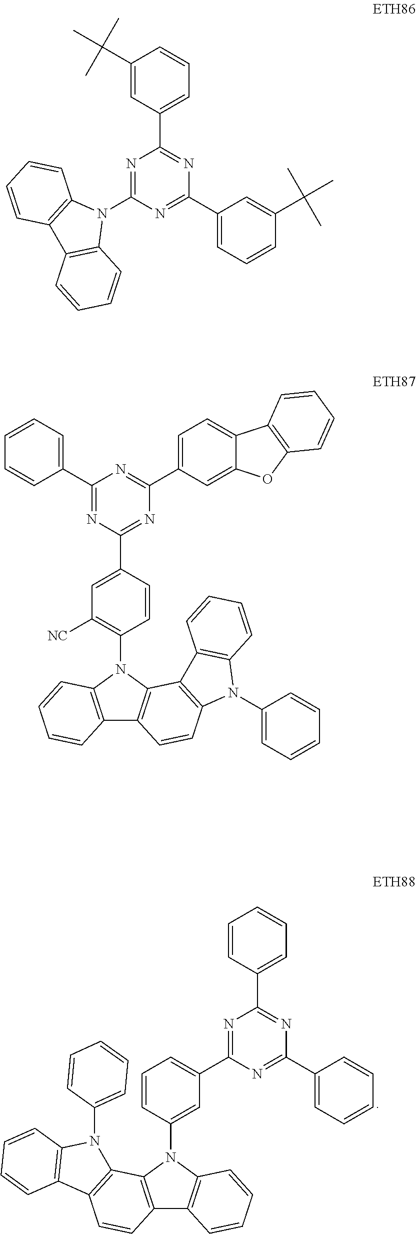 [SMILES: CC(C)(C)c1cccc(-c2nc(-c3cccc(C(C)(C)C)c3)nc(-n3c4ccccc4c4ccccc43)n2)c1 ; N#Cc1cc(-c2nc(-c3ccccc3)nc(-c3ccc4c(c3)oc3ccccc34)n2)ccc1-n1c2ccccc2c2ccc3c(c4ccccc4n3-c3ccccc3)c21 ; c1ccc(-c2nc(-c3ccccc3)nc(-c3cccc(-n4c5ccccc5c5ccc6c7ccccc7n(-c7ccccc7)c6c54)c3)n2)cc1]

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (T1) of the exciplex formed by the hole transport host and the electron transport host may be in a range of about 2.4 eV to about 3.0 eV. The triplet energy level of the exciplex may be a value that is smaller than an energy gap of each host material. The exciplex may have a triplet energy level equal to or less than about 3.0 eV, which is an energy gap between the hole transport host and the electron transport host.

In an embodiment, the emission layer EML may include a fourth compound, in addition to the first compound, the second compound, and the third compound. The fourth compound may be used as a phosphorescence sensitizer in an emission layer EML. Energy may be transferred from the fourth compound to the first compound, thereby implementing light emission.

In an embodiment, the emission layer EML may further include, as a fourth compound, an organometallic complex that includes platinum (Pt) as a central metal atom and ligands bonded to the central metal atom. In an embodiment, the emission layer EML may include a fourth compound represented by Formula D-1:

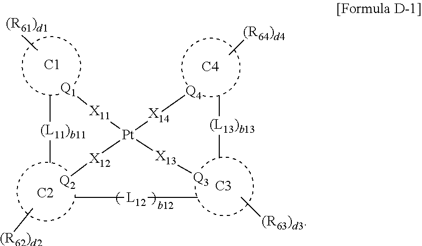

In Formula D-1, Q₁ to Q₄t may each independently be C or N.

In Formula D-1, C1 to C4 may each independently be a substituted or unsubstituted hydrocarbon ring of 5 to 30 ring-forming carbon atoms or a substituted or unsubstituted heterocycle of 2 to 30 ring-forming carbon atoms.

In Formula D-1, X₁₁ to X₁₄ may each independently be a direct linkage or *—O—* For example, one of X₁₁ to X₁₄ may be *—O—*, and the remainder of X₁₁ to X₁₄ may each be a direct linkage.

In Formula D-1, L₁₁ to L₁₃ may each independently be a direct linkage, *—O—* *—S—*

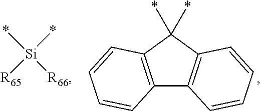

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In Ln to L₁₃, —* represents a bond to one of C1 to C4.

In Formula D-1, b11 to b13 may each independently be 0 or 1. If b11 is 0, C1 and C2 may not be directly bonded to each other. If b12 is 0, C2 and C3 may not be directly bonded to each other. If b3 is 0, C3 and C4 may not be directly bonded to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or bonded to an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. If d1 to d4 are each 0, the fourth compound may not be substituted with R₆₁ to R₆₄, respectively. A case where d1 to d4 are each 4 and four groups of each of R₆₁ to R₆₄ are all hydrogen atoms may be the same as a case where d1 to d4 are each 0. If d1 to d4 are each 2 or more, multiple groups of each of R₆₁ to R₆₄ may all be the same, or at least one thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-5:

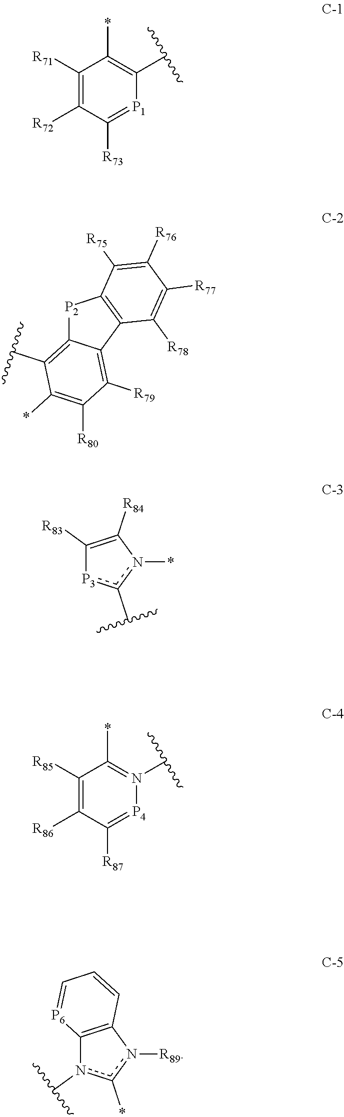

In Formula C-1 to Formula C-5, P₁ may be C—* or C(R₇₄), P₂ may be N—* or N(R₈₁), P₃ may be N—* or N(R₈₂), P₄ may be C—* or C(R₈₈), and P₆ may be C—* or C(R₉₀).

In Formula C-1 to Formula C-5, R₇₁ to R₉₀ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring.

In Formula C-1 to Formula C-5,

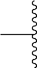

represents a bond to a central metal atom of Pt, and —* represents a bond to an adjacent ring group (C1 to C4) or to a linking moiety (L₁₁ to L₁₃).

In an embodiment, the emission layer EML may include the first compound that is a fused polycyclic compound according to an embodiment, and at least one off the second compound, the third compound, and the fourth compound. For example, the emission layer EML may include the first compound, the second compound, and the third compound. In the emission layer EML, the second compound and the third compound may form an exciplex, and energy may be transferred from the exciplex to the first compound, thereby implementing light emission.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby implementing light emission. In an embodiment, the fourth compound may be a sensitizer. In the light-emitting element ED, the fourth compound included in the emission layer EML may serve as a sensitizer that transfers energy from a host (for example, an exciplex host) to the first compound, which is a light-emitting dopant. For example, the fourth compound, which serves as an auxiliary dopant, may accelerate energy transfer to the first compound, which is a light emitting dopant, thereby increasing an emission ratio of the first compound. Accordingly, the emission layer EML may have improved emission efficiency. If energy transfer to the first compound increases, excitons formed in the emission layer EML may not accumulate in the emission layer EML and may rapidly emit light, so that deterioration of a device may be reduced. Accordingly, the lifetime of the light-emitting element ED may increase.

The light-emitting element ED may include the first compound, the second compound, the third compound, and the fourth compound, and the emission layer EML may include a combination of two host materials and two dopant materials. In the light-emitting element ED, the emission layer EML may include the second compound and the third compound, which are two different hosts, the first compound which emits delayed fluorescence, and the fourth compound that includes an organometallic complex, so that the light-emitting element ED may exhibit excellent emission efficiency properties.

In an embodiment, the fourth compound represented by Formula D-1 may be selected from Compound Group 4. In an embodiment, in light-emitting element ED, the fourth compound may include at least one compound selected from Compound Group 4:

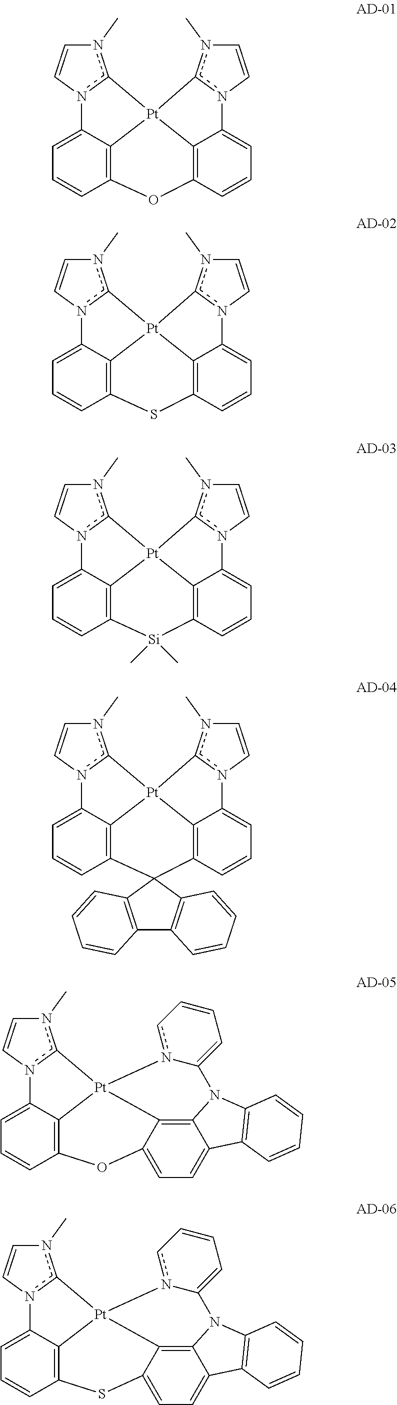

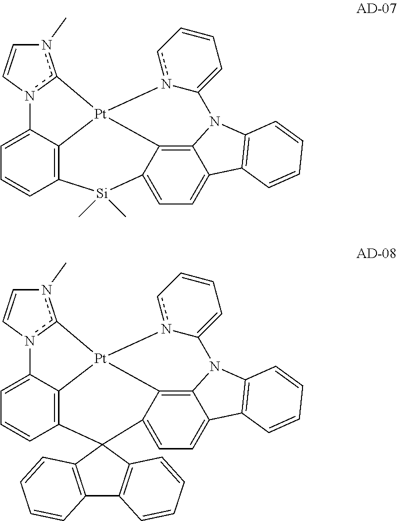

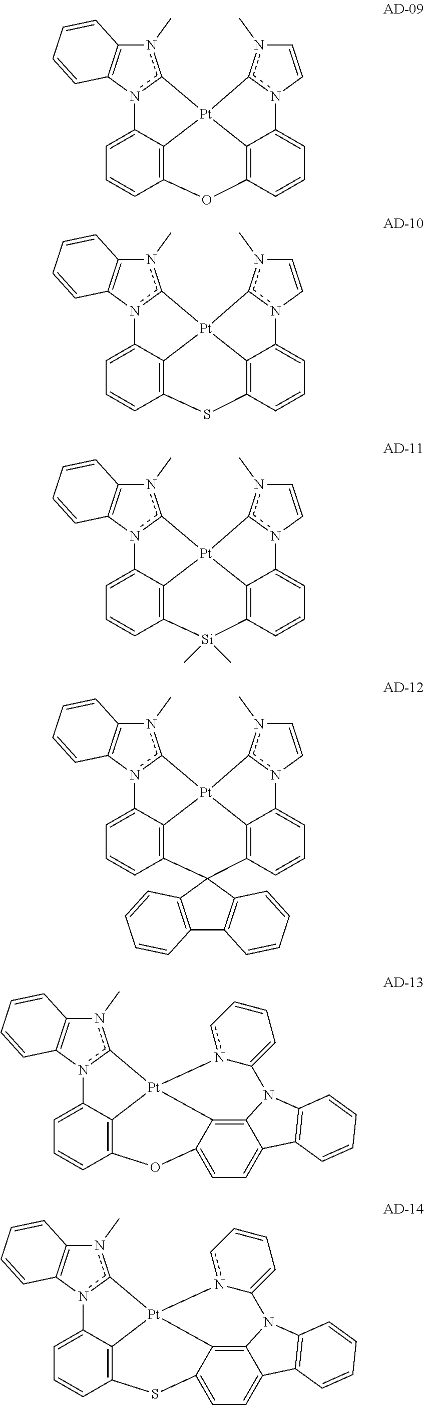

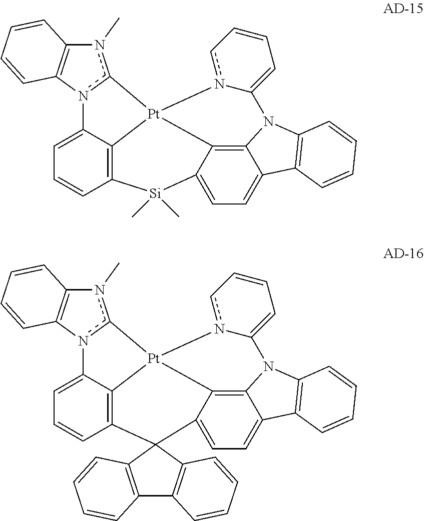

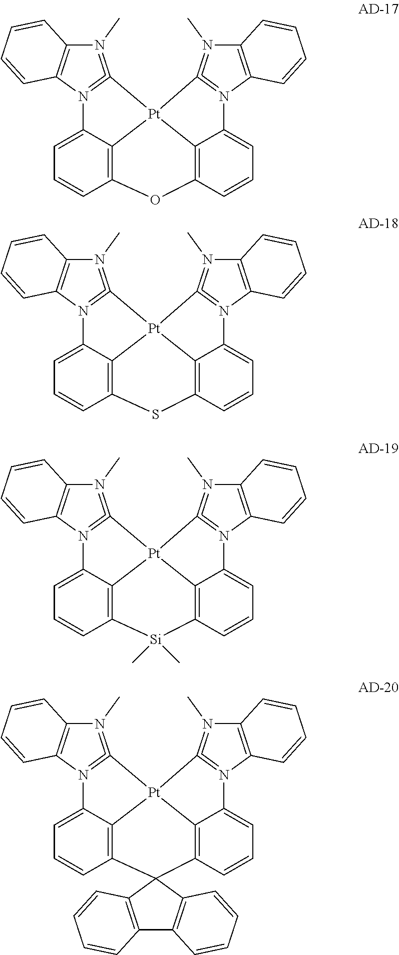

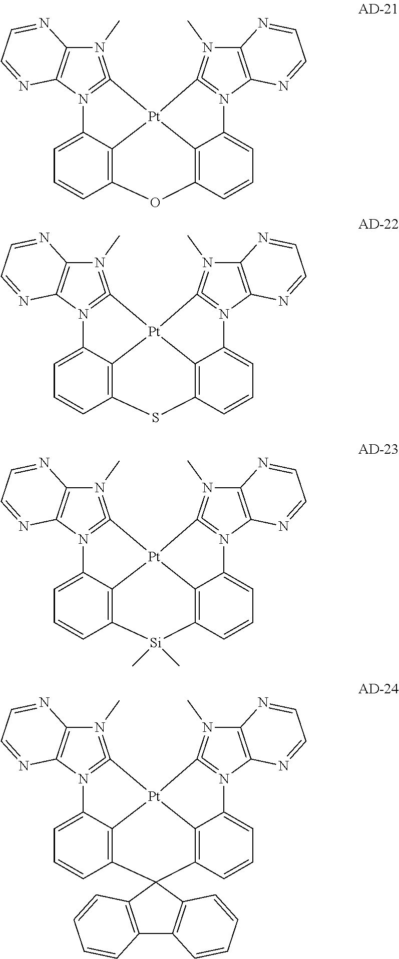

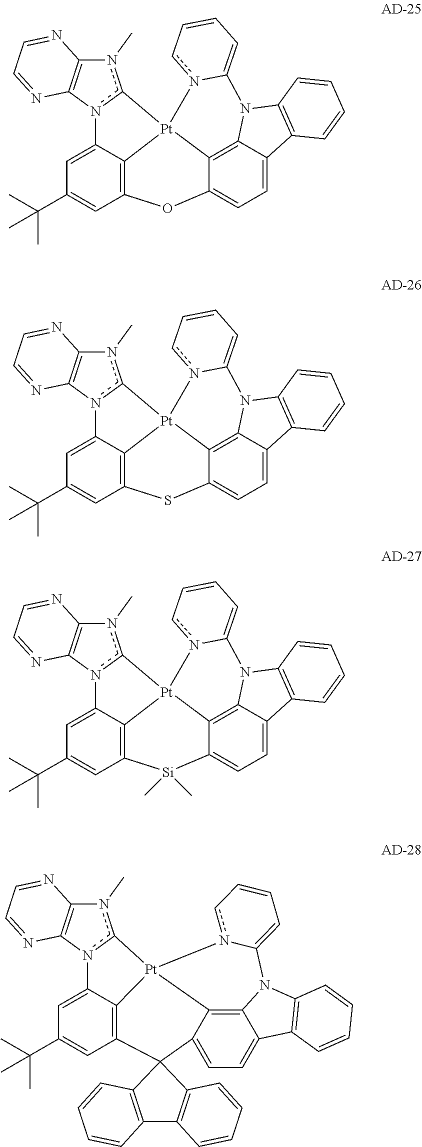

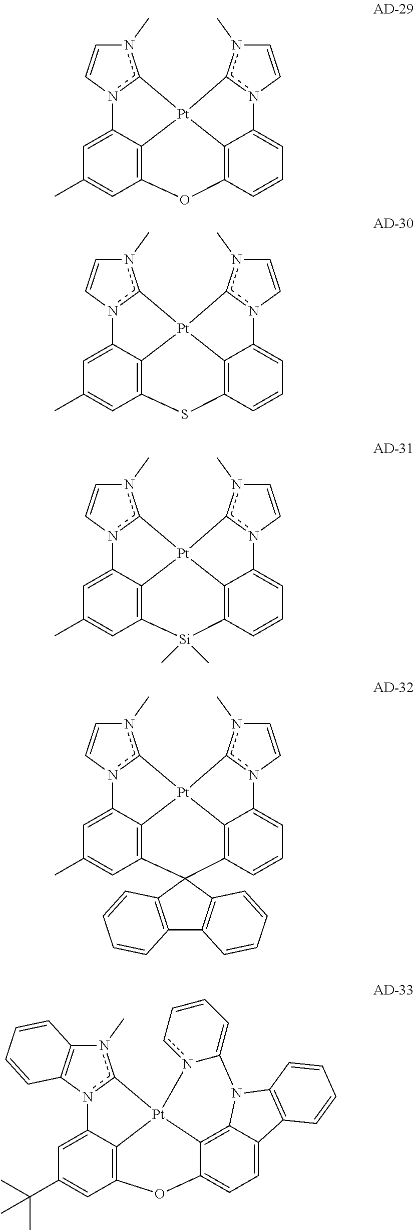

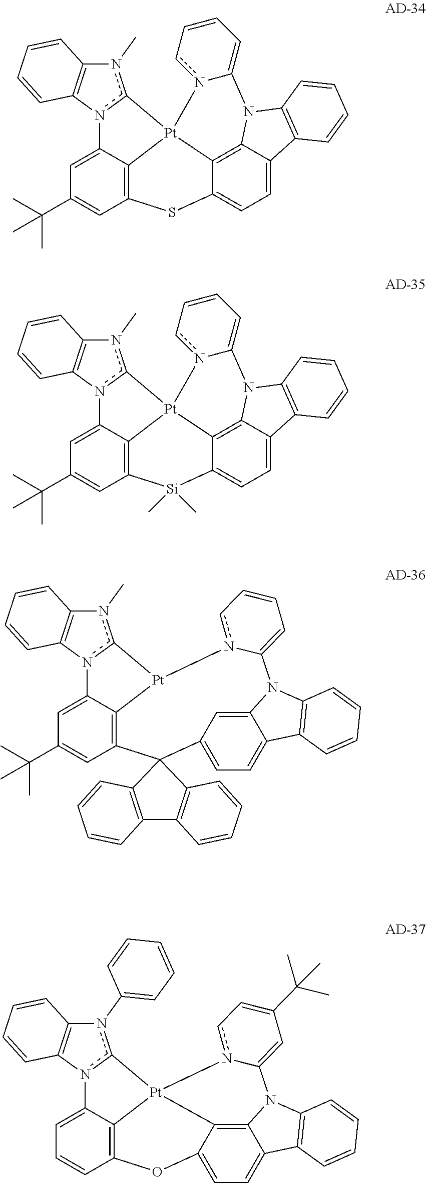

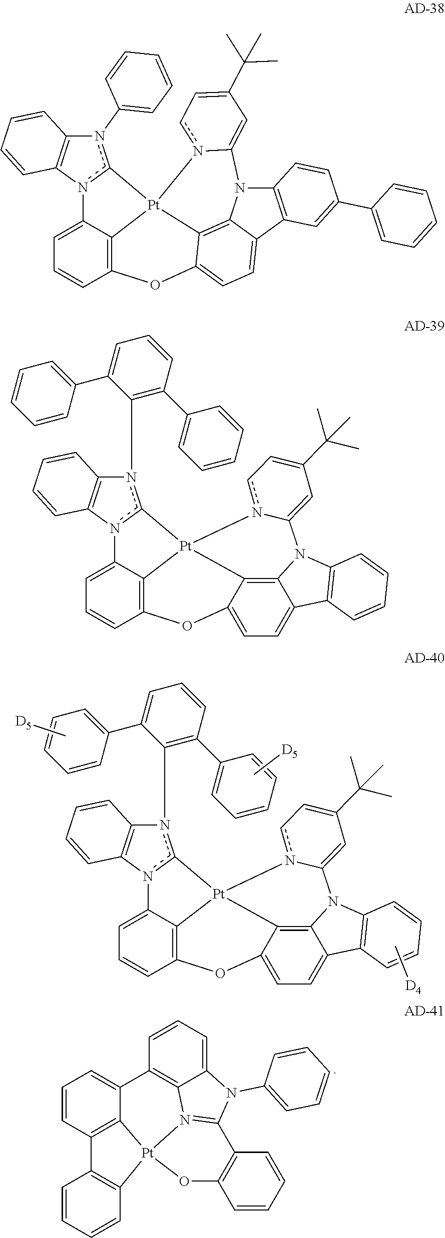

In Compound Group 4, D represents a deuterium atom.

In an embodiment, the light-emitting element ED may include multiple emission layers. Multiple emission layers may be stacked between a first electrode and a second electrode, so that a light-emitting element ED that includes multiple emission layers may emit white light. The light-emitting element ED that includes multiple emission layers may be a light-emitting element having a tandem structure. If the light-emitting element ED includes multiple emission layers, at least one emission layer EML may include a first compound represented by Formula 1. If the light-emitting element ED includes multiple emission layers, at least one emission layer EML may include the first compound, the second compound, the third compound, and the fourth compound.

In the light-emitting element ED, if the emission layer EML includes the first compound, the second compound, the third compound, and the fourth compound, an amount of the first compound may be in a range of about 0.1 wt % to about 5 wt %, based on a total weight of the first compound, the second compound, the third compound, and the fourth compound. However, embodiments are not limited thereto. If the amount of the first compound satisfies the range described above, energy transfer from the second compound and the third compound to the first compound may increase, and accordingly, emission efficiency and device lifetime may increase.

In the emission layer EML, a combined amount of the second compound and the third compound may be the remainder of the total weight of the first compound, the second compound, the third compound, and the fourth compound, excluding the amount of the first compound and the fourth compound. For example, a combined amount of the second compound and the third compound may be in a range of about 65 wt % to about 95 wt %, based on a total weight of the first compound, the second compound, the third compound, and the fourth compound.

Within the combined amount of the second compound and the third compound, a weight ratio of the second compound to the third compound may be in a range of about 3:7 to about 7:3.

If the amounts of the second compound and the third compound satisfy the ranges and ratios described above, charge balance properties in the emission layer EML may be improved, and emission efficiency and device lifetime may be improved. If the amounts of the second compound and the third compound deviate from the ranges and ratios described above, charge balance in the emission layer EML may not be achieved, emission efficiency may be reduced, and the device may readily deteriorate.

If the emission layer EML includes the fourth compound, an amount of the fourth compound may be in a range of about 4 wt % to 30 wt %, based on a total weight of the first compound, the second compound, the third compound, and the fourth compound in the emission layer EML. However, embodiments are not limited thereto. If the amount of the fourth compound satisfies the range described above, energy transfer from a host (for example, an exciplex host) to the first compound, which is a light emitting dopant, may increase, so that an emission ratio may be improved. Accordingly, emission efficiency of the emission layer EML may be improved. If the amounts of the first compound, the second compound, the third compound, and the fourth compound included in the emission layer EML satisfy the ranges and ratios described above, excellent emission efficiency and a long device lifetime may be achieved.

In the light-emitting element ED, the emission layer EML may further include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light-emitting element ED according to embodiments as shown in FIG. 3 to FIG. 6, the emission layer EML may further include hosts and dopants of the related art, in addition to the above-described host and dopant. In an embodiment, the emission layer EML may include a compound represented by Formula E-1. The compound represented by Formula E-1 may be used as a fluorescence host material.

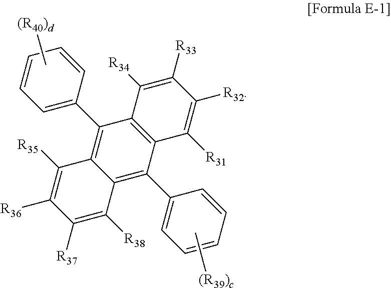

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

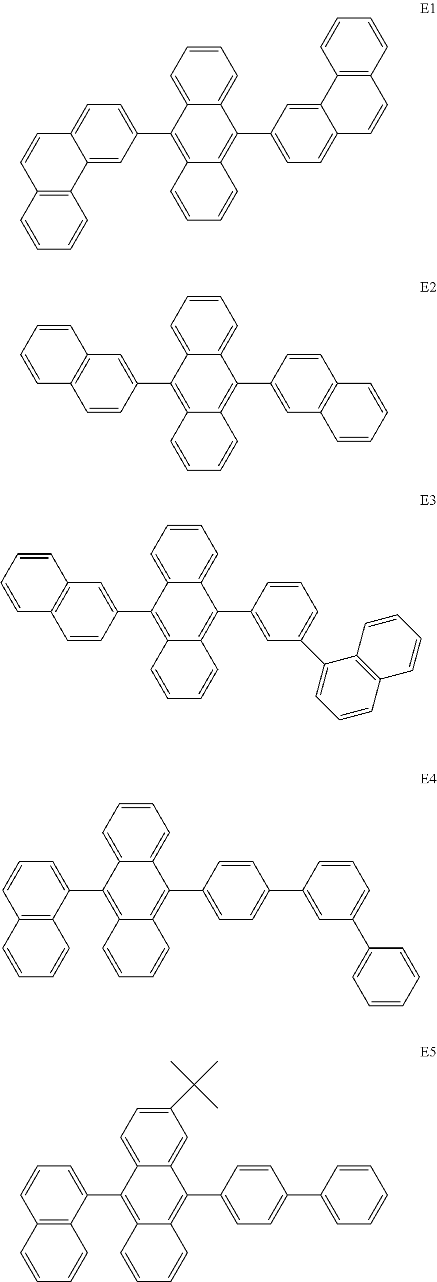

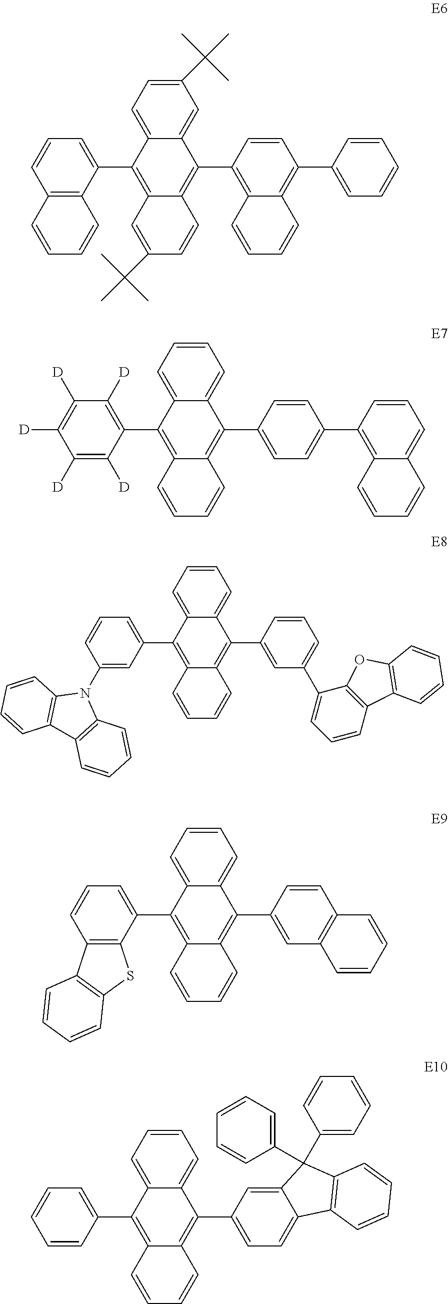

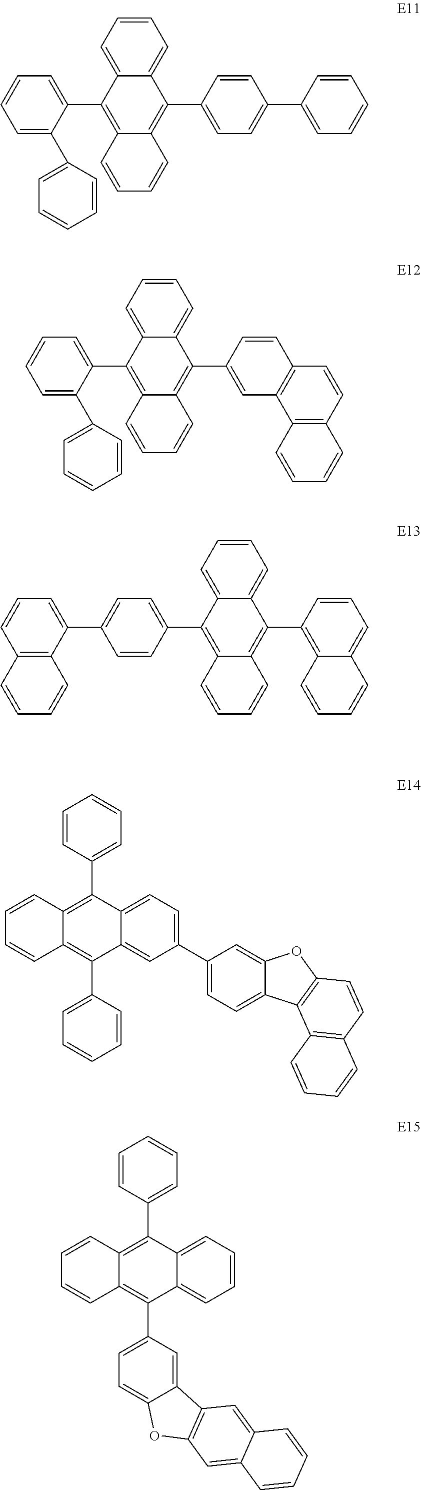

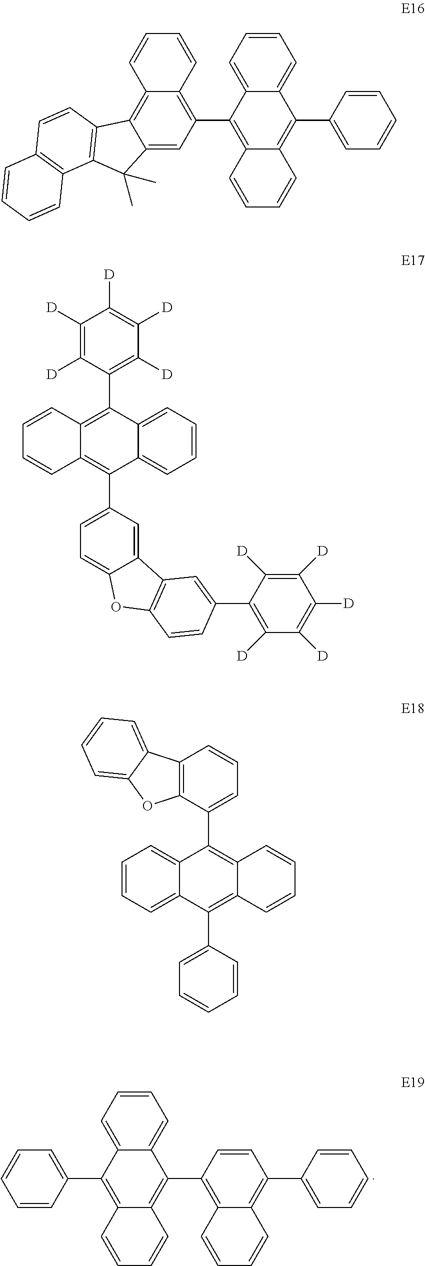

In an embodiment, the emission layer EML may include a compound represented by Formula E-2a or Formula E-2b. The compound represented by Formula E-2a or Formula E-2b may be used as a host material for phosphorescent emission layer.

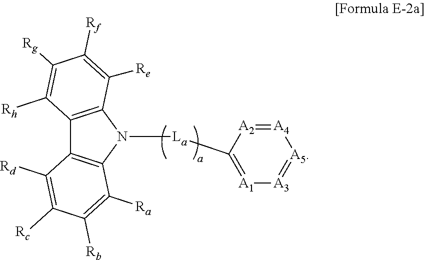

In Formula E-2a, a may be an integer from 0 to 10; and Lₐ may be a direct linkage, a substituted or unsubstituted arylene group of 6 to 30 ring-forming carbon atoms, or a substituted or unsubstituted heteroarylene group of 2 to 30 ring-forming carbon atoms. If a is 2 or more, multiple Lₐ may each independently be a substituted or unsubstituted arylene group of 6 to 30 ring-forming carbon atoms or a substituted or unsubstituted heteroarylene group of 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be bonded to an adjacent group to form a ring. For example, Rₐ to Rᵢ may be bonded to an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

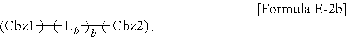

In Formula E-2b, Cbz1 and Cbz2 may each independently be an unsubstituted carbazole group or a carbazole group substituted with an aryl group of 6 to 30 ring-forming carbon atoms.

In Formula E-2b, L_{b} may be a direct linkage, a substituted or unsubstituted arylene group of 6 to 30 ring-forming carbon atoms, or a substituted or unsubstituted heteroarylene group of 2 to 30 ring-forming carbon atoms. In Formula E-2b, b may be an integer from 0 to 10. If b is 2 or more, multiple L_{b} may each independently be a substituted or unsubstituted arylene group of 6 to 30 ring-forming carbon atoms or a substituted or unsubstituted heteroarylene group of 2 to 30 ring-forming carbon atoms.

In an embodiment, the compound represented by Formula E-2a or Formula E-2b may be any compound selected from Compound Group E-2. However, the compounds shown in Compound Group E-2 are only examples, and the compound represented by Formula E-2a or Formula E-2b is not limited to Compound Group E-2:

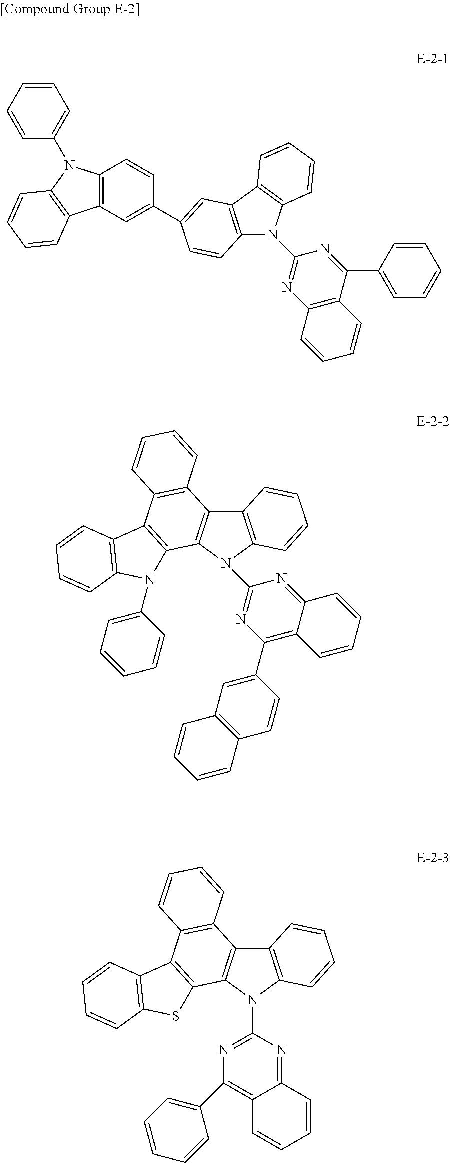 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

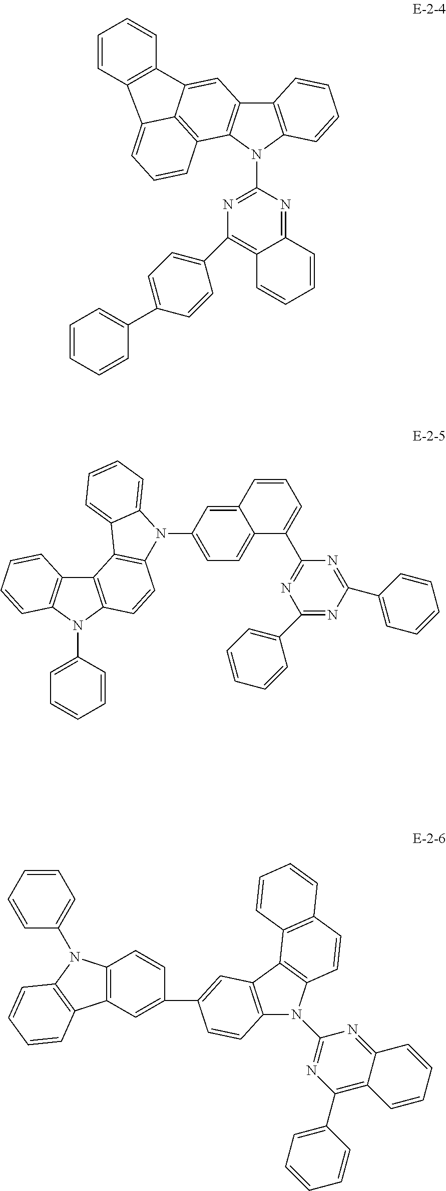 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

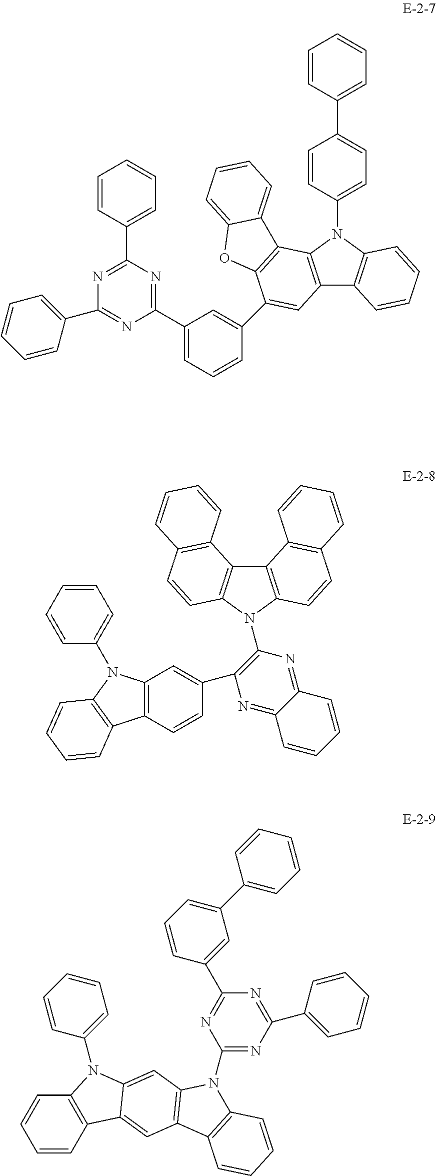 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

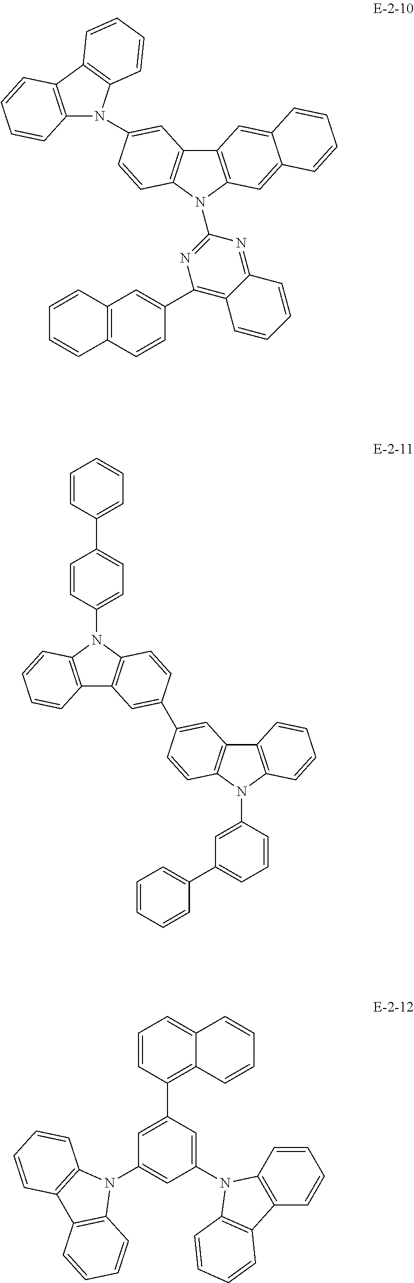 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

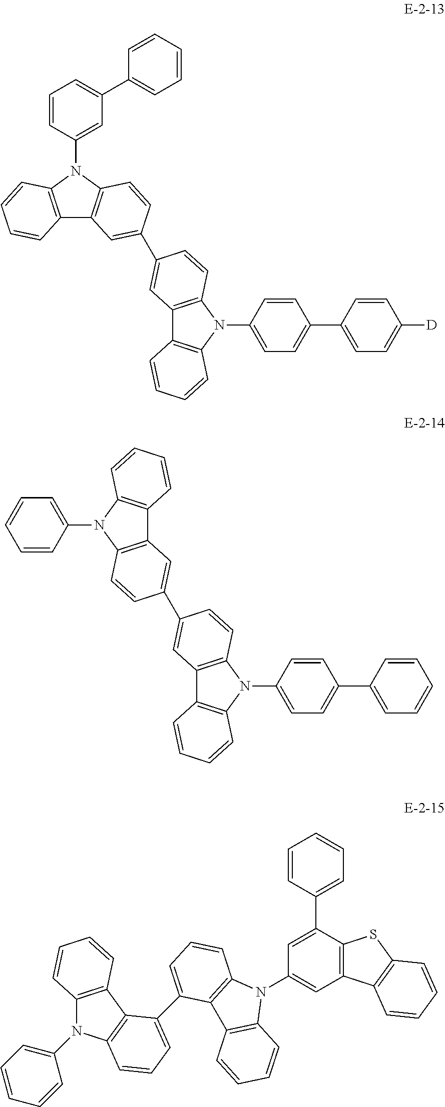 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

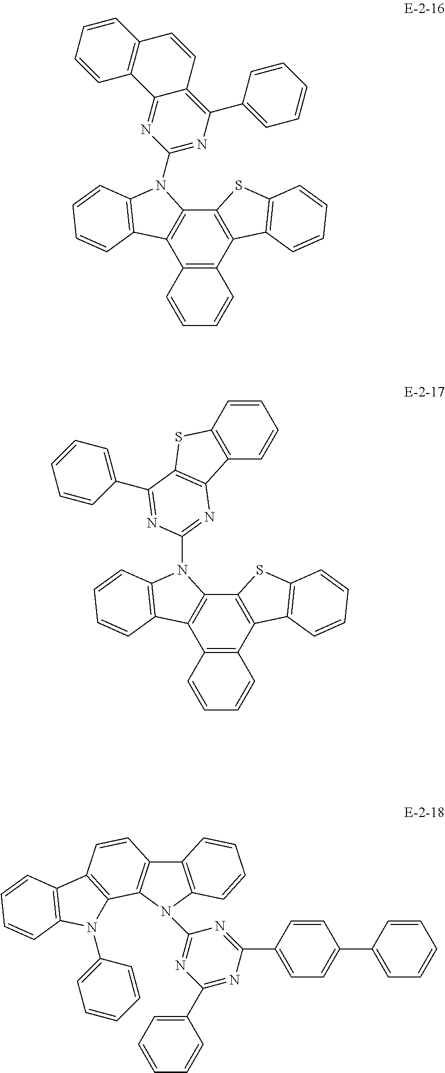 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

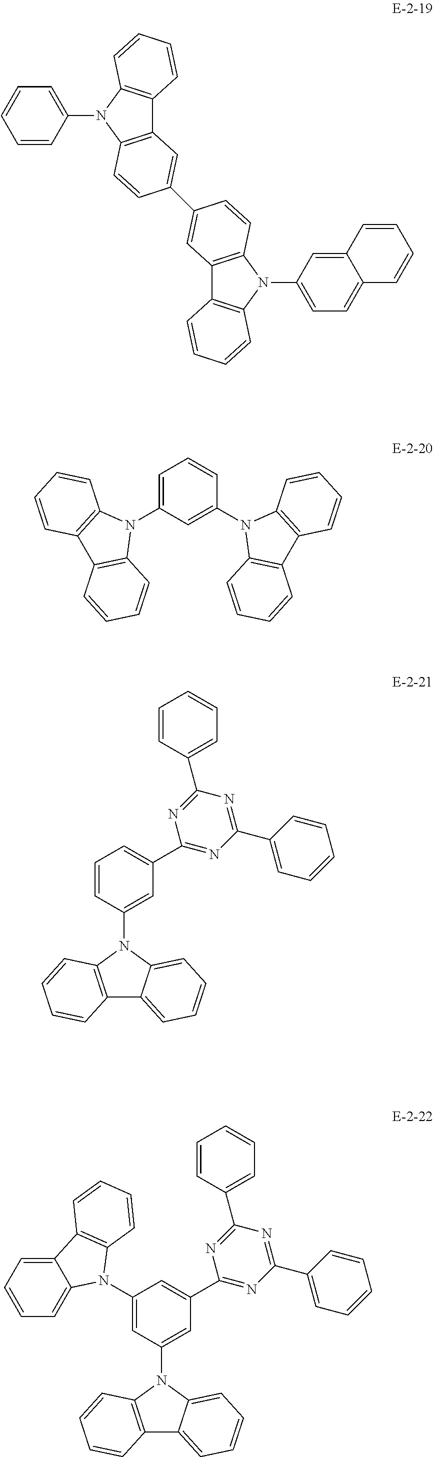 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

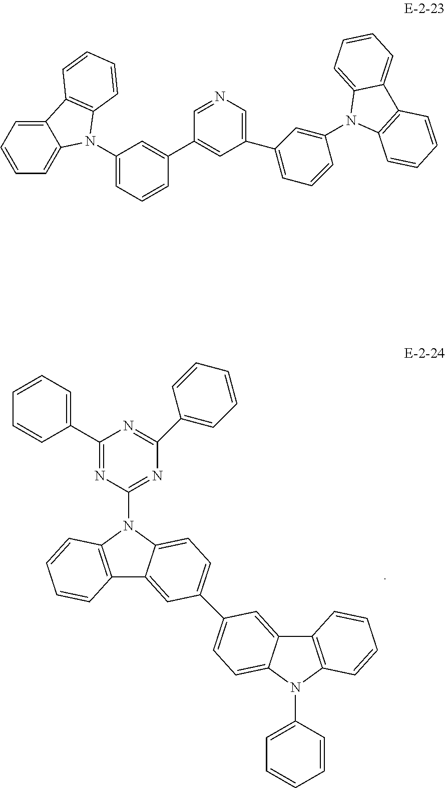 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In an embodiment, the emission layer EML may further include a material of the related art as a host material. For example, the emission layer EML may include, as a host material, at least one of bis(4-(9H-carbazol-9-yl)phenyl) diphenylsilane (BCPDS), (4-(1-(4-(diphenylamino)phenyl) cyclohexyl)phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4 ′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

In an embodiment, the emission layer EML may include a compound represented by Formula M-a. The compound represented by Formula M-a may be used as a phosphorescence dopant material.

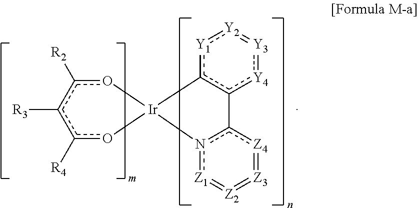

In Formula M-a, Y₁ to Y₄ and Zi to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring. In Formula M-a, m may be 0 or 1, and n may be 2 or 3. In Formula M-a, if m is 0, n may be 3, and if m is 1, n may be 2.

In an embodiment, the compound represented by Formula M-a may be any compound selected from Compounds M-a1 to M-a25. However, Compounds M-a1 to M-a25 are only examples, and the compound represented by Formula M-a is not limited to Compounds M-a1 to M-a25:

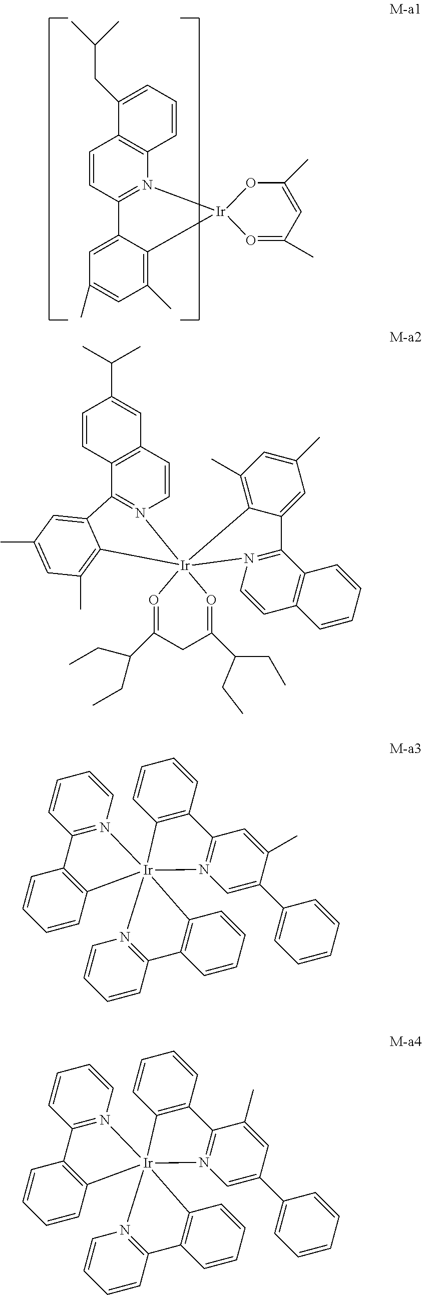

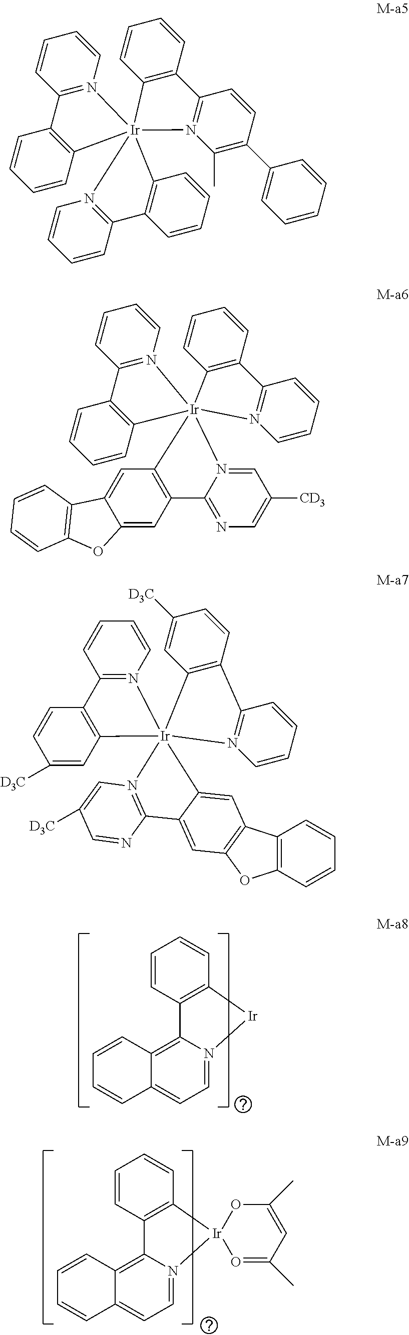

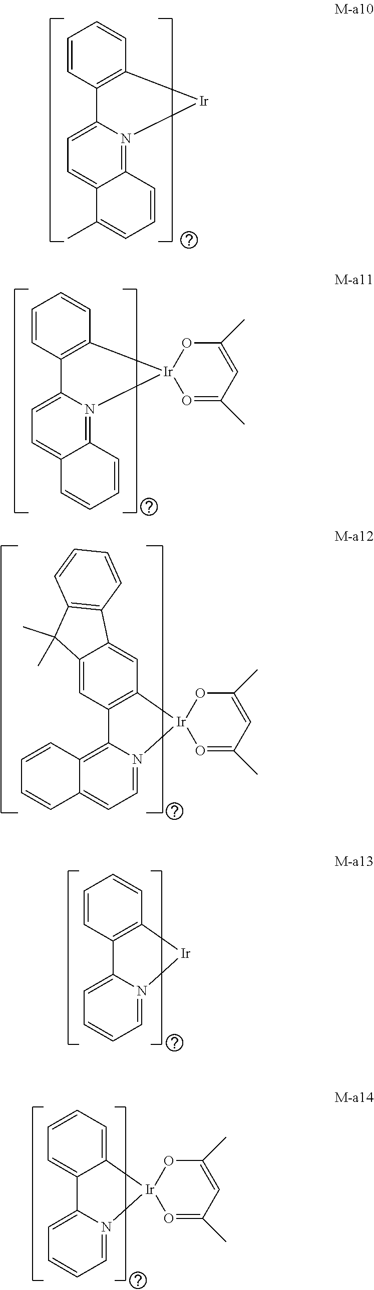

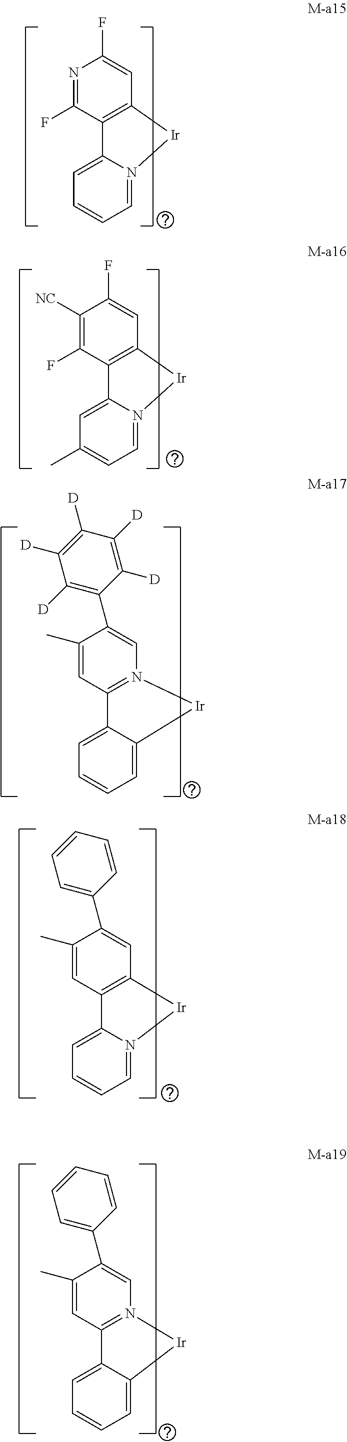

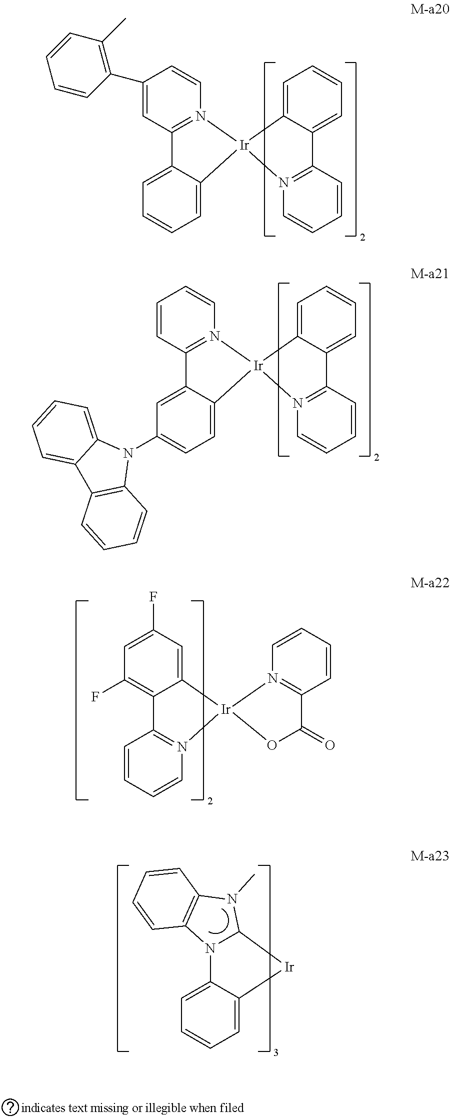

In an embodiment, the emission layer EML may further include a compound represented by one of Formula F-a to Formula F-c. The compounds represented by one of Formula F-a to Formula F-c may be used as fluorescence dopant materials.

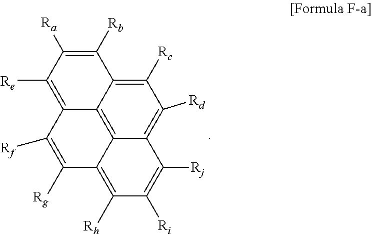

In Formula F-a, two of Rₐ to Rⱼ may each independently be substituted with a group represented by *—Ar₁Ar₂. The remainder of Rₐ to Rⱼ that are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the group represented by *—NAr₁Ar₂, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ and Ar₂ may each independently be a heteroaryl group including O or S as a ring-forming atom.

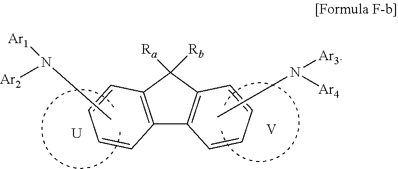

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring. In Formula F-b, Ar₁ to Ar₄ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ to Ar₄ may each independently be a heteroaryl group including O or S as a ring-forming atom.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms.

In Formula F-b, the number of rings represented by U and V may each independently be 0 or 1. If the number of U or V is 1, a fused ring may be present at a portion respectively designated by U or V, and if the number of U or V is 0, a fused ring may not be present at the portion respectively designated by U or V. If the number of U is 0 and the number of V is 1, or if the number of U is 1 and the number of V is 0, a fused ring having the fluorene core of Formula F-b may be a cyclic compound with four rings. If the number of U and V is each 0, a fused ring having the fluorene core of Formula F-b may be a cyclic compound with three rings. If the number of U and V is each 1, a fused ring having the fluorene core of Formula F-b may be a cyclic compound with five rings.

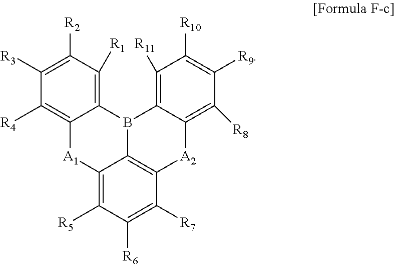

In Formula F-c, A₁ and A₂ may each independently be O, S, Se, or N(Rₘ); and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring.

In Formula F-c, A₁ and A₂ may each independently be bonded to a substituent of an adjacent ring to form a fused ring. For example, if A₁ and A₂ are each independently N(Rₘ), A₁ may be bonded to R₄ or Rₛ to form a ring, and/or A₂ may be bonded to R₇ or R₈ to form a ring.

In an embodiment, the emission layer EML may include, as a dopant material of the related art, a styryl derivative (for example, 1,4-bis [2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene or a derivative thereof (for example, 2,5,8,11-tetra-t-butylperylene (TBP)), pyrene or a derivative thereof (for example, 1,1-dipyrene, 1,4-dipyrenylbenzene, and 1,4-bis(N,N-diphenylamino)pyrene), etc.

The emission layer EML may include a phosphorescence dopant material of the related art. For example, the phosphorescence dopant may include a metal complex that includes iridium (Ir), platinum (Pt), osmium (Os), gold (Au), titanium (Ti), zirconium (Zr), hafnium (Hf), europium (Eu), terbium (Tb), or thulium (Tm). For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescence dopant. However, embodiments are not limited thereto.

In an embodiment, the emission layer may include a quantum dot.

In the specification, a quantum dot may be a crystal of a semiconductor compound. A quantum dot may emit light in various emission wavelengths according to a size of the crystal. A quantum dot may emit light in various emission wavelengths by adjusting an elemental ratio of a quantum dot compound.

A diameter of a quantum dot may be, for example, in a range of about 1 nm to about 10 nm.

A quantum dot may be synthesized by chemical bath deposition, metal organic chemical vapor deposition, molecular beam epitaxy, or a similar process.

Chemical bath deposition is a method of mixing an organic solvent and a precursor material and growing a quantum dot particle crystal. While growing the crystal, the organic solvent may naturally serve as a dispersant that is coordinated on the surface of the quantum dot crystal and may control the growth of the crystal. Accordingly, chemical bath deposition may be more advantageous as compared to a vapor deposition method such as metal organic chemical vapor deposition (MOCVD) and molecular beam epitaxy (MBE), and the growth of a quantum dot particle may be controlled through a low-cost process.

A quantum dot may include a Group II-VI compound, a Group III-VI compound, a Group 1-III-VI compound, a Group III-V compound, a Group III-II-V compound, a Group IV-VI compound, a Group IV element, a Group IV compound, or a combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound such as HgZnTeS, CdZnSeS, CdZnSeTe, CdZnSTe, CdHgSeS, CdHgSeTe, CdHgSTe, HgZnSeS, HgZnSeTe, and a mixture thereof; and any combination thereof. In an embodiment, a Group II-VI compound may further include a Group I metal and/or a Group IV element. Examples of a Group 1-II-VI compound may include CuSnS and CuZnS, and examples of a Group II-IV-VI compound may include ZnSnS and the like. Examples of a Group I-II-IV-VI compound may include a quaternary compound such as Cu₂ZnSnS₂, Cu₂ZnSnS₄, Cu₂ZnSnSe₄, Ag₂ZnSnS₂, and a mixture thereof.

Examples of a Group III-VI compound may include: a binary compound such as In₂S₃ and In₂Se₃; a ternary compound such as InGaS₃ and InGaSe₃; and any combination thereof.

Examples of a Group 1-III-VI compound may include: a ternary compound such as AgInS, AgInS₂, CuInS, CuInS₂, AgGaS₂, CuGaS₂, CuGaO₂, AgGaO₂, AgAlO₂, and mixtures thereof; a quaternary compound such as AgInGaS₂ and CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and mixtures thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof; and any combination thereof. In an embodiment, a Group III-V compound may further include a Group II metal. Examples of a Group III-II-V compound may include InZnP, etc.

Examples of a Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; a quaternary compound such as SnPbSSe, SnPbSeTe, SnPbSTe, and a mixture thereof; and any combination thereof.

Examples of a Group II-IV-V compound may include a ternary compound such as ZnSnP, ZnSnP₂, ZnSnAs₂, ZnGeP₂, ZnGeAs₂, CdSnP₂, and CdGeP₂, and a mixture thereof.

Examples of a Group IV element may include Si, Ge, and a mixture thereof. Examples of a Group IV compound may include a binary compound such as SiC, SiGe, and a mixture thereof.

Each element included in a compound, such as a binary compound, a ternary compound, or a quaternary compound, may be present in a particle at a uniform concentration distribution or at a non-uniform concentration distribution. For example, a formula may indicate the elements that are included in a compound, but an elemental ratio of the compound may vary. For example, AgInGaS₂ may indicate AgInₓGa₁₋ₓS₂ (wherein x is a real number between 0 and 1).

In an embodiment, a quantum dot may have a core/shell structure in which a quantum dot surrounds another quantum dot. An interface between the core and the shell may have a concentration gradient in which the concentration of an element that is present in the shell decreases toward the center.

In embodiments, a quantum dot may have the above-described core-shell structure that includes a nanocrystal core and a shell that surrounds the core. The shell of a quantum dot may serve as a protection layer that prevents chemical deformation of the core to maintain semiconductor properties and/or may serve as a charging layer that imparts the quantum dot with electrophoretic properties. The shell may be single-layered or multilayered. Examples of a shell of a quantum dot may include a metal oxide, a non-metal oxide, a semiconductor compound, and combinations thereof.

Examples of a metal oxide or a non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, and NiO; or a ternary compound such as MgAl₂O₄, CoFe₂O₄, NiFe₂O₄, and CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

A quantum dot may have a full width at half maximum (FWHM) of an emission wavelength spectrum equal to or less than about 45 nm. For example, the quantum dot may have an FWHM of an emission wavelength spectrum equal to or less than about 40 nm. For example, the quantum dot may have an FWHM of an emission wavelength spectrum equal to or less than about 30 nm. Within any of the above ranges, color purity or color reproducibility may be improved. Light emitted through a quantum dot may be emitted in all directions, so that viewing angle properties may be improved.

The shape of a quantum dot may be any shape used in the related art, without specific limitation. For example, a quantum dot may have a spherical shape, a pyramidal shape, a multi-arm shape, or a cubic shape, or a quantum dot may be in the form of a nanoparticle, a nanotube, a nanowire, a nanofiber, a nanoplate particle, etc.

As a size of a quantum dot or an elemental ratio of a quantum dot compound is adjusted, an energy band gap may be accordingly controlled to obtain light of various wavelengths from a quantum dot emission layer. Therefore, by utilizing quantum dots as described above (using quantum dots of different sizes or having different element ratios in a quantum dot compound), a light-emitting element may emit light of various wavelengths. For example, a size of a quantum dot or an elemental ratio of a quantum dot compound may be adjusted to emit red light, green light, and/or blue light. In an embodiment, quantum dots may be configured to emit white light by combining light of various colors.

In the light-emitting element ED according to embodiments, as shown in each of FIG. 3 to FIG. 6, the electron transport region ETR may be provided on the emission layer EML. The electron transport region ETR may include at least one of a hole blocking layer HBL, an electron transport layer ETL, and an electron injection layer EIL. However, embodiments are not limited thereto.

The electron transport region ETR may have a structure consisting of a layer consisting of a single material, a structure consisting of a layer including different materials, or a structure including multiple layers including different materials.

For example, the electron transport region ETR may have a single-layered structure of an electron injection layer EIL or an electron transport layer ETL, or may have a single-layered structure that includes an electron injection material and an electron transport material. In embodiments, the electron transport region ETR may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. A thickness of the electron transport region ETR may be, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light-emitting element ED according to an embodiment, the electron transport region ETR may include a compound represented by Formula ET-2:

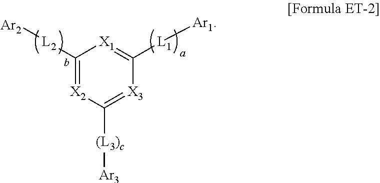

In Formula ET-2, at least one of X₁ to X₃ may each be N, and the remainder of X₁ to X₃ may each independently be C(Rₐ). In Formula ET-2, Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula ET-2, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are each 2 or more, multiple groups of each of L₁ to L₃ may each independently be a substituted or unsubstituted arylene group of 6 to 30 ring-forming carbon atoms or a substituted or unsubstituted heteroarylene group of 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), beryllium bis(benzoquinolin-10-olate) (Bebg₂), 9,10-di(naphthalene-2-yl)anthracene (ADN), 1,3-bis[3,5-di(pyridin-3-yl)phenyl]benzene (BmPyPhB), CNNPTRZ (4′-(4-(4-(4,6-diphenyl-1,3,5-triazin-2-yl)phenyl)naphthalen-1-yl)-[1,1′-biphenyl]-4-carbonitrile), or a mixture thereof, without limitation.

In an embodiment, the electron transport region ETR may include a compound selected from Compound Group 3.

In an embodiment, the electron transport region ETR may include at least one of Compounds ET1 to ET36:

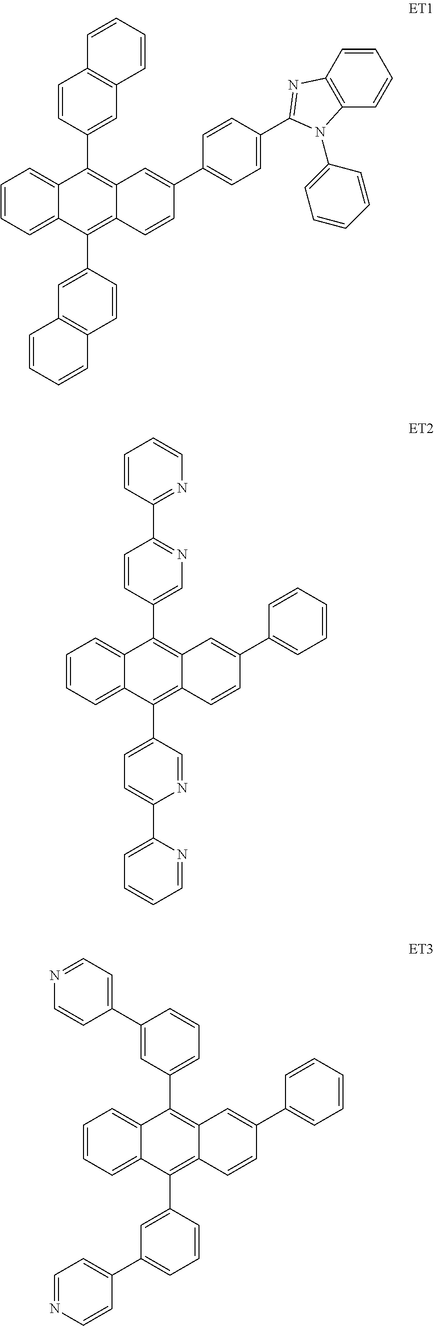 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

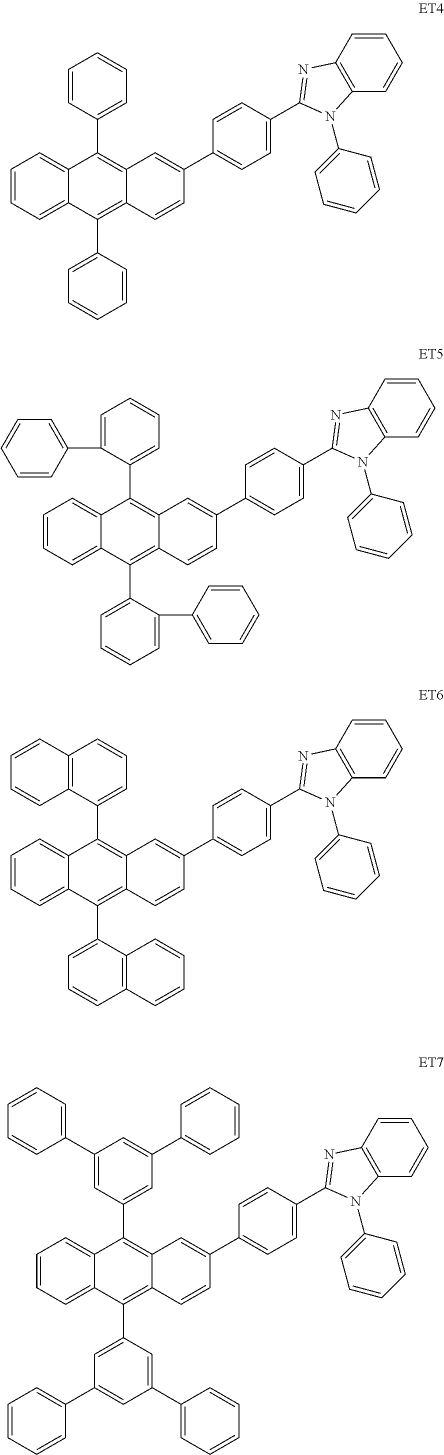 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

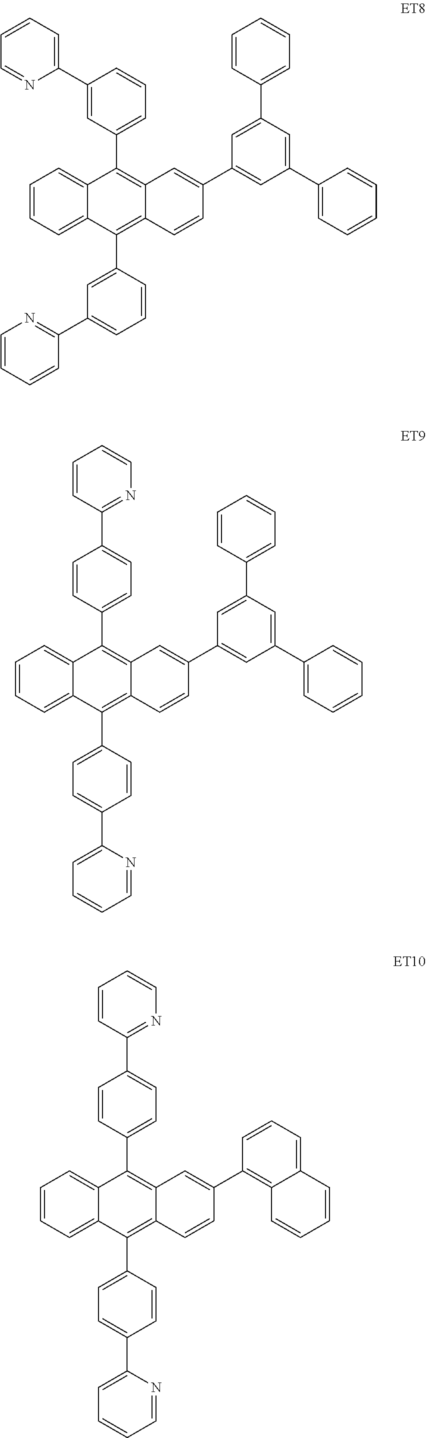 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

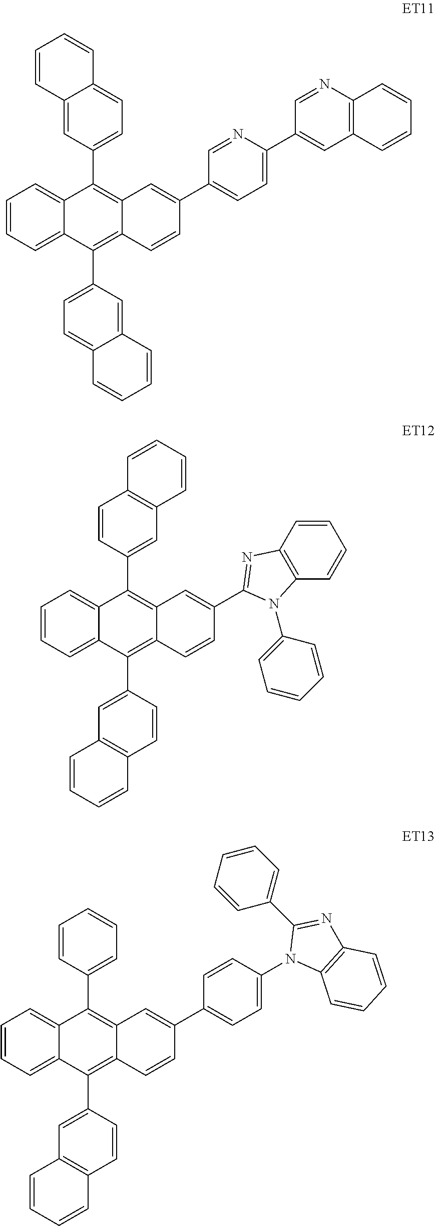 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

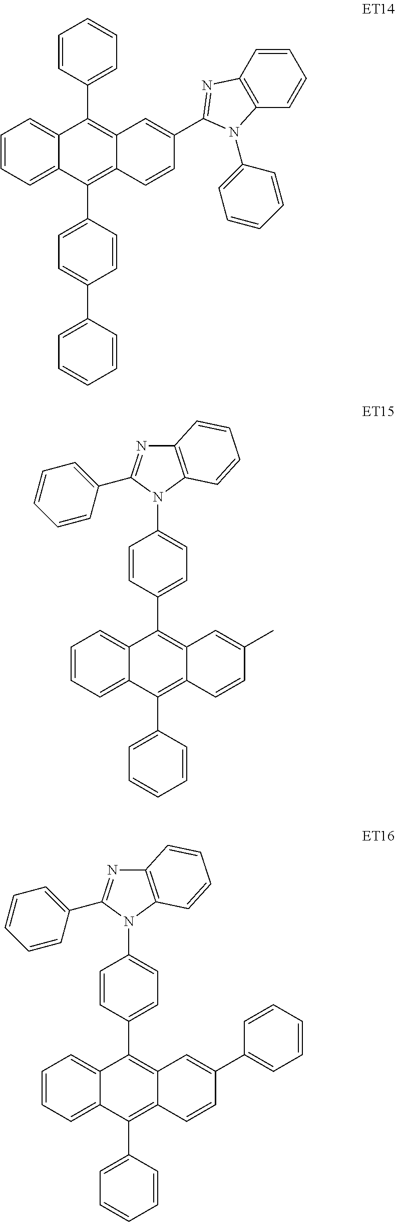 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

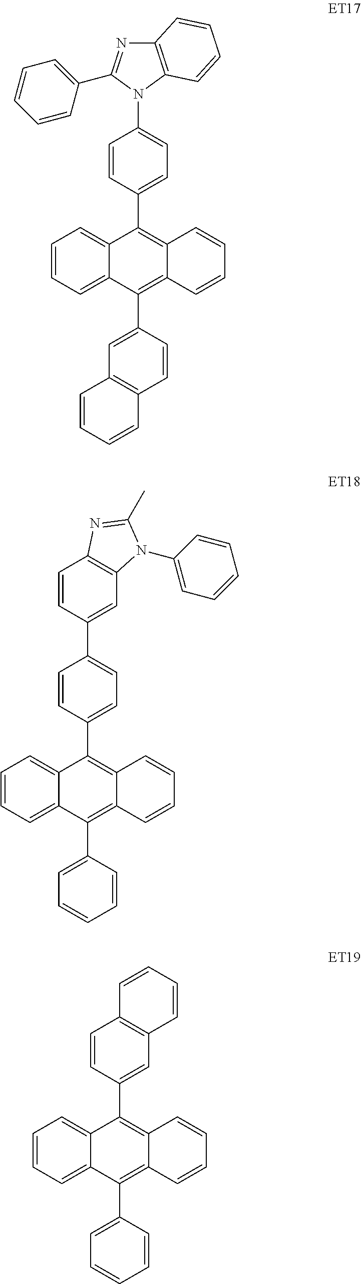

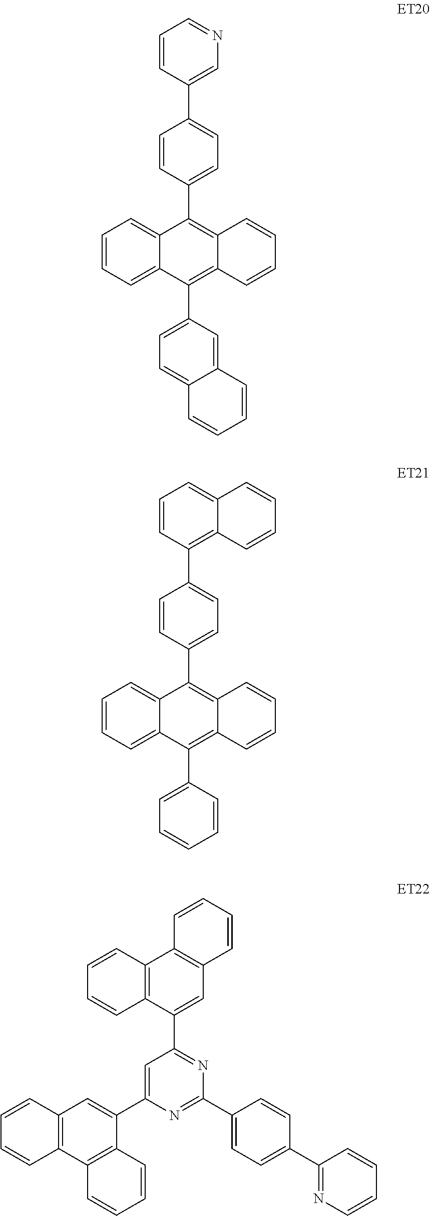

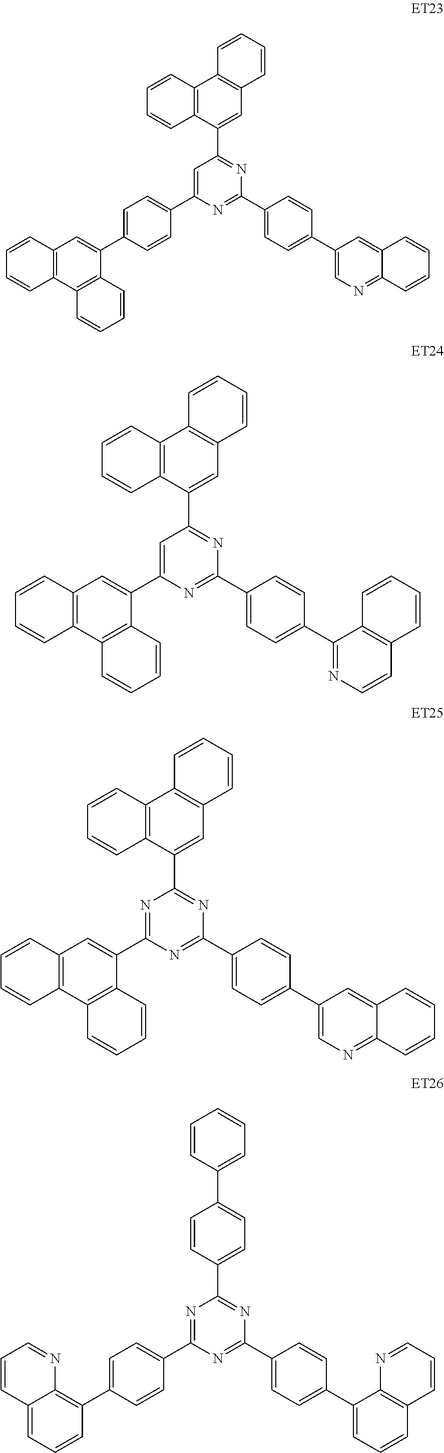 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

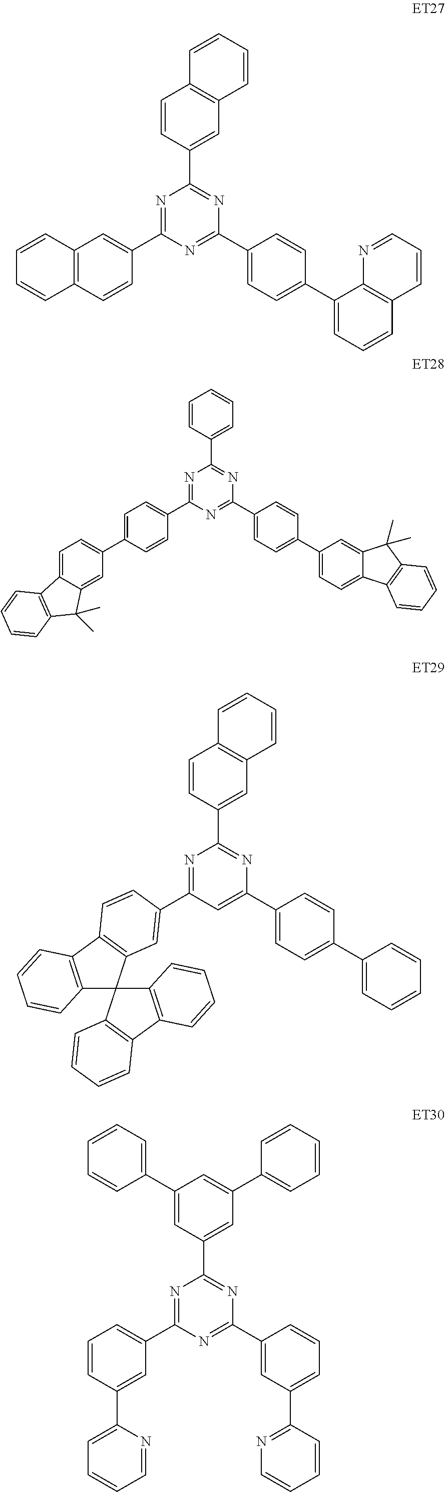

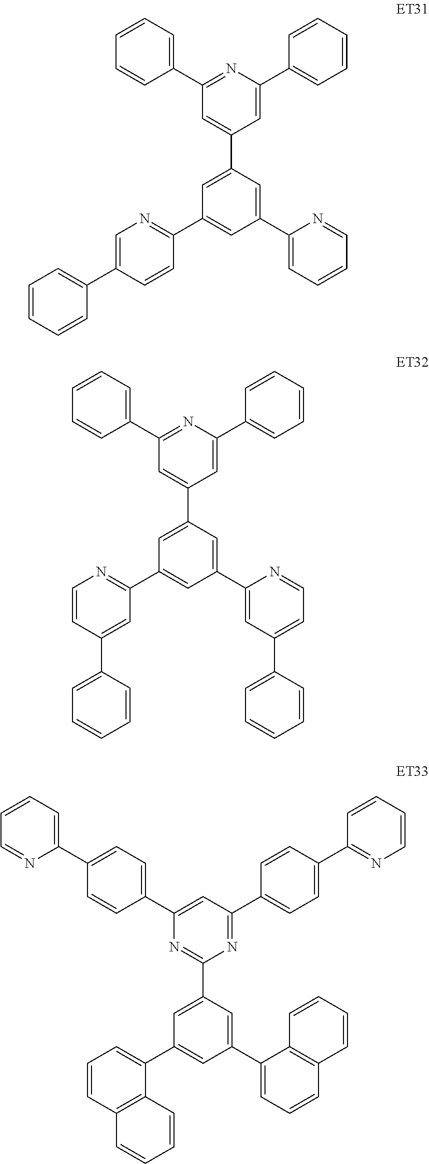 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

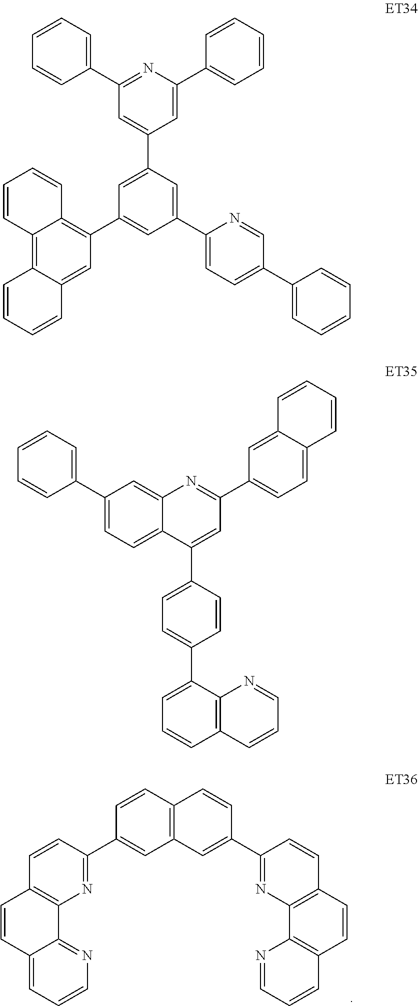

In an embodiment, the electron transport region ETR may include a metal halide such as LiF, NaCl, CsF, RbCl, RbI, CuI, and KI; a lanthanide such as Yb; or a co-deposited material of a metal halide and a lanthanide. For example, the electron transport region ETR may include KI:Yb, RbI:Yb, LiF:Yb, etc., as a co-deposited material. The electron transport region ETR may include a metal oxide such as LizO and BaO, or 8-hydroxy-lithium quinolate (Lig). However, embodiments are not limited thereto. In another embodiment, the electron transport region ETR may include a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the aforementioned materials. However, embodiments are not limited thereto.

The electron transport region ETR may include the compounds of the electron transport region in at least one of an electron injection layer EIL, an electron transport layer ETL, and a hole blocking layer HBL.

If the electron transport region ETR includes an electron transport layer ETL, a thickness of the electron transport layer ETL may be in a range of about 100 Å to about 1,000 Å. For example, the thickness of the electron transport layer ETL may be in a range of about 150 Å to about 500 Å.

If the thickness of the electron transport layer ETL satisfies any of the above-described ranges, satisfactory electron transport properties may be obtained without a substantial increase of driving voltage. If the electron transport region ETR includes an electron injection layer EIL, a thickness of the electron injection layer EIL may be in a range of about 1 Å to about 100 Å. For example, the thickness of the electron injection layer EIL may be in a range of about 3 Å to about 90 Å. If the thickness of the electron injection layer EIL satisfies any of the above described ranges, satisfactory electron injection properties may be obtained without inducing a substantial increase of driving voltage.

The second electrode EL2 may be provided on the electron transport region ETR. The second electrode EL2 may be a common electrode. The second electrode EL2 may be a cathode or an anode, but embodiments are not limited thereto. For example, if the first electrode EL1 is an anode, the second electrode EL2 may be a cathode, and if the first electrode EL1 is a cathode, the second electrode EL2 may be an anode.

The second electrode EL2 may be a transmissive electrode, a transflective electrode or a reflective electrode. If the second electrode EL2 is a transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgYb). In an embodiment, the second electrode EL2 may have a multilayered structure that includes a reflective layer or a transflective layer formed using the above-described materials and a transparent conductive layer formed using ITO, IZO, ZnO, ITZO, etc. For example, the second electrode EL2 may include the aforementioned metal materials, combinations of two or more of the aforementioned metal materials, or oxides of the aforementioned metal materials.

Although not shown in the drawings, in an embodiment, the second electrode EL2 may be electrically connected to an auxiliary electrode. If the second electrode EL2 is electrically connected to an auxiliary electrode, resistance of the second electrode EL2 may decrease.

In an embodiment, the light-emitting element ED may further include a capping layer CPL disposed on the second electrode EL2. The capping layer CPL may have a multilayered structure or a single-layered structure.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNₓ, SiO_{y}, etc.

For example, if the capping layer CPL includes an organic material, the organic material may include 2,2′-dimethyl-N,N′-di-[(1-naphthyl)-N,N′-diphenyl]-1,1′-biphenyl-4,4′-diamine (a-NPD), NPB, TPD, m-MTDATA, Alq₃, CuPc, N4,N4,N4′,N4′-tetra(biphenyl-4-yl) biphenyl-4,4′-diamine (TPD15), 4,4 ′,4″-tris(carbazol-9-yl)triphenylamine (TCTA), etc., or may include an epoxy resin, or an acrylate such as methacrylate. In an embodiment, a capping layer CPL may include at least one of Compounds P1 to P5, but embodiments are not limited thereto.

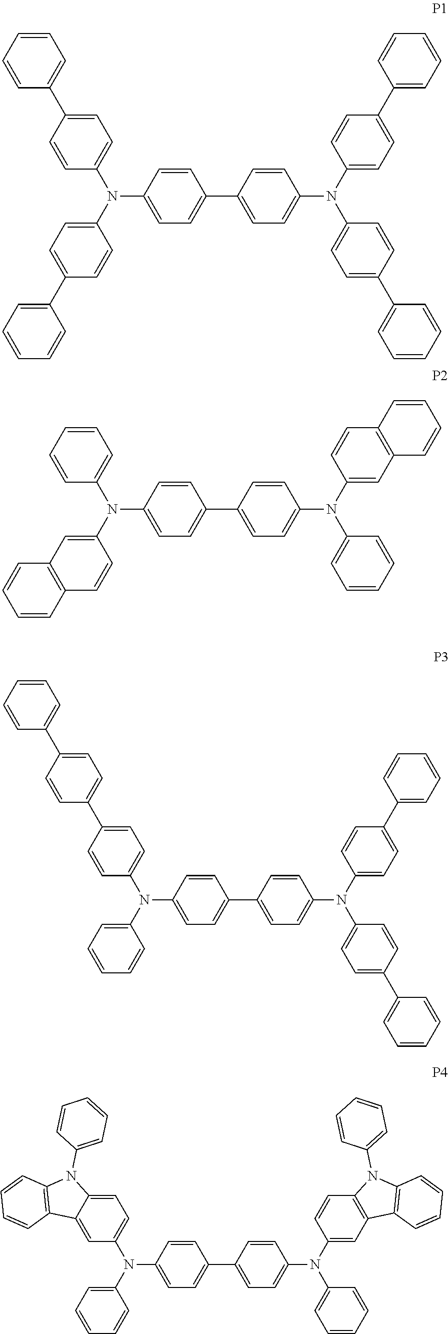 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

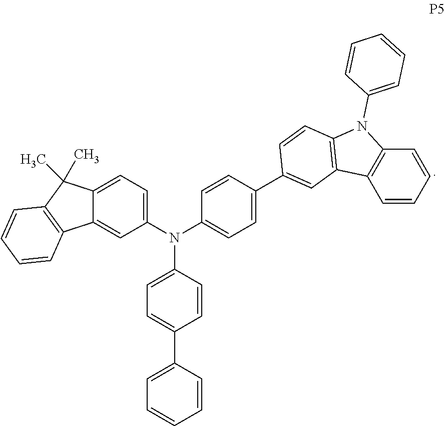 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

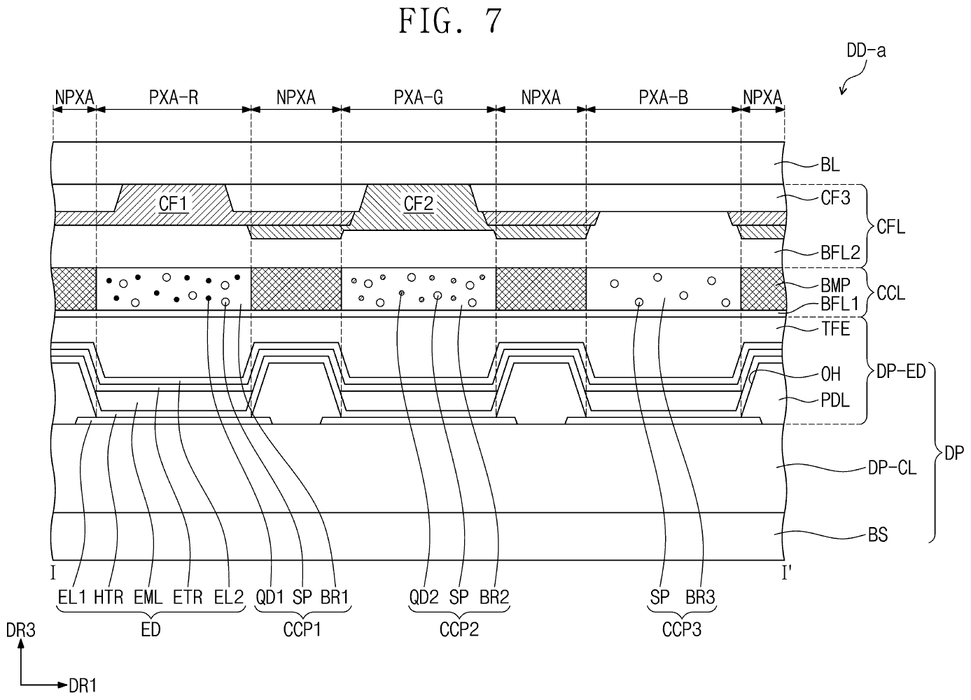

FIG. 7 to FIG. 10 are each a schematic cross-sectional view of a display device according to embodiments. In the explanation on the display devices according to embodiments as shown in FIG. 7 to FIG. 10, the features that have been described above with respect to FIG. 1 to FIG. 6 will not be explained again, and the differing features will be explained.

Referring to FIG. 7, a display device DD-a according to an embodiment may include a display panel DP that includes a display element layer DP-ED, a light controlling layer CCL disposed on the display panel DP, and a color filter layer CFL. In an embodiment shown in FIG. 7, the display panel DP includes a base layer BS, a circuit layer DP-CL provided on the base layer BS, and a display element layer DP-ED, and the display element layer DP-ED may include a light-emitting element ED.

The light-emitting element ED may include a first electrode ELI, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light-emitting element ED shown in FIG. 7 may be the same as a structure of a light-emitting element according to one of FIG. 3 to FIG. 6 as described above.

An emission layer EML of the light-emitting element ED included in the display device DD-a according to an embodiment may include the fused polycyclic compound according to an embodiment as described above.

Referring to FIG. 7, the emission layer EML may be disposed in an opening OH defined in a pixel defining film PDL. For example, the emission layer EML, which is separated by the pixel defining film PDL and provided to correspond to each of the light emitting regions PXA-R, PXA-G, and PXA-B, may emit light in a same wavelength region. In the display device DD-a, the emission layer EML may emit blue light. Although not shown in the drawings, in an embodiment, the emission layer EML may be provided as a common layer for all of the light emitting regions PXA-R, PXA-G, and PXA-B.

The light controlling layer CCL may be disposed on the display panel DP. The light controlling layer CCL may include a light converter. The light converter may be a quantum dot or a phosphor. The light converter may convert the wavelength of a provided light and emit the resulting light. For example, the light controlling layer CCL may be a layer that includes a quantum dot or a layer that includes a phosphor.

The light controlling layer CCL may include light controlling parts CCP1, CCP2, and CCP3. The light controlling parts CCP1, CCP2, and CCP3 may be spaced apart from each other.

Referring to FIG. 7, a partition pattern BMP may be disposed between the separated light controlling parts CCP1, CCP2, and CCP3, but embodiments are not limited thereto. In FIG. 7, it is shown that the partition pattern BMP does not overlap the light controlling parts CCP1, CCP2, and CCP3, but the edges of the light controlling parts CCP1, CCP2, and CCP3 may overlap at least a portion of the partition pattern BMP.

The light controlling layer CCL may include a first light controlling part CCP1 including a first quantum dot QD1 that converts first color light provided from the light-emitting element ED into second color light, a second light controlling part CCP2 including a second quantum dot QD2 that converts first color light into third color light, and a third light controlling part CCP3 that transmits first color light. In an embodiment, the first light controlling part CCP1 may provide red light, which is the second color light, and the second light controlling part CCP2 may provide green light, which is the third color light. The third light controlling part CCP3 may provide blue light by transmitting the first color light provided from the light-emitting element ED. For example, the first quantum dot QD1 may be a red quantum dot, and the second quantum dot QD2 may be a green quantum dot. The quantum dots QD1 and QD2 may each be a quantum dot as described above.

The light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but may include the scatterer SP.

The scatterer SP may be an inorganic particle. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or may be a mixture of two or more materials selected from TiO₂, ZnO, Al₂O₃, SiO₂, and hollow silica.

The first light controlling part CCP1, the second light controlling part CCP2, and the third light controlling part CCP3 may include base resins BR1, BR2, and BR3, in which the quantum dots QD1 and QD2 and the scatterer SP are dispersed. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer SP dispersed in the third base resin BR3.

The base resins BR1, BR2, and BR3 are mediums in which the quantum dots QD1 and QD2 and the scatterer SP are dispersed, and may include various resin compositions which may be referred to as a binder. For example, the base resins BR1, BR2, and BR3 may be acrylic resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light controlling layer CCL may include a barrier layer BFL1. The barrier layer BFL1 may block the penetration of moisture and/or oxygen (hereinafter, will be referred to as “humidity/oxygen”). The barrier layer BFL1 may block the light controlling parts CCP1, CCP2, and CCP3 from exposure to humidity/oxygen. The barrier layer BFL1 may cover the light controlling parts CCP1, CCP2, and CCP3. In an embodiment, a color filter layer CFL, which will be explained later, may include a barrier layer BFL2 disposed on the light controlling parts CCP1, CCP2, and CCP3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film that secures light transmittance. The barrier layers BFL1 and BFL2 may each independently further include an organic layer. The barrier layers BFL1 and BFL2 may be composed of a single layer or of multiple layers.

In the display device DD-a, the color filter layer CFL may be disposed on the light controlling layer CCL. In an embodiment, the color filter layer CFL may be disposed directly on the light controlling layer CCL. For example, the barrier layer BFL2 may be omitted.

The color filter layer CFL may include filters CF1, CF2, and CF3. The first to third filters CF1, CF2, and CF3 may be disposed so that they respectively correspond to a red light emitting region PXA-R, a green light emitting region PXA-G, and a blue light emitting region PXA-B.

The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be provided as separate filters and may be provided as a unitary filter.

Although not shown in the drawings, in an embodiment, the color filter layer CFL may further include a light blocking part (not shown). The light blocking part (not shown) may be a black matrix. The light blocking part (not shown) may include an organic light blocking material or an inorganic light blocking material, each including a black pigment or a black dye. The light blocking part (not shown) may prevent light leakage, and may separate the boundaries between adjacent filters CF1, CF2, and CF3.

A base substrate BL may be disposed on the color filter layer CFL. The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

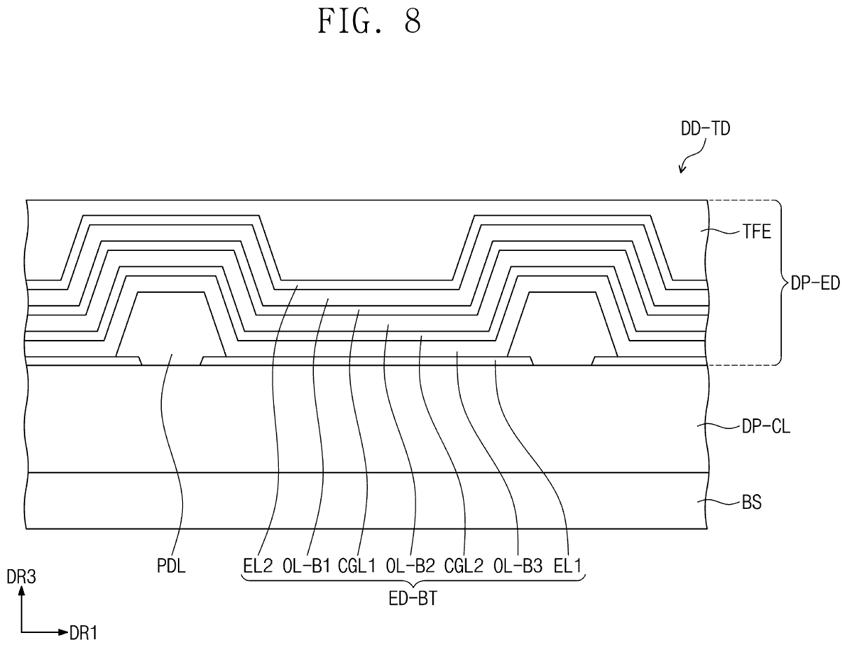

FIG. 8 is a schematic cross-sectional view of a portion of a display device according to an embodiment. In a display device DD-TD according to an embodiment, a light-emitting element ED-BT may include light emitting structures OL-B1, OL-B2, and OL-B3. The light-emitting element ED-BT may include a first electrode EL1 and a second electrode EL2 that face each other, and light emitting structures OL-B1, OL-B2, and OL-B3 stacked in a thickness direction between the first electrode EL1 and the second electrode EL2. The light emitting structures OL-B1, OL-B2, and OL-B3 may each include a hole transport region HTR, an emission layer EML (FIG. 7), and an electron transport region ETR, which may be disposed in that order between the first electrode EL1 and the second electrode EL2.

For example, the light-emitting element ED-BT included in the display device DD-TD may be a light-emitting element having a tandem structure that includes multiple emission layers.

In an embodiment shown in FIG. 8, light emitted from the light emitting structures OL-B1, OL-B2, and OL-B3 may each be blue light. However, embodiments are not limited thereto, and the light emitted from the light emitting structures OL-B1, OL-B2, and OL-B3 may have wavelength ranges that are different from each other. For example, the light-emitting element ED-BT that includes the light emitting structures OL-B1, OL-B2, and OL-B3, which emit light in different wavelength regions, may emit white light.

Charge generating layers CGL1 and CGL2 may each be disposed between two adjacent light emitting structures among the light emitting structures OL-B1, OL-B2, and OL-B3. The charge generating layers CGL1 and CGL2 may each independently include a p-type charge generating layer and/or an n-type charge generating layer.

The fused polycyclic compound according to an embodiment as described above may be included in at least one of the light emitting structures OL-B1, OL-B2, and OL-B3 included in the display device DD-TD. For example, at least one of the emission layers included in the light-emitting element ED-BT may include the fused polycyclic compound according to an embodiment.

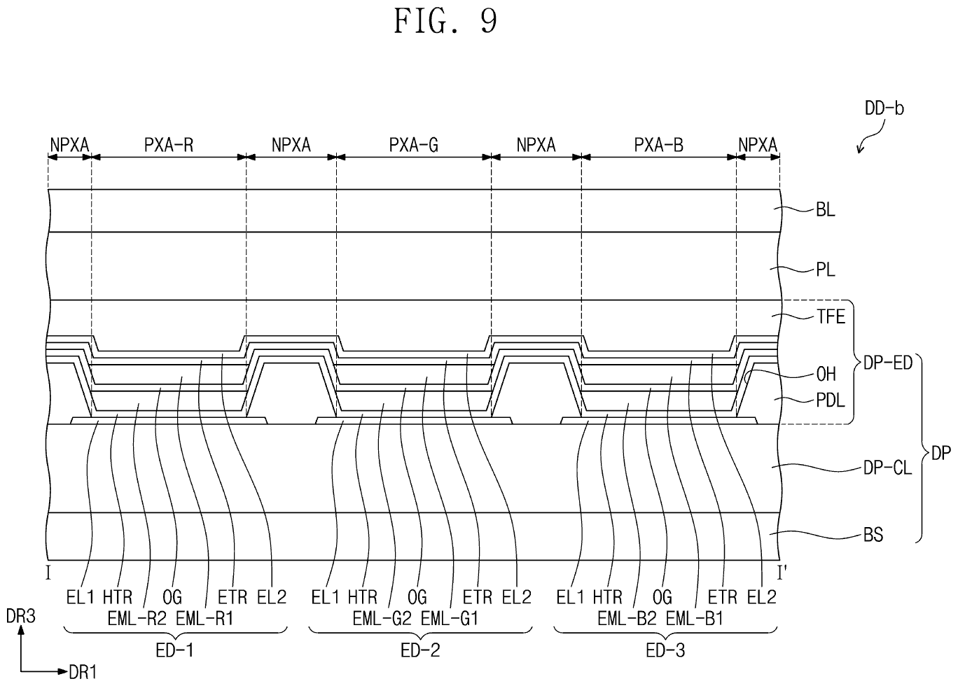

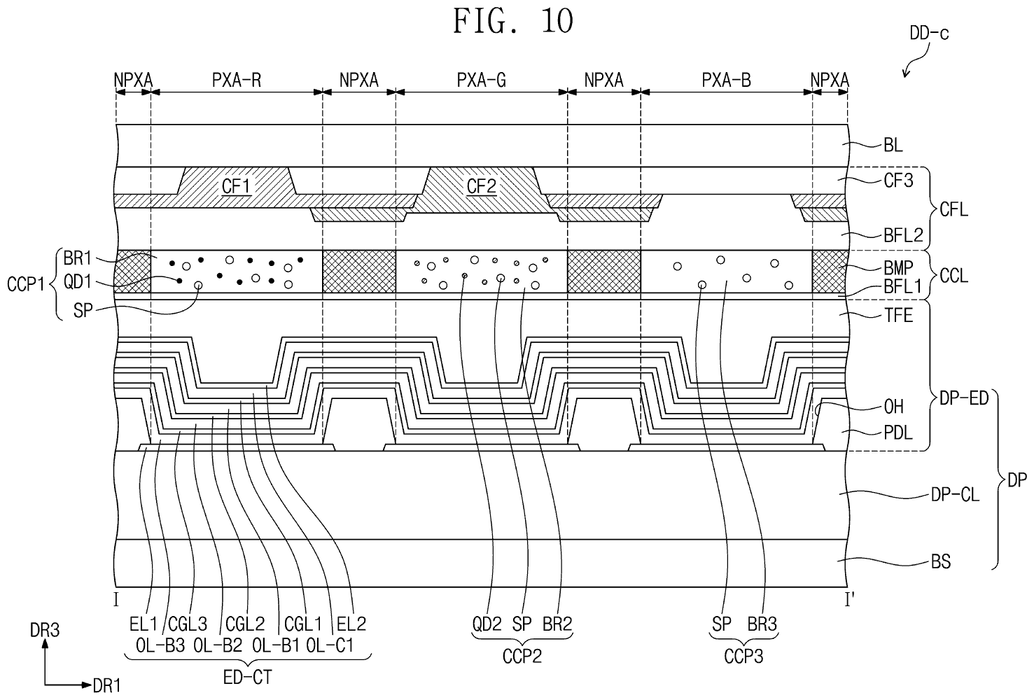

FIG. 9 is a schematic cross-sectional view of a display device DD-b according to an embodiment. FIG. 10 is a schematic cross-sectional view of a display device DD-c according to an embodiment.

Referring to FIG. 9, a display device DD-b according to an embodiment may include light-emitting elements ED-1, ED-2, and ED-3, in which two emission layers are stacked. In comparison to the display device DD shown in FIG. 2, the embodiment shown in FIG. 9 is different at least in that the first to third light-emitting elements ED-1, ED-2, and ED-3 each include two emission layers that are stacked in a thickness direction. In the first to third light-emitting elements ED-1, ED-2, and ED-3, the two emission layers may emit light in a same wavelength region.

The first light-emitting element ED-1 may include a first red emission layer EML-R1 and a second red emission layer EML-R2. The second light-emitting element ED-2 may include a first green emission layer EML-G1 and a second green emission layer EML-G2. The third light-emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may have a single-layered structure or a multilayered structure. The emission auxiliary part OG may include a charge generating layer. For example, the emission auxiliary part OG may include an electron transport region, a charge generating layer, and a hole transport region, which may be stacked in that order. The emission auxiliary part OG may be provided as a common layer for the first to third light-emitting elements ED-1, ED-2, and ED-3. However, embodiments are not limited thereto, and the emission auxiliary part OG may be provided by being patterned within the openings OH defined in a pixel defining film PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

The first light-emitting element ED-1 may include a first electrode EL1, a hole transport region HTR, a second red emission layer EML-R2, an emission auxiliary part OG, a first red emission layer EML-R1, an electron transport region ETR, and a second electrode EL2, which are stacked in that order. The second light-emitting element ED-2 may include a first electrode EL1, a hole transport region HTR, a second green emission layer EML-G2, an emission auxiliary part OG, a first green emission layer EML-G1, an electron transport region ETR, and a second electrode EL2, which are stacked in that order. The third light-emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, which are stacked in that order.

An optical auxiliary layer PL may be disposed on a display element layer DP-ED. The optical auxiliary layer PL may include a polarization layer. The optical auxiliary layer PL may be disposed on a display panel DP and may control light that is reflected at the display panel DP from an external light. Although not shown in the drawings, in an embodiment, the optical auxiliary layer PL may be omitted from the display device DD-b.

At least one emission layer included in the display device DD-b illustrated in FIG. 9 may include the fused polycyclic compound according to an embodiment as described above. For example, in an embodiment, at least one of the first blue emission layer EML-B1 and the second blue emission layer EML-B2 may include the fused polycyclic compound according to an embodiment.

In contrast to FIG. 8 and FIG. 9, FIG. 10 shows a display device DD-c that is different at least in that it includes four light emitting structures OL-B1, OL-B2, OL-B3, and OL-C1. A light-emitting element ED-CT may include a first electrode EL1 and a second electrode EL2 that face each other, and first to fourth light emitting structures OL-B1, OL-B2, OL-B3, and OL-C1 that are stacked in a thickness direction between the first electrode EL1 and the second electrode EL2. In an embodiment, the third light emitting structure OL-B3, the second light emitting structure OL-B2, the first light emitting structure OL-B1, and the fourth light emitting structure OL-C1 may be stacked in that order in a thickness direction between the first electrode EL1 and the second electrode EL2.

Charge generating layers CGL1, CGL2, and CGL3 may each be disposed between two adjacent light emitting structures among the first to fourth light emitting structures OL-B1, OL-B2, OL-B3, and OL-C1. For example, a first charge generating layer CGL1 may be disposed between the first light emitting structure OL-B1 and the fourth light emitting structure OL-C1, a second charge generating layer CGL2 may be disposed between the first light emitting structure OL-B1 and the second light emitting structure OL-B2, and a third charge generating layer CGL3 may be disposed between the second light emitting structure OL-B2 and the third light emitting structure OL-B3. The charge generating layers CGL1, CGL2, and CGL3 may each independently include a p-type charge generating layer and/or an n-type charge generating layer.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having wavelength regions that are different from each other.

The fused polycyclic compound according to an embodiment may be included in at least one of the light emitting structures OL-B1, OL-B2, OL-B3, and OL-C1 included in the display device DD-c. In an embodiment, at least one of the first to third light emitting structures OL-B1, OL-B2, and OL-B3 may each independently include the fused polycyclic compound according to an embodiment.

The light-emitting element ED according to an embodiment may include the fused polycyclic compound represented by Formula 1 in at least one functional layer between a first electrode EL1 and a second electrode EL2, thereby exhibiting excellent luminous efficiency and improved lifespan. For example, the fused polycyclic compound according to an embodiment may be included in an emission layer EML of the light-emitting element ED, and thus the light-emitting element ED may exhibit long lifespan characteristics.

In an embodiment, an electronic apparatus may include a display device that includes multiple light-emitting elements and a control part that controls the display device. The electronic apparatus may be an apparatus that is activated according to electrical signals. The electronic apparatus may include display devices according to various embodiments. Examples of an electronic apparatus may include large, medium-sized, and small electronic devices, such as a television, a monitor, a billboard, a personal computer, a laptop computer, a personal digital terminal, a display device for a vehicle, a game console, a portable electronic device, and a camera.

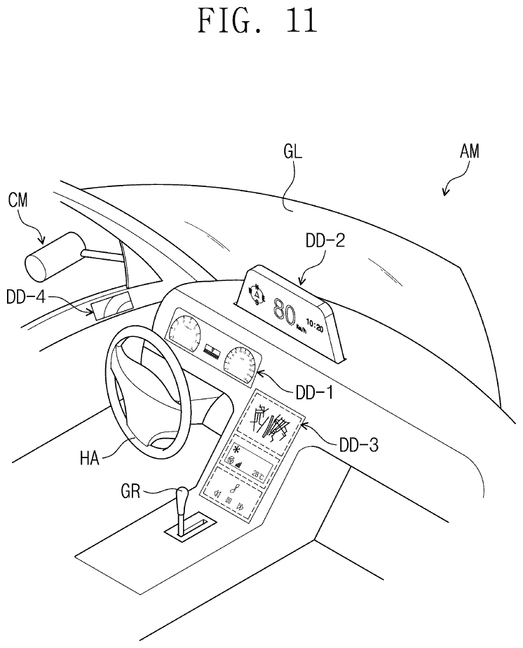

FIG. 11 is a schematic diagram of a vehicle AM in which first to fourth display devices DD-1, DD-2, DD-3, and DD-4 are disposed. At least one of the first to fourth display devices DD-1, DD-2, DD-3, and DD-4 may have a structure according to one of display devices DD, DD-TD, DD-a, DD-b, and DD-c, as described above with reference to FIGS. 1, 2, and 7 to 10.

In FIG. 11, an automobile is shown as a vehicle AM, but this is only an example, and the first to fourth display devices DD-1, DD-2, DD-3, and DD-4 may be disposed in various transportation means, such as a bicycle, a motorcycle, a train, a ship, and an airplane. In an embodiment, at least one of the first to fourth display devices DD-1, DD-2, DD-3, and DD-4 having a structure according to one of display devices DD, DD-TD, DD-a, DD-b, and DD-c may be included in a personal computer, a laptop computer, a personal digital terminal, a game console, a portable electronic device, a television, a monitor, a billboard, or the like. However, these are merely provided as examples, and the display device may be included in other electronic apparatuses.

At least one of the first to fourth display devices DD-1, DD-2, DD-3, and DD-4 may each independently include a light-emitting element ED according to an embodiment as described with reference to any of FIG. 3 to FIG. 6. The light-emitting element ED may include the fused polycyclic compound according to an embodiment. At least one of the first to fourth display devices DD-1, DD-2, DD-3, and DD-4 may include a light-emitting element ED that includes the fused polycyclic compound according to an embodiment, and thus may have improved display lifespan.

Referring to FIG. 11, the vehicle AM may include a steering wheel HA for operating the vehicle AM and a gearshift GR. The vehicle AM may include a front window GL that is disposed so as to face a driver.

A first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, as revolutions per minute (RPM)), and images that represent a fuel gauge. The first scale and the second scale may each be represented by digital images.

A second display device DD-2 may be disposed in a second region facing a driver's seat that overlaps the front window GL. The driver's seat may be a seat where the steering wheel HA is disposed. For example, the second display device DD-2 may be a head up display (HUD) that shows second information of the vehicle AM. The second display device DD-2 may be optically transparent. The second information may include digital numbers that indicate a driving speed of the vehicle AM, and may further include information such as the current time. Although not shown in the drawings, in an embodiment, the second information of the second display device DD-2 may be displayed by being projected onto the front window GL.

A third display device DD-3 may be disposed in a third region that is adjacent to the gearshift GR. For example, the third display device DD-3 may be a center information display (CID) for a vehicle that is disposed between a driver's seat and a passenger seat and which displays third information. The passenger seat may be a seat that is spaced apart from the driver's seat, the gearshift GR may be disposed between the driver's seat and the passenger seat. The third information may include information about traffic conditions (for example, navigation information), about music or radio that is playing, about a video (or image) that is displayed, about temperatures in the vehicle AM, or the like.

A fourth display device DD-4 may be disposed in a fourth region that is spaced apart from the steering wheel HA and the gearshift GR and adjacent to a side of the vehicle AM. For example, the fourth display device DD-4 may be a digital side-view mirror that displays fourth information.

The fourth display device DD-4 may display an image that is external to the vehicle AM, which may be taken by a camera module CM that is disposed on the exterior of the vehicle AM. The fourth information may include an exterior image of the vehicle AM.

The first to fourth information as described above are only provided as examples, and the first to fourth display devices DD-1, DD-2, DD-3, and DD-4 may further display information on the interior and exterior of the vehicle AM. The first to fourth information may include information that is different from each other. However, embodiments are not limited thereto, and a portion of the first to fourth information may include a same information.

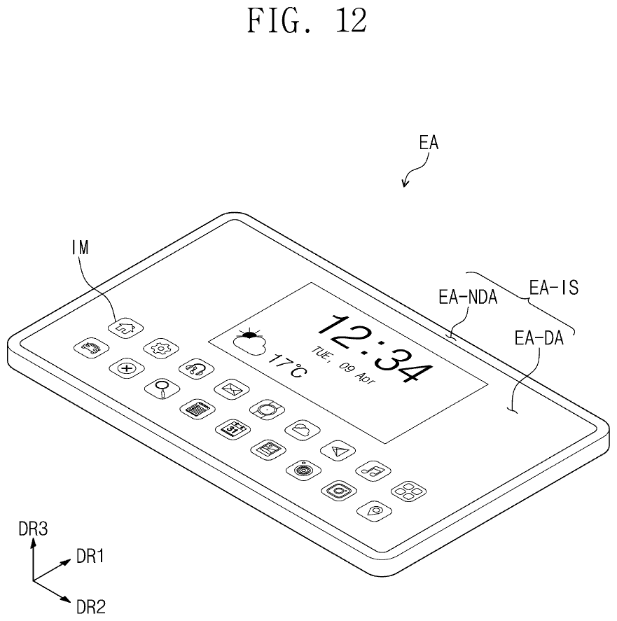

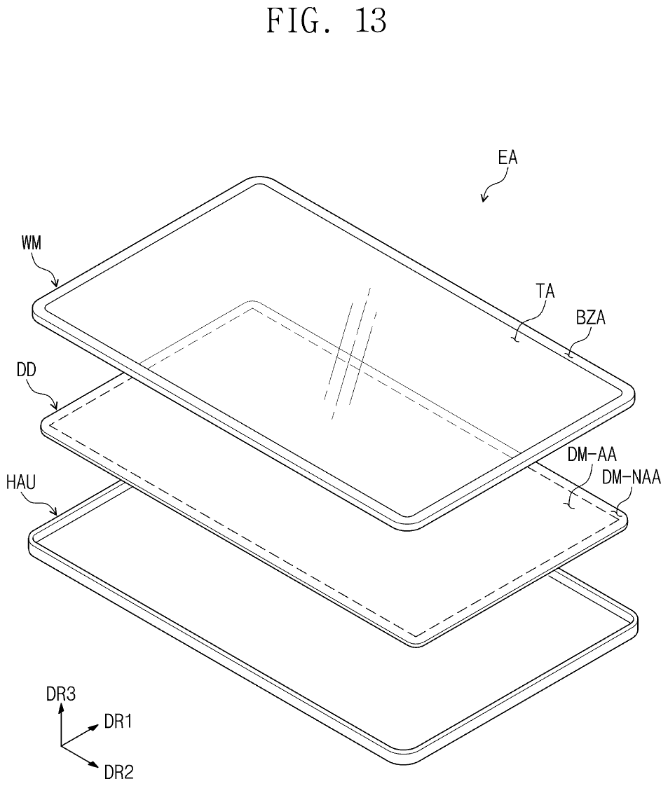

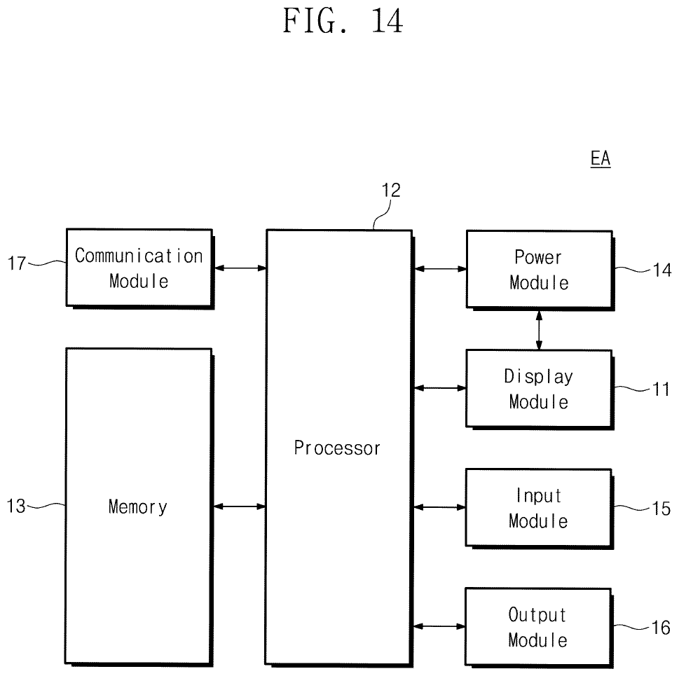

FIG. 12 is a schematic perspective view of an electronic apparatus according to an embodiment. FIG. 13 is an exploded schematic perspective view of an electronic apparatus according to an embodiment.

As shown in FIG. 12, an electronic apparatus EA may display an image IM through a display surface EA-IS. The image IM may be a dynamic image or a static image. The display surface EA-IS may be parallel to a plane defined by a first direction axis DR1 and a second direction axis DR2. FIG. 12 shows that the electronic apparatus EA has a flat display surface EA-IS, but embodiments are not limited thereto. For example, the electronic apparatus EA may include a curved display surface or a three-dimensional display surface. In an embodiment, a three-dimensional display surface may include multiple display areas that are disposed or positioned in different directions from each other.

The display surface EA-IS may include a display area EA-DA and a non-display area EA-NDA. The electronic apparatus EA may display an image IM through the display area EA-DA.

The non-display area EA-NDA may have a selected or given color. The non-display area EA-NDA may be adjacent to the display area EA-DA. In an embodiment, the non-display area EA-NDA may surround the display area EA-DA. Accordingly, the shape of the display area EA-DA may be substantially defined by the non-display area EA-NDA. However, FIG. 12 is only an illustration, and the non-display area EA-NDA may be disposed to be adjacent to only a side of the display area EA-DA or may be omitted.

Referring to FIG. 13, the electronic apparatus EA may include a display device DD, a window member WM, and a housing HAU.

The window member WM may cover an outer surface of the electronic apparatus EA.

For example, the window member WM may cover the entire outer surface of the electronic apparatus EA. The window member WM may include a transparent area TA and a bezel area BZA.

The front surface of the window member WM that includes the transparent area TA and the bezel area BZA may correspond to a front surface of the electronic apparatus EA. The transparent area TA may correspond to the display area EA-DA of the electronic apparatus EA illustrated in FIG. 12, and the bezel area BZA may correspond to the non-display area EA-NDA of the electronic apparatus EA illustrated in FIG. 12.

The transparent area TA may be an optically transparent area. The bezel area BZA may be an area having a relatively low light transmittance, as compared to the transparent area TA. The bezel area BZA may have a selected or given color. The bezel area BZA may be adjacent to the transparent area TA and may surround the transparent area TA. The bezel area BZA may define the shape of the transparent area TA. However, embodiments are not limited thereto, and the bezel area BZA may be disposed to be adjacent to only a side of the transparent area TA, or a portion thereof may be omitted.

The housing HAU may include a material having relatively high rigidity. For example, the housing HAU may include a frame and/or a plate made of glass, plastic, or metal. The frames and/or plates may be provided as multiple pieces. The housing HAU may provide a receiving space for the display device DD. The display device DD may be accommodated in the receiving space and protected from external impact.

The display device DD may have a configuration according to one of the display devices DD, DD-TD, DD-a, DD-b, and DD-c as described above with reference to FIGS. 1, 2, and 7 to 10.

The display device DD may include at least one light-emitting element ED according to an embodiment as described with reference to any of FIGS. 3 to 6. Accordingly, the electronic apparatus EA including the display device DD according to an embodiment may exhibit excellent reliability.

An active area DM-AA and a peripheral area DM-NAA may be defined in the display device DD. The active area DM-AA may overlap the display area EA-DA illustrated in FIG. 12, and the peripheral area DM-NAA may overlap the non-display area EA-NDA illustrated in FIG. 12.

The active area DM-AA may be an area that is activated according to an electrical signal.

The peripheral area DM-NAA may be an area that is adjacent to at least one side of the active area DM-AA. The active area DM-AA may include the non-light emitting regions NPXA and light emitting regions PXA-R, PXA-G, and PXA-B, as illustrated in FIG. 1. The peripheral area DM-NAA may surround the active area DM-AA. However, embodiments are not limited thereto. In another embodiment, at least a portion of the peripheral areas DM-NAA may be omitted. A driving circuit or driving wiring for driving the active area DM-AA may be disposed in the peripheral area DM-NAA.

The electronic apparatus EA according to an embodiment includes the display device DD as described above, and may further include a module or device having an additional function.

FIG. 14 is a block diagram of an electronic apparatus according to an embodiment. Referring to FIG. 14, an electronic apparatus EA according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. Data that are necessary for the operation of the processor 12 or the display module 11 may be stored in the memory 13. If the processor 12 executes an application stored in the memory 13, an image data signal and/or an input control signal are transmitted to the display module 11, and the display module 11 may process the received signal and output image information through a display screen.

The power module 14 may include a power supply module such as a power adapter or a battery device, and a power conversion module that converts the power supplied by the power supply module to generate power necessary for the operation of the electronic apparatus EA.

The display module 11 may have a configuration according to one of the display devices DD, DD-TD, DD-a, DD-b, and DD-c, as described above with reference to FIGS. 1, 2, and 7 to 10. For example, a configuration of the display module 11 may include a base layer BS, a circuit layer DP-CL, and a display element layer DP-ED, as shown in the display devices DD, DD-TD, DD-a, DD-b, and DD-c, as described with reference to FIGS. 1, 2, and 7 to 10. The display module 11 may further include at least one of an optical layer PP (FIG. 2), a light control layer CCL (FIGS. 7 and 10), a color filter layer CFL (FIGS. 7 and 10), and an optical auxiliary layer PL (FIG. 9).

The electronic apparatus EA may further include an input module 15, a non-image output module 16, and/or a communication module 17.

The input module 15 may provide input information to the processor 12 and/or the display module 11. The input module 15 may include various sensor modules as well as physical buttons, a keyboard, and a microphone. Examples of sensor modules may include touch sensors, pressure sensors, distance sensors, position sensors, digitizers, motion recognition sensors, camera sensors, photodetectors, photoelectric conversion sensors, temperature sensors, and biosensors such as blood pressure sensors, blood sugar sensors, electrocardiogram sensors, and heart rate sensors.

The non-image output module 16 may receive information other than images transmitted from the processor 12 and provide the information to the user. Examples of the non-image output module 16 may include an audio module, a haptic module, a light emitting module, and the like, and may include other electronic device-specific functional modules (e.g., a cooling module for a refrigerator, and the like).

The communication module 17 is a module that transmits and receives information between the electronic apparatus EA and an external device, and may include a receiving part and a transmitting part. The communication module 17 may include various wireless communication modules such as a mobile communication module, a Wi-Fi module, and a Bluetooth module, or various wired communication modules.

In an embodiment, one or more of the individual modules that are functionally included in one module may be included in the display device, and other modules may be provided separately from the display device. For example, the display device may include the display module 11, and the processor 12, the memory 13, and the power module 14 may be provided in the form of other devices within the electronic apparatus EA other than the display device.

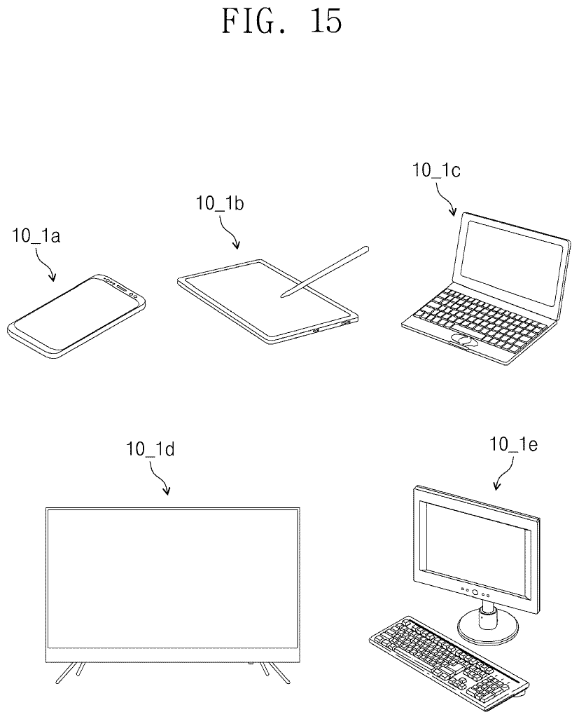

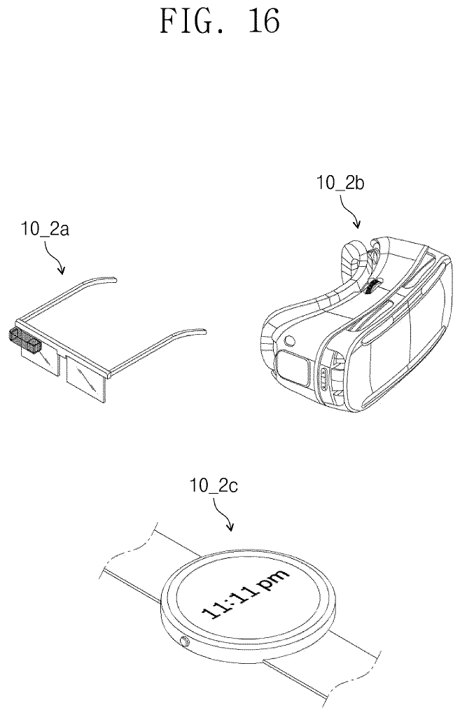

FIGS. 15 and 16 are each a schematic diagram of an electronic apparatus according to embodiments. Referring to FIGS. 15 and 16, various electronic apparatuses may include a display device (for example, at least one of DD, DD-TD, DD-a, DD-b, and DD-c, as shown in FIGS. 1, 2, and 7 to 10) according to an embodiment, and examples of such electronic apparatuses may include not only image display electronic apparatuses, such as a smart phone 10_1a, a tablet computer 10_ib, a laptop computer 10_ic, a television 10_id, and a desktop monitor 10_le, and such examples may also include wearable electronic apparatuses that include display modules such as smart glasses 10_2a, a head-mounted display 10_2b, and a smart watch 10_2c. However, these embodiments are merely shown as examples, and the electronic apparatus according to embodiments is not limited thereto.

Hereinafter, a fused polycyclic compound according to an embodiment and a light-emitting element according to an embodiment will be described in detail with reference to the Examples and the Comparative Examples. The Examples described below are only provided to facilitate in understanding the disclosure, and the scope thereof is not limited to thereto.

### EXAMPLES

### 1. Synthesis of fused polycyclic compound

A synthesis method of the fused polycyclic compounds according to an embodiment will be described in detail by describing synthesis methods for Compounds 2, 15, 16, 85, 88, 99, and 133. In the following descriptions, the synthesis methods of the fused polycyclic compounds are only provided as examples, and the synthesis method of the fused polycyclic compound according to an embodiment is not limited to the Examples below.

### (1) Synthesis of Compound 2

Compound 2 may be synthesized by Reaction Scheme 1 below.

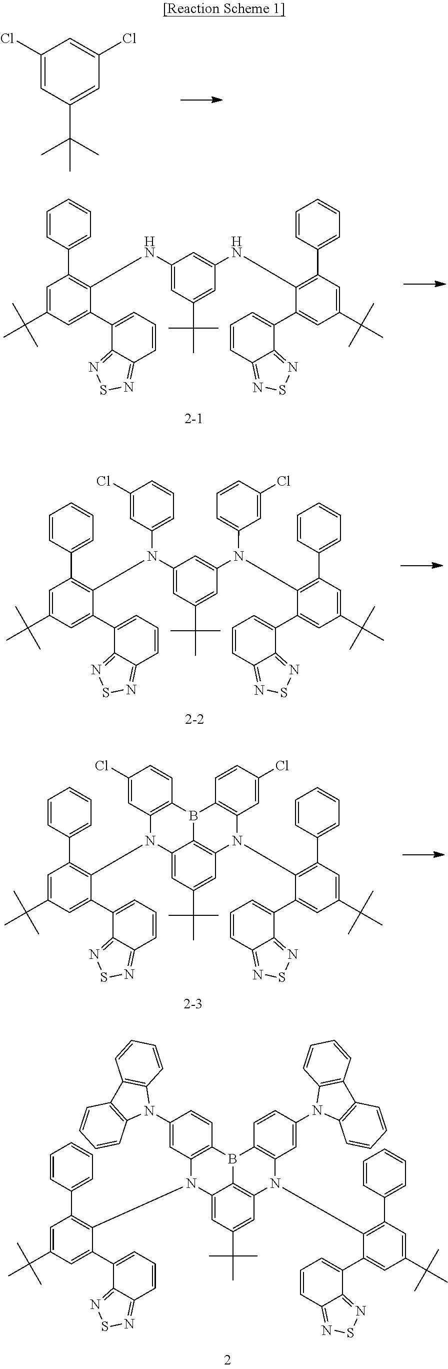

### 1) Synthesis of Intermediate Compound 2-1

In a nitrogen atmosphere, 1-(tert-butyl)-3,5-dichlorobenzene (1 eq), 3-(benzo[c][1,2,5]thiadiazol-4-yl)-5-(tert-butyl)-[1,1′-biphenyl]-2-amine (2.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 2-1 (yield: 73%)

### 2) Synthesis of Intermediate Compound 2-2

In a nitrogen atmosphere, Intermediate Compound 2-1 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days.

After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 2-2 (yield: 63%).

### 3) Synthesis of Intermediate Compound 2-3

In a nitrogen atmosphere, Intermediate Compound 2-2 (1 eq) was dissolved in o-dichlorobenzene, cooled using ice water, BBr₃ (5 equiv.) was slowly added dropwise, and the reaction solution was stirred at about 180° C. for about 24 hours. After cooling, the reaction was terminated with triethylamine (5 equiv.), water/CH₂Cl₂ were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 2-3 (yield: 37%).

### 4) Synthesis of Compound 2

In a nitrogen atmosphere, Intermediate Compound 2-3 (1 eq), carbazole (2.2 eq). Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Compound 2 (yield: 78%).

### (2) Synthesis of Compound 15

Compound 15 may be synthesized by Reaction Scheme 2 below.

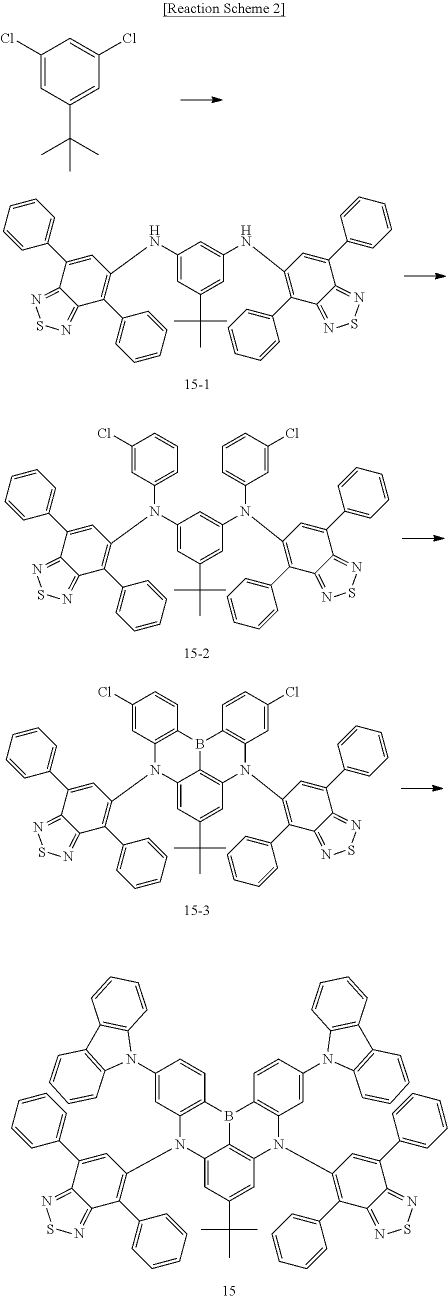

### 1) Synthesis of Intermediate Compound 15-1

In a nitrogen atmosphere, 1-(tert-butyl)-3,5-dichlorobenzene (1 eq), 5-bromo-4,7-diphenylbenzo[c][1,2,5]thiadiazole(2.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 15-1 (yield: 83%).

### 2) Synthesis of Intermediate Compound 15-2

In a nitrogen atmosphere, Intermediate Compound 15-1 (1 eq), 3-iodochlorobenzene (10 eq), Pd₂(dba)₃ (0.5 eq), tris-tert-butyl phosphine (1 eq), and sodium tert-butoxide (4eq) were added and dissolved in o-xylene, and the reaction solution was stirred at about 160° C. for about 3 days.

After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 15-2 (yield: 62%).

### 3) Synthesis of Intermediate Compound 15-3

In a nitrogen atmosphere, Intermediate Compound 15-2(1 eq) was dissolved in o-dichlorobenzene and cooled using ice water, BBr₃ (5 equiv.) was slowly added dropwise, and the reaction solution was stirred at about 180° C. for about 24 hours. After cooling, the reaction was terminated with triethylamine (5 equiv.), water/CH₂Cl₂ were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 15-3 (yield: 34%).

### 4) Synthesis of Compound 15

In a nitrogen atmosphere, Intermediate Compound 15-3 (1 eq), carbazole (2.2 eq). Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Compound 15 (yield: 75%).

### (3) Synthesis of Compound 16

Compound 16 may be synthesized by Reaction Scheme 3 below.

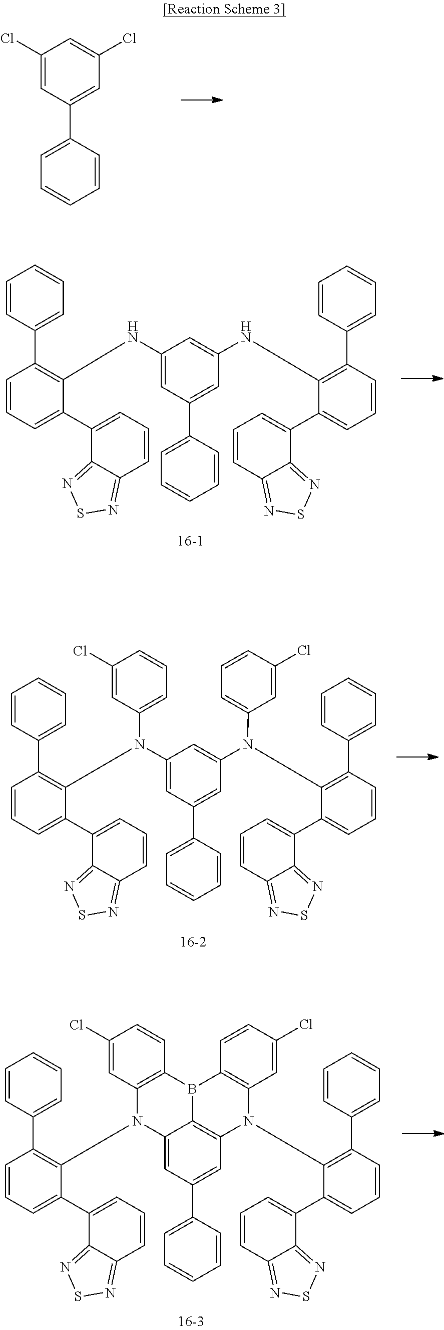 [SMILES: Clc1cc(Cl)cc(-c2ccccc2)c1 ; c1ccc(-c2cc(Nc3c(-c4ccccc4)cccc3-c3cccc4nsnc34)cc(Nc3c(-c4ccccc4)cccc3-c3cccc4nsnc34)c2)cc1 ; Clc1cccc(N(c2cc(-c3ccccc3)cc(N(c3cccc(Cl)c3)c3c(-c4ccccc4)cccc3-c3cccc4nsnc34)c2)c2c(-c3ccccc3)cccc2-c2cccc3nsnc23)c1 ; Clc1ccc2c(c1)N(c1c(-c3ccccc3)cccc1-c1cccc3nsnc13)c1cc(-c3ccccc3)cc3c1B2c1ccc(Cl)cc1N3c1c(-c2ccccc2)cccc1-c1cccc2nsnc12]

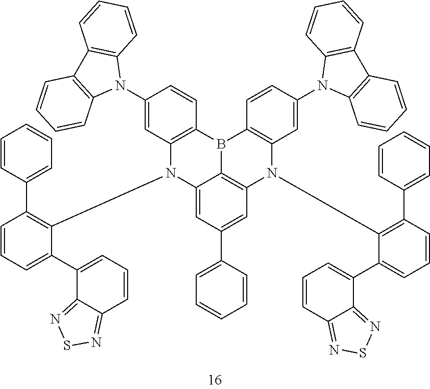 [SMILES: c1ccc(-c2cc3c4c(c2)N(c2c(-c5ccccc5)cccc2-c2cccc5nsnc25)c2cc(-n5c6ccccc6c6ccccc65)ccc2B4c2ccc(-n4c5ccccc5c5ccccc54)cc2N3c2c(-c3ccccc3)cccc2-c2cccc3nsnc23)cc1]

### 1) Synthesis of Intermediate Compound 16-1

In a nitrogen atmosphere, 3,5-dichloro-1,1′-biphenyl (1 eq), 3-(benzo[c][1,2,5]thiadiazol-4-yl)-[1,1′-biphenyl]-2-amine (2.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 16-1 (yield: 73%).

### 2) Synthesis of Intermediate Compound 16-2

In a nitrogen atmosphere, Intermediate Compound 16-1 (1 eq), 3-iodochlorobenzene (10 eq), Pd₂(dba)₃ (0.5 eq), tris-tert-butyl phosphine (1 eq), sodium tert-butoxide (4 eq) were added and dissolved in o-xylene, and the reaction solution was stirred at about 160° C. for about 3 days. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 16-2 (yield: 63%).

### 3) Synthesis of Intermediate Compound 16-3

In a nitrogen atmosphere, Intermediate Compound 16-2 (1 eq) was dissolved in o-dichlorobenzene and cooled using ice water, BBr₃ (5 equiv.) was slowly added dropwise, and the reaction solution was stirred at about 180° C. for about 24 hours. After cooling, the reaction was terminated with triethylamine (5 equiv.), water/CH₂Cl₂ were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 16-3 (yield: 37%).

### 4) Synthesis of Compound 16

In a nitrogen atmosphere, Intermediate Compound 16-3 (1 eq), carbazole (2.2 eq). Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Compound 16 (yield: 78%).

### (4) Synthesis of Compound 85

Compound 85 may be synthesized by Reaction Scheme 4 below.

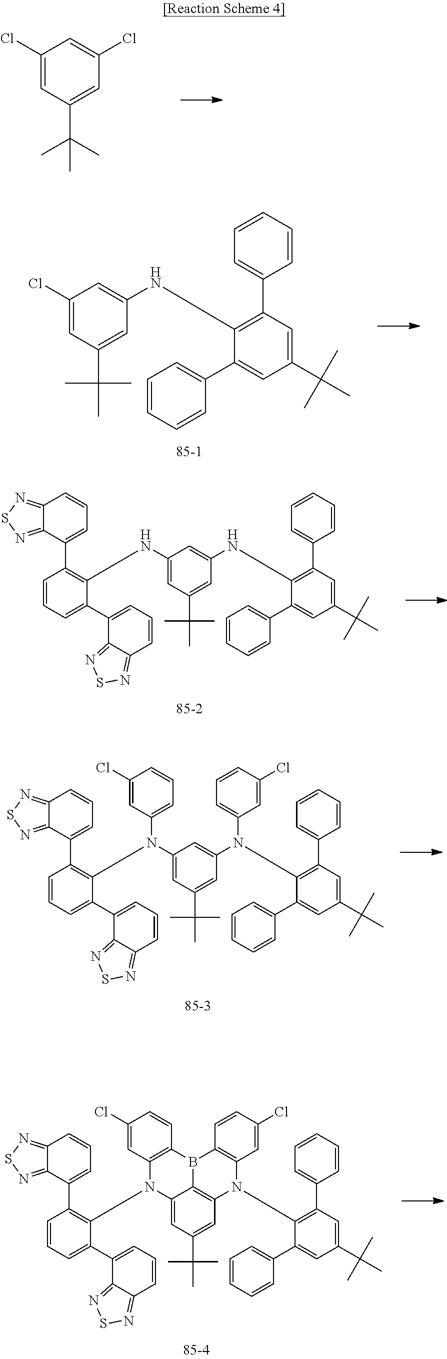 [SMILES: CC(C)(C)c1cc(Cl)cc(Cl)c1 ; CC(C)(C)c1cc(Cl)cc(Nc2c(-c3ccccc3)cc(C(C)(C)C)cc2-c2ccccc2)c1 ; CC(C)(C)c1cc(Nc2c(-c3ccccc3)cc(C(C)(C)C)cc2-c2ccccc2)cc(Nc2c(-c3cccc4nsnc34)cccc2-c2cccc3nsnc23)c1 ; CC(C)(C)c1cc(N(c2cccc(Cl)c2)c2c(-c3ccccc3)cc(C(C)(C)C)cc2-c2ccccc2)cc(N(c2cccc(Cl)c2)c2c(-c3cccc4nsnc34)cccc2-c2cccc3nsnc23)c1 ; CC(C)(C)c1cc(-c2ccccc2)c(N2c3cc(Cl)ccc3B3c4ccc(Cl)cc4N(c4c(-c5cccc6nsnc56)cccc4-c4cccc5nsnc45)c4cc(C(C)(C)C)cc2c43)c(-c2ccccc2)c1]

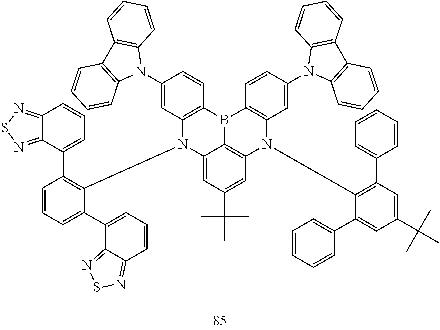 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5cccc6nsnc56)cccc4-c4cccc5nsnc45)c4cc(C(C)(C)C)cc2c43)c(-c2ccccc2)c1]

### 1) Synthesis of Intermediate Compound 85-1

In a nitrogen atmosphere, 1-(tert-butyl)-3,5-dichlorobenzene (1 eq), 5′-(tert-butyl)-[1,1′:3′,1″-terphenyl]-2′-amine(1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 85-1 (yield: 81%).

### 2) Synthesis of Intermediate Compound 85-2

In a nitrogen atmosphere, Intermediate Compound 85-1 (1 eq), 2,6-bis(benzo[c][1,2,5]thiadiazol-4-yl)aniline(1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 85-2 (yield: 85%).

### 3) Synthesis of Intermediate Compound 85-3

In a nitrogen atmosphere, Intermediate Compound 85-2 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 85-3 (yield: 61%).

### 4) Synthesis of Intermediate Compound 85-4

In a nitrogen atmosphere, Intermediate Compound 85-3 (1 eq) was dissolved in o-dichlorobenzene and cooled using ice water, BBr₃ (5 equiv.) was slowly added dropwise, and the reaction solution was stirred at about 180° C. for about 24 hours. After cooling, the reaction was terminated with triethylamine (5 equiv.), water/CH₂Cl₂ were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 85-4 (yield: 34%).

### 5) Synthesis of Compound 85

In a nitrogen atmosphere, Intermediate Compound 85-4 (1 eq), carbazole (2.2 eq). Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Compound 85 (yield: 71%).

### (5) Synthesis of Compound 88

Compound 88 may be synthesized by Reaction Scheme 5 below.

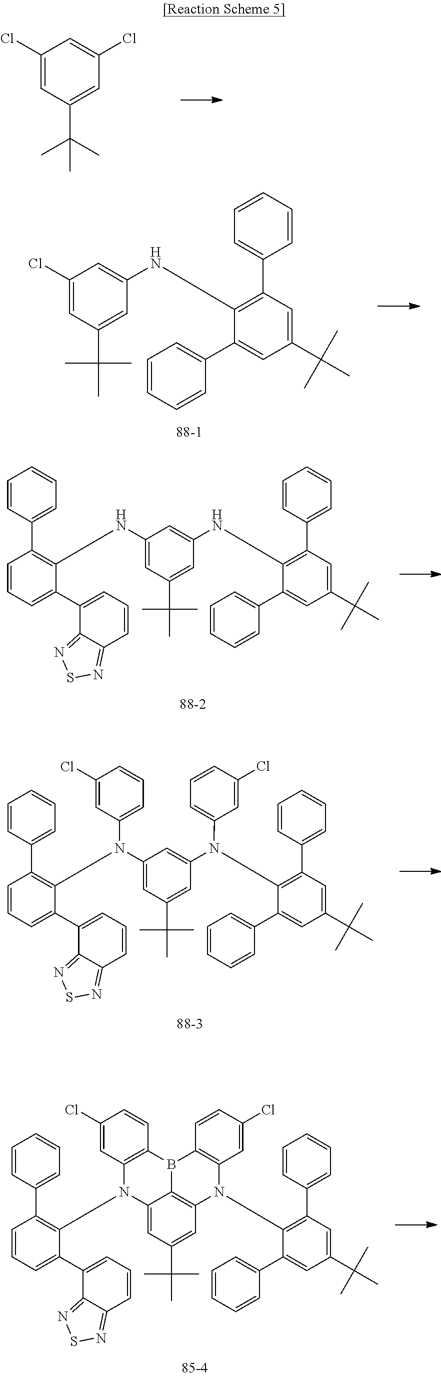 [SMILES: CC(C)(C)c1cc(Cl)cc(Cl)c1 ; CC(C)(C)c1cc(Cl)cc(Nc2c(-c3ccccc3)cc(C(C)(C)C)cc2-c2ccccc2)c1 ; CC(C)(C)c1cc(Nc2c(-c3ccccc3)cc(C(C)(C)C)cc2-c2ccccc2)cc(Nc2c(-c3ccccc3)cccc2-c2cccc3nsnc23)c1 ; CC(C)(C)c1cc(N(c2cccc(Cl)c2)c2c(-c3ccccc3)cc(C(C)(C)C)cc2-c2ccccc2)cc(N(c2cccc(Cl)c2)c2c(-c3ccccc3)cccc2-c2cccc3nsnc23)c1 ; CC(C)(C)c1cc(-c2ccccc2)c(N2c3cc(Cl)ccc3B3c4ccc(Cl)cc4N(c4c(-c5ccccc5)cccc4-c4cccc5nsnc45)c4cc(C(C)(C)C)cc2c43)c(-c2ccccc2)c1]

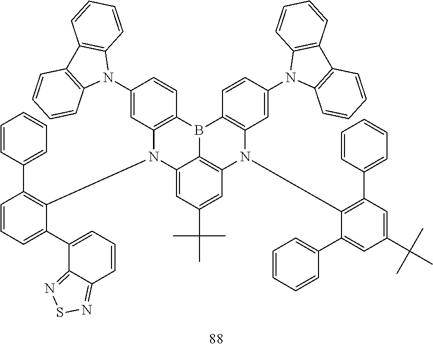 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cccc4-c4cccc5nsnc45)c4cc(C(C)(C)C)cc2c43)c(-c2ccccc2)c1]

### 1) Synthesis of Intermediate Compound 88-1

In a nitrogen atmosphere, 1-(tert-butyl)-3,5-dichlorobenzene (1 eq), 53-(tert-butyl)-[1,e:3c,1″-terphenyl]-24-amine(1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 88-1 (yield: 81%).

### 2) Synthesis of Intermediate Compound 88-2

In a nitrogen atmosphere, Intermediate Compound 88-1 (1 eq), 3-(benzo[c][1,2,5]thiadiazol-4-yl)-[1,1′-biphenyl]-2-amine(1 eq), Pd₂(dba)₃ (0.05 eq), tris-tert-butyl phosphine (0.1 eq),and sodium tert-butoxide (1.5 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 88-2 (yield: 83%).

### 3) Synthesis of Intermediate Compound 88-3

In a nitrogen atmosphere, Intermediate Compound 88-2 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days.

After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 88-3 (yield: 83%).

### 4) Synthesis of Intermediate Compound 88-4

In a nitrogen atmosphere, Intermediate Compound 88-3 (1 eq) was dissolved in o-dichlorobenzene and cooled using ice water, BBr₃ (5 equiv.) was slowly added dropwise, and the reaction solution was stirred at about 180° C. for about 24 hours. After cooling, the reaction was terminated with triethylamine (5 equiv.), water/CH₂C1₂ were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 88-4 (yield: 37%).

### 5) Synthesis of Compound 88

In a nitrogen atmosphere, Intermediate Compound 88-4 (1 eq), carbazole (2.2 eq). Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Compound 88 (yield: 71%).

### (5) Synthesis of Compound 99

Compound 99 may be synthesized by Reaction Scheme 6 below.

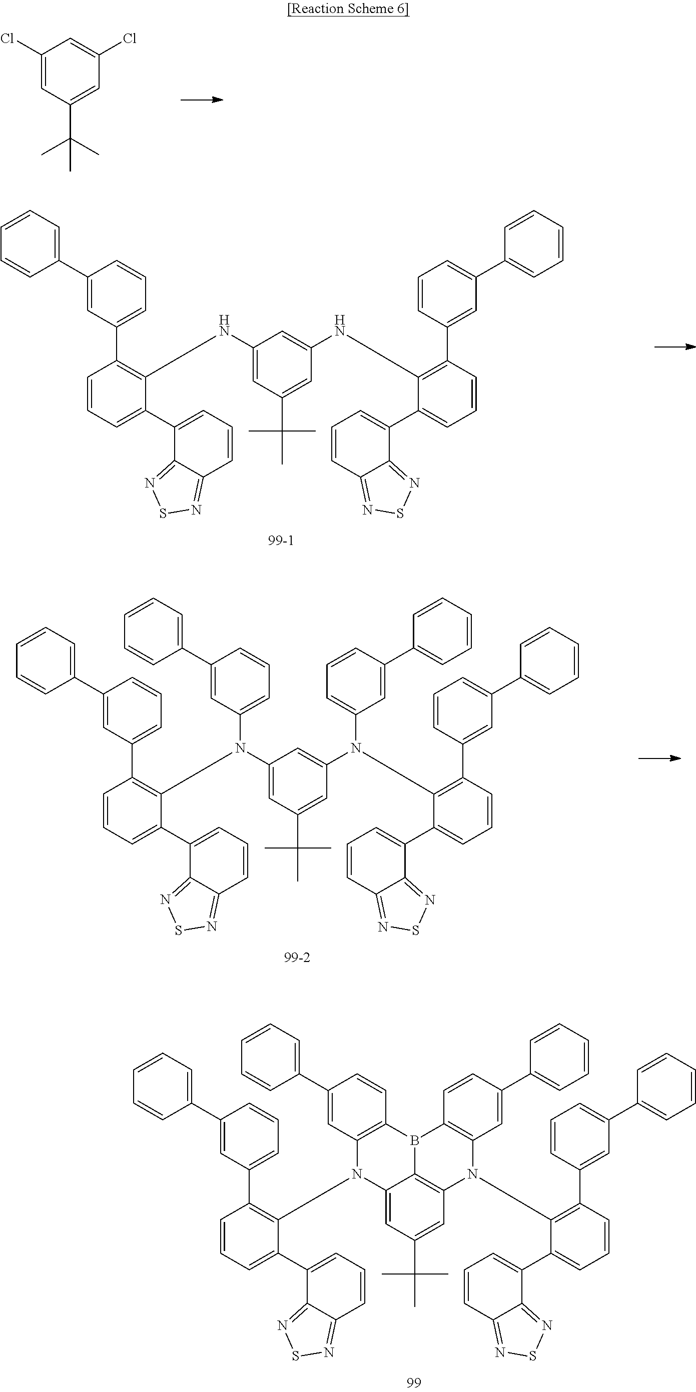 [SMILES: CC(C)(C)c1cc(Cl)cc(Cl)c1 ; CC(C)(C)c1cc(Nc2c(-c3cccc(-c4ccccc4)c3)cccc2-c2cccc3nsnc23)cc(Nc2c(-c3cccc(-c4ccccc4)c3)cccc2-c2cccc3nsnc23)c1 ; CC(C)(C)c1cc(N(c2cccc(-c3ccccc3)c2)c2c(-c3cccc(-c4ccccc4)c3)cccc2-c2cccc3nsnc23)cc(N(c2cccc(-c3ccccc3)c2)c2c(-c3cccc(-c4ccccc4)c3)cccc2-c2cccc3nsnc23)c1 ; CC(C)(C)c1cc2c3c(c1)N(c1c(-c4cccc(-c5ccccc5)c4)cccc1-c1cccc4nsnc14)c1cc(-c4ccccc4)ccc1B3c1ccc(-c3ccccc3)cc1N2c1c(-c2cccc(-c3ccccc3)c2)cccc1-c1cccc2nsnc12]

In a nitrogen atmosphere, 1-(tert-butyl)-3,5-dichlorobenzene (1 eq), 3-(benzo[c][1,2,5]thiadiazol-4-yl)-[1,1′:3′,1″-terphenyl]-2-amine (2.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 99-1 (yield: 73%).

### 2) Synthesis of Intermediate Compound 99-2

In a nitrogen atmosphere, Intermediate Compound 99-1 (1 eq), 3-iodo-1,1′-biphenyl (10 eq), Pd₂(dba)₃ (0.5 eq), tris-tert-butyl phosphine (1 eq), sodium tert-butoxide (4 eq) were added and dissolved in o-xylene, and the reaction solution was stirred at about 160° C. for about 3 days. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 99-2 (yield: 65%).

### 3) Synthesis of Compound 99

In a nitrogen atmosphere, Intermediate Compound 99-2 (1 eq) was dissolved in o-dichlorobenzene and cooled using ice water, BBr₃ (5 equiv.) was slowly added dropwise, and the reaction solution was stirred at about 180° C. for about 24 hours. After cooling, the reaction was terminated with triethylamine (5 equiv.), water/CH₂Cl₂ were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Compound 99 (yield: 33%).

### (7) Synthesis of Compound 133

Compound 133 may be synthesized by Reaction Scheme 7 below.

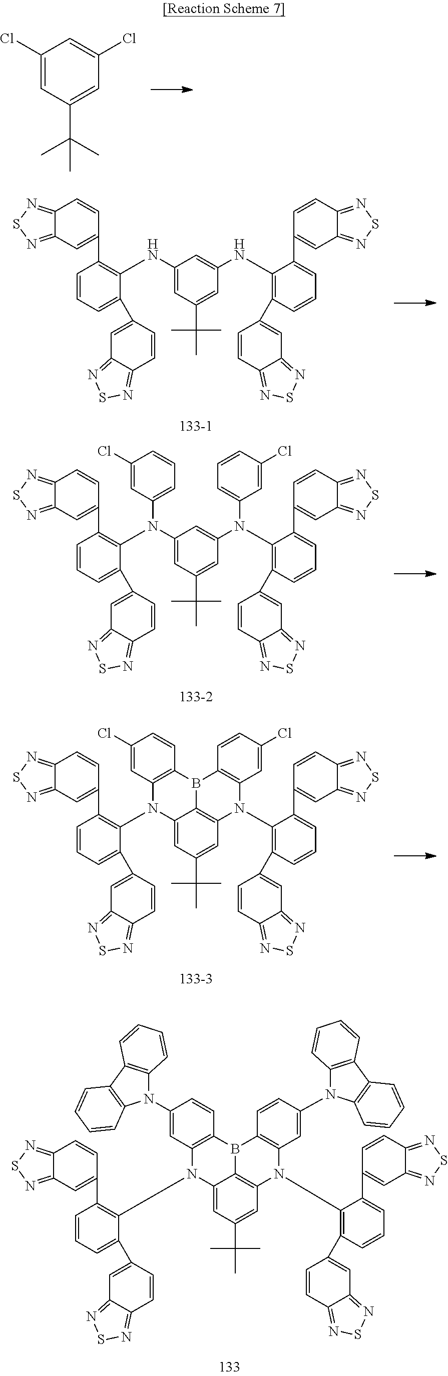

### 1) Synthesis of Intermediate Compound 133-1

In a nitrogen atmosphere, 1-(tert-butyl)-3,5-dichlorobenzene (1 eq), 2,6-bis(benzo[c][1,2,5]thiadiazol-4-yl)aniline (2.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 133-1 (yield: 83%).

### 2) Synthesis of Intermediate Compound 133-2

In a nitrogen atmosphere, Intermediate Compound 133-1 (1 eq), 3-iodochlorobenzene (10 eq), Pd₂(dba)₃ (0.5 eq), tris-tert-butyl phosphine (1 eq), and sodium tert-butoxide (4eq) were added and dissolved in o-xylene, and the reaction solution was stirred at about 160° C. for about 3 days.

After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 133-2 (yield: 62%).

### 3) Synthesis of Intermediate Compound 133-3

In a nitrogen atmosphere, Intermediate Compound 133-2 (1 eq) was dissolved in o-dichlorobenzene and cooled using ice water, BBr₃ (5 equiv.) was slowly added dropwise, and the reaction solution was stirred at about 180° C. for about 24 hours. After cooling, the reaction was terminated with triethylamine (5 equiv.), water/CH₂Cl₂ were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Intermediate Compound 133-3 (yield: 34%).

### 4) Synthesis of Compound 133

In a nitrogen atmosphere, Intermediate Compound 133-3 (1 eq), carbazole (2.2 eq). Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, water and ethyl acetate were added for extraction to collect an organic layer, and the resultant was dried over MgSO₄ and filtered. The filtered solution was concentrated under reduced pressure to remove a solvent, and the obtained reactant was purified and separated by column chromatography using silica gel to obtain Compound 133 (yield: 75%).

2. Manufacture and evaluation of light-emitting element

A light-emitting element according to an embodiment that includes a fused polycyclic compound according to an embodiment in an emission layer was manufactured by the following method. The light-emitting elements according to Example 1 to Example 7 were manufactured respectively using, as a dopant material for the emission layer, Compounds 2, 15, 16, 85, 88, 99, and 133, which are the Example Compounds described above. Light-emitting elements according to Comparative Example 1 to Comparative Example 3 correspond to light-emitting elements that were manufactured respectively using Comparative Example Compound 1 to Comparative Example Compound 3 as a dopant material for the emission layer.

### Example Compounds

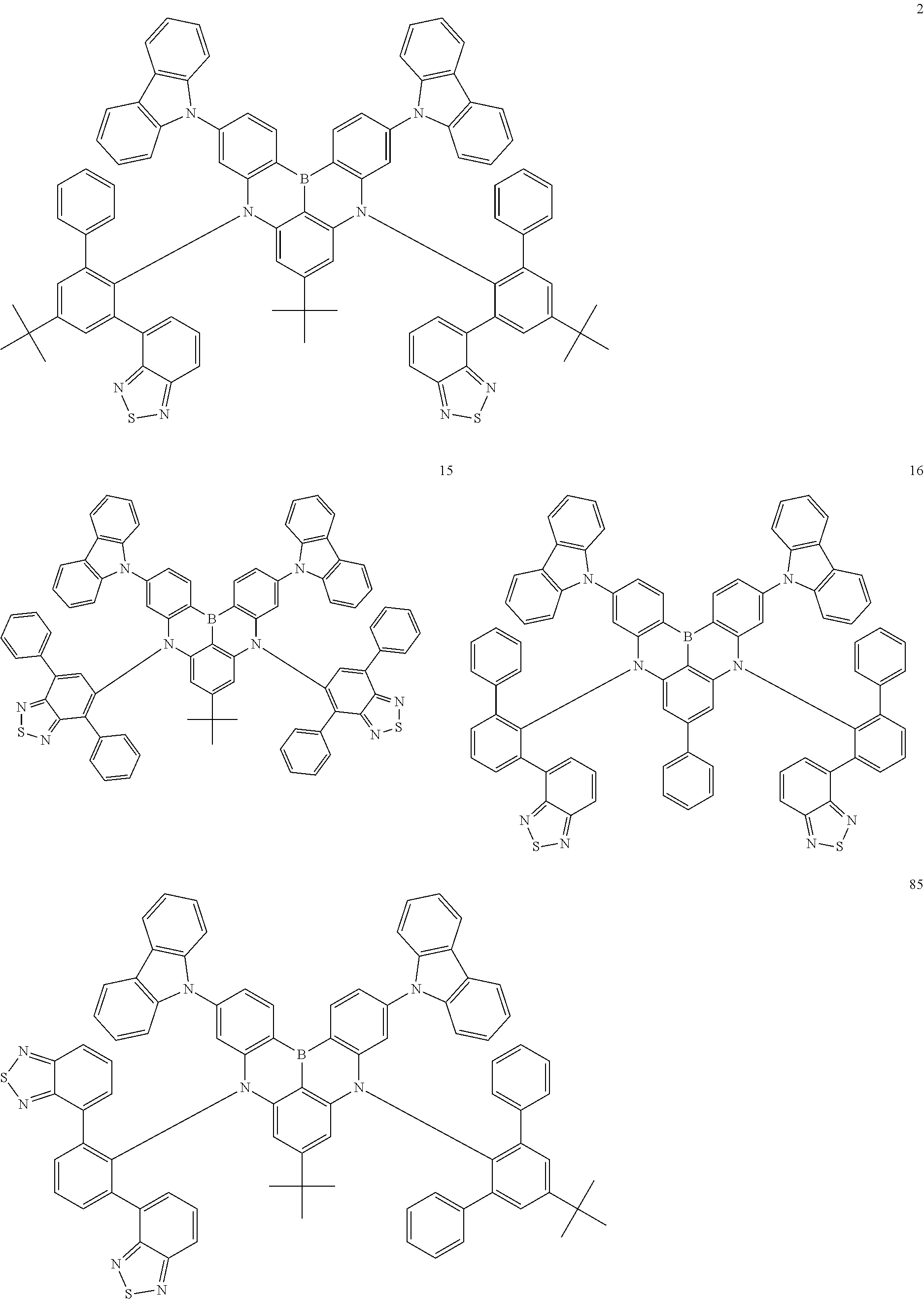

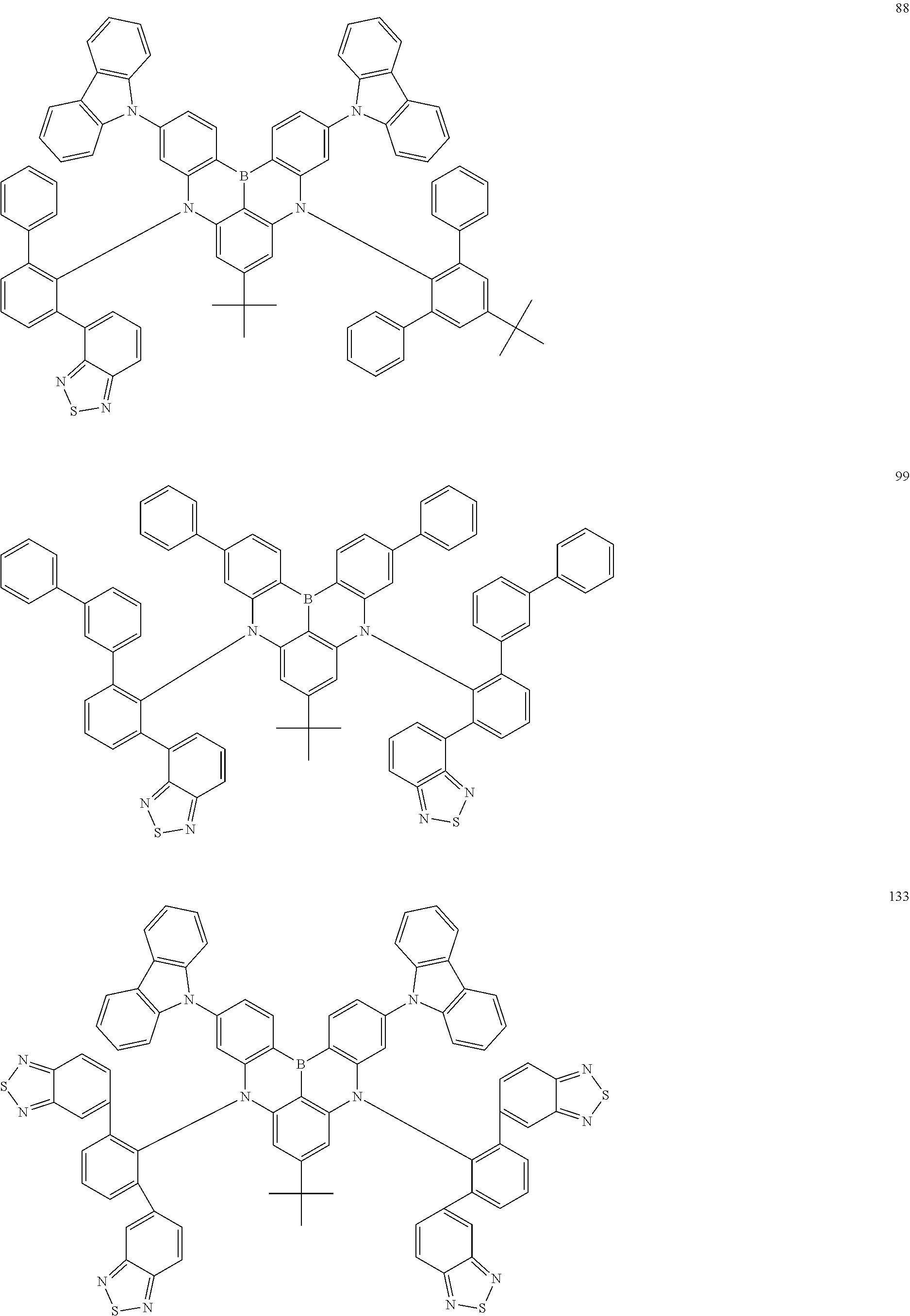

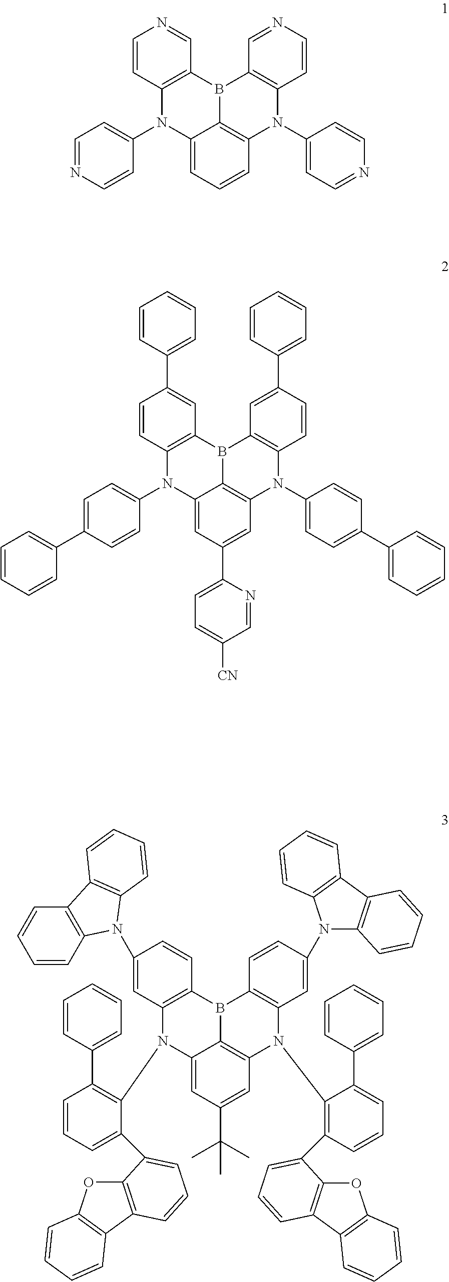 [SMILES: c1cc2c3c(c1)N(c1ccncc1)c1ccncc1B3c1cnccc1N2c1ccncc1 ; N#Cc1ccc(-c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)nc1 ; CC(C)(C)c1cc2c3c(c1)N(c1c(-c4ccccc4)cccc1-c1cccc4c1oc1ccccc14)c1cc(-n4c5ccccc5c5ccccc54)ccc1B3c1ccc(-n3c4ccccc4c4ccccc43)cc1N2c1c(-c2ccccc2)cccc1-c1cccc2c1oc1ccccc12]

(Manufacture of light-emitting element)

As an anode, a glass substrate (made by Corning Incorporated), on which an ITO electrode of 15 Ω/cm² (1,200 Å) was formed, was cut to a size of about 50 mm×50 mm×0.7 mm, ultrasonically cleaned using isopropyl alcohol and pure water for about 5 minutes each, irradiated with ultra violet ray for about 30 minutes, cleaned by exposing to ozone, and mounted on a vacuum deposition device.

NPD was deposited on the anode to form a hole injection layer having a thickness of about 300 Å, and one of Compounds H-1-1 to H-1-3 was deposited on the hole injection layer to form a hole transport layer having a thickness of about 200 Å. CzSi was deposited on the hole transport layer to form an emission auxiliary layer having a thickness of about 100 Å.

A mixed HT+ET (host), a phosphorescence-sensitizer (PS), and the fused polycyclic compound according to an embodiment were co-deposited on the emission auxiliary layer at a weight ratio of about 85:14:1 to form an emission layer having a thickness of about 200 Å.

TSPO1 was co-deposited on the emission layer to form a hole blocking layer having a thickness of about 200 Å, and TPBi was deposited on the hole blocking layer to form an electron transport layer having a thickness of about 300 Å. LiF was deposited on the electron transport layer to form an electron injection layer having a thickness of about 10 Å, Al was deposited on the electron injection layer to form a cathode having a thickness of about 3,000 Å, and Compound P4 was deposited on the electrode to form a capping layer having a thickness of about 700 Å, thereby manufacturing a light-emitting element.

The compounds used in manufacturing the light-emitting elements according to the Examples and the Comparative Examples are disclosed as follows. The following materials are materials of the related art, and commercial products were purified through sublimation and used in the manufacture of the elements.

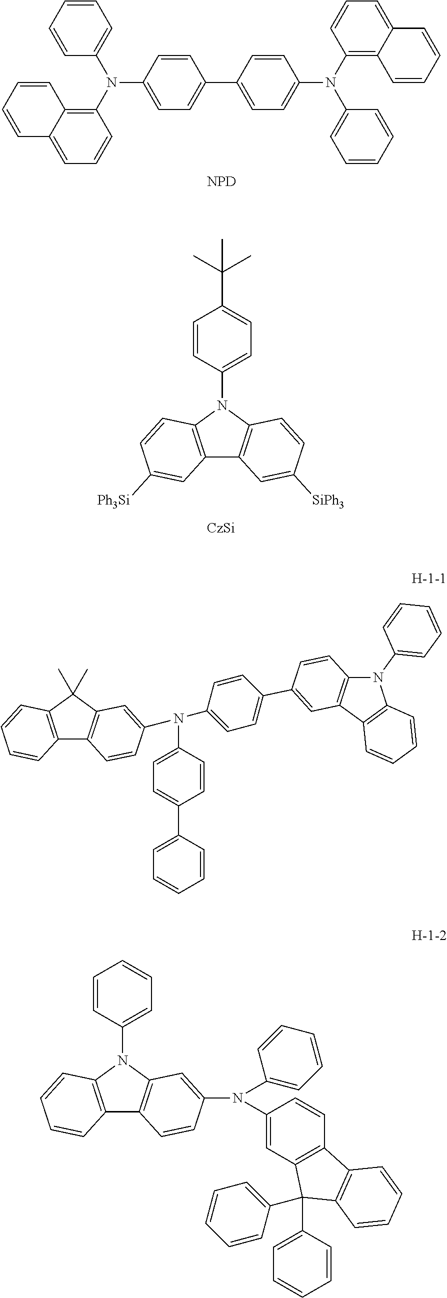

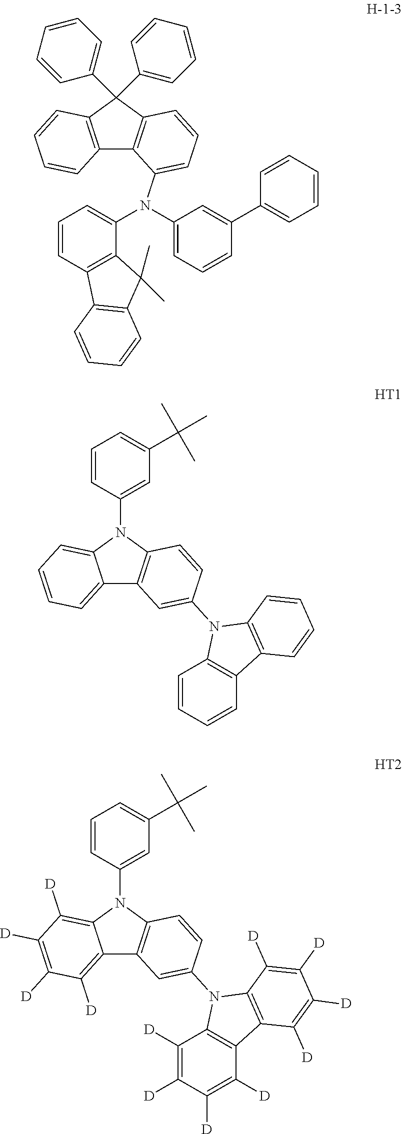 [SMILES: CC1(C)c2ccccc2-c2cccc(N(c3cccc(-c4ccccc4)c3)c3cccc4c3-c3ccccc3C4(c3ccccc3)c3ccccc3)c21 ; CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1]

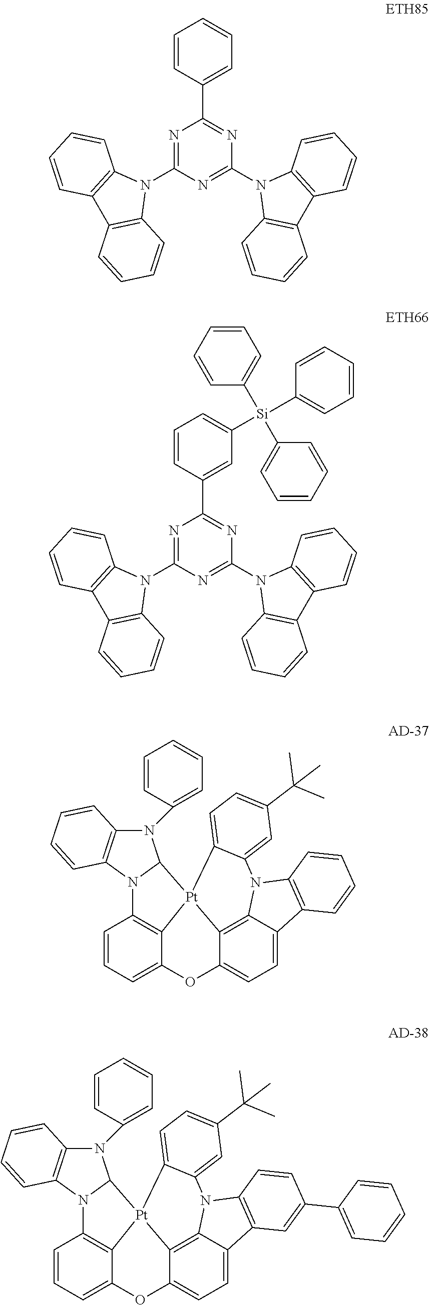

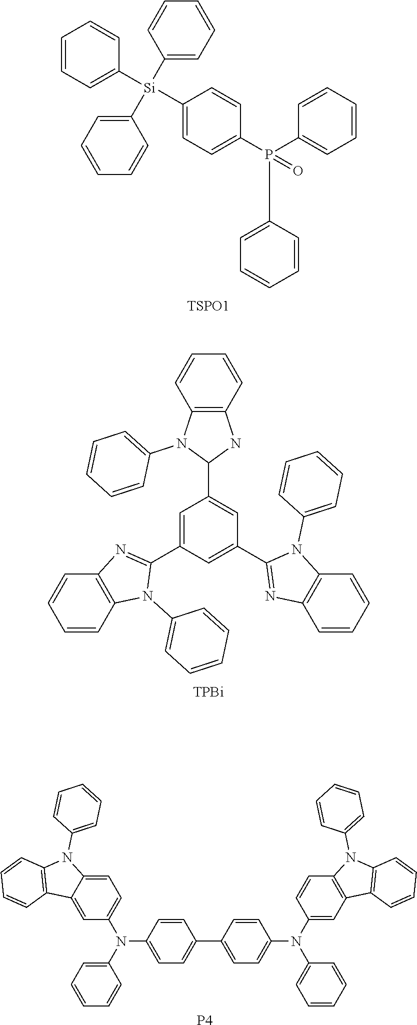

(Evaluation of Characteristics of light-emitting element)

A driving voltage (V) at 1,000 cd/m², luminous efficiency (cd/A), maximum external quantum efficiency (%), and emission color of each of the light-emitting elements according to Example 1 to Example 7 and Comparative Example 1 to Comparative Example 3, were measured using Keithley MU 236 and a luminance meter. Time taken for peak luminance to decrease to about 95% thereof was measured as a lifespan (T₉₅), wherein a comparative lifespan of each light-emitting element was calculated with respect to the lifespan of the light-emitting element according to Comparative Example 1, and the results are listed in Table 1. Further evaluation was conducted in the same manner as in Table 1, except that each light-emitting element did not include the sensitizer materials as shown in Table 1, and luminous efficiency (cd/A), maximum external quantum efficiency (%), lifespan (T₉₅), and emission color thereof were measured and the results are listed in Table 2.

TABLE 1

| | | | | | | | Maximum | | |
|---|---|---|---|---|---|---|---|---|---|
| | Hole | | | | | | external | | |
| | transport | Host | | | Driving | | quantum | Element | |
| | layer | (HT:ET = | | Dopant | voltage | Efficiency | efficiency | lifespan | Emission |
| | material | 5:5) | Sensitizer | Compound | (V) | (cd/A) | (%) | (%) | color |
| Example 1 | H-1-2 | HT1/ETH85 | AD-37 | Compound 2 | 4.3 | 25.5 | 24.3 | 210 | blue |
| Example 2 | H-1-2 | HT1/ETH85 | AD-38 | Compound 15 | 4.4 | 20.1 | 18.3 | 150 | blue |
| Example 3 | H-1-2 | HT2/ETH85 | AD-37 | Compound 16 | 4.4 | 24.8 | 23.1 | 203 | blue |
| Example 4 | H-1-2 | HT2/ETH85 | AD-38 | Compound 85 | 4.4 | 23.8 | 22.3 | 195 | blue |
| Example 5 | H-1-2 | HT2/ETH85 | AD-37 | Compound 88 | 4.3 | 22.6 | 21.3 | 184 | blue |
| Example 6 | H-1-1 | HT1/ETH66 | AD-37 | Compound 99 | 4.3 | 23.4 | 21.4 | 195 | blue |
| Example 7 | H-1-2 | HT2/ETH85 | AD-38 | Compound 133 | 4.4 | 18.5 | 17.3 | 135 | blue |
| Comparative | H-1-3 | HT1/ETH66 | AD-38 | Comparative | 4.3 | 11.1 | 10.2 | 100 | blue |
| Example 1 | | | | Example | | | | | |
| | | | | Compound 1 | | | | | |
| Comparative | H-1-2 | HT2/ETH66 | AD-37 | Comparative | 4.4 | 10.8 | 9.8 | 96 | blue |
| Example 2 | | | | Example | | | | | |
| | | | | Compound 2 | | | | | |
| Comparative | H-1-2 | HT2/ETH66 | AD-37 | Comparative | 4.4 | 17.5 | 15.4 | 127 | blue |
| Example 3 | | | | Example | | | | | |
| | | | | Compound 3 | | | | | |

TABLE 2

| | Hole | | | | | Maximum | |
|---|---|---|---|---|---|---|---|
| | transport | Host | | Luminous | Element | external | |
| | layer | (HT:ET = | Dopant | efficiency | lifespan | quantum | Emission |
| | material | 5:5) | Compound | (cd/A) | (%) | efficiency (%) | color |
| Example 1 | H-1-2 | HT1/ETH85 | Compound 2 | 8.5 | 220 | 8.1 | blue |
| Example 2 | H-1-2 | HT1/ETH85 | Compound 15 | 6.7 | 153 | 6.1 | blue |
| Example 3 | H-1-2 | HT2/ETH85 | Compound 16 | 8.3 | 208 | 7.7 | blue |
| Example 4 | H-1-2 | HT2/ETH85 | Compound 85 | 7.9 | 200 | 7.4 | blue |
| Example 5 | H-1-2 | HT2/ETH85 | Compound 88 | 7.5 | 194 | 7.1 | blue |
| Example 6 | H-1-1 | HT1/ETH66 | Compound 99 | 7.8 | 200 | 7.1 | blue |
| Example 7 | H-1-2 | HT2/ETH85 | Compound 133 | 6.2 | 140 | 5.7 | blue |
| Comparative | H-1-3 | HT1/ETH66 | Comparative | 3.7 | 100 | 3.4 | blue |
| Example 1 | | | Example | | | | |
| | | | Compound 1 | | | | |
| Comparative | H-1-2 | HT2/ETH66 | Comparative | 3.6 | 95 | 3.3 | blue |
| Example 2 | | | Example | | | | |
| | | | Compound 2 | | | | |
| Comparative | H-1-2 | HT2/ETH66 | Comparative | 5.8 | 130 | 5.1 | blue |
| Example 3 | | | Example | | | | |
| | | | Compound 3 | | | | |

Referring to the results in Table 1, it can be confirmed that the light-emitting elements according to the Examples, using the fused polycyclic compound according to an embodiment as emission materials, have improved characteristics of luminous efficiency and lifespan, as compared to the light-emitting elements according to the Comparative Examples. Referring to the results in Table 2, even though measurements in which the sensitizer was excluded from each light-emitting element were performed, it can be confirmed that the light-emitting elements, according to the Examples using the fused polycyclic compound according to an embodiment as emission materials have improved characteristics of luminous efficiency and lifespan, as compared to the light-emitting elements according to the Comparative Examples.

Since the fused polycyclic compound according to embodiments includes at least one substituent represented by Formula 3, an unoccupied p-orbital of the boron atom is effectively protected from electrons, and thus lifespan may be improved. By the inclusion of the substituent represented by Formula 3, the fused polycyclic compound according to an embodiment has a relatively large volume and increased intermolecular distance, thereby improving stability, and increasing luminous efficiency. In the fused polycyclic compound according to an embodiment, since the substituent directly bonded to the nitrogen atom of the core includes at least one benzothiadiazole moiety, a band gap of the molecule increases, and thus color purity may be improved. The fused polycyclic compound according to an embodiment has a high triplet energy, which is advantageous for reverse intersystem crossing, and thus efficiency and lifespan may be improved.

The light-emitting element according to Comparative Example 1 includes Comparative Example Compound 1 in the emission layer. Since Comparative Example Compound 1 does not include a benzothiadiazole moiety, which is unlike the fused polycyclic compound according to embodiments, the p-orbital of the boron atom is not effectively protected against nucleophiles, thereby demonstrating deteriorated molecular stability and low triplet energy and deteriorated efficiency and lifespan.

The light-emitting element according to Comparative Example 2 includes Comparative Example Compound 2 in the emission layer. Since Comparative Example Compound 2 does not include a benzothiadiazole moiety, which is unlike the fused polycyclic compound according to embodiments, the p-orbital of the boron atom is not effectively protected against nucleophiles, thereby demonstrating deteriorated molecular stability and low triplet energy and deteriorated efficiency and lifespan. The substituents of Comparative Example Compound 2 have a larger size than those of Comparative Example Compound 1. However, it is determined that in Comparative Example Compound 2, the p-orbital of the boron atom remains unprotected against nucleophiles.

The light-emitting element according to Comparative Example 3 includes Comparative Example Compound 3 in the emission layer. Since Comparative Example Compound 3 does not include a benzothiadiazole moiety, which is unlike the fused polycyclic compound according to embodiments, the p-orbital of the boron atom is not effectively protected against nucleophiles, thereby demonstrating deteriorated molecular stability and low triplet energy deteriorated efficiency and lifespan. The substituents of Comparative Example Compound 3 have a larger size than those of Comparative Example Compound 1. However, it is determined that in Comparative Example Compound 3, the p-orbital of the boron atom remains unprotected against nucleophiles.

The light-emitting element according to an embodiment may exhibit improved element characteristics of high efficiency and long lifespan.

The fused polycyclic compound according to an embodiment may be included in the emission layer and thus may contribute to improvements in high efficiency and long lifespan of the light-emitting element.

The display device according to an embodiment may exhibit excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting element comprising:
a first electrode;
a second electrode disposed on the first electrode; and
at least one functional layer disposed between the first electrode and the second electrode, wherein
the at least one functional layer includes a first compound represented by Formula 1: 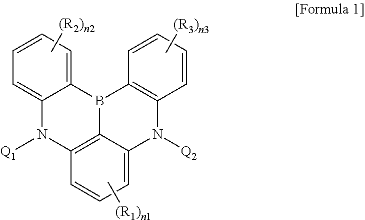
wherein in Formula 1,
R₁ to R₃ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring,
n1 is an integer from 0 to 3,
n2 and n3 are each independently an integer from 0 to 4, and
Q₁ and Q₂ are each independently a group represented by Formula 2 or Formula 3: 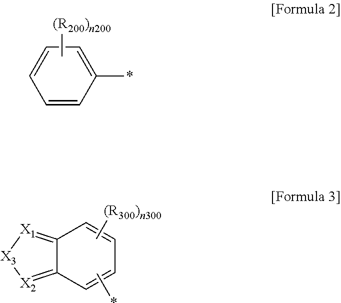
wherein in Formula 2 and Formula 3,
R₂₀₀ and R₃₀₀ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring,
n200 is an integer from 1 to 5,
n300 is an integer from 0 to 3,
X₁ and X₂ are each independently N or P, and
X₃is O or S;
in Formula 1, if Q₁ and Q₂ are each a group represented by Formula 2, among Q₁ and Q₂, at least one of R₂₀₀ is each independently a group represented by Formula 3,
in Formula 2, —* represents a bond to Formula 1, and
in Formula 3, —* represents a bond to Formula 1 or Formula 2.

2. The light-emitting element of claim 1, wherein a group represented by Formula 2 is a group represented by Formula 2-a or Formula 2-b: 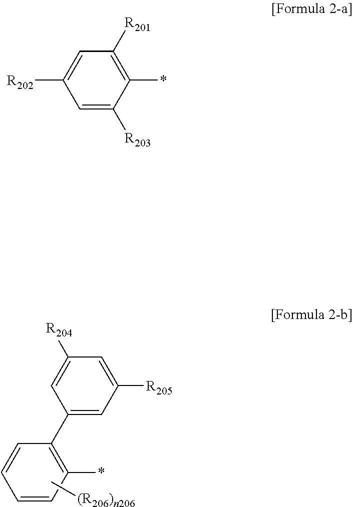
wherein in Formula 2-a and Formula 2-b above
R₂₀₁ to R₂₀₃ and R₂₀₆ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring,
R₂₀₄ and R₂₀₅ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons,
n206 is an integer from 0 to 4, and
—* represents a bond to Formula 1.

3. The light-emitting element of claim 2, wherein in Formula 2-a, R₂₀₂ is a substituted or unsubstituted t-butyl group or a substituted or unsubstituted phenyl group.

4. The light-emitting element of claim 1, wherein a group represented by Formula 2 is a group represented by Formula 2-c1, Formula 2-c2, Formula 2-d1, or Formula 2-d2: 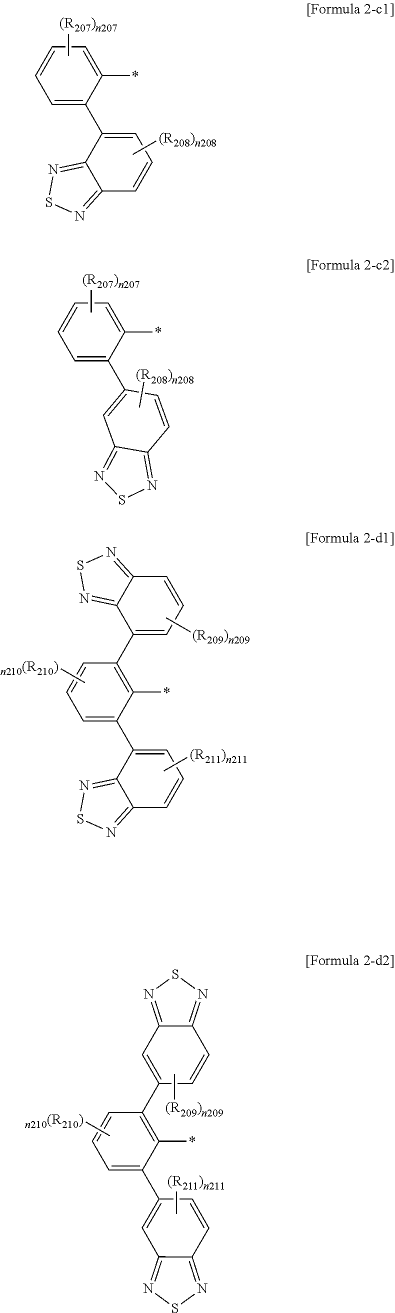
wherein in Formula 2-c1, Formula 2-c2, Formula 2-d1, and Formula 2-d2,
R₂₀₇ to R₂₁₁ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring,
n207 is an integer from 0 to 4,
n208 to n211 are each independently an integer from 0 to 3, and
—* represents a bond to Formula 1.

5. The light-emitting element of claim 1, wherein a group represented by Formula 2 is a group represented by Formula 2-e, Formula 2-f, Formula 2-gi, or Formula 2-g2: 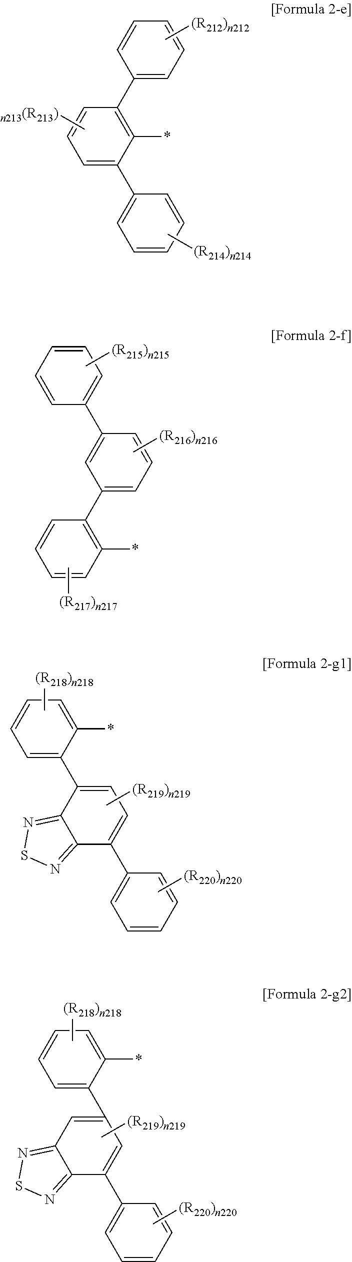
wherein in Formula 2-e, Formula 2-f, Formula 2-g1, and Formula 2-g2,
R₂₁₂ to R₂₂₀ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring,
n212, n214, n215, and n220 are each independently an integer from 0 to 5,
n213 is an integer from 0 to 3,
n216, n217, and n218 are each independently an integer from 0 to 4,
n219 is an integer from 0 to 2, and
—* represents a bond to Formula 1.

6. The light-emitting element of claim 1, wherein in Formula 3,
X₁ and X₂ are each N, and
X₃ is S.

7. The light-emitting element of claim 1, wherein a group represented by Formula 3 is a group represented by Formula 3-a or Formula 3-b: 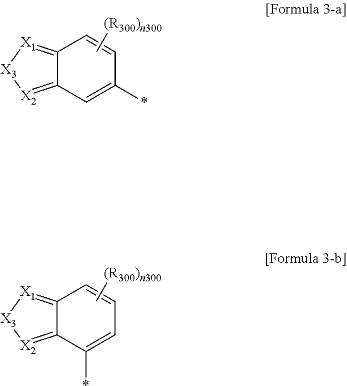
wherein in Formula 3-a and Formula 3-b,
X₁ to X₃, R₃₀₀, and n300 are the same as defined in Formula 3, and
—* represents a bond to Formula 1 or Formula 2.

8. The light-emitting element of claim 1, wherein a group represented by Formula 3 is a group represented by Formula 3-c: 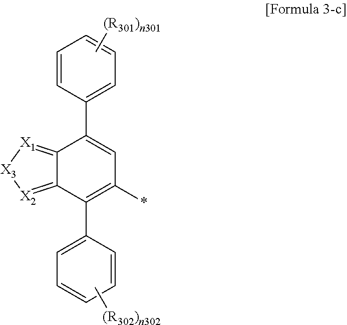
wherein in Formula 3-c,
R₃₀₁ and R₃₀₂ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring,
n301 and n302 are each independently an integer from 0 to 5,
X₁ to X₃ are the same as defined in Formula 3, and
—* represents a bond to Formula 1 or Formula 2.

9. The light-emitting element of claim 1, wherein the first compound is represented by Formula 4: 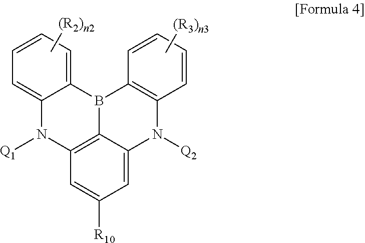
wherein in Formula 4, R₁₀ is a substituted or unsubstituted alkyl group having 1 to 60 carbons or a substituted or unsubstituted aryl group having 6 to 60 ring-forming carbons, and
R₂, R₃, Q₁, Q₂, n2, and n3 are the same as defined in Formula 1.

10. The light-emitting element of claim 1, wherein in Formula 1, R₁ is a substituted or unsubstituted t-butyl group or a substituted or unsubstituted phenyl group.

11. The light-emitting element of claim 1, wherein the first compound is represented by one of Formula 5-a to Formula 5-3: 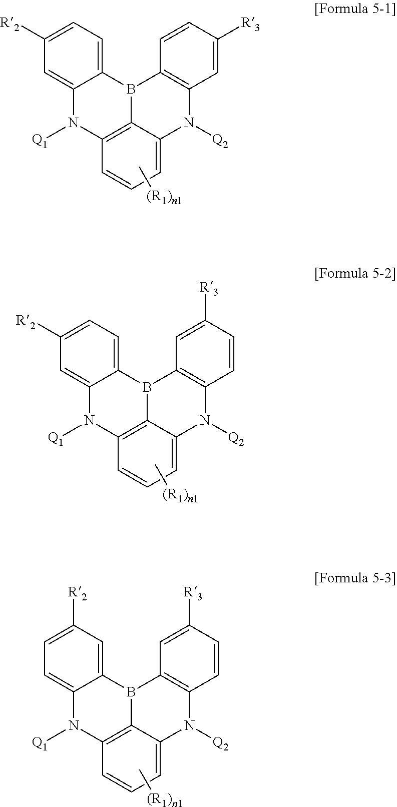
wherein in Formula 5-1 to Formula 5-3,
R′₂ and R′₃ are each independently a substituted or unsubstituted aryl group having 6 to 60 ring-forming carbons, or a substituted or unsubstituted heteroaryl group having 2 to 60 ring-forming carbons, and
R₁, Q₁, Q₂, and n1 are the same as defined in Formula 1.

12. The light-emitting element of claim 1, wherein in Formula 1, R₂ and R₃ are each independently a hydrogen atom, a substituted or unsubstituted phenyl group, or a substituted or unsubstituted carbazole group.

13. The light-emitting element of claim 1, wherein
the at least one functional layer includes an emission layer, and
the emission layer includes:
the first compound; and
at least one of a second compound represented by Formula HT-1, a third compound represented by Formula ET-1, and a fourth compound represented by Formula D-1: 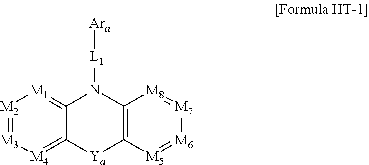
wherein in Formula HT-1,
M₁ to M₈ are each independently N or C(R₈₁),
L₁ is a direct linkage, a substituted or unsubstituted arylene group having 6 to 30 ring-forming carbons, or a substituted or unsubstituted heteroarylene group having 2 to 30 ring-forming carbons,
Yₐ is a direct linkage, C(R₈₂)(R₈₃), or Si(R₅₄)(R₈₈),
Arₐ is a substituted or unsubstituted aryl group having 6 to 30 ring-forming carbons or a substituted or unsubstituted heteroaryl group having 2 to 30 ring-forming carbons, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, or bonded to an adjacent group to form a ring; 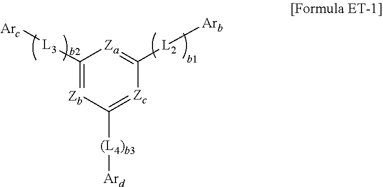
wherein in Formula ET-1,
at least one of Zₐ to Z_{c} is N,
the remainder of Zₐ to Z_{c} are each independently C(R₅₆),
R₅₆ is a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons,
b1 to b3 are each independently an integer from 0 to 10,
Ar_{b} to Ar_{d} are each independently a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and
L₂ to L₄ are each independently a direct linkage, a substituted or unsubstituted arylene group having 6 to 30 ring-forming carbons, or a substituted or unsubstituted heteroaryl group having 2 to 30 ring-forming carbons; 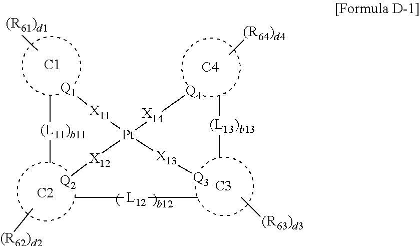
wherein in Formula D-1,
Q₁ to Q₄ are each independently C or N,
C1 to C4 are each independently a substituted or unsubstituted hydrocarbon ring having 5 to 30 ring-forming carbons or a substituted or unsubstituted heterocycle having 2 to 30 ring-forming carbons,
X₁₁ to X₁₄ are each independently a direct linkage or *—O—*
L₁₁ to L₁₃ are each independently a direct linkage, *—O—*, *—S—*, 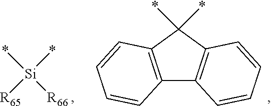
a substituted or unsubstituted alkylene group having 1 to 20 carbons, a substituted or unsubstituted arylene group having 6 to 30 ring-forming carbons, or a substituted or unsubstituted heteroarylene group having 2 to 30 ring-forming carbons,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, and
d1 to d4 are each independently an integer from 0 to 4.

14. An electronic apparatus comprising:
a circuit layer disposed on a base layer; and
a display element layer disposed on the circuit layer and including a light-emitting element, wherein
the light-emitting element comprises:
a first electrode;
a second electrode disposed on the first electrode; and
an emission layer disposed between the first electrode and the second electrode, and
the emission layer includes a first compound represented by Formula 1: 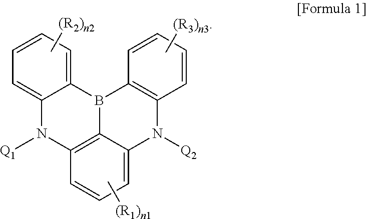
wherein in Formula 1,
R₁ to R₃ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring,
n1 is an integer from 0 to 3,
n2 and n3 are each independently an integer from 0 to 4, and
Q₁ and Q₂ are each independently a group represented by Formula 2 or Formula 3: 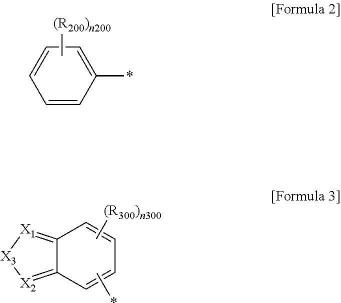
wherein in Formula 2 and Formula 3,
R₂₀₀ and R₃₀₀ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring,
n200 is an integer from 1 to 5,
n300 is an integer from 0 to 3,
X₁ and X₂ are each independently N or P, and
X₃ is 0 or S;
in Formula 1, if Q₁ and Q₂ are each a group represented by Formula 2, among Q₁ and Q₂, at least one of R₂₀₀ is each independently a group represented by Formula 3,
in Formula 2, —* represents a bond to Formula 1, and
in Formula 3, —* represents a bond to Formula 1 or Formula 2.

15. The electronic apparatus of claim 14 further comprising:
an optical control layer disposed on the display element layer and including a quantum dot, wherein
the light-emitting element emits a first color light, and
the optical control layer includes:
a first optical control part that includes a first quantum dot that converts the first color light to a second color light in a longer wavelength region than the first color light;
a second optical control part that includes a second quantum dot that converts the first color light to a third color light in a longer wavelength region than the first color light and the second color light; and
a third optical control part that transmits the first color light.

16. The electronic apparatus of claim 15, further comprising:
a color filter layer disposed on the optical control layer, wherein
the color filter layer includes:
a first filter that transmits the second color light;
a second filter that transmits the third color light; and
a third filter that transmits the first color light.

17. A fused polycyclic compound represented by Formula 1: 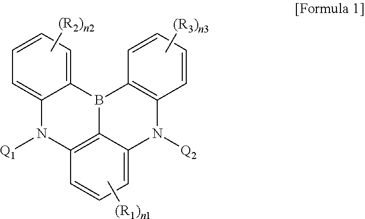
wherein in Formula 1,
R₁ to R₃ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring,
n1 is an integer from 0 to 3,
n2 and n3 are each independently an integer from 0 to 4, and
Q₁ and Q₂ are each independently a group represented by Formula 2 or Formula 3: 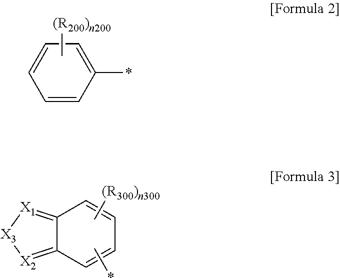
wherein in Formula 2 and Formula 3,
R₂₀₀ and R₃₀₀ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring,
n200 is an integer from 1 to 5,
n300 is an integer from 0 to 3,
X₁ and X₂ are each independently N or P, and
X₃ is O or S;
in Formula 1, if Q₁ and Q₂ are each a group represented by Formula 2, among Q₁ and Q₂, at least one of R₂₀₀ is each independently a group represented by Formula 3,
in Formula 2, —* represents a bond to Formula 1, and
in Formula 3, —* represents a bond to Formula 1 or Formula 2.

18. The fused polycyclic compound of claim 17, wherein a group represented by Formula 2 is a group represented by Formula 2-a: 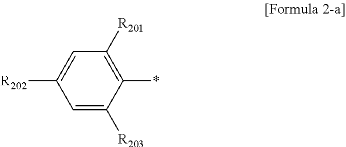
wherein in Formula 2-a,
R₂₀₁ to R₂₀₃ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring, and
—* represents a bond to Formula 1.

19. The fused polycyclic compound of claim 17, wherein a group represented by Formula 2 is a group represented by Formula 2-c1, Formula 2-c2, Formula 2-d1, or Formula 2-d2: 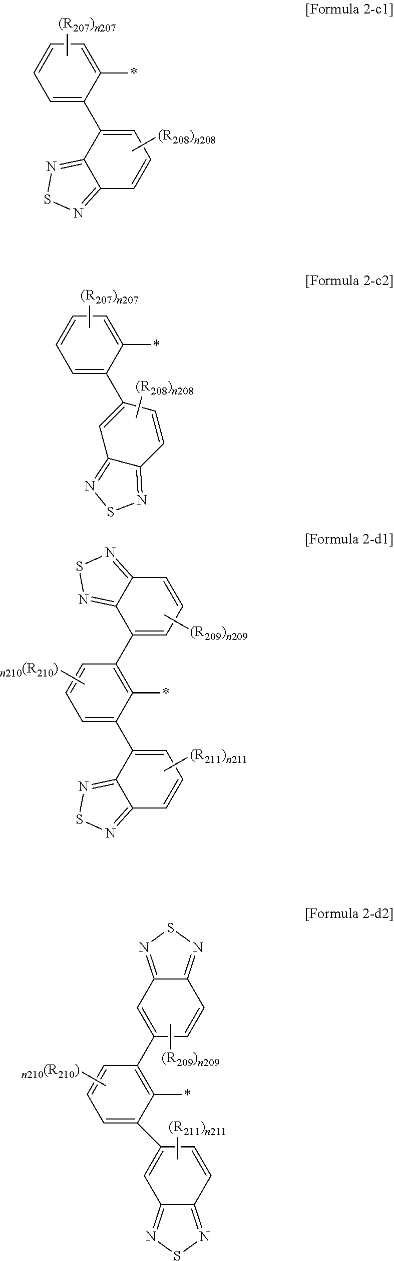
wherein in Formula 2-c1, Formula 2-c2, Formula 2-d1, and Formula 2-d2,
R₂₀₇ to R₂₁ are each independently a hydrogen atom, a deuterium atom, a halogen atom, a cyano group, a nitro group, a substituted or unsubstituted silyl group, a substituted or unsubstituted amine group, a substituted or unsubstituted alkyl group having 1 to 60 carbons, a substituted or unsubstituted alkoxy group having 1 to 60 carbons, a substituted or unsubstituted alkenyl group having 2 to 60 carbons, a substituted or unsubstituted aryl group having 6 to 60 ring-forming carbons, a substituted or unsubstituted aryloxy group having 6 to 60 ring-forming carbons, or a substituted or unsubstituted heteroaryl group having 2 to 60 ring-forming carbons, or bonded to an adjacent group to form a ring,
n207 is an integer from 0 to 4,
n208 to n211 are each independently an integer from 0 to 3, and
—* represents a bond to Formula 1.

20. The fused polycyclic compound of claim 17, wherein the fused polycyclic compound is selected from Compound Group 1: 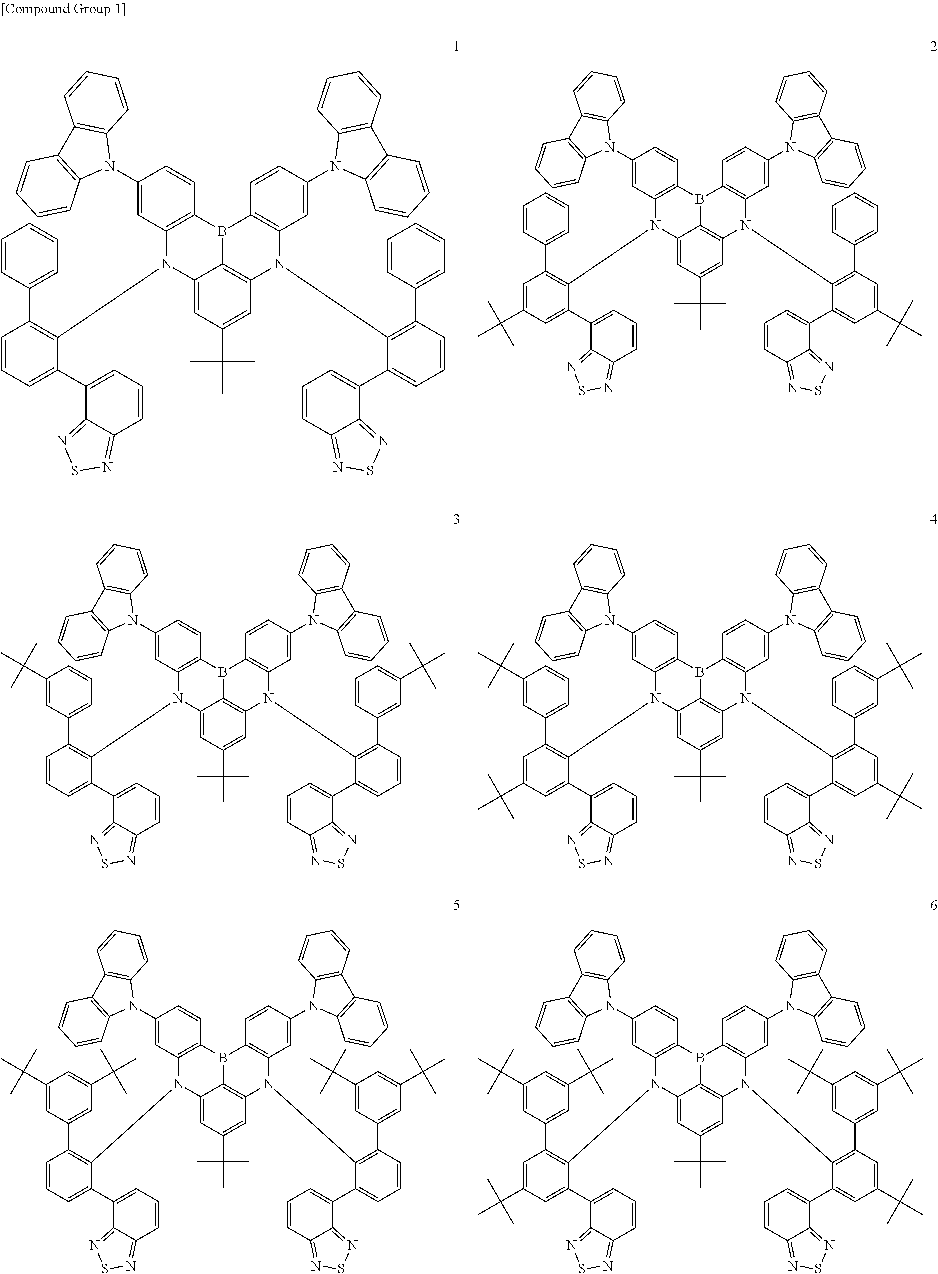 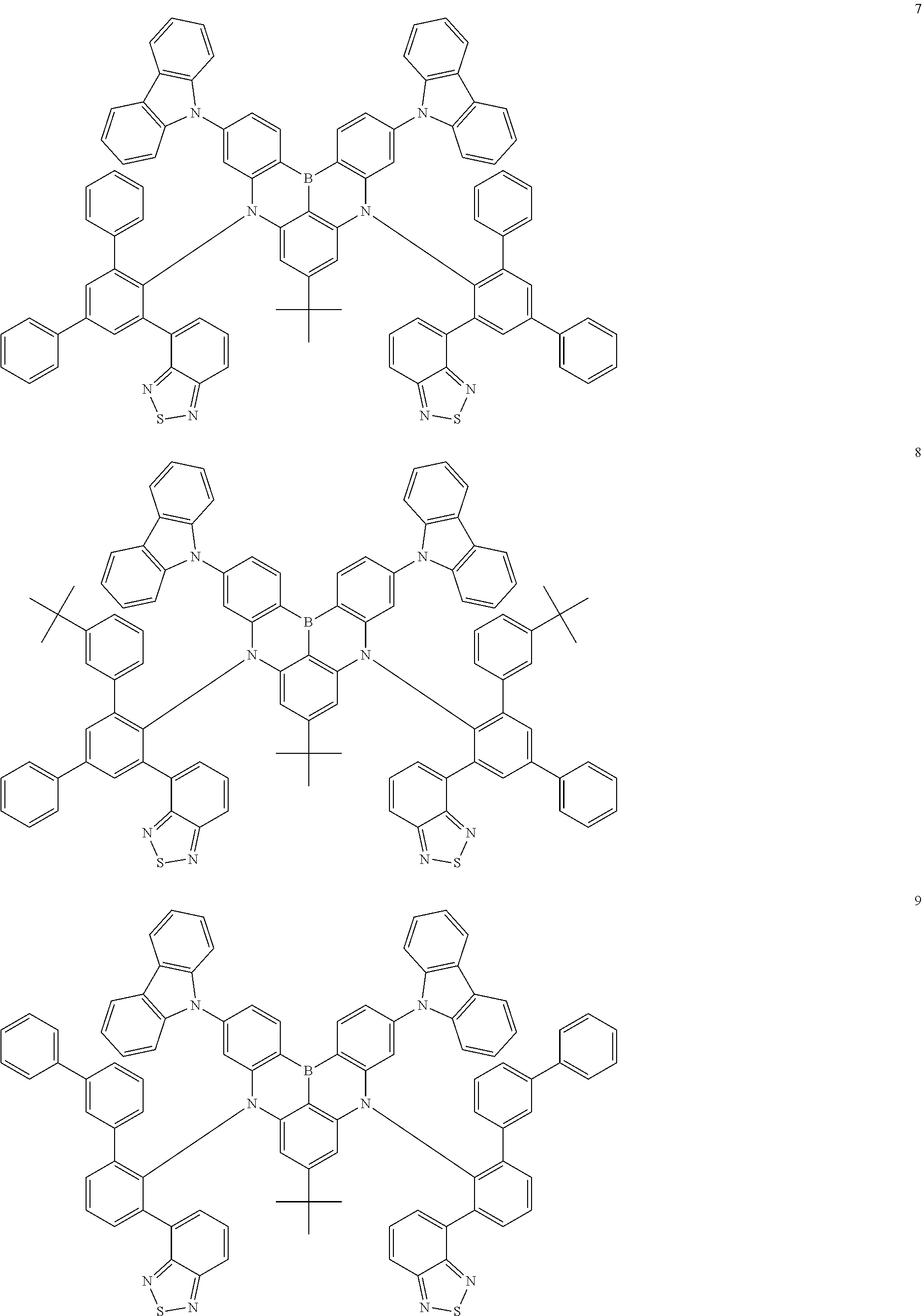 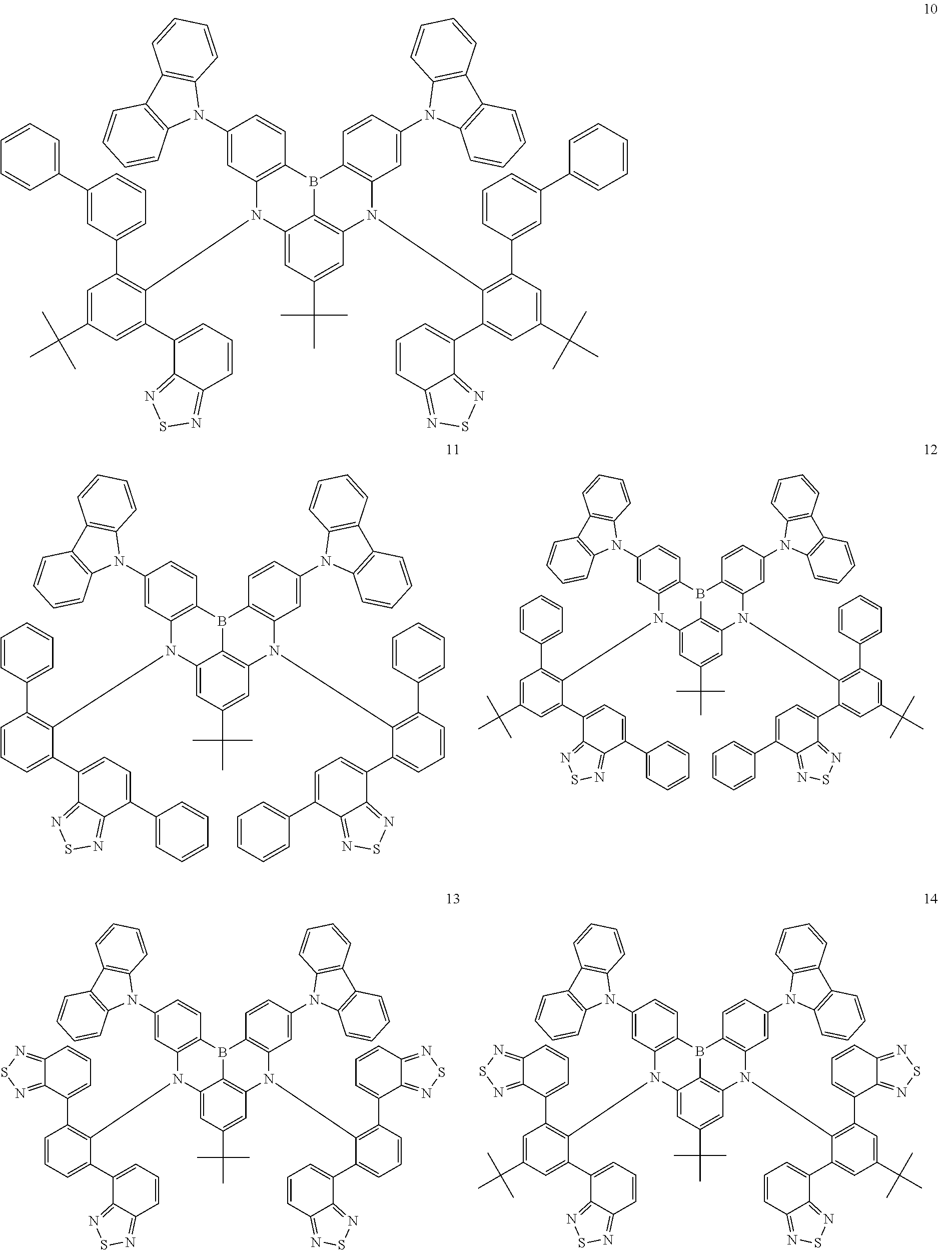 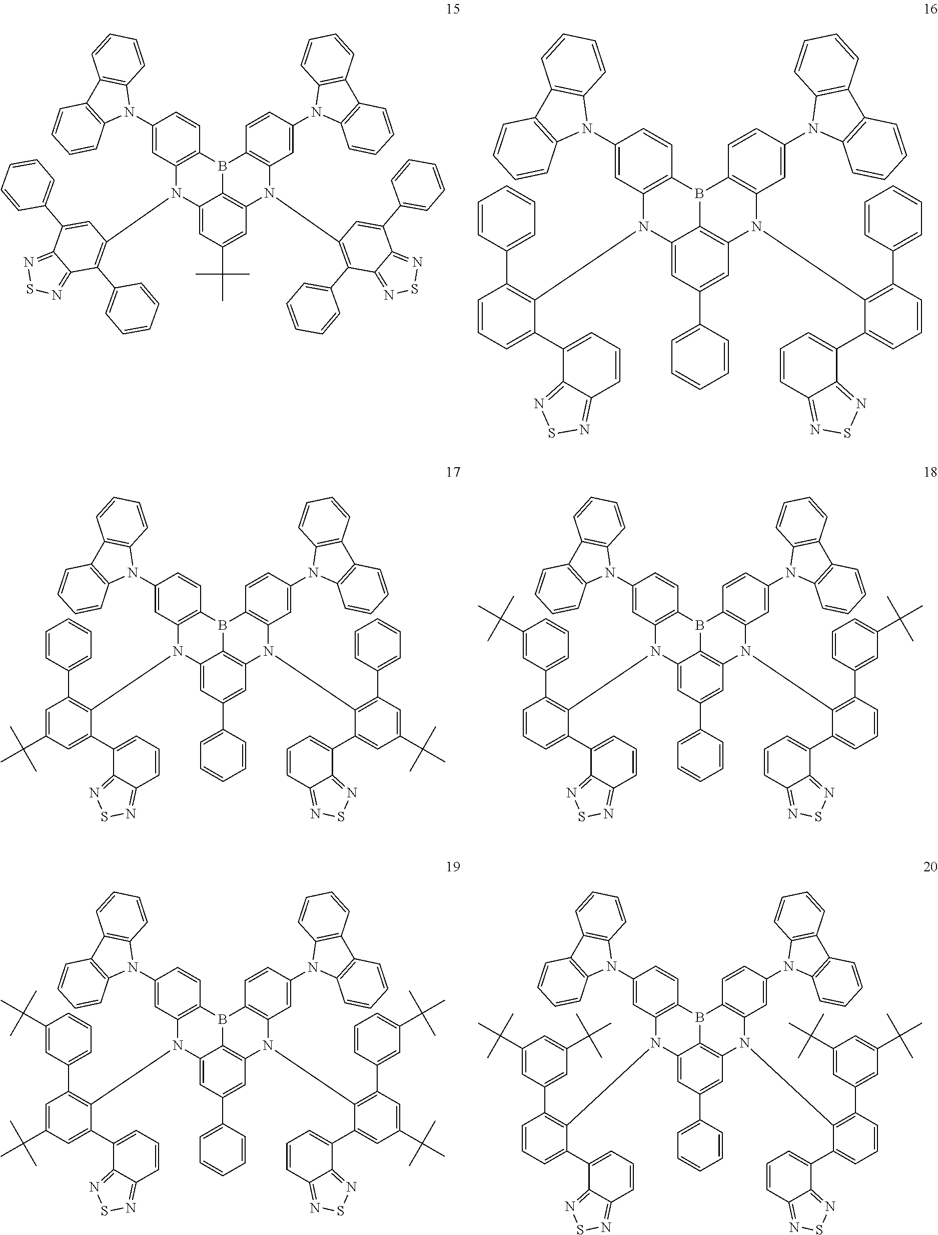 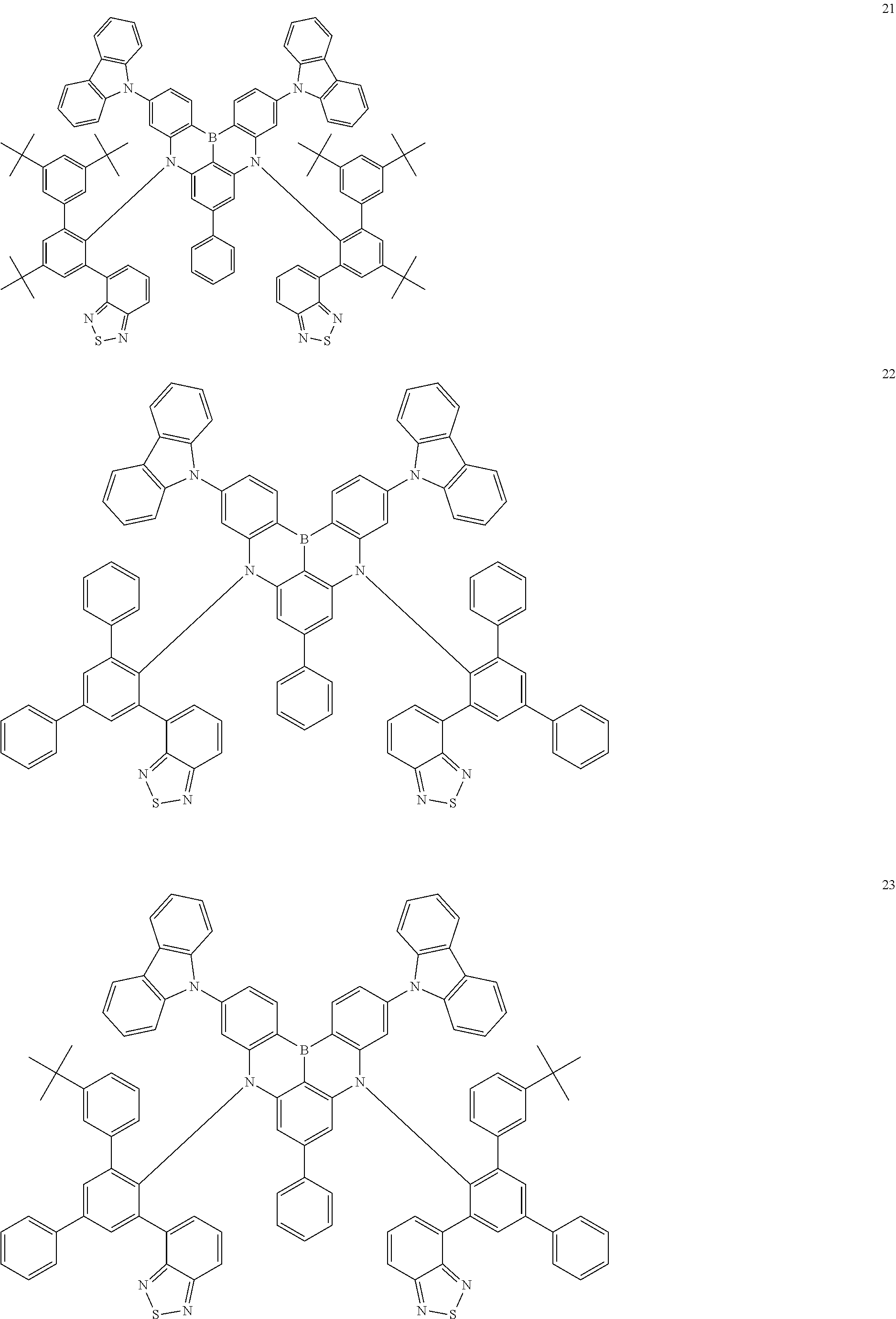 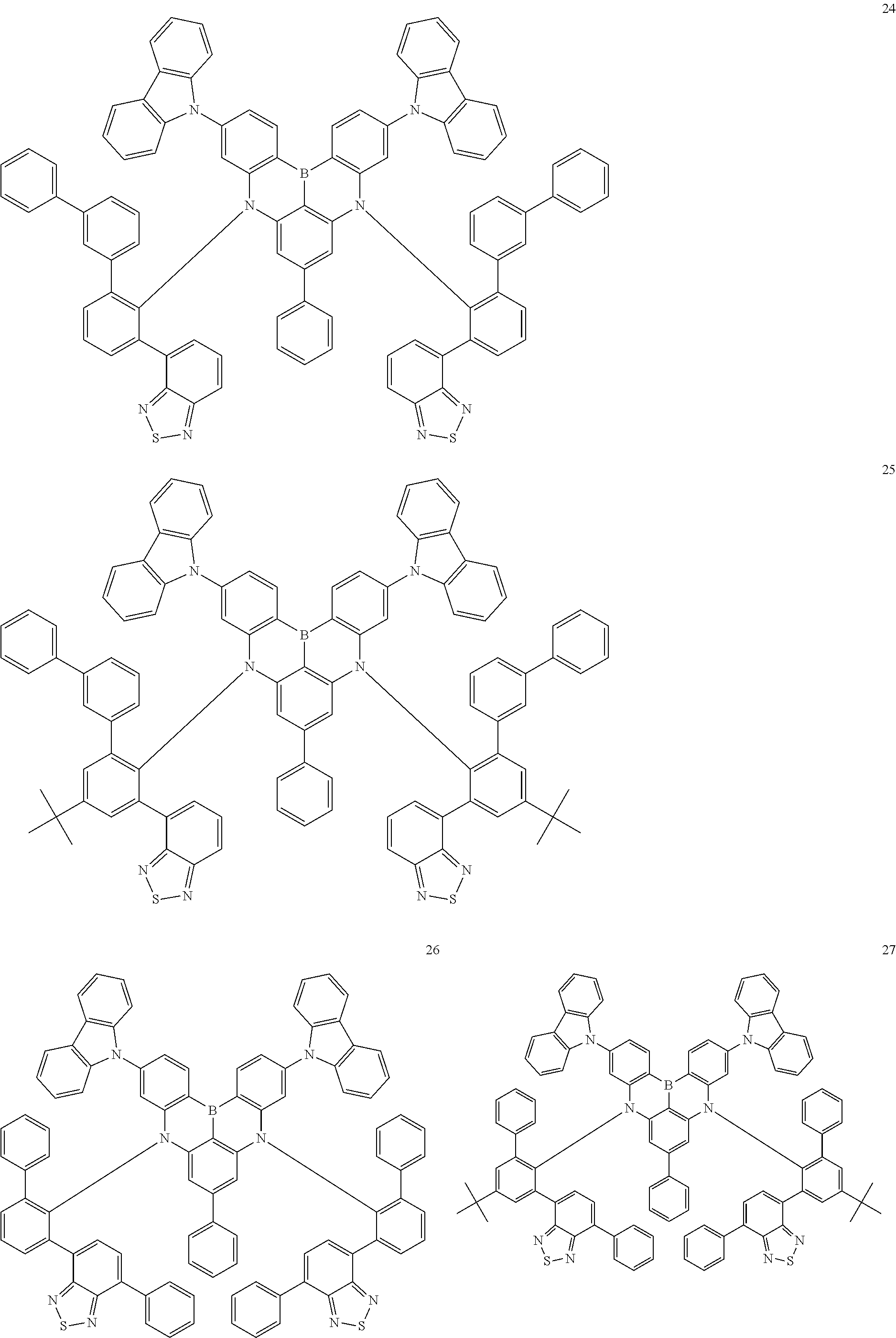 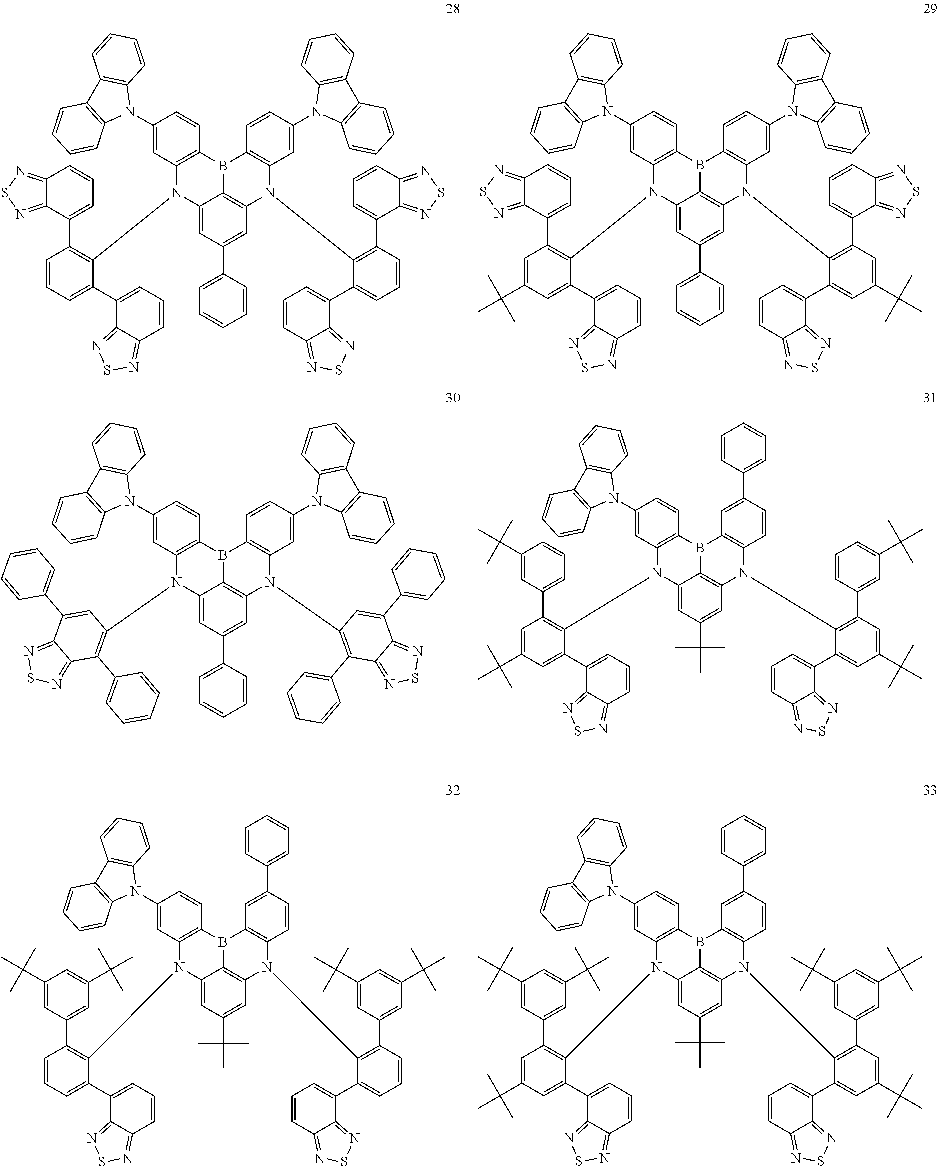 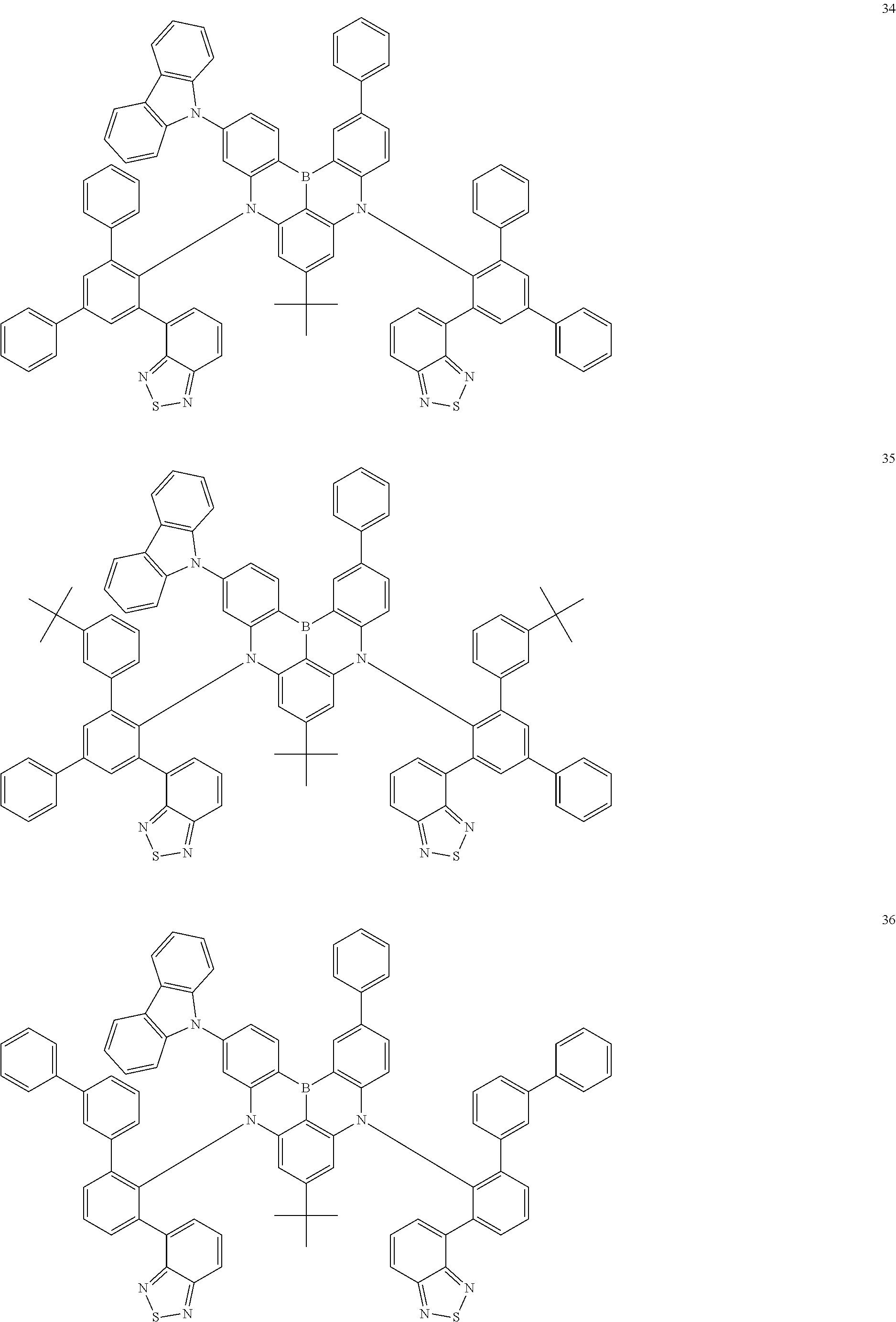 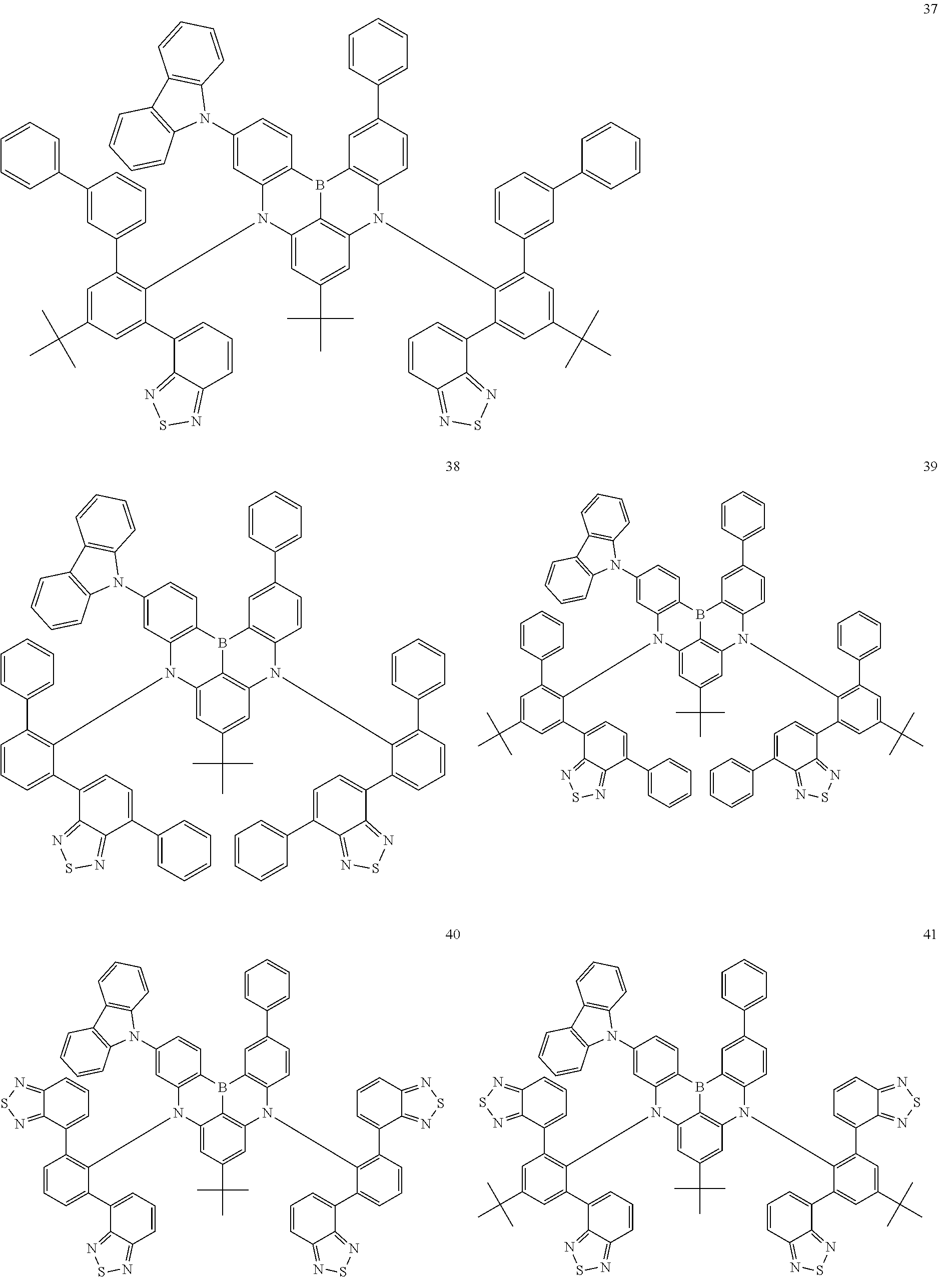 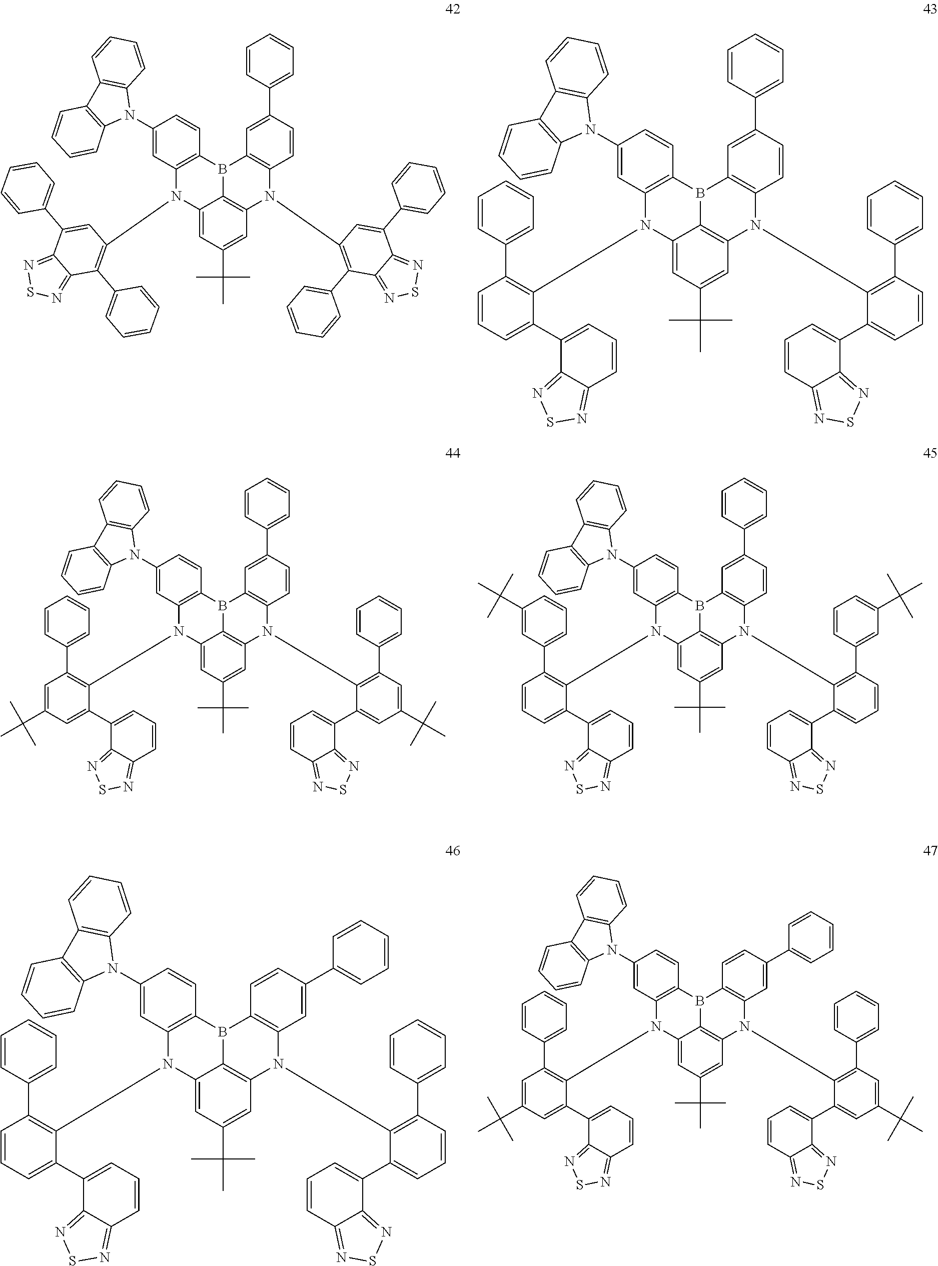 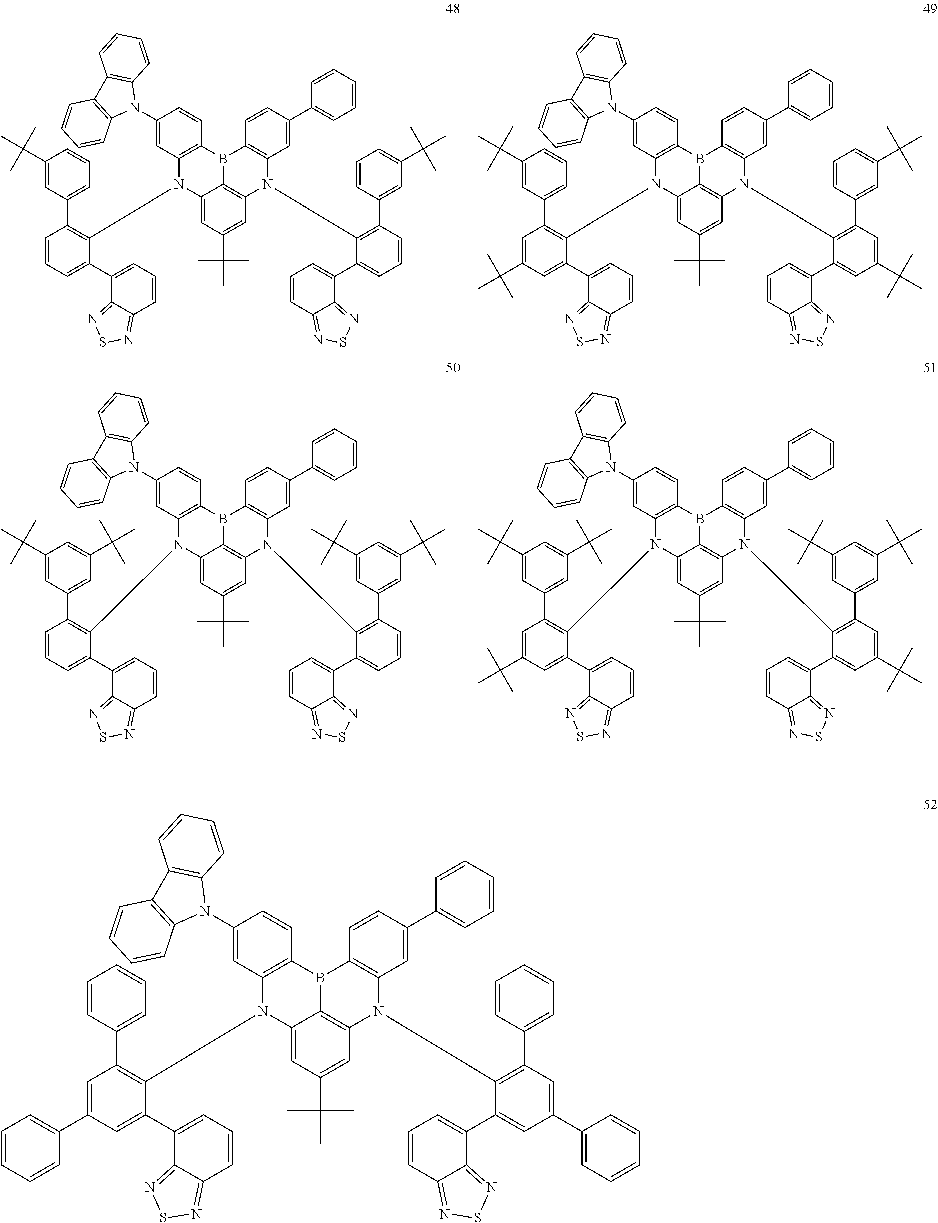 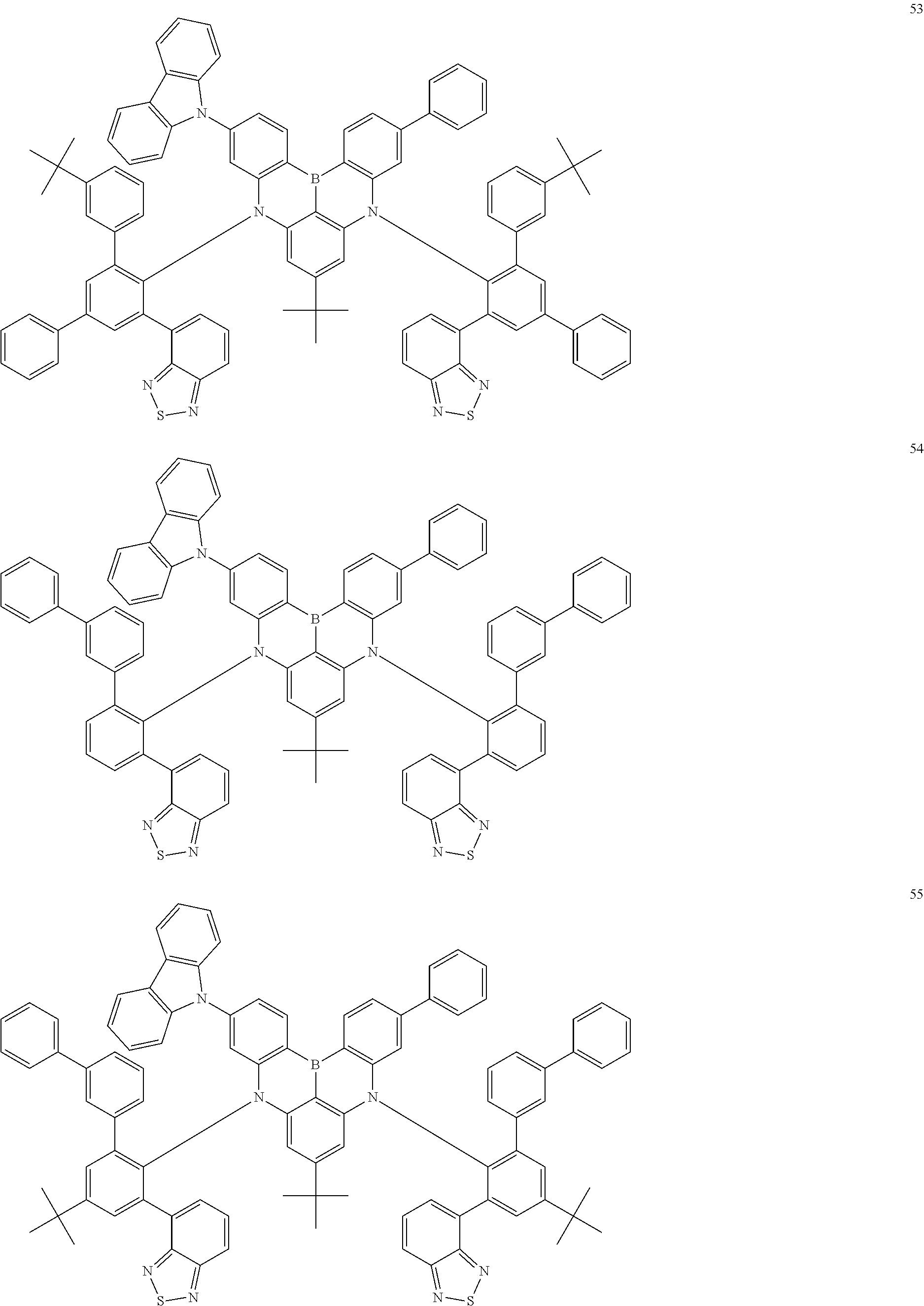 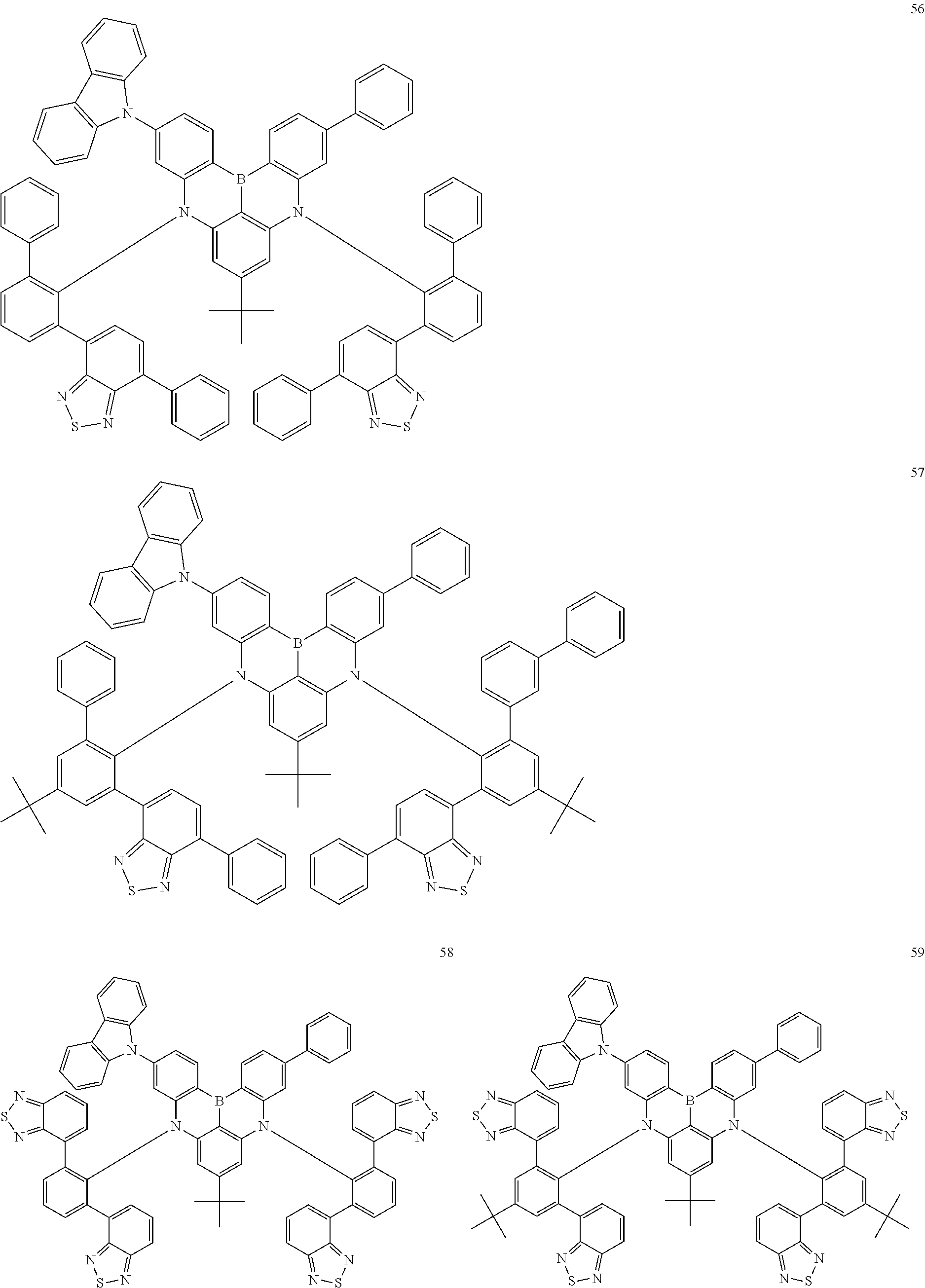 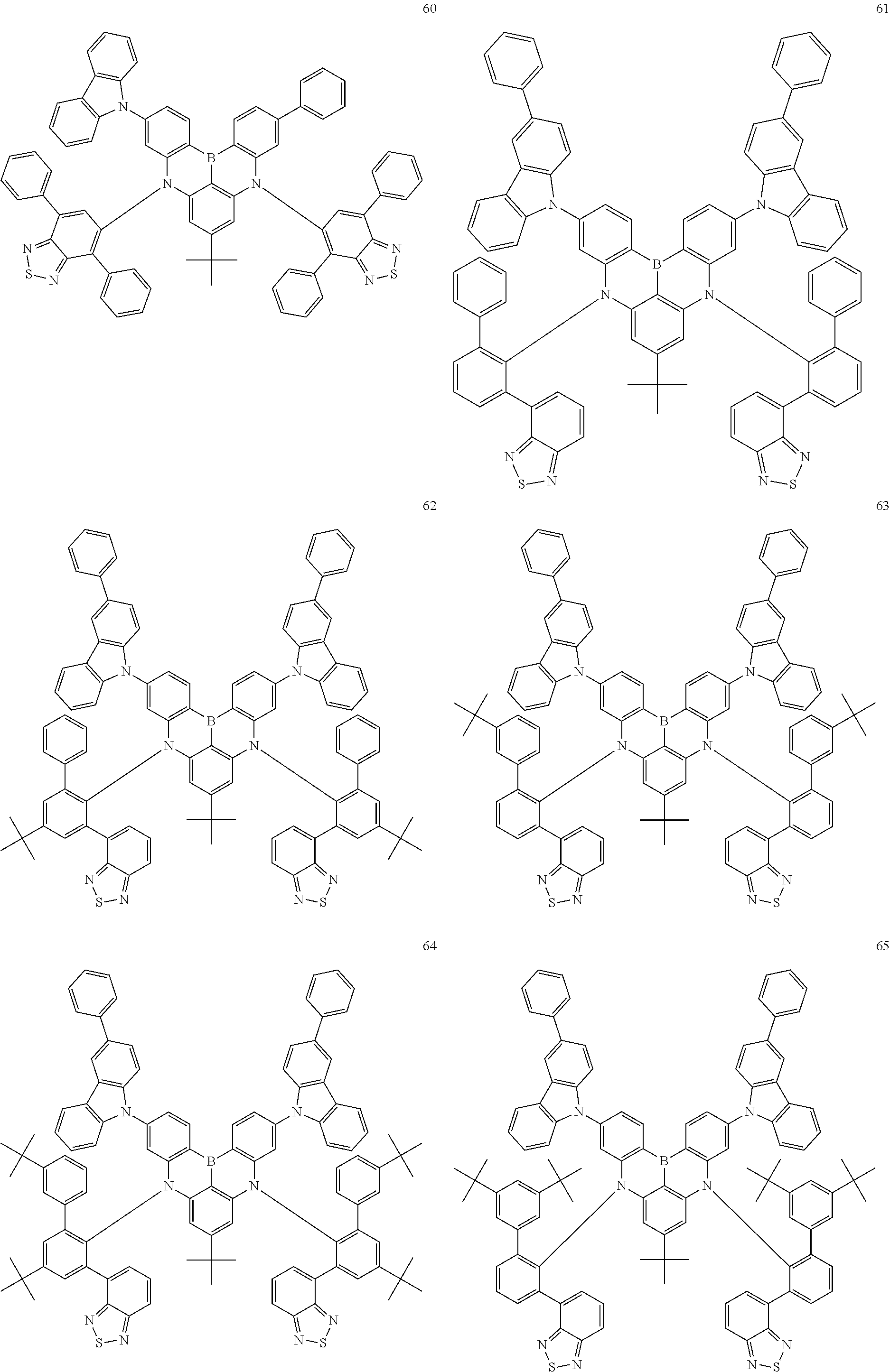 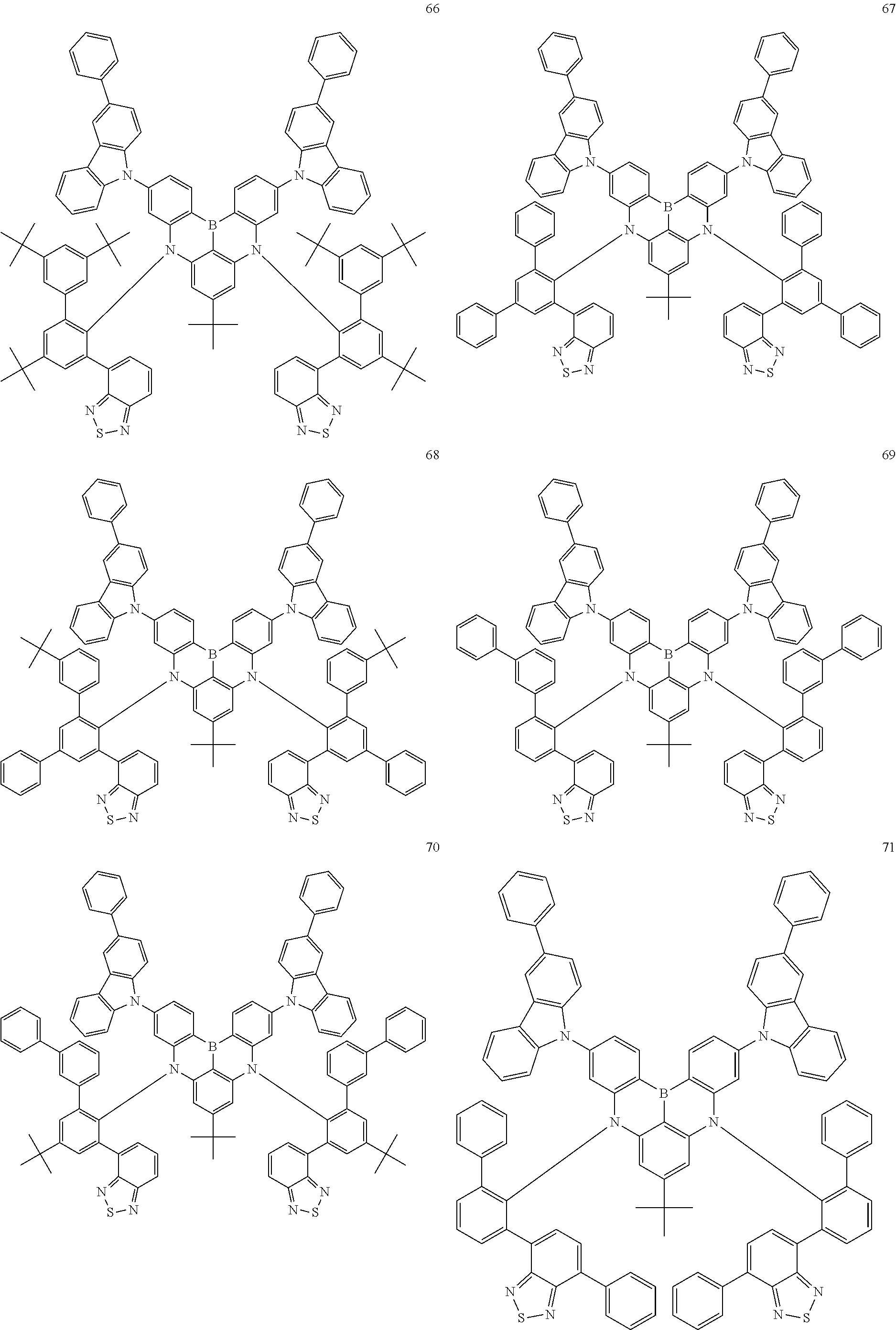 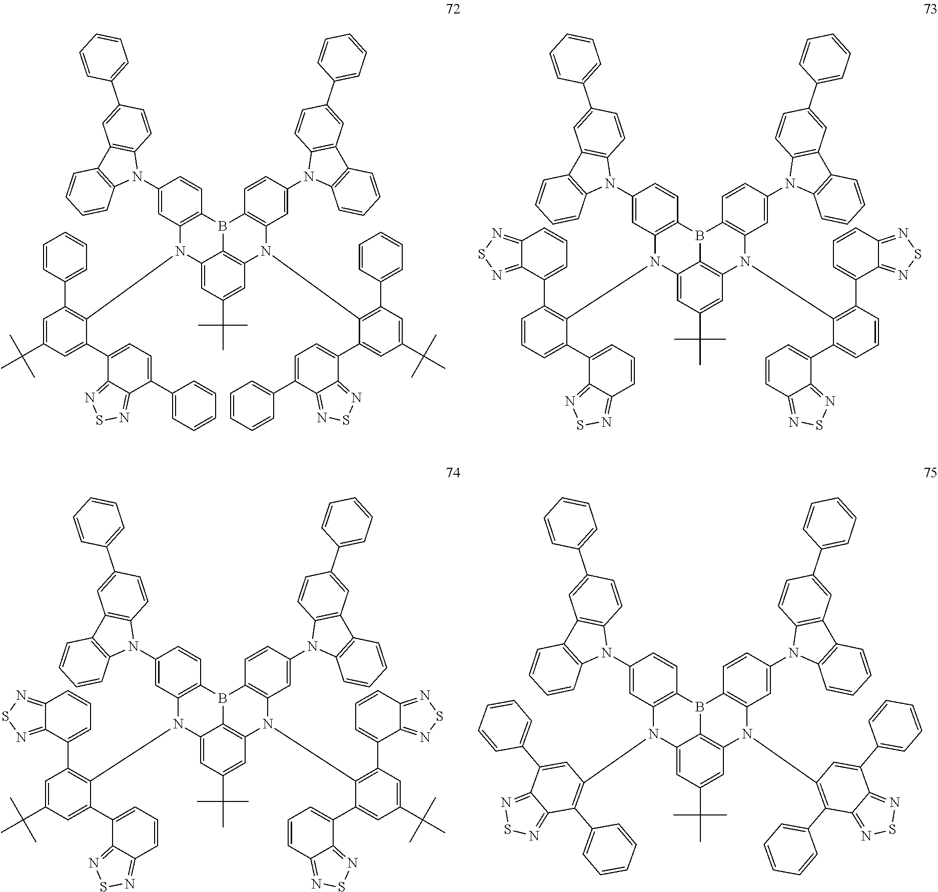 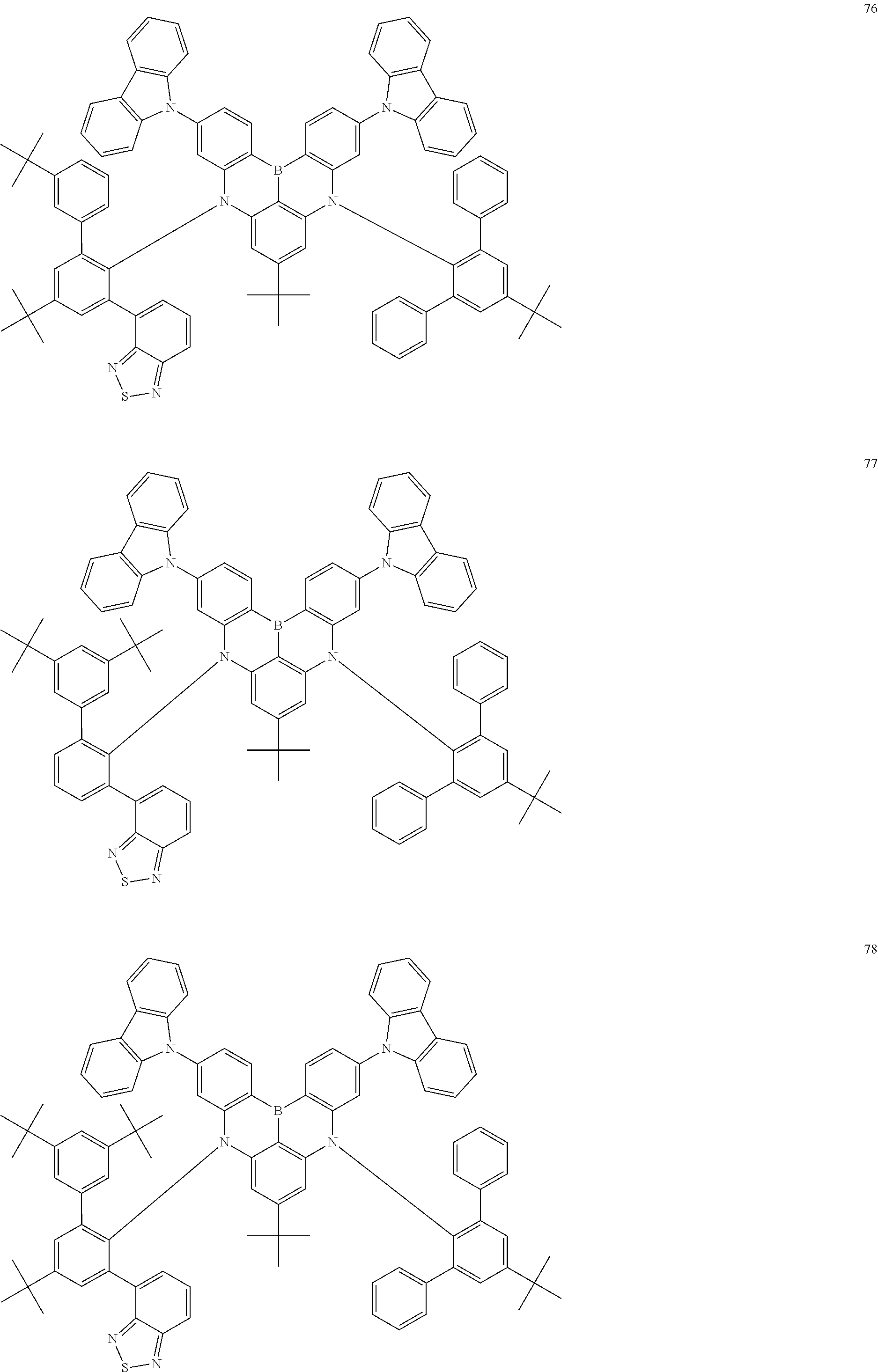 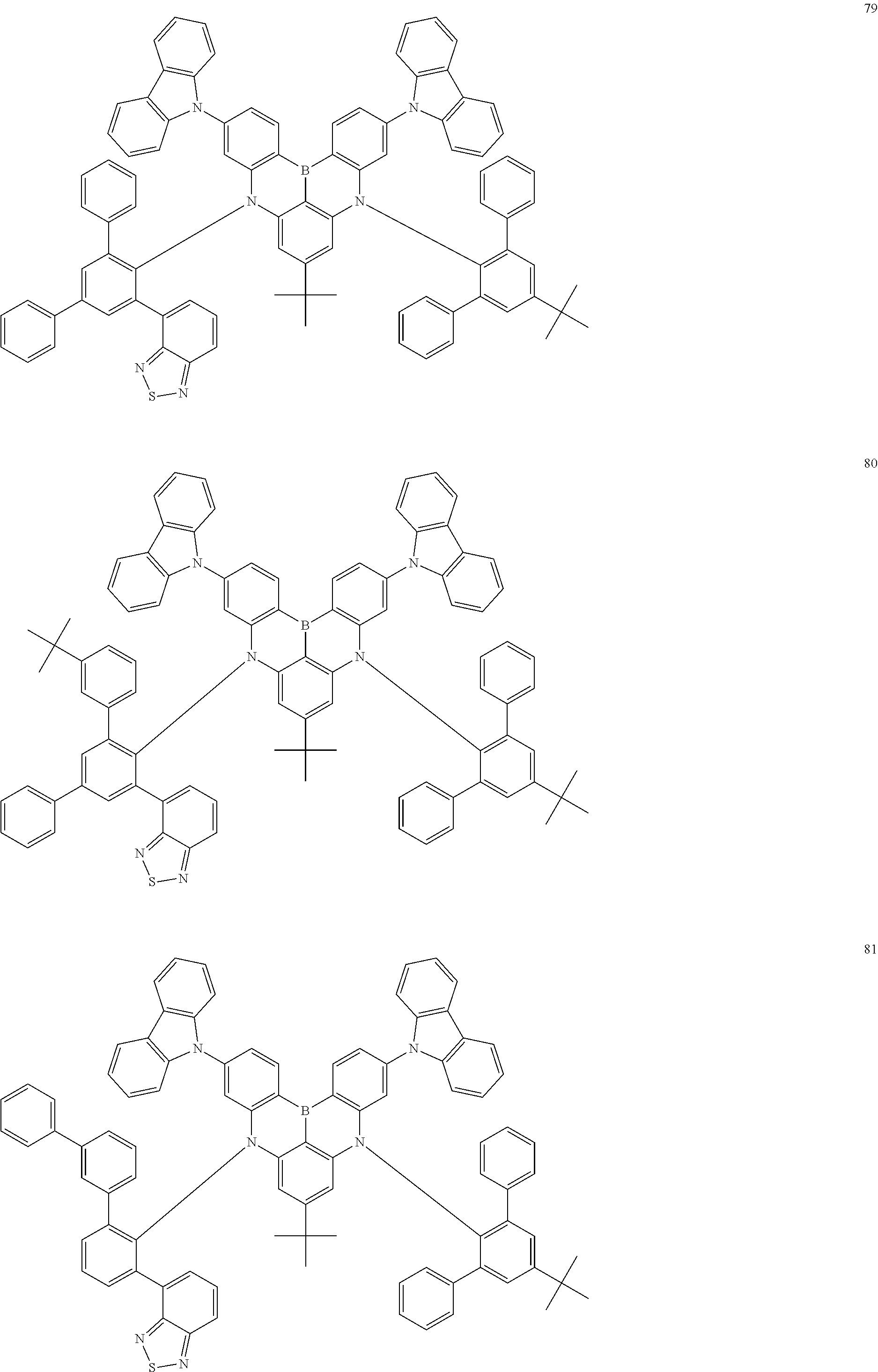 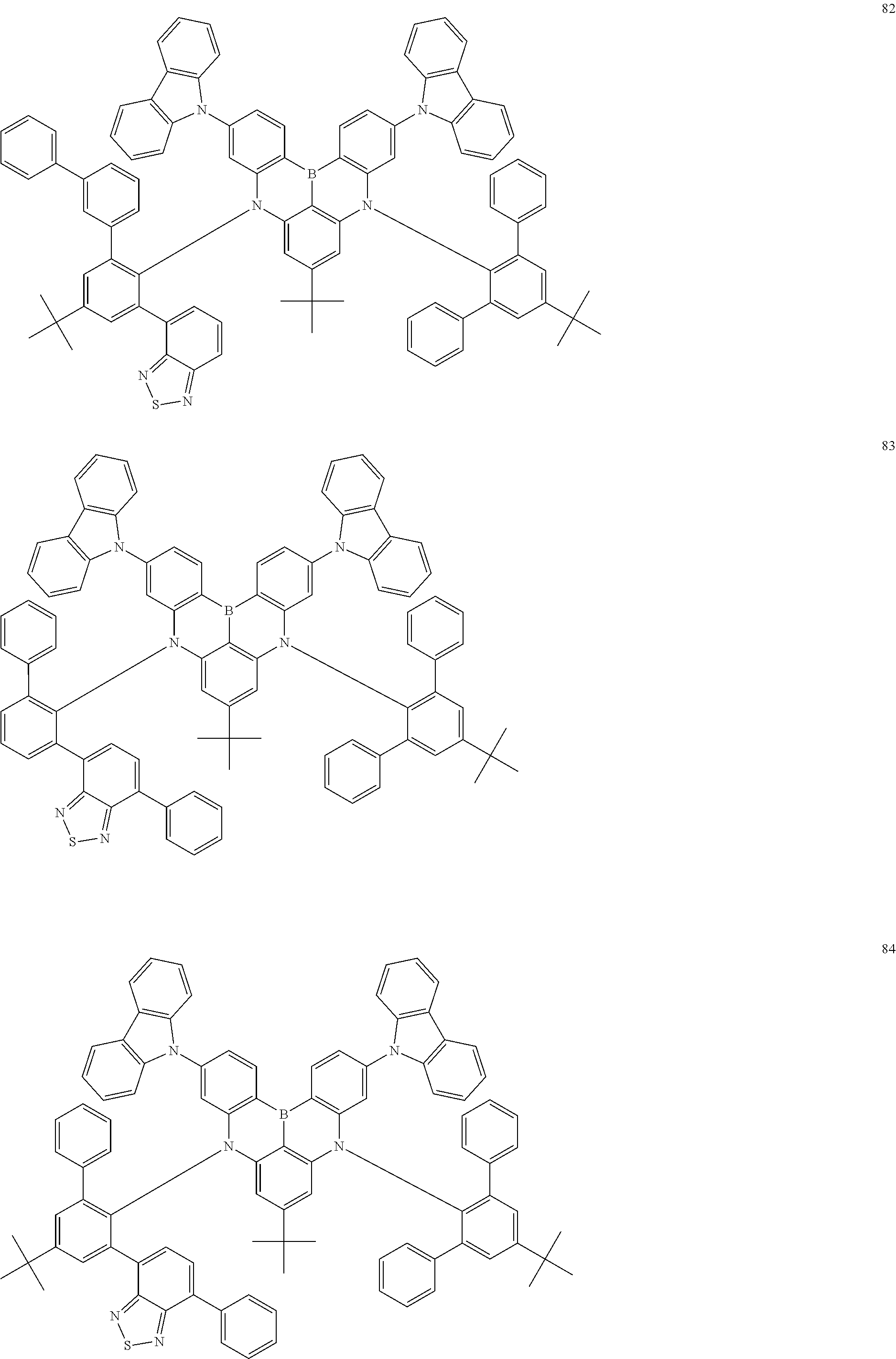 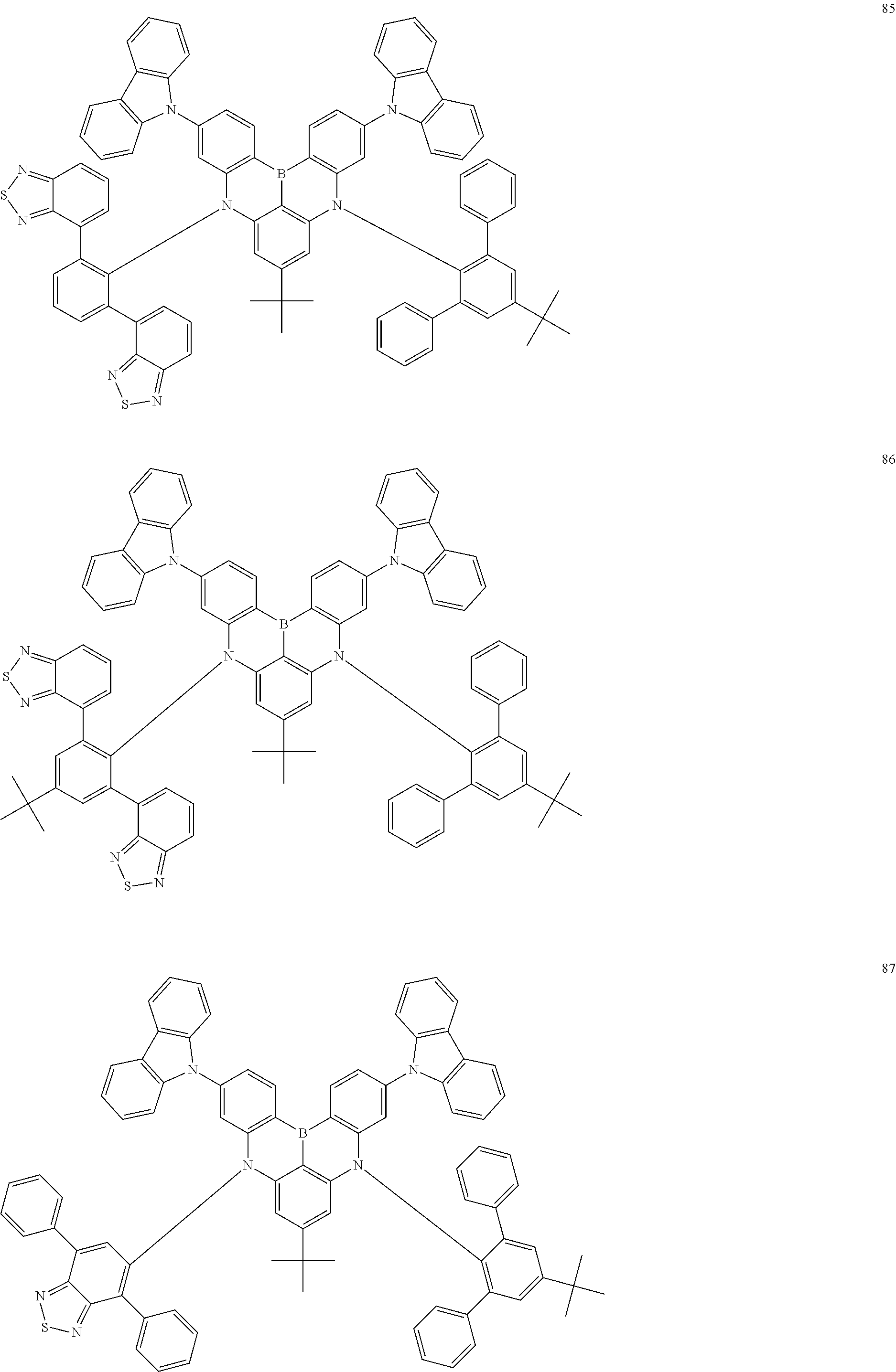 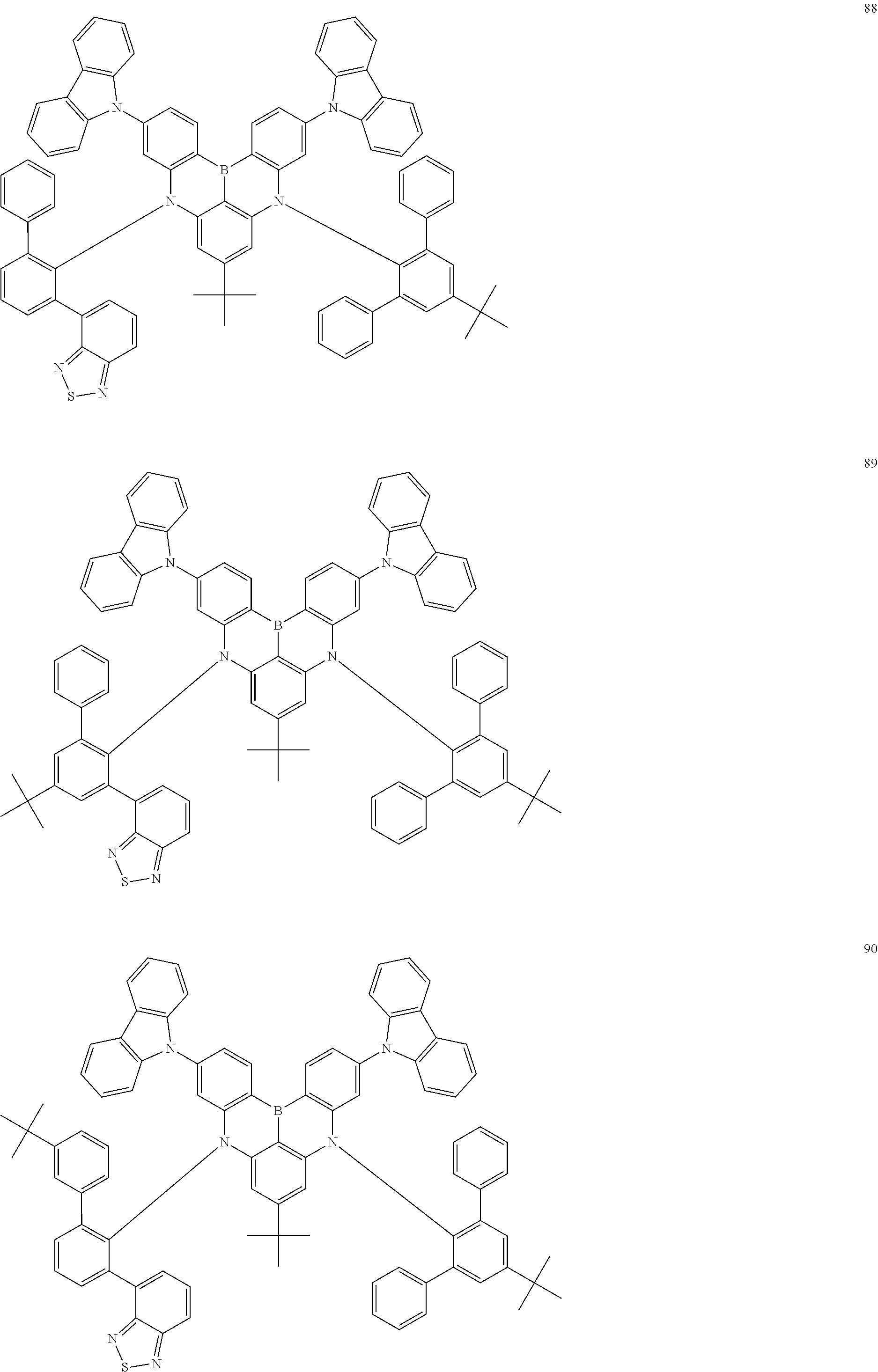 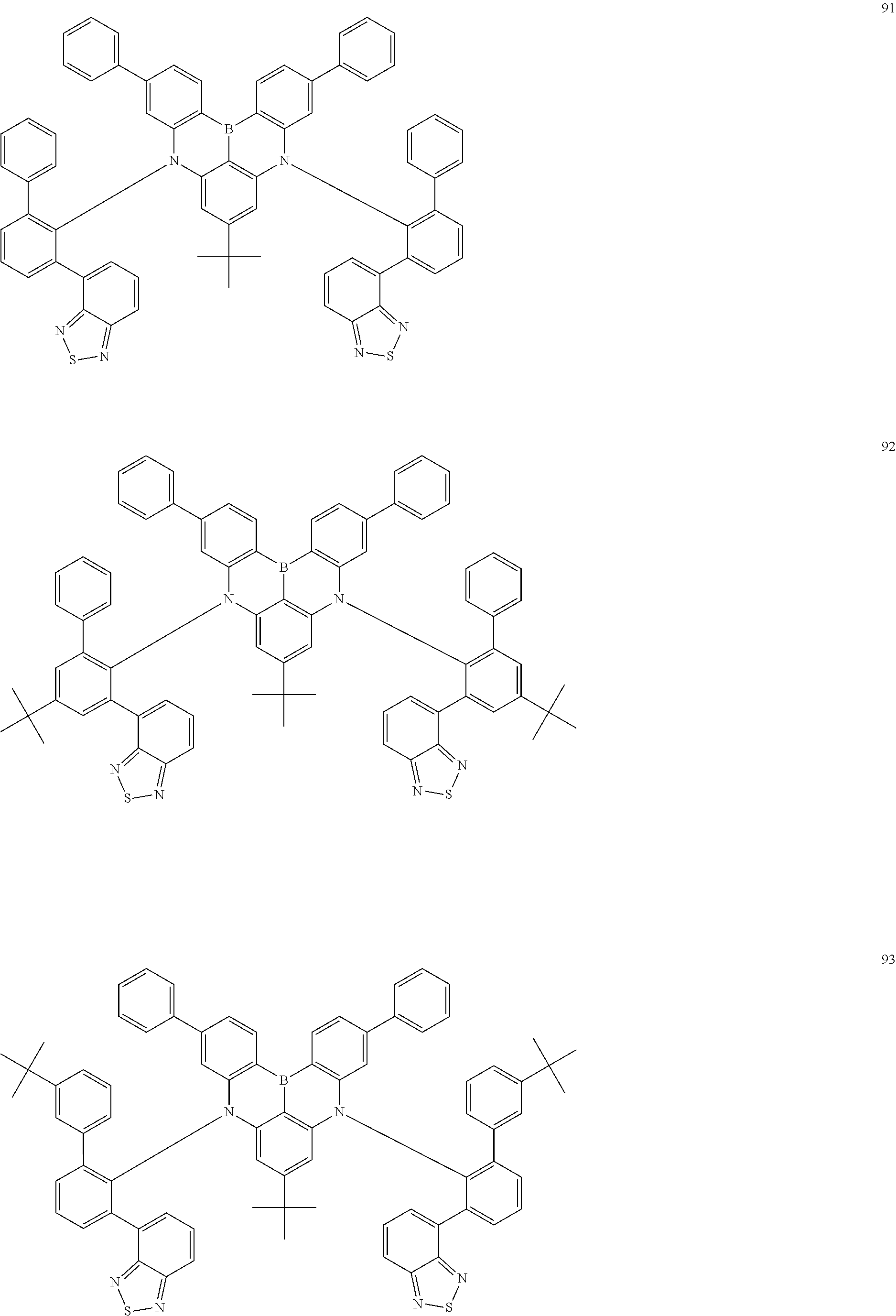 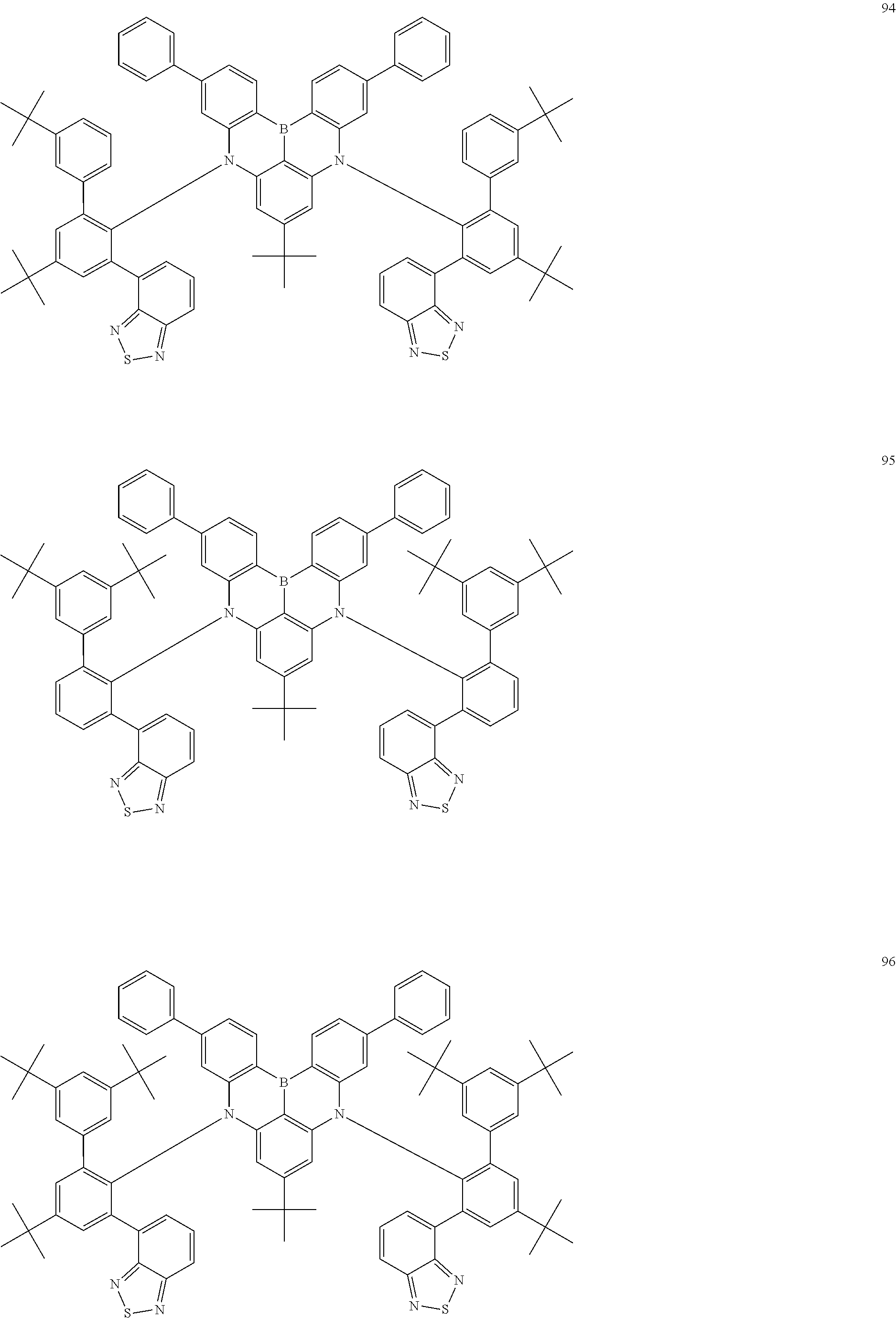 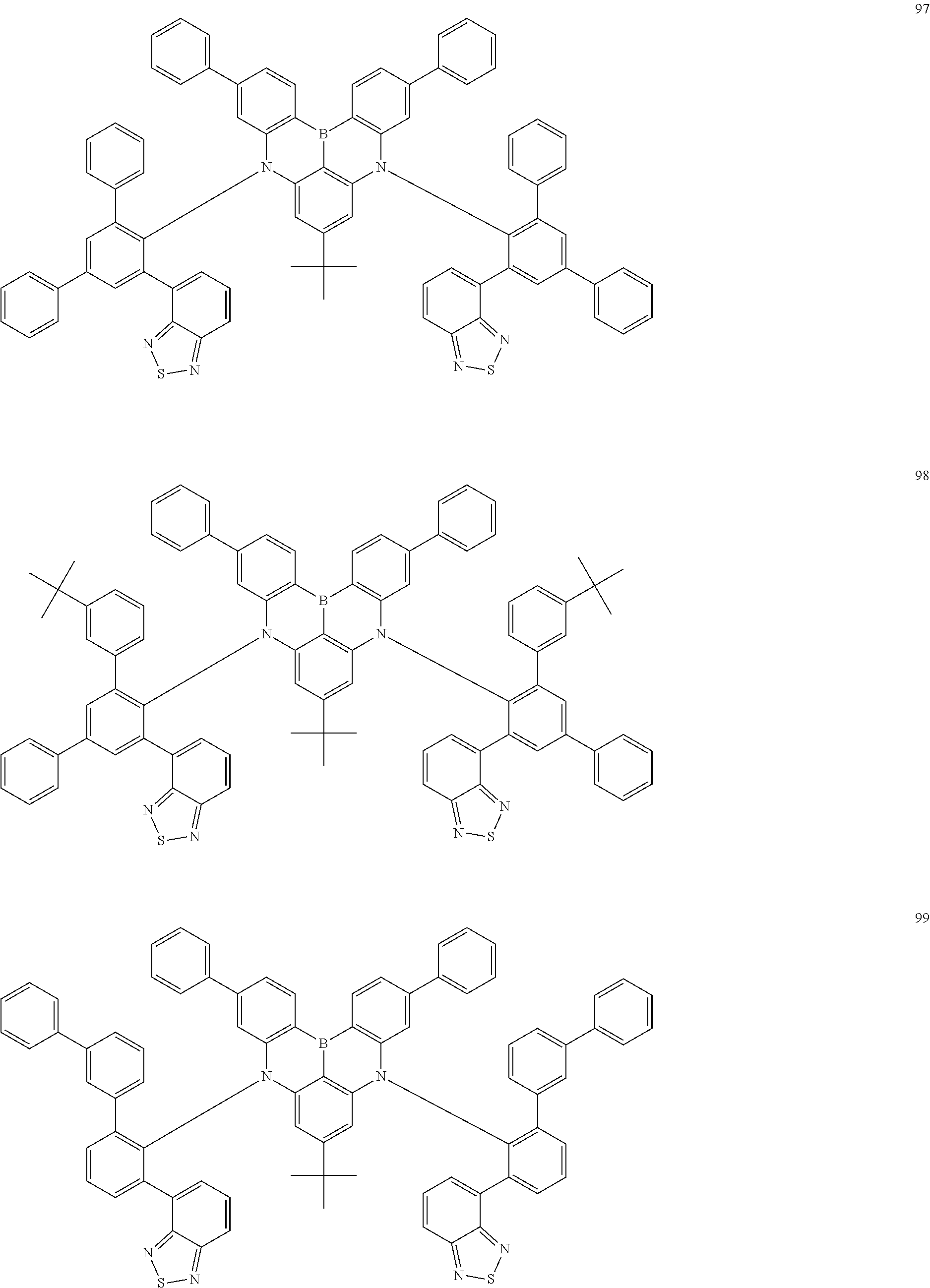 [SMILES: CC(C)(C)c1cc2c3c(c1)N(c1c(-c4ccccc4)cc(-c4ccccc4)cc1-c1cccc4nsnc14)c1cc(-c4ccccc4)ccc1B3c1ccc(-c3ccccc3)cc1N2c1c(-c2ccccc2)cc(-c2ccccc2)cc1-c1cccc2nsnc12 ; CC(C)(C)c1cccc(-c2cc(-c3ccccc3)cc(-c3cccc4nsnc34)c2N2c3cc(-c4ccccc4)ccc3B3c4ccc(-c5ccccc5)cc4N(c4c(-c5cccc(C(C)(C)C)c5)cc(-c5ccccc5)cc4-c4cccc5nsnc45)c4cc(C(C)(C)C)cc2c43)c1 ; CC(C)(C)c1cc2c3c(c1)N(c1c(-c4cccc(-c5ccccc5)c4)cccc1-c1cccc4nsnc14)c1cc(-c4ccccc4)ccc1B3c1ccc(-c3ccccc3)cc1N2c1c(-c2cccc(-c3ccccc3)c2)cccc1-c1cccc2nsnc12] 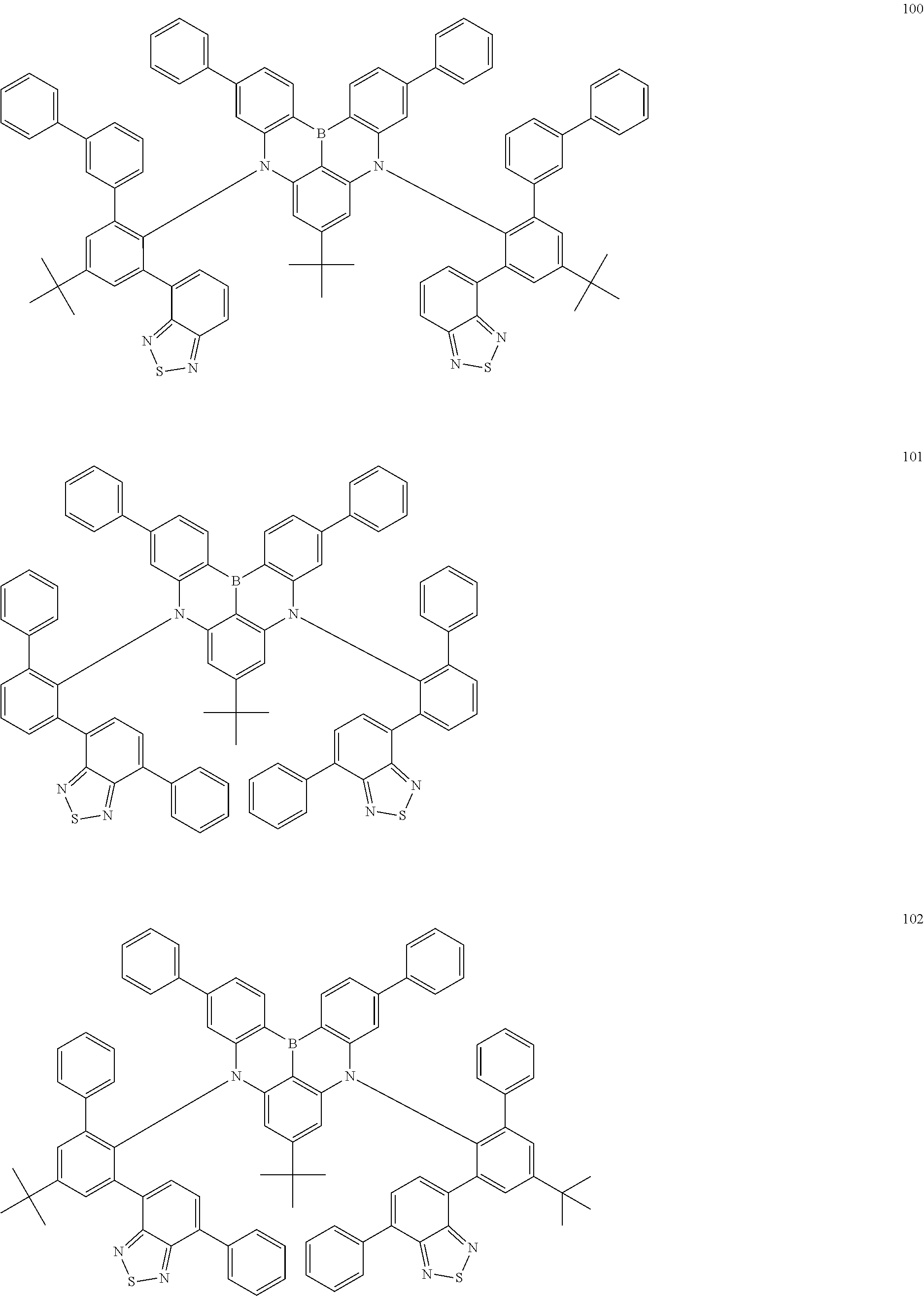 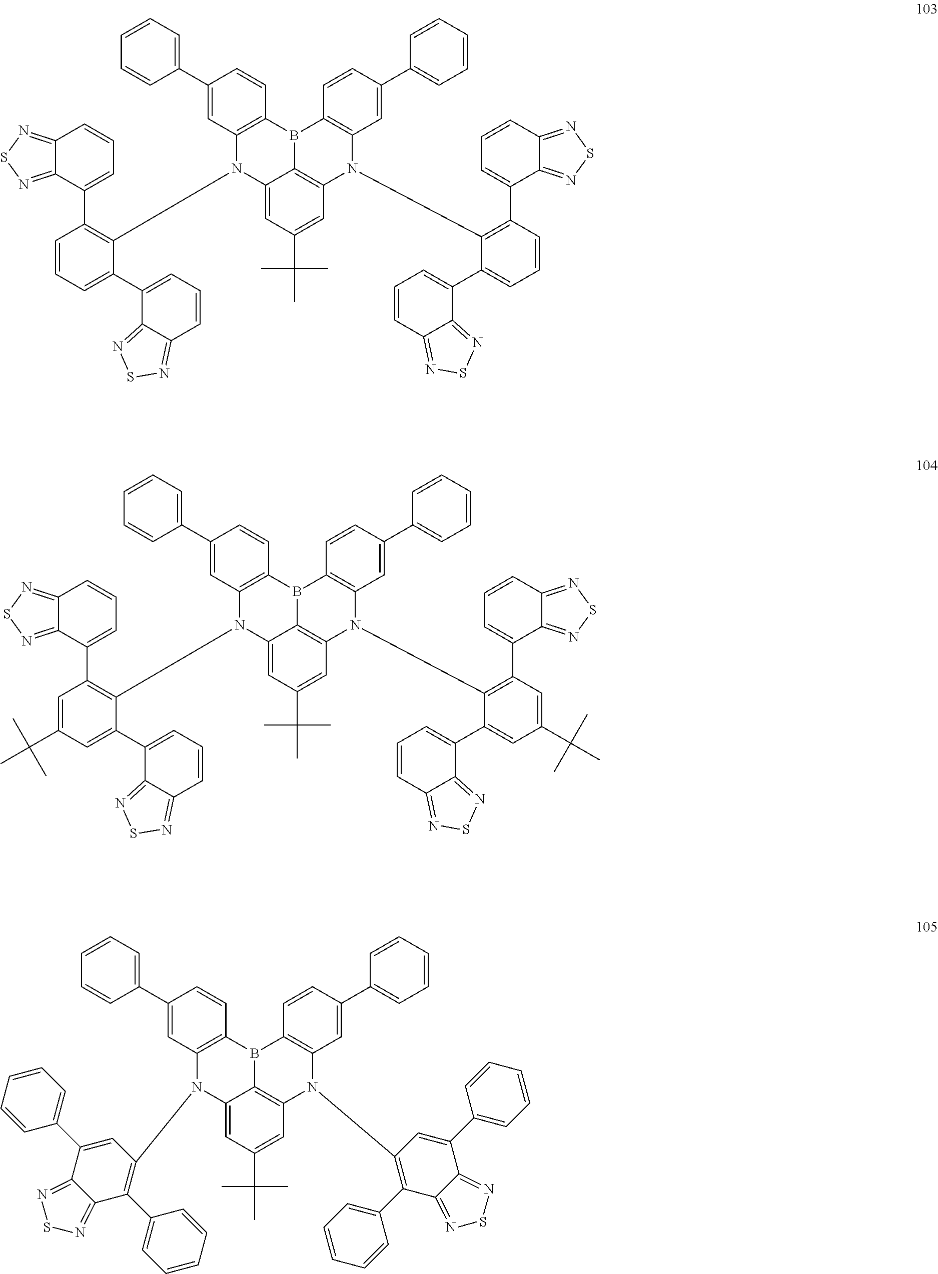 [SMILES: CC(C)(C)c1cc2c3c(c1)N(c1c(-c4cccc5nsnc45)cccc1-c1cccc4nsnc14)c1cc(-c4ccccc4)ccc1B3c1ccc(-c3ccccc3)cc1N2c1c(-c2cccc3nsnc23)cccc1-c1cccc2nsnc12 ; CC(C)(C)c1cc(-c2cccc3nsnc23)c(N2c3cc(-c4ccccc4)ccc3B3c4ccc(-c5ccccc5)cc4N(c4c(-c5cccc6nsnc56)cc(C(C)(C)C)cc4-c4cccc5nsnc45)c4cc(C(C)(C)C)cc2c43)c(-c2cccc3nsnc23)c1 ; CC(C)(C)c1cc2c3c(c1)N(c1cc(-c4ccccc4)c4nsnc4c1-c1ccccc1)c1cc(-c4ccccc4)ccc1B3c1ccc(-c3ccccc3)cc1N2c1cc(-c2ccccc2)c2nsnc2c1-c1ccccc1] 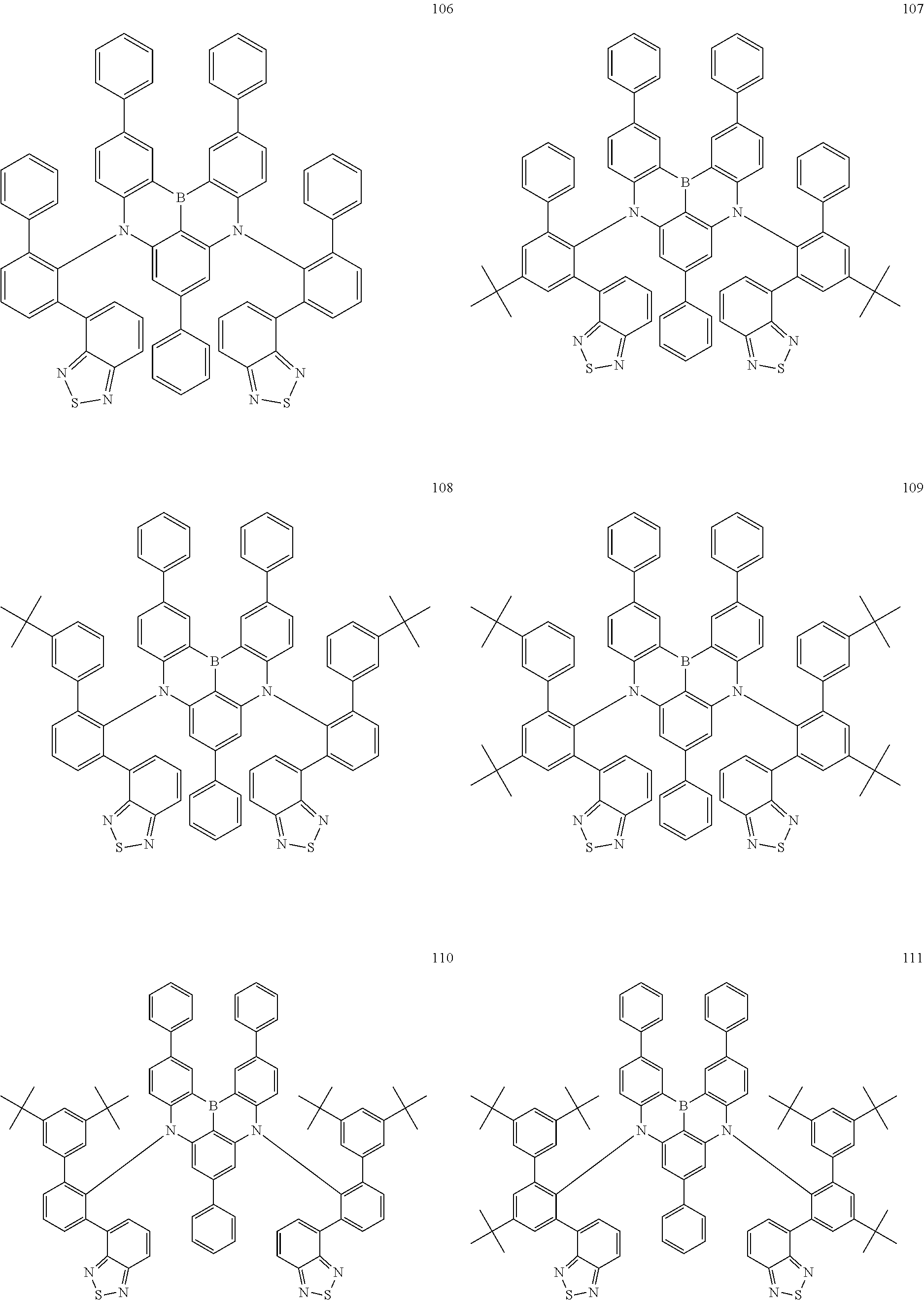 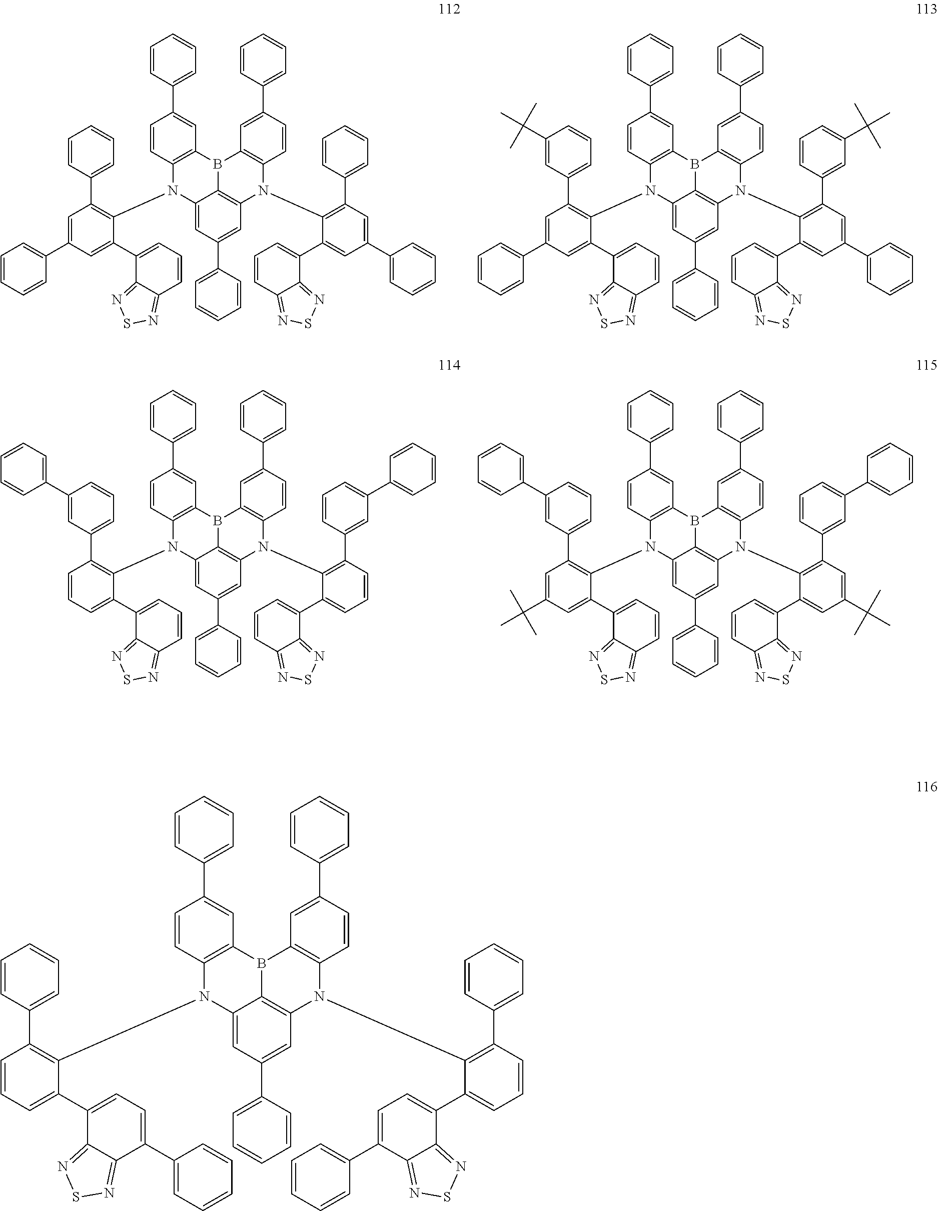 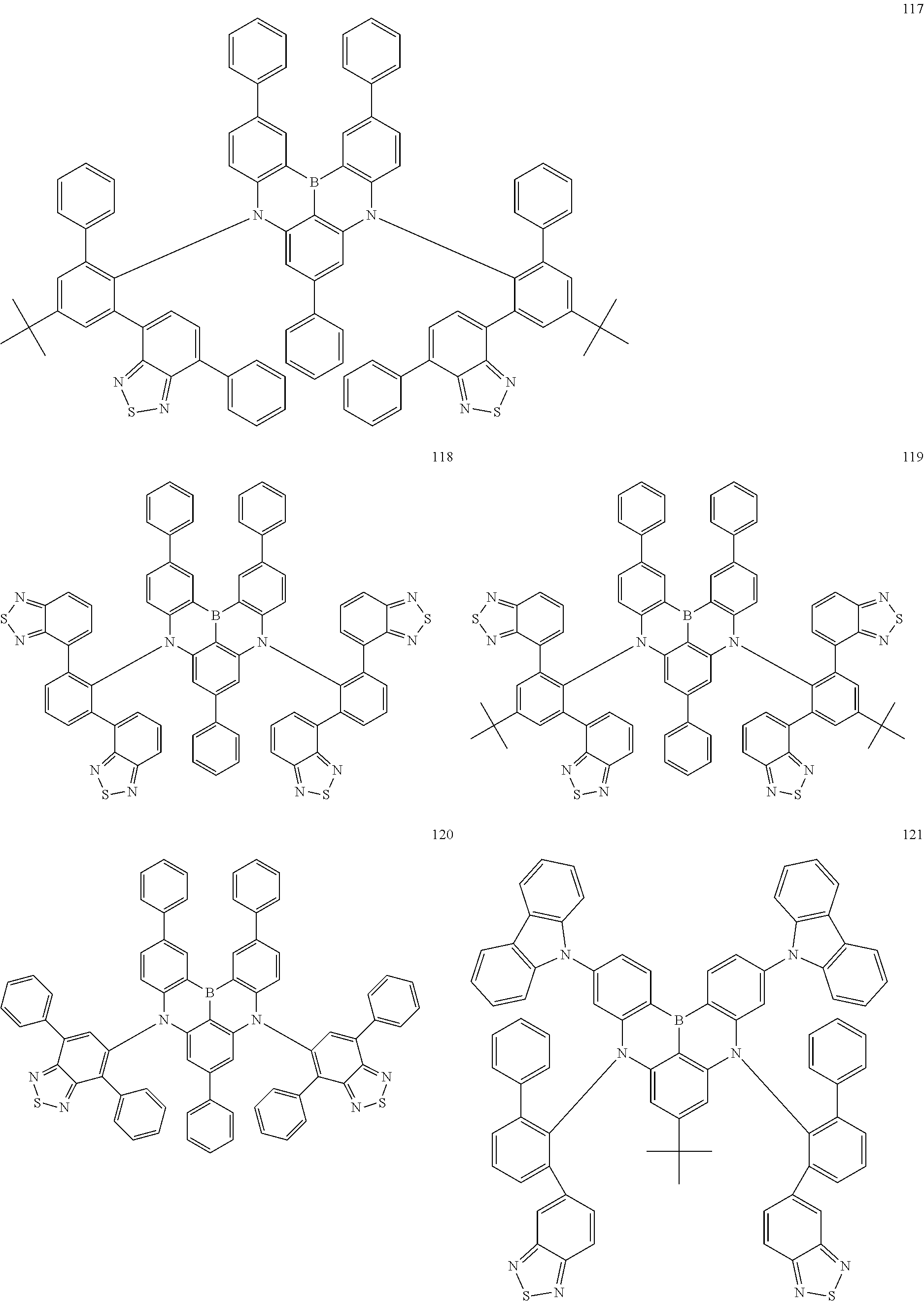 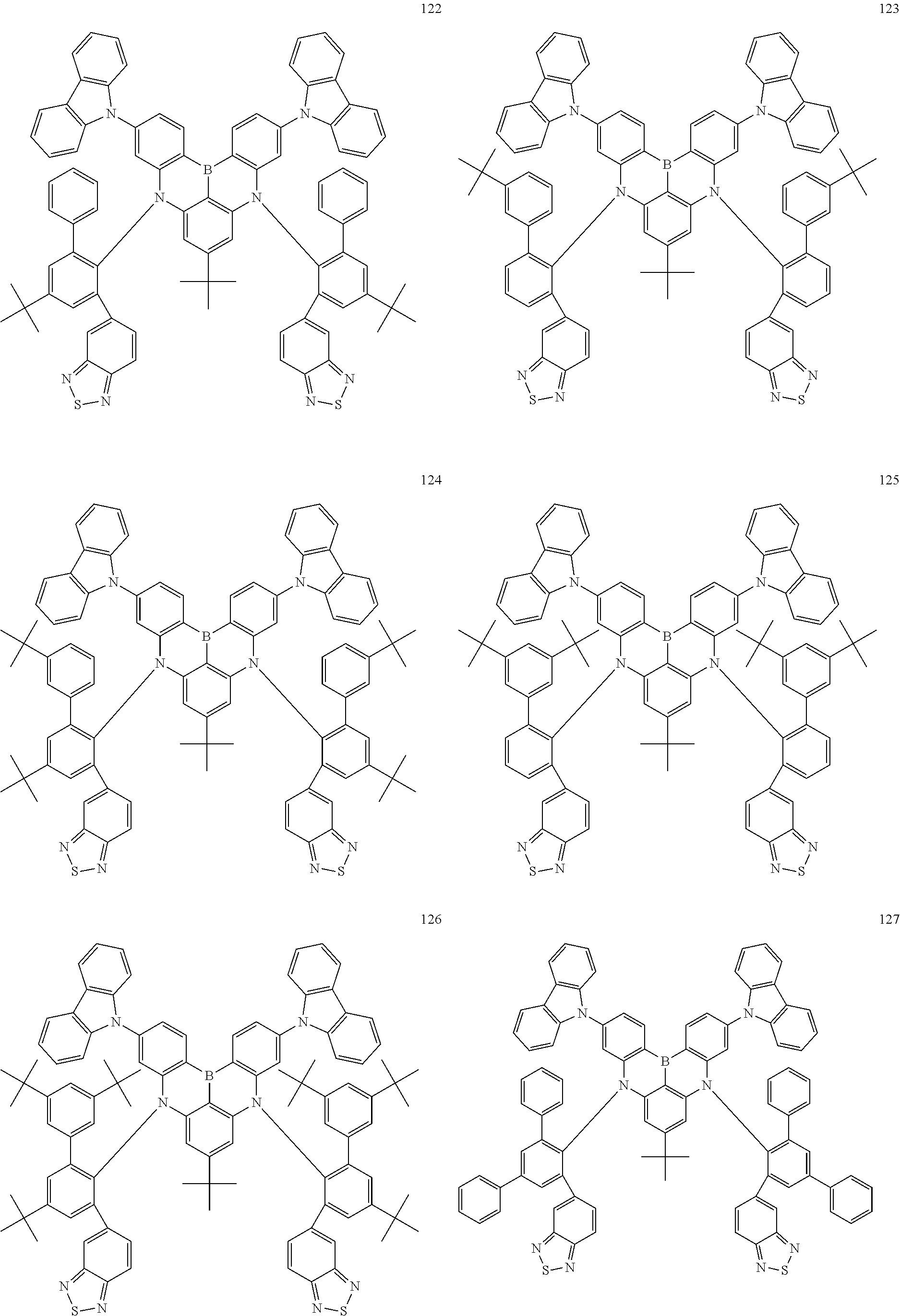 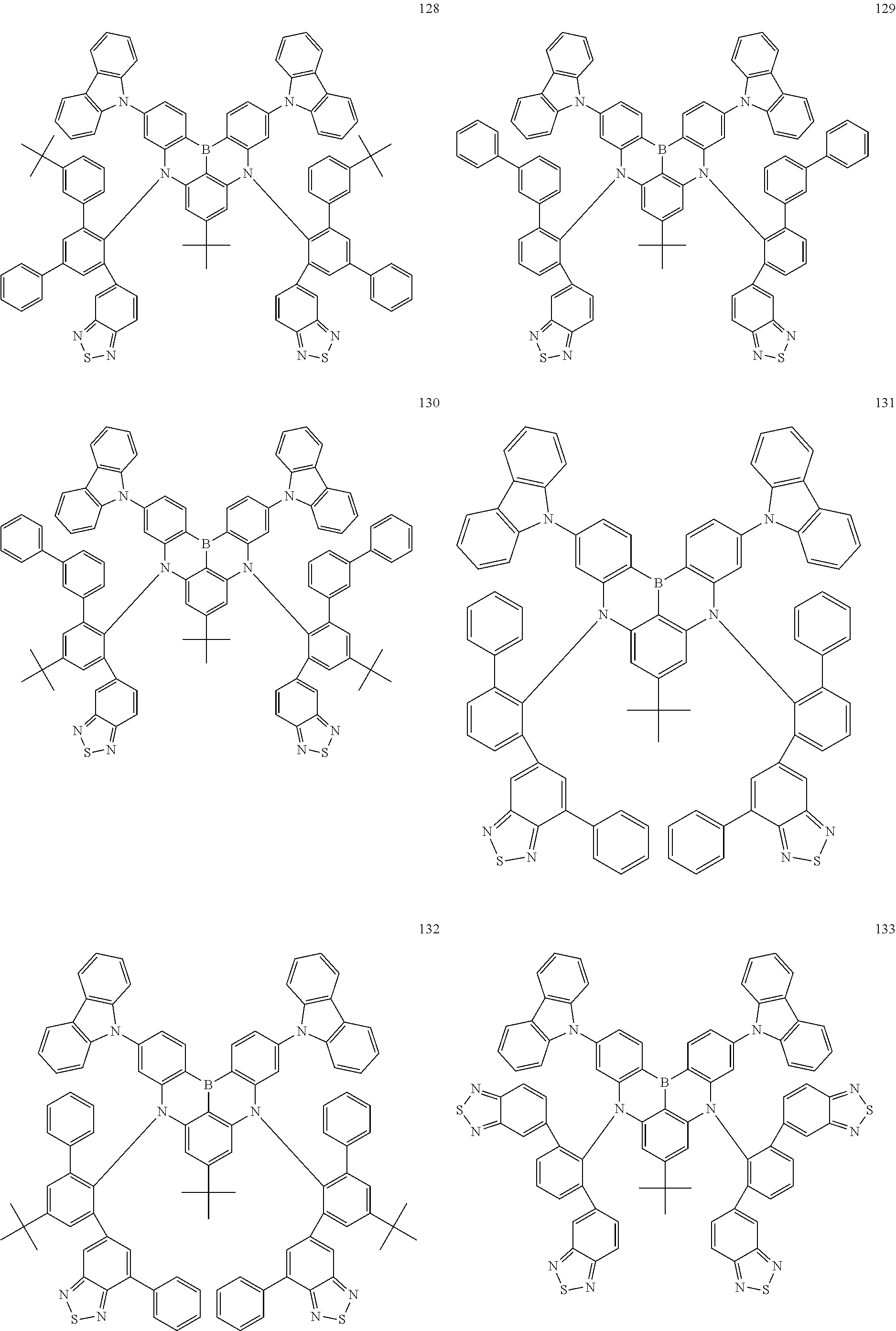 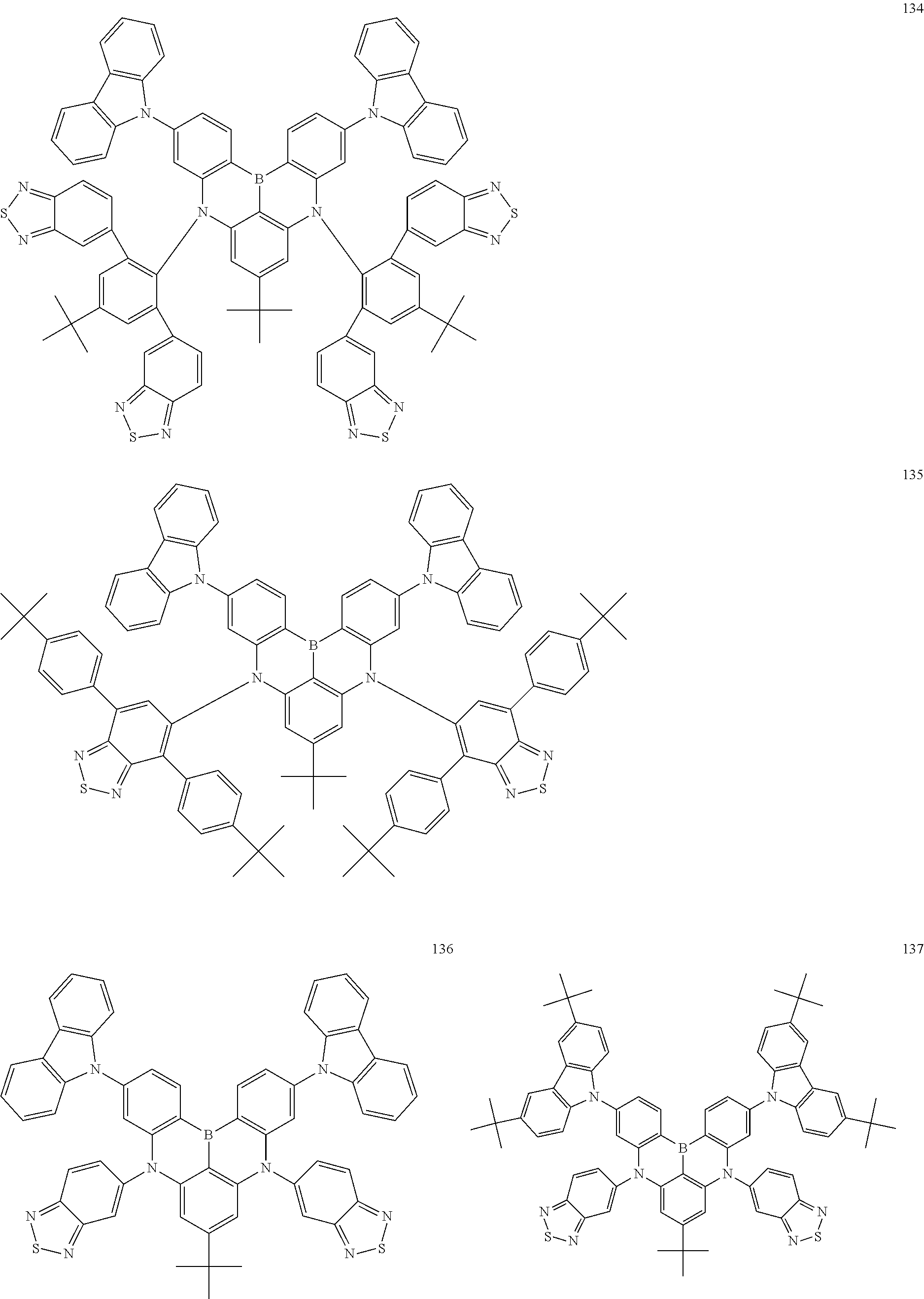 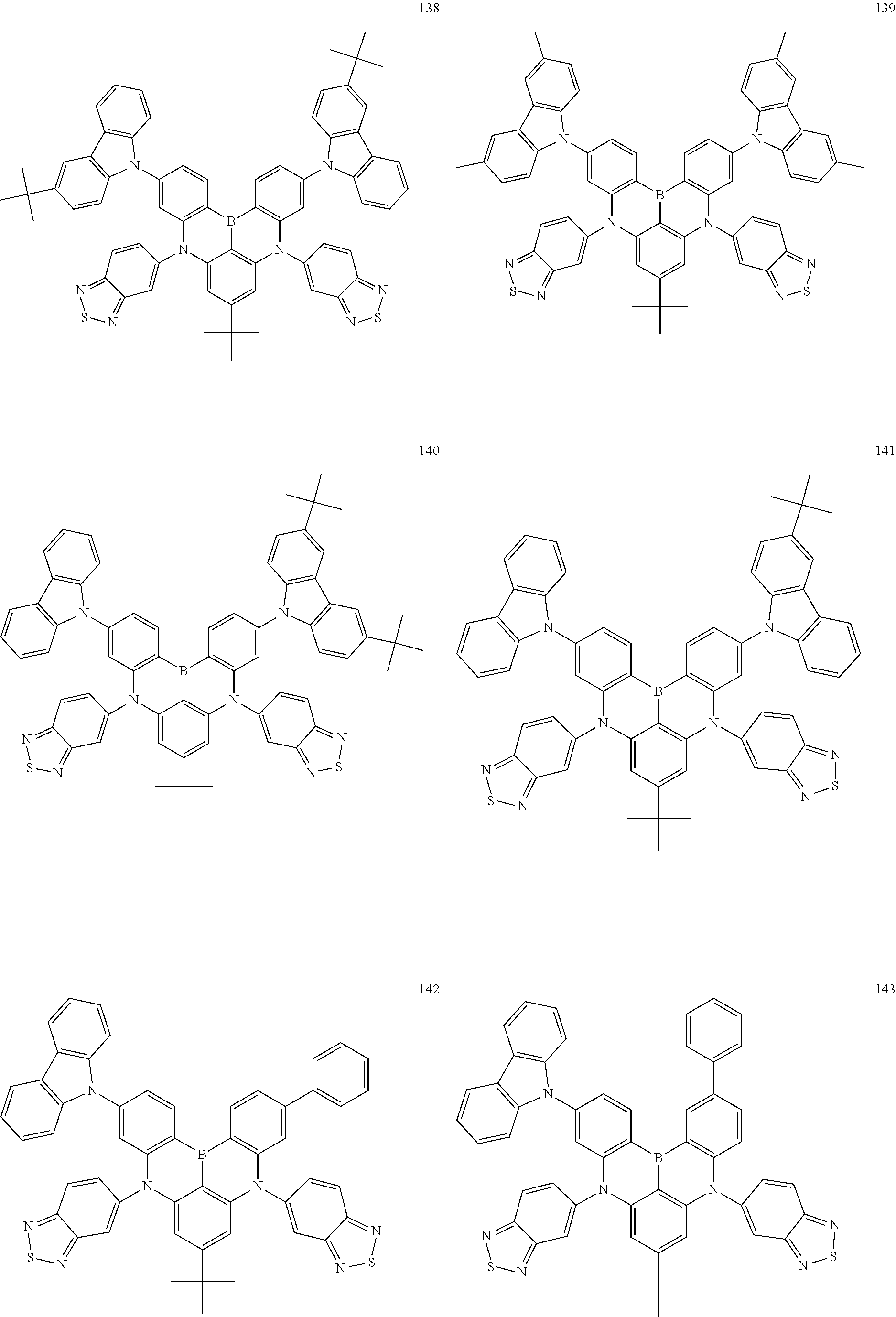 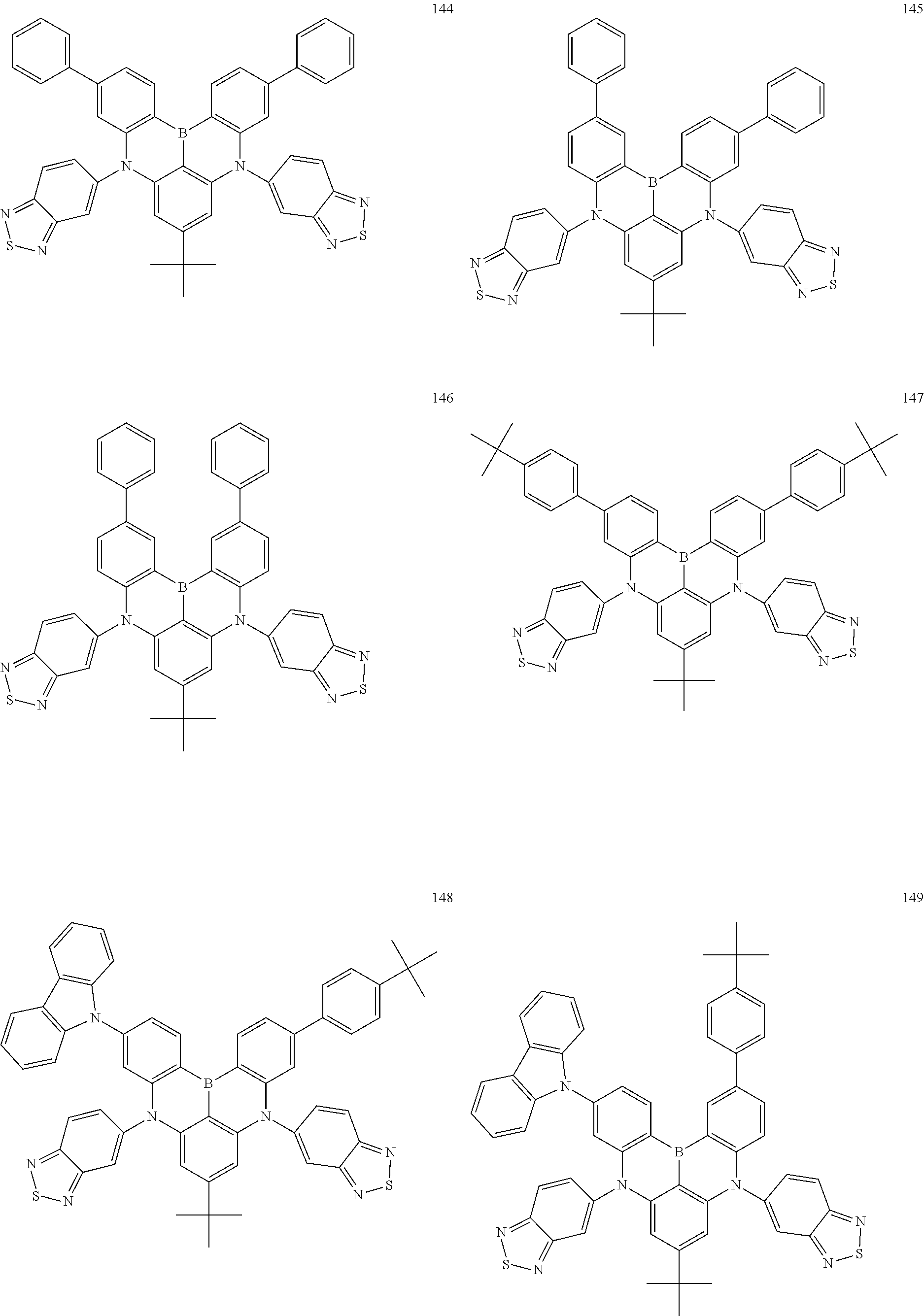 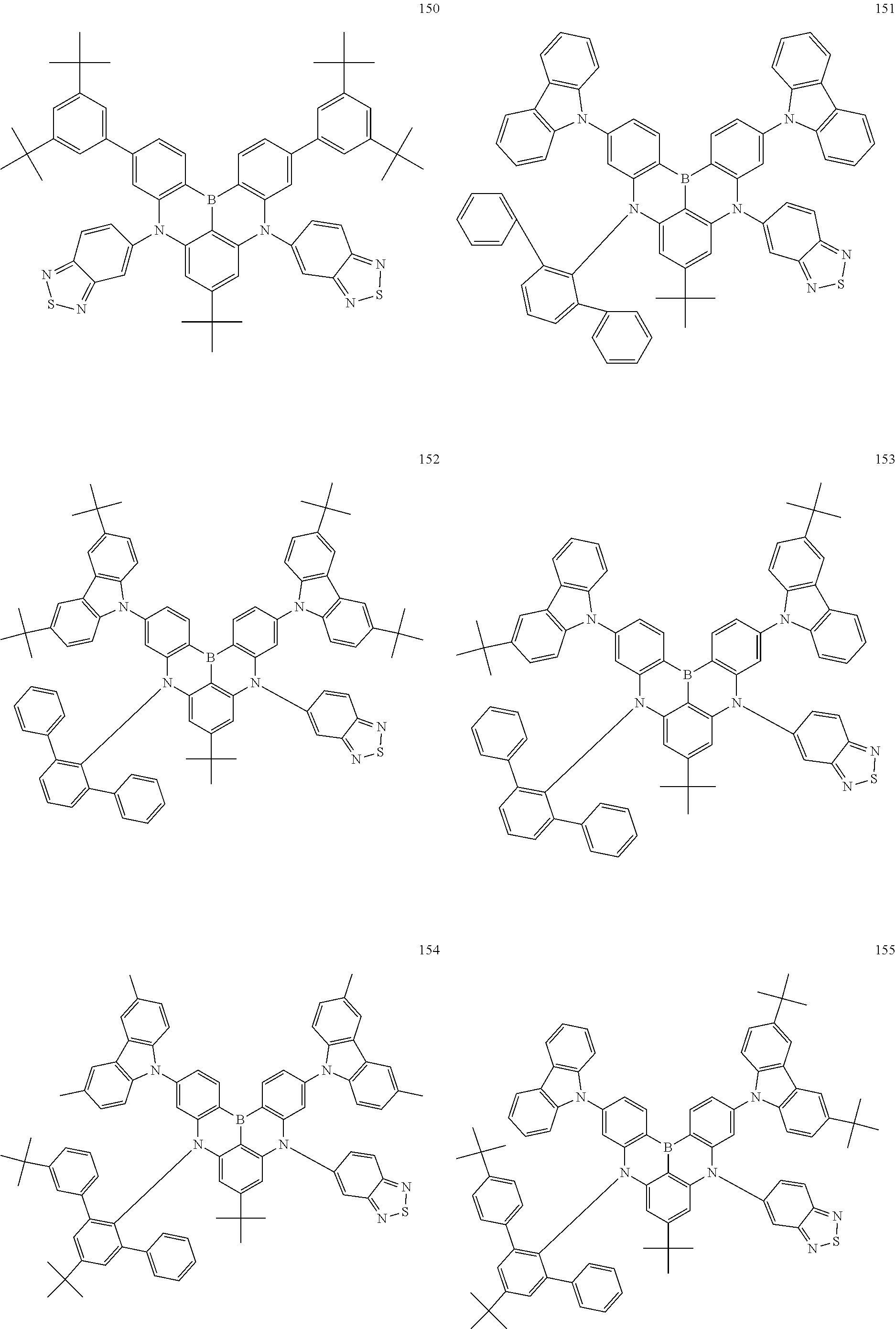 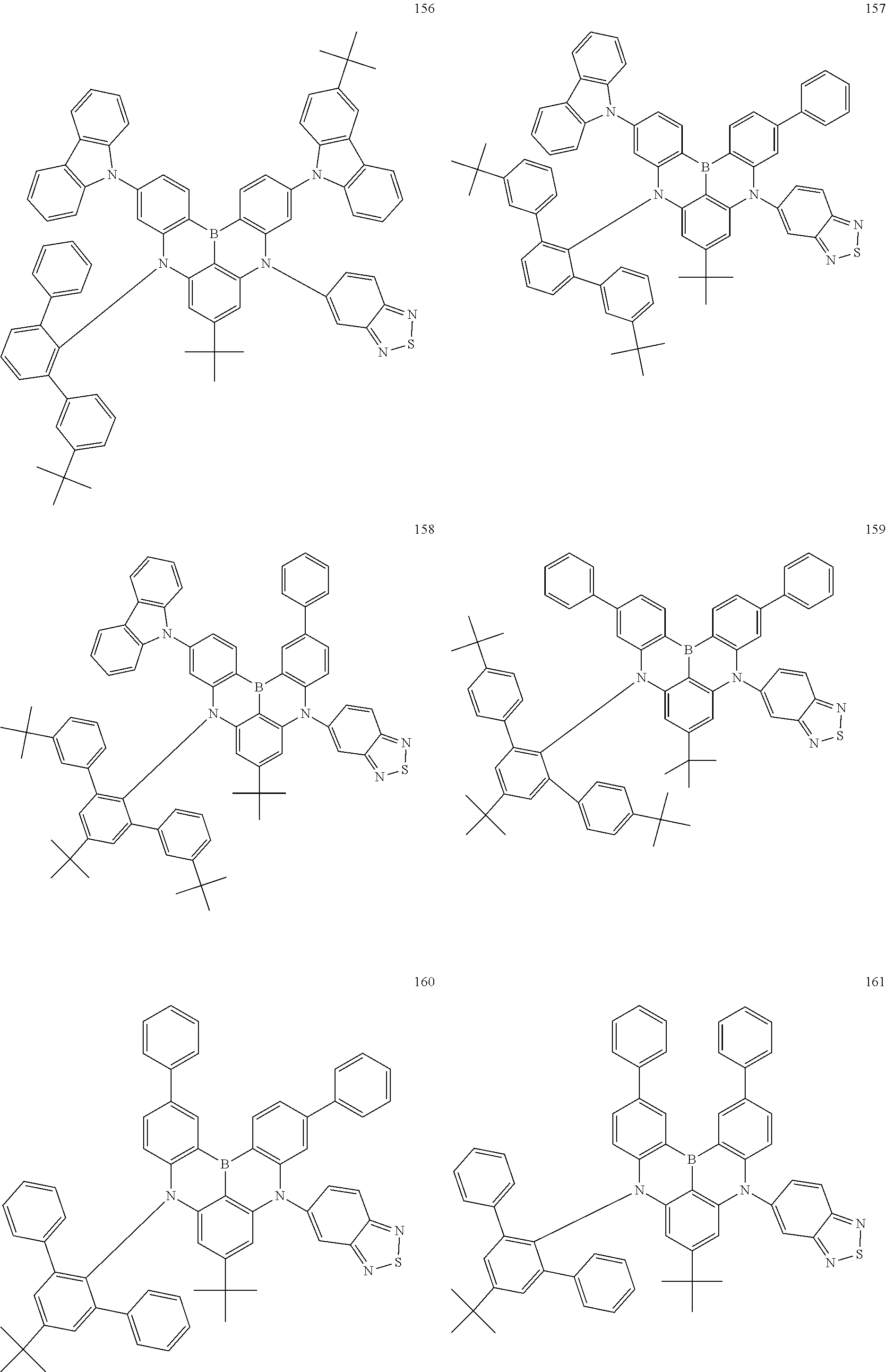 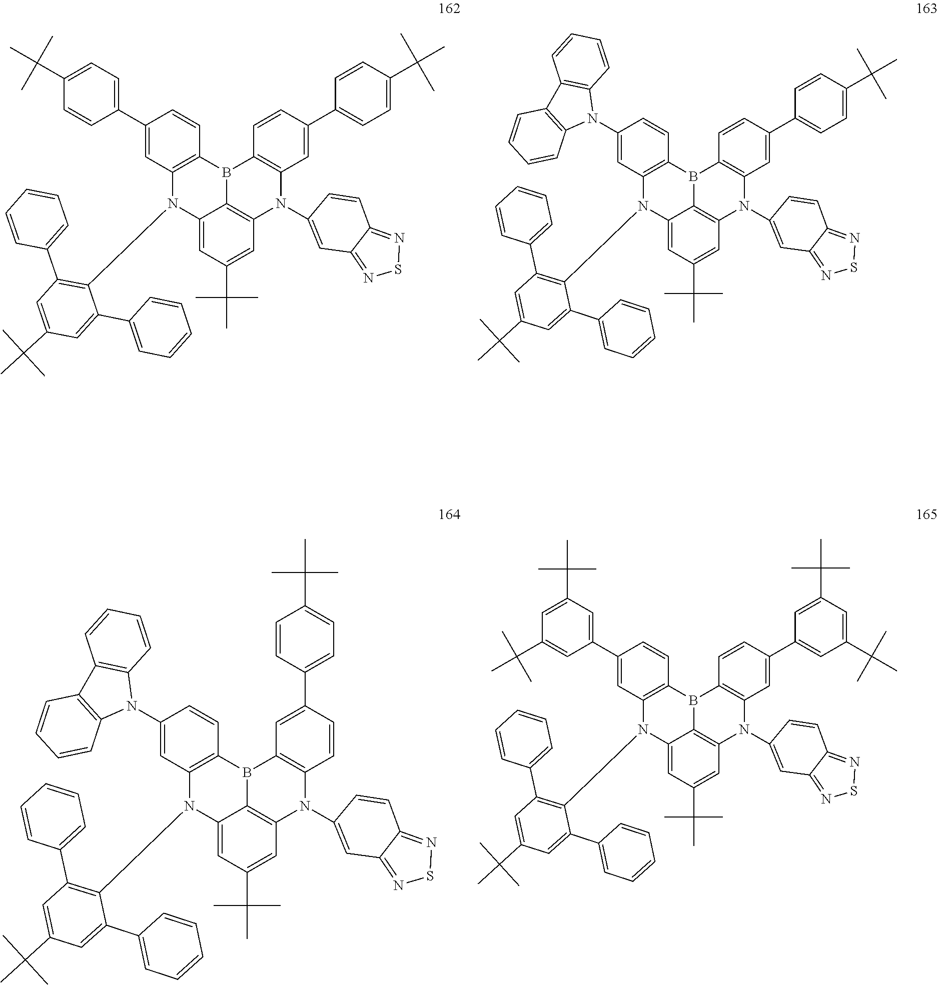 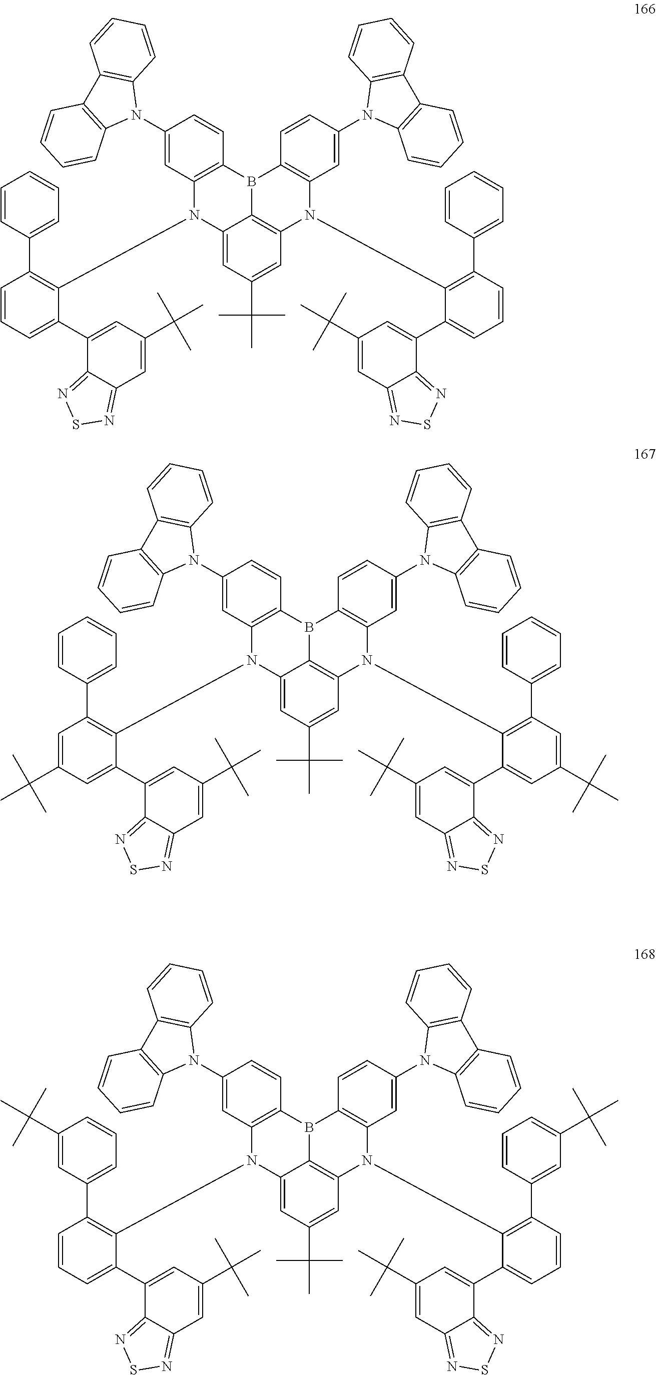 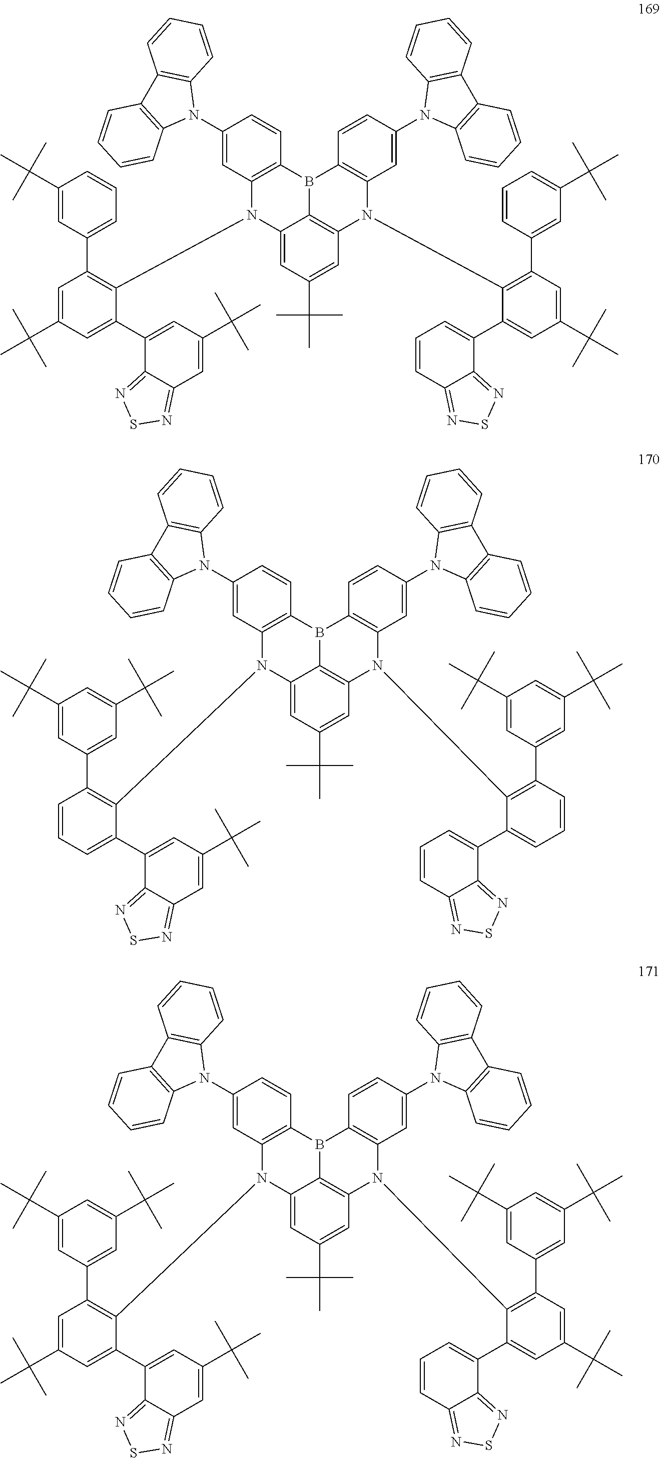 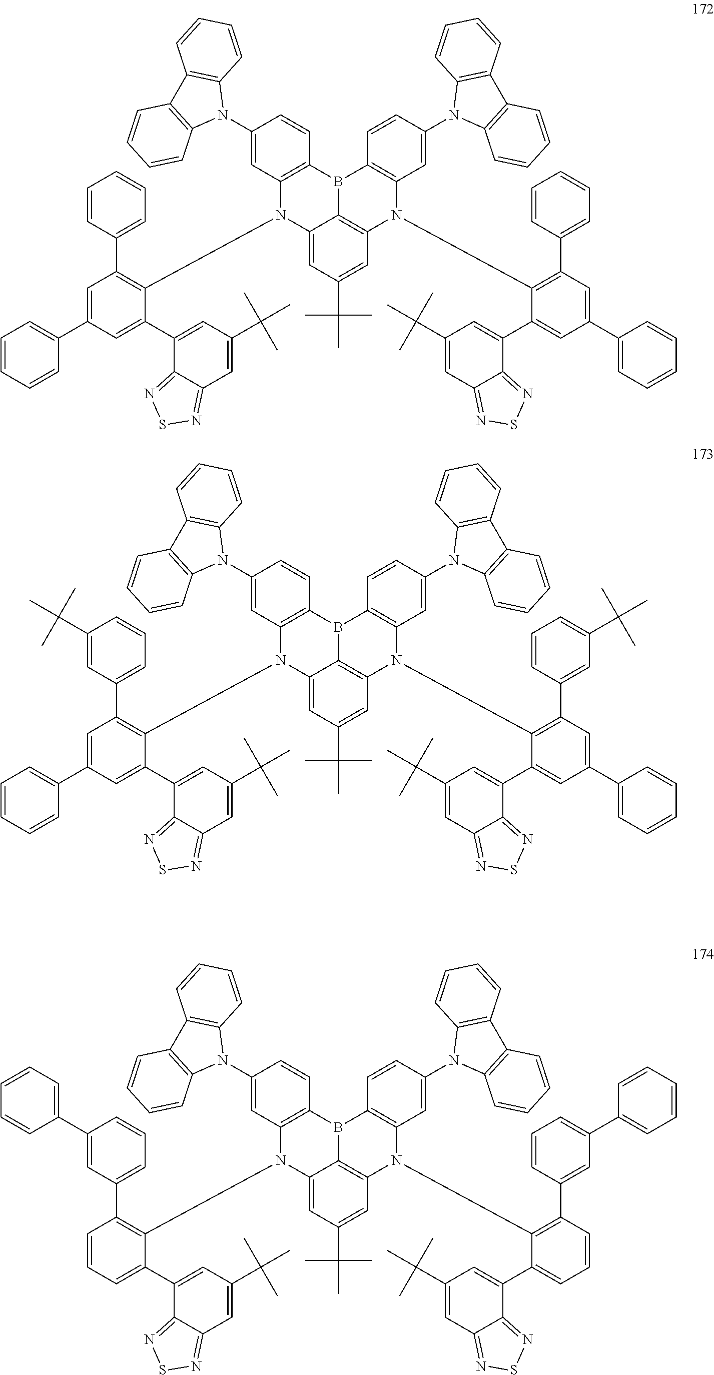 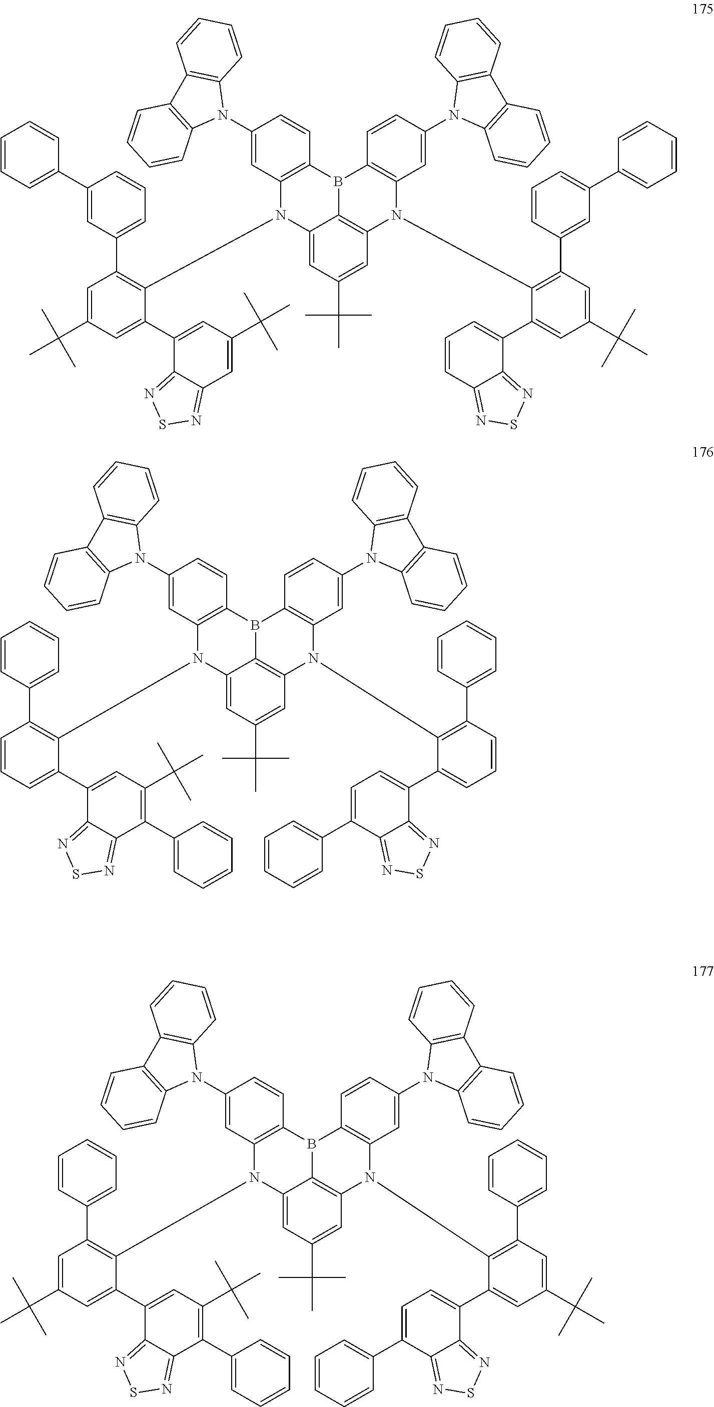 [chemical structure]
